(19) United States
(12) Patent Application Publication
(10) Pub. No.: US 2019/0352322 A1
(43) Pub. Date: Nov. 21, 2019

(54) ORGANOMETALLIC COMPOUND, ORGANIC LIGHT-EMITTING DEVICE INCLUDING THE ORGANOMETALLIC COMPOUND, DIAGNOSTIC COMPOSITION INCLUDING THE ORGANOMETALLIC COMPOUND

(71) Applicant: Samsung Electronics Co., Ltd., Suwon-si (KR)

(72) Inventors: Kyuyoung HWANG, Anyang-si (KR); Seungyeon KWAK, Suwon-si (KR); Sunyoung LEE, Seoul (KR); Jeoungin YI, Seoul (KR); Aram JEON, Suwon-si (KR); Yuri CHO, Suwon-si (KR); Seokhwan HONG, Seoul (KR); Yoonhyun KWAK, Seoul (KR); Hyeonho CHOI, Seoul (KR)

(21) Appl. No.: 16/415,435

(22) Filed: May 17, 2019

(30) Foreign Application Priority Data
May 18, 2018 (KR) 10-2018-0057436
May 16, 2019 (KR) 10-2019-0057288

(51) Int. Cl. C07F 15/00; H01L 51/00

(52) U.S. Cl. CPC C07F 15/0086; H01L 51/5016; H01L 51/0087

(57) ABSTRACT

An organometallic compound represented by Formula 1, an organic light-emitting device including the organometallic compound, and a diagnostic composition including the organometallic compound:

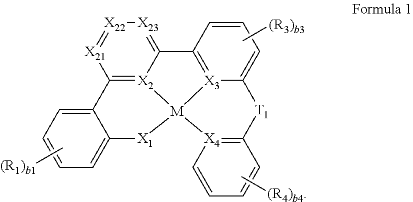

### CROSS-REFERENCE TO RELATED APPLICATION

This application claims priority to Korean Patent Applications No. 10-2018-0057436, filed on May 18, 2018, and No. 10-2019-0057288, filed on May 16, 2019, in the Korean Intellectual Property Office, and all the benefits accruing therefrom under 35 U.S.C. § 119, the contents of which in their entirety are herein incorporated by reference.

### BACKGROUND

### 1. Field

One or more embodiments relate to an organometallic compound, an organic light-emitting device including the organometallic compound, and a diagnostic composition including the organometallic compound.

### 2. Description of the Related Art

Organic light-emitting devices are self-emission devices, which have better characteristics in terms of a viewing angle, a response time, a brightness, a driving voltage, and a response speed, and produce full-color images.

In an example, an organic light-emitting device includes an anode, a cathode, and an organic layer between the anode and the cathode, wherein the organic layer includes an emission layer. A hole transport region may be between the anode and the emission layer, and an electron transport region may be between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transit from an excited state to a ground state, thereby generating light.

Luminescent compounds may be used to monitor, sense, or detect a variety of biological materials including cells and proteins. An example of the luminescent compounds includes a phosphorescent luminescent compound.

### SUMMARY

Aspects of the present disclosure provide an organometallic compound, an organic light-emitting device including the organometallic compound, and a diagnostic composition including the organometallic compound.

Additional aspects will be set forth in part in the description which follows and, in part, will be apparent from the description, or may be learned by practice of the presented embodiments.

An aspect of the present disclosure provides an organometallic compound represented by Formula 1:

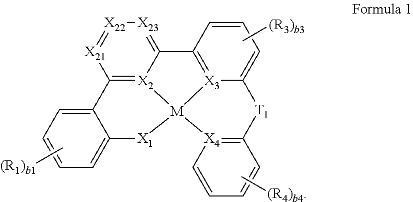

In Formula 1,

M may be beryllium (Be), magnesium (Mg), aluminum (Al), calcium (Ca), titanium (Ti), manganese (Mn), cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au),

X₁ may be O or S, and a bond between X₁ and M may be a covalent bond,

X₂ to X₄ may each independently be C or N,

a bond between X₂ and M, a bond between X₃ and M, or a bond between X₄ and M may be a covalent bond, and the others thereof may each be a coordinate bond,

X₂₁ may be N or C(R₂ₐ), X₂₂ may be N or C(R_{2b}), X₂₃ may be N or C(R_{2c}), and X₂₁, X₂₂, X₂₃, or a combination thereof may be N,

T₁ may be *—N(R₅)—*′, *—B(R₅)—*′, *—P(R₅)—*′, *—C(R₅)(R₆)—*′, *—Si(R₅)(R₆)—*′, *—Ge(R₅)(R₆)—*′, *—S—*′, *—Se—*′, *—O—*′, *—C(═O)—*′, *—S(═O)—*′, *—S(═O)₂—*′, *—C(R₅)=*′, *═C(R₅)—*′, *—C(R₅)═C(R₆)—*′, *—C(═S)—*′, or *—C≡C—*′,

R₅ and R₆ may optionally be linked via a single bond, a double bond, or a first linking group to form a C₅-C₃₀ carbocyclic group that is unsubstituted or substituted with R₁₀ₐ, a C₁-C₃₀ heterocyclic group, or a combination thereof that is unsubstituted or substituted with an R₁₀ₐ,

R₁, R₃ to R₆, and R₂ₐ to R_{2c} may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉),

b1 and b4 may each independently be 0, 1, 2, 3, or 4,

b3 may be 0, 1, 2, or 3,

two or more R₁ in the number of b1 may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ,

two or more R₂ₐ to R_{2c} may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ,

two or more R₃ in the number of b3 may optionally be linked to form a C₅-C₃₀ carbocyclic group that is unsubstituted or substituted with R₁₀ₐ, a C₁-C₃₀ heterocyclic group, or a combination thereof that is unsubstituted or substituted with an R₁₀ₐ,

two or more R₄ in the number of b4 may optionally be linked to form a C₅-C₃₀ carbocyclic group that is unsubstituted or substituted with R₁₀ₐ, a C₁-C₃₀ heterocyclic group, or a combination thereof that is unsubstituted or substituted with an R₁₀ₐ,

R₅, R₆, or R₃ may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ,

R₅, R₆, or R₄ may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ,

R₁₀ₐ may be the same as described in connection with R₁,

a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, or the substituted monovalent non-aromatic condensed heteropolycyclic group may be:

deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a combination thereof;

a C₁-C₆₀ alkyl group, a C₂-C₆₀ alkenyl group, a C₂-C₆₀ alkynyl group, a C₁-C₆₀ alkoxy group, or a combination thereof, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₂₋₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), —P(═O)(Q₁₈)(Q₁₉), or a combination thereof;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or a combination thereof, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), —P(═O)(Q₂₈)(Q₂₉), or a combination thereof;

—N(Q₃₁)(Q₃₂), —Si(Q₃₃)(Q₃₄)(Q₃₅), —B(Q₃₆)(Q₃₇), —P(═O)(Q₃₈)(Q₃₉), or a combination thereof; or

any combination thereof, and

Q₁ to Q₉, Q₁₁ to Q₁₉, Q₂₁ to Q₂₉, and Q₃₁ to Q₃₉ may each independently be hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, or a C₆-C₆₀ aryl group substituted with a C₁-C₆₀ alkyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or a combination thereof.

Another aspect of the present disclosure provides an organic light-emitting device including: a first electrode; a second electrode; and an organic layer between the first electrode and the second electrode and including an emission layer, wherein the organic layer includes the organometallic compound.

Another aspect of the present disclosure provides a diagnostic composition including the organometallic compound represented by Formula 1.

### BRIEF DESCRIPTION OF THE DRAWING

These and/or other aspects will become apparent and more readily appreciated from the following description of the embodiments, taken in conjunction with FIGURE which is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein.

Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer” or “section” discussed below could be termed a second element, component, region, layer, or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the FIGURE. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

An organometallic compound according to an embodiment is represented by Formula 1:

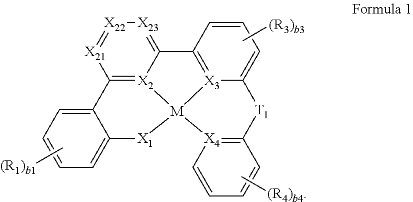

In Formula 1, M may be beryllium (Be), magnesium (Mg), aluminum (Al), calcium (Ca), titanium (Ti), manganese (Mn), cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au).

In an exemplary embodiment, M may be Pd, Pt, or Au, but embodiments of the present disclosure are not limited thereto.

In Formula 1, X₁ may be O or S, and a bond between X₁ and M may be a covalent bond.

In an exemplary embodiment, X₁ may be O, but embodiments of the present disclosure are not limited thereto.

In Formula 1, X₂ to X₄ may each independently be C or N.

In Formula 1, a bond between X₂ and M, a bond between X₃ and M, or a bond between X₄ and M may be a covalent bond, and the others thereof may each be a coordinate bond. Therefore, the organometallic compound represented by Formula 1 may be electrically neutral.

In an exemplary embodiment, in Formula 1, i) X₂ and X₄ may each independently be N, X₃ may be C, a bond between X₂ and M and a bond between X₄ and M may each be a coordinate bond, and a bond between X₃ and M may be a covalent bond, or ii) X₂ may be C, X₃ and X₄ may each independently be N, a bond between X₂ and M may be a covalent bond, and a bond between X₃ and M and a bond between X₄ and M may each be a coordinate bond, but embodiments of the present disclosure are not limited thereto.

In Formula 1, X₂₁ may be N or C(R₂ₐ), X₂₂ may be N or C(R_{2b}), X₂₃ may be N or C(R_{2c}), and X₂₁, X₂₂, X₂₃, or a combination thereof may be N.

In an exemplary embodiment, one or two of X₂₁ to X₂₃ may be N.

In one embodiment, in Formula 1, X₂₁ may be N, X₂₂ may be C(R_{2b}), and X₂₃ may be C(R_{2c}); or X₂₁ may be N, X₂₂ may be C(R_{2b}), and X₂₃ may be N, but embodiments of the present disclosure are not limited thereto.

In Formula 1, Ti may be *—N(R₅)—*′, *—B(R₅)—*′, *—P(R₅)—*′, *—C(R₅)(R₆)—*′, *—Si(R₅)(R₆)—*′, *—Ge(R₅)(R₆)—*′, *—S—*′, *—Se—*′, *—O—*′, *—C(═O)—*′, *—S(═O)—*′, *—S(═O)₂—*′, *—C(R₅)=*′, *═C(R₅)—*′, *—C(R₅)═C(R₆)—*′, *—C(═S)—*′, or *—C≡C—*′. R₅ and R₆ may each independently be the same as described herein. R₅ and R₆ may optionally be linked via a single bond, a double bond, or a first linking group to form a C₅-C₃₀ carbocyclic group that is unsubstituted or substituted with R₁₀ₐ, a C₁-C₃₀ heterocyclic group, or a combination thereof that is unsubstituted or substituted with an R₁₀ₐ (for example, a fluorene group, a xanthene group, or an acridine group, each unsubstituted or substitute with an R₁₀ₐ). R₁₀ₐ may be the same as described in connection with R₁.

The first linking group may be *—N(R₇)—*′, *—B(R₇)—*′, *—P(R₇)—*′, *—C(R₇)(R₅)—*′, *—Si(R₇)(R₈)—*′, *—Ge(R₇)(R₈)—*′, *—S—*′, *—Se—*′, *—O—*′, *—C(═O)—*′, *—S(═O)—*′, *—S(═O)₂—*′, *—C(R₇)=*′, *═C(R₇)—*′, *—C(R₇)═C(R)—*′, *—C(═S)—*′, or *—C≡C—*′, R₇ and R₈ may each independently be the same as described in connection with R₁, and * and *′ each indicate a binding site to a neighboring atom.

In one embodiment, T₁ may be *—N(R₅)—*′, *—C(R₅)(R₆)—*′, *—Si(R₅)(R₆)—*′, *—S—*′, or *—O—*′, but embodiments of the present disclosure are not limited thereto.

R₁, R₃ to R₆, and R₂ₐ to R_{2c} may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₁₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉), and Q₁ to Q₉ are the same as described above.

In an exemplary embodiment, R₁, R₃ to R₆, and R₂ₐ to R_{2c} may each independently be:

hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;

a C₁-C₂₀ alkyl group or a C₁-C₂₀ alkoxy group, each substituted with —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cycloctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[1.1.1]octyl group, a phenyl group, a biphenyl group, a terphenyl group, a naphthyl group, a pyridinyl group, a pyrimidinyl group, or a combination thereof;

a cyclopentyl group, a cyclohexyl group, a cycloheptyl group, a cycloctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[1.1.1]octyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each unsubstituted or substituted with —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cycloctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[1.1.1]octyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —Si(Q₃₃)(Q₃₄)(Q₃₅), or a combination thereof; or

—N(Q₁)(Q₂), —Si(Q₃)(Q₄)(Q₅), —B(Q₆)(Q₇), or —P(═O)(Q₅)(Q₉), and

Q₁ to Q₉ and Q₃₃ to Q₃₅ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, and a naphthyl group, each unsubstituted or substituted with a C₁-C₁₀ alkyl group, a phenyl group, or a combination thereof, but embodiments of the present disclosure are not limited thereto.

In one embodiment, R₁, R₃ to R₆, and R₂ₐ to R_{2c} may each independently be hydrogen, deuterium, —F, a cyano group, a nitro group, —SF₅, —CH₃, —CD₃, —CD₂H, —CDH₂, —CF₃, —CF₂H, —CFH₂, groups represented by Formulae 9-1 to 9-66, groups represented by Formulae 9-1 to 9-66 in which a hydrogen is substituted with deuterium, groups represented by Formulae 10-1 to 10-249, groups represented by Formulae 10-1 to 10-249 in which a hydrogen is substituted with deuterium, or —Si(Q₃)(Q₄)(Q₅) (wherein Q₃ to Q₅ are the same as described above), but embodiments of the present disclosure are not limited thereto:

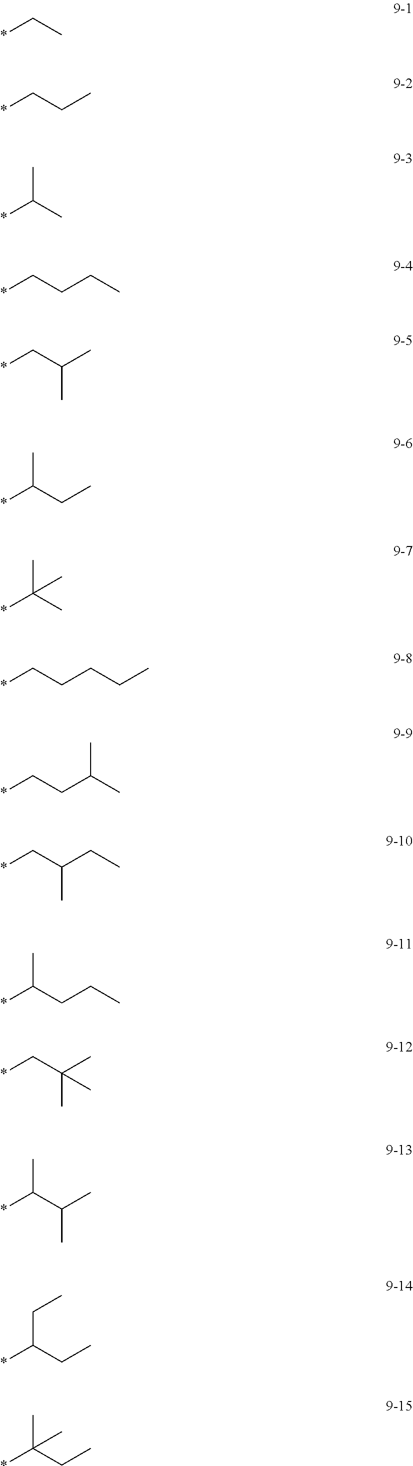

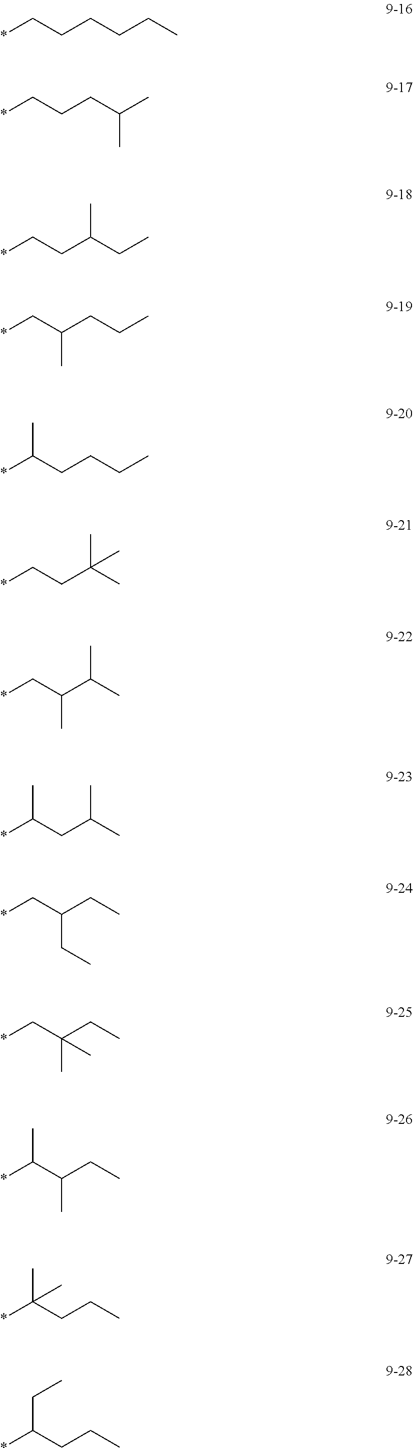

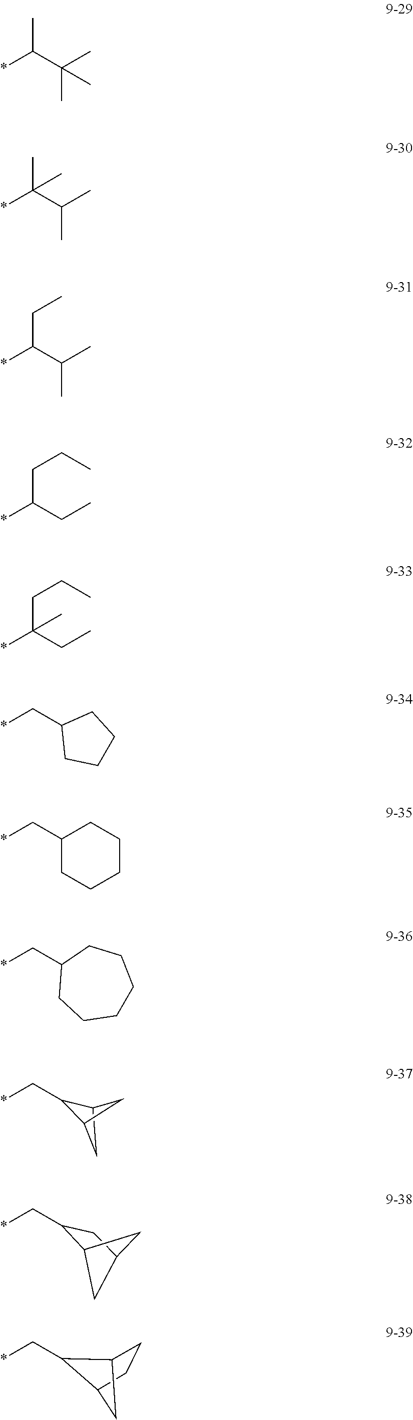

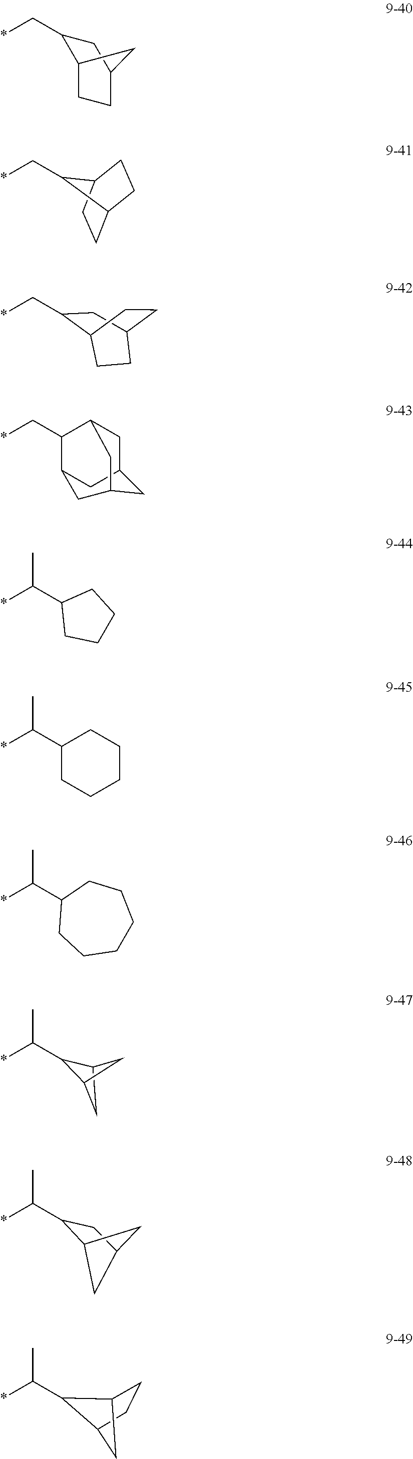

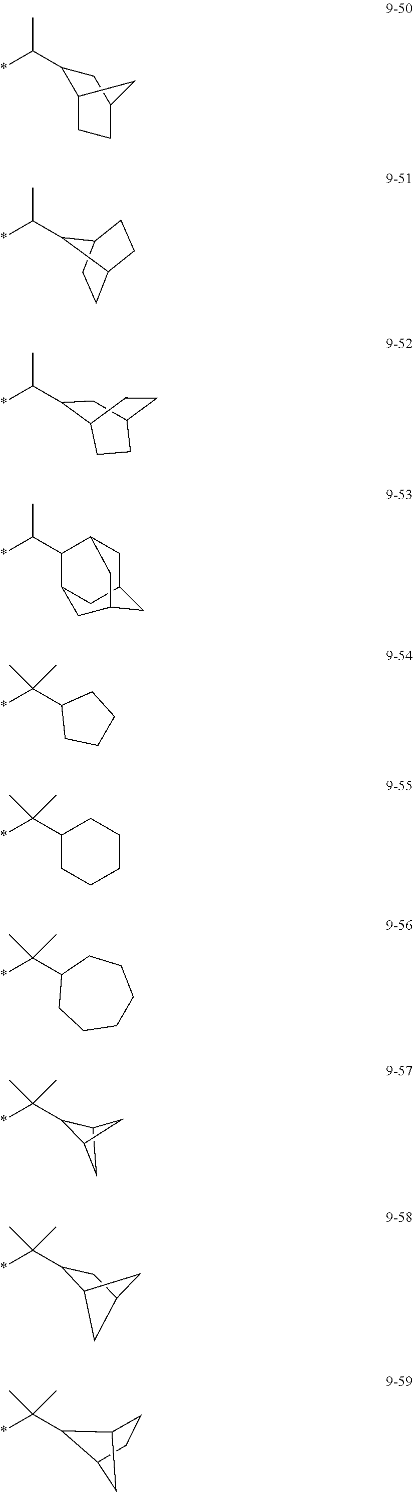

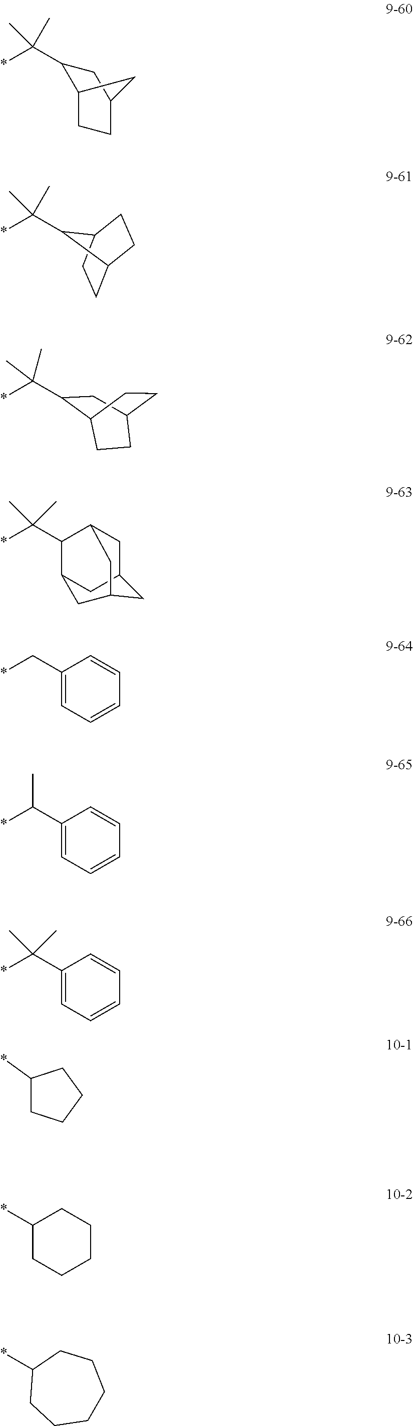

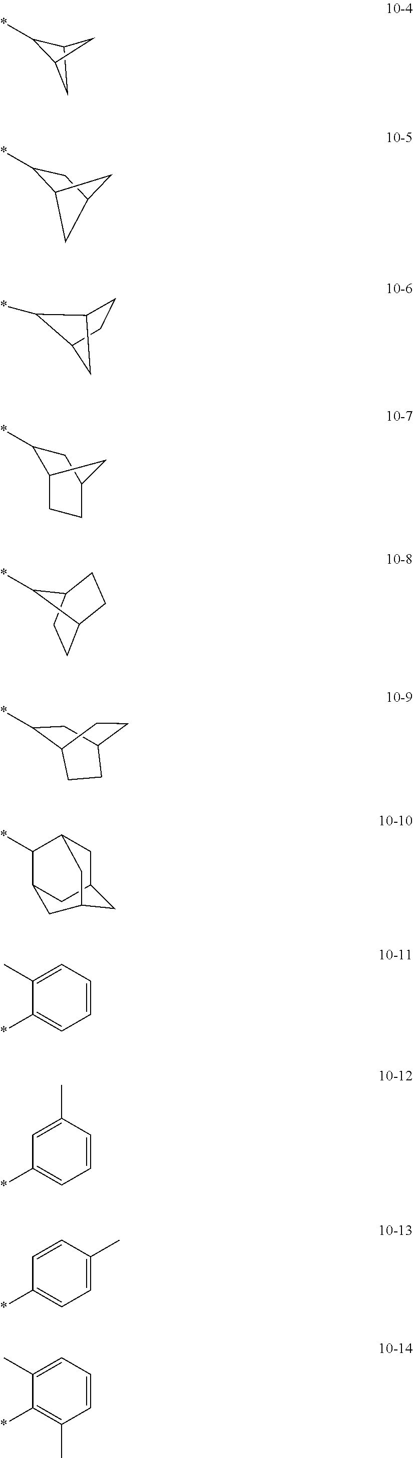

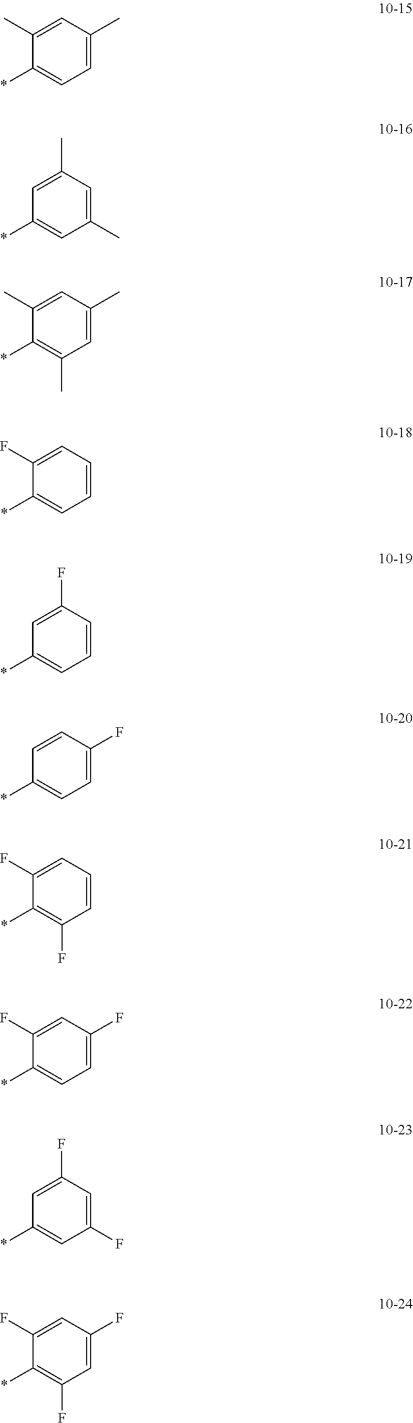

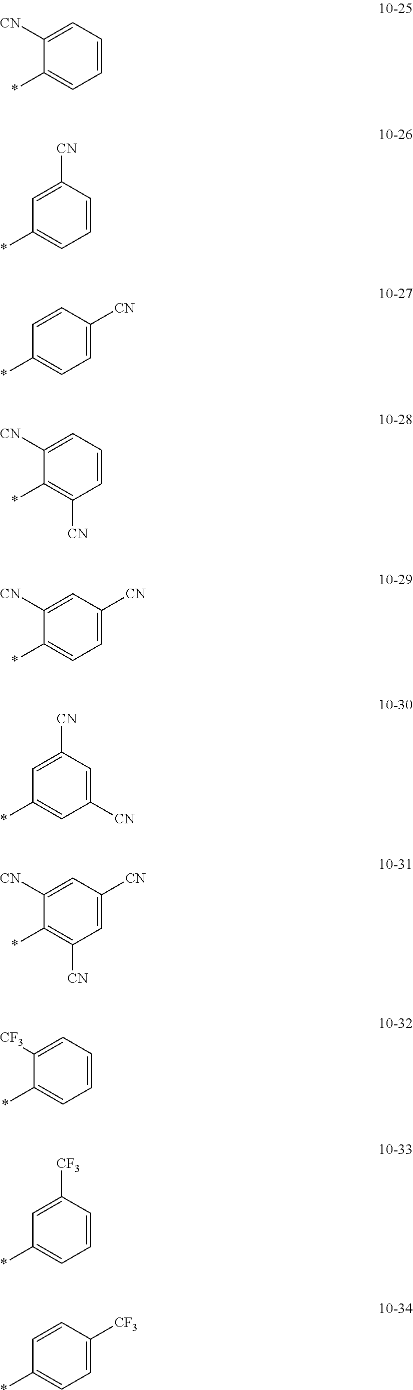

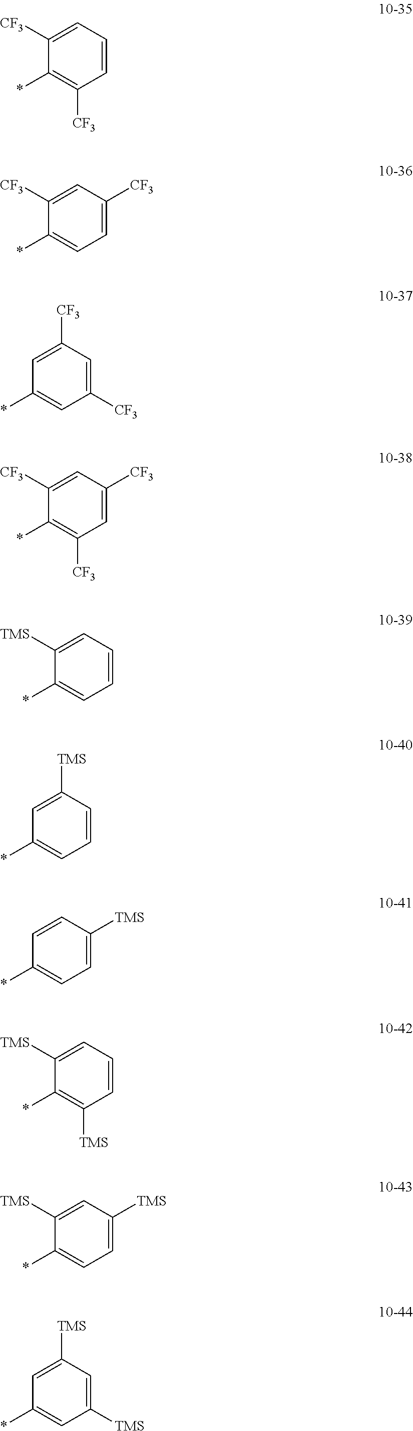

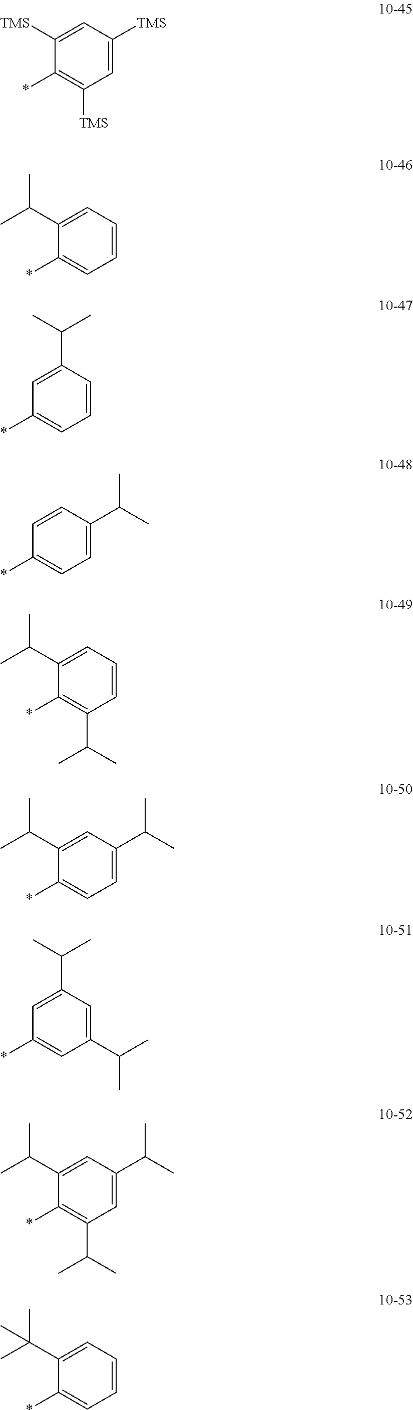

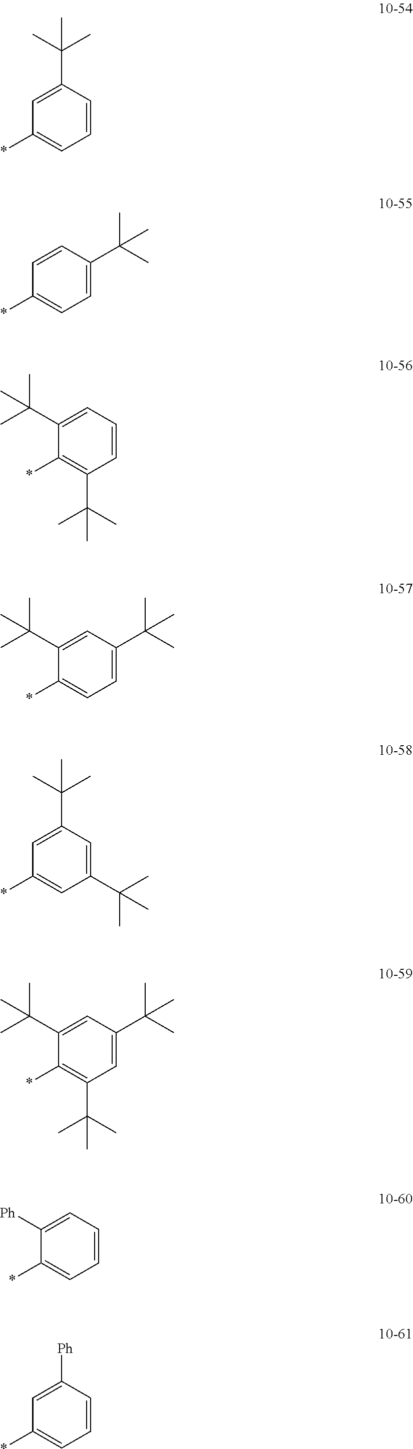

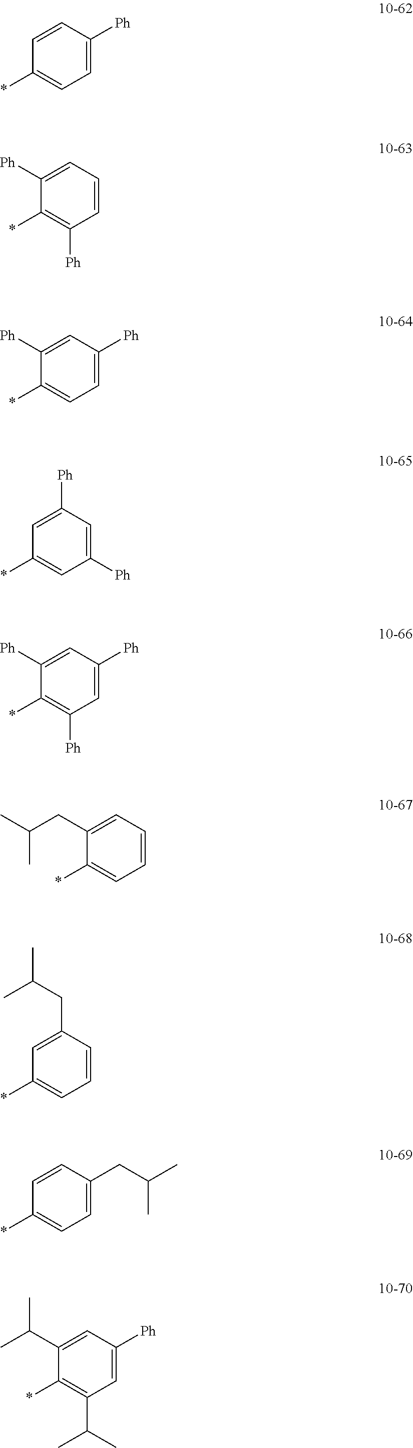

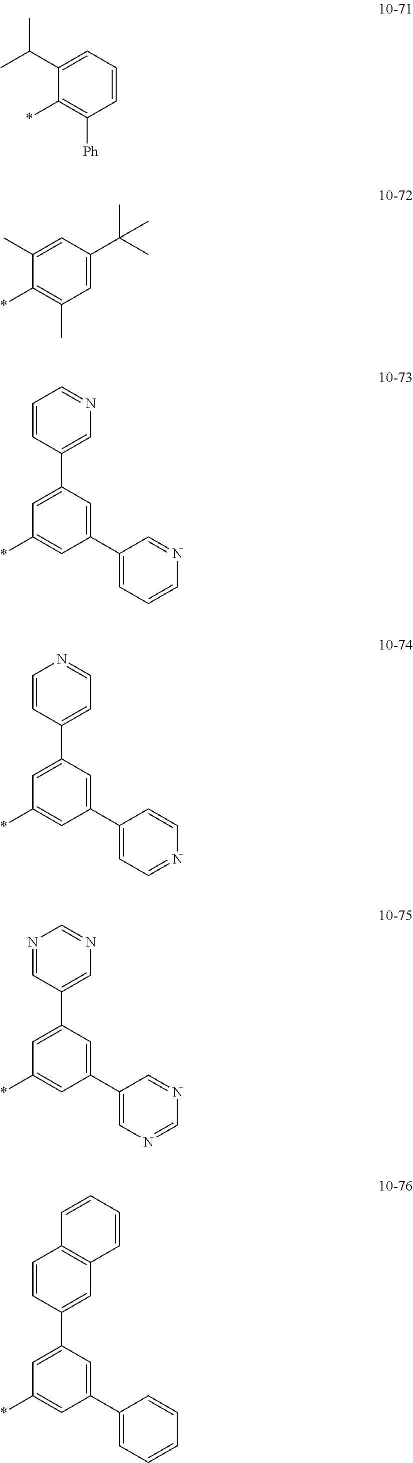 [SMILES: *c1c(-c2ccccc2)cccc1C(C)C ; *c1c(C)cc(C(C)(C)C)cc1C ; *c1cc(-c2cccnc2)cc(-c2cccnc2)c1 ; *c1cc(-c2ccncc2)cc(-c2ccncc2)c1 ; *c1cc(-c2cncnc2)cc(-c2cncnc2)c1 ; *c1cc(-c2ccccc2)cc(-c2ccc3ccccc3c2)c1]

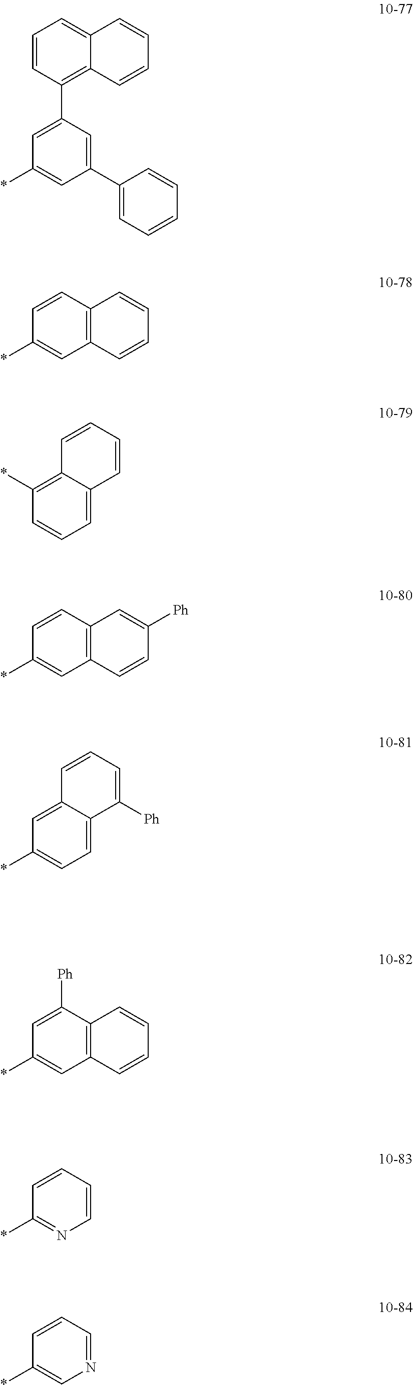

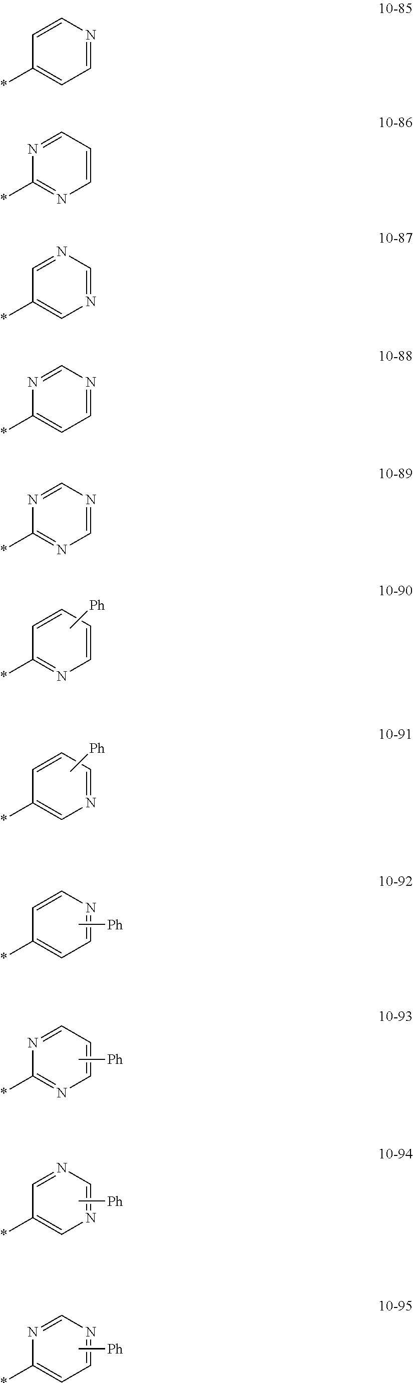

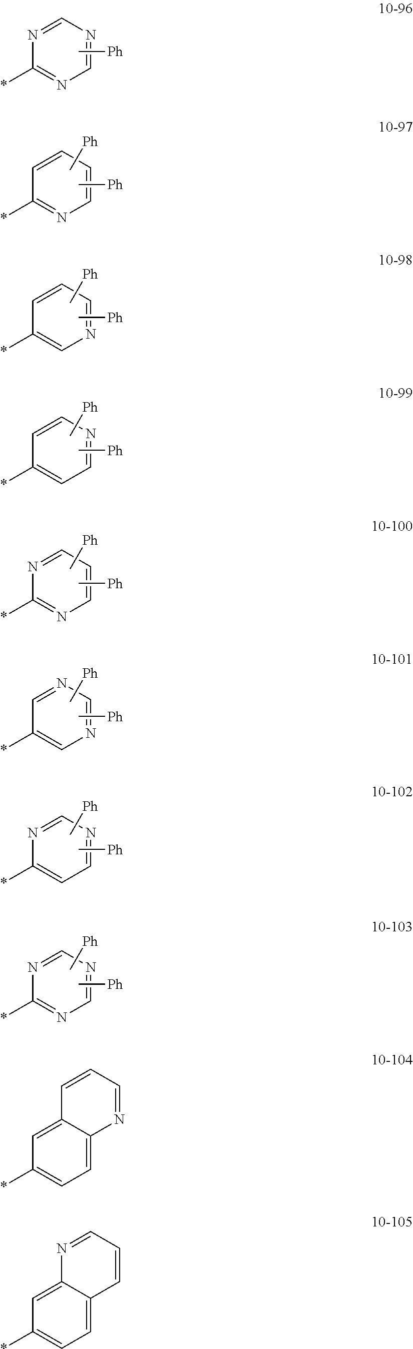

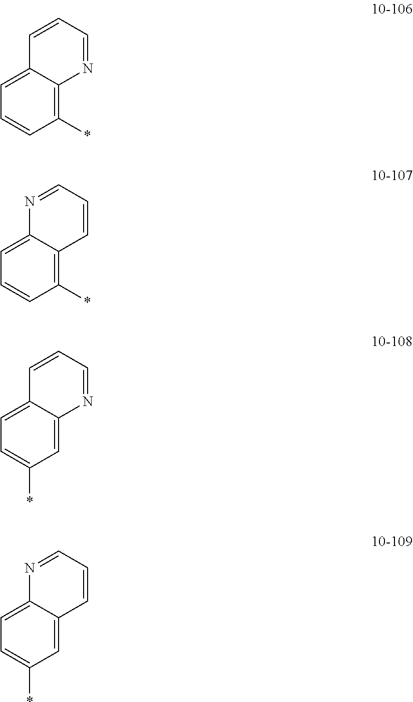 [SMILES: *c1cccc2cccnc12 ; *c1cccc2ncccc12 ; *c1ccc2cccnc2c1 ; *c1ccc2ncccc2c1]

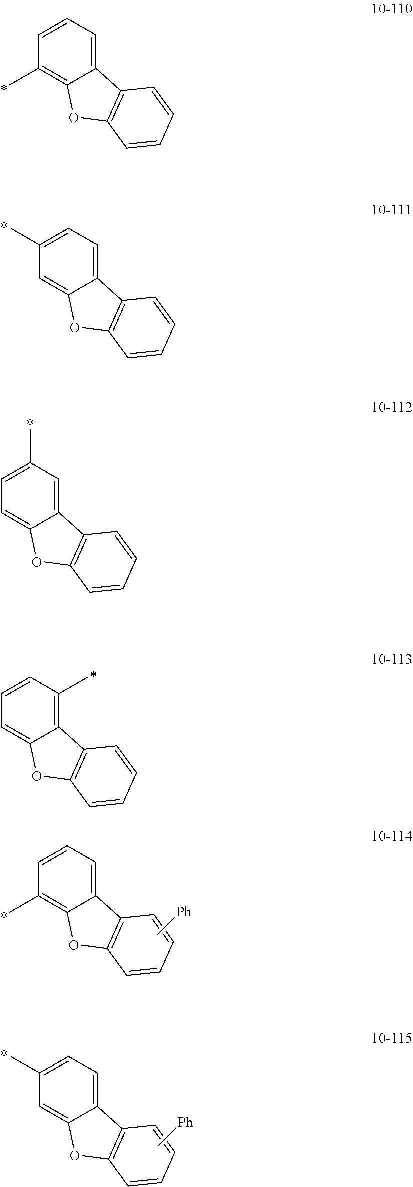

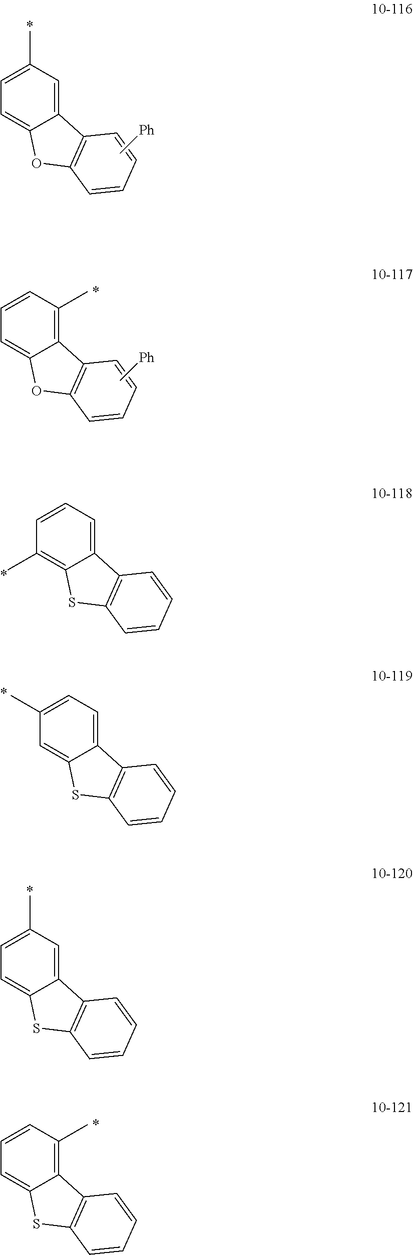

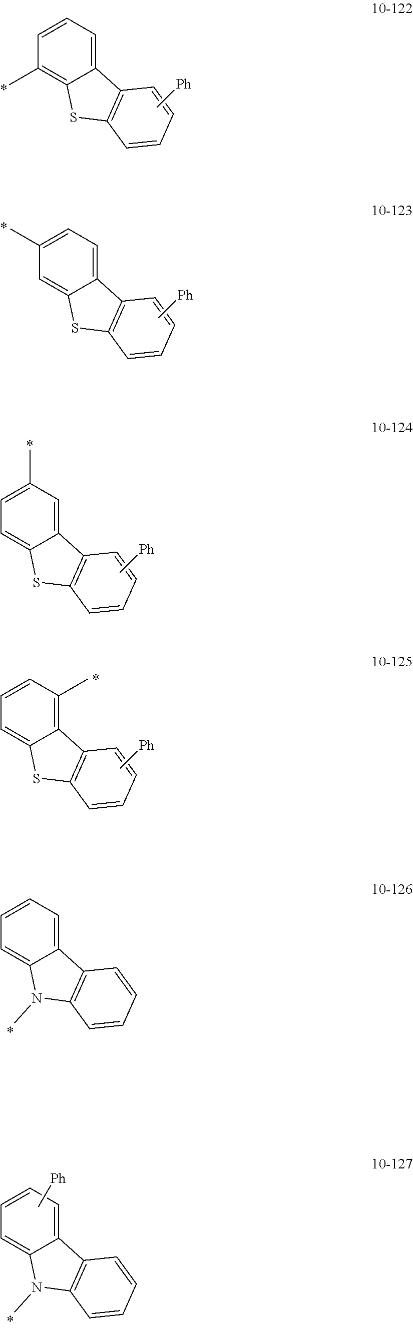

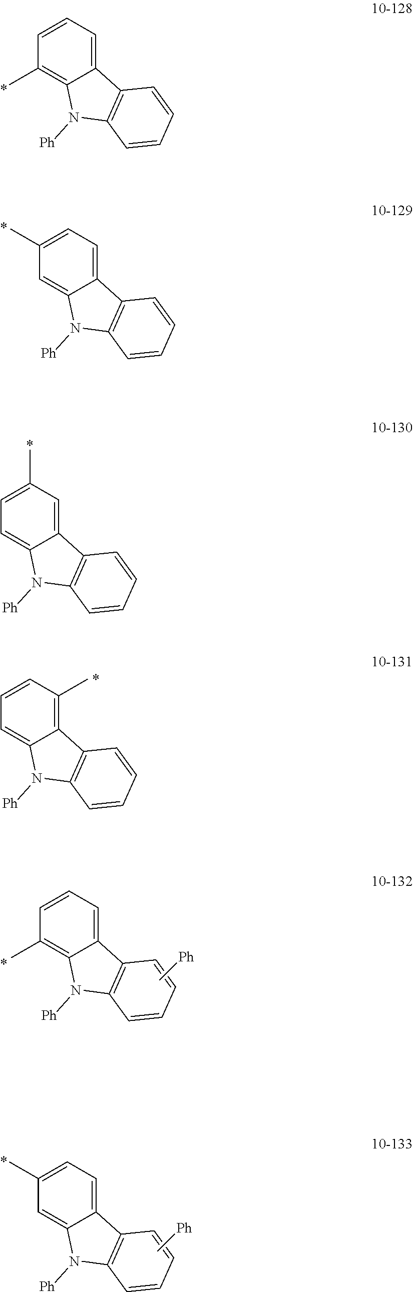

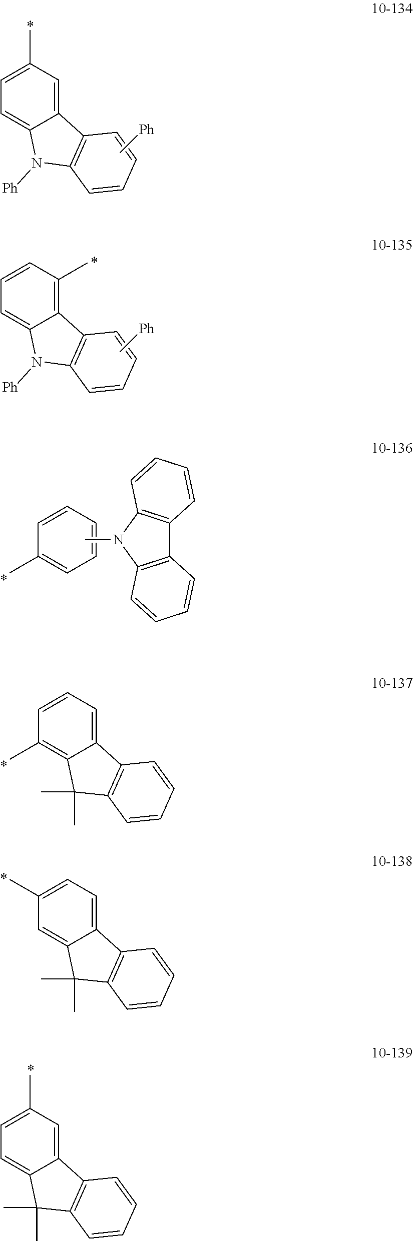

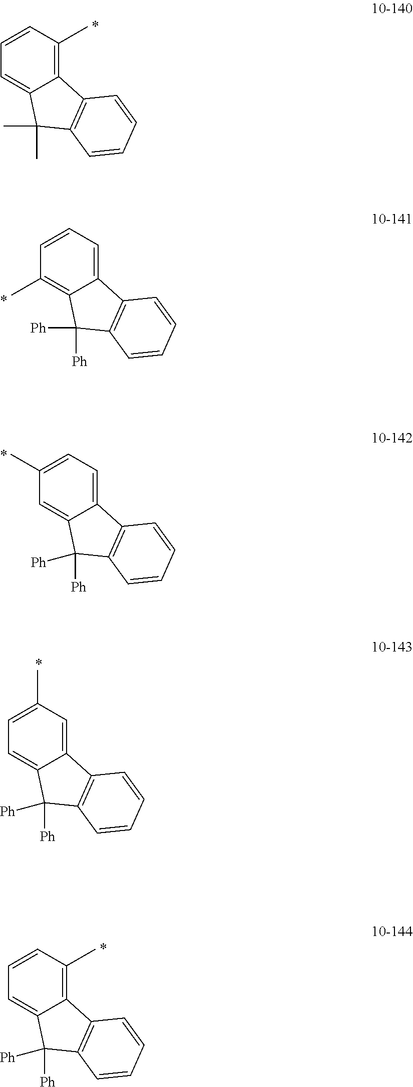

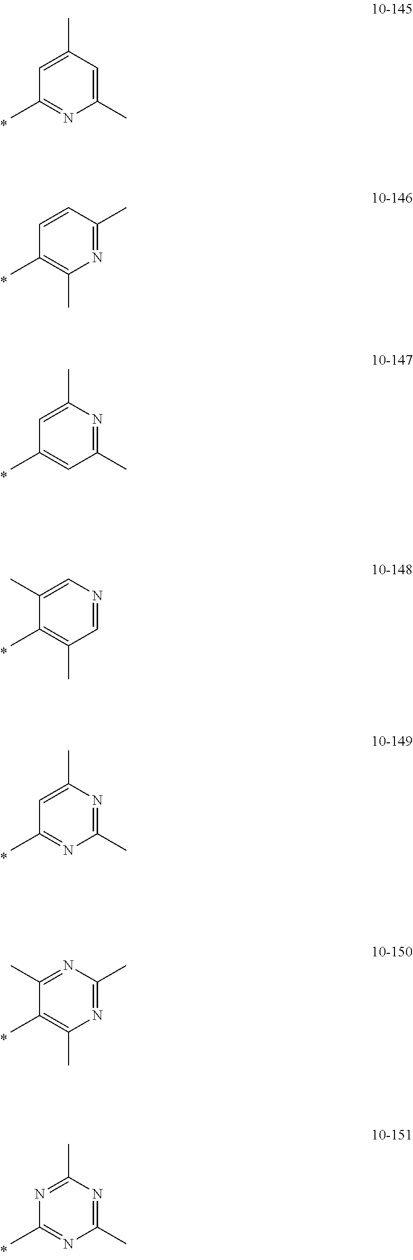

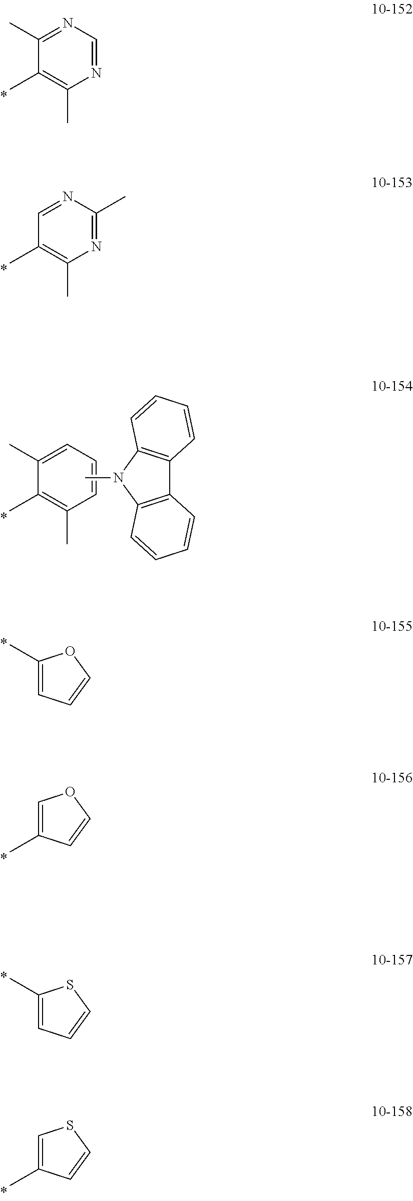

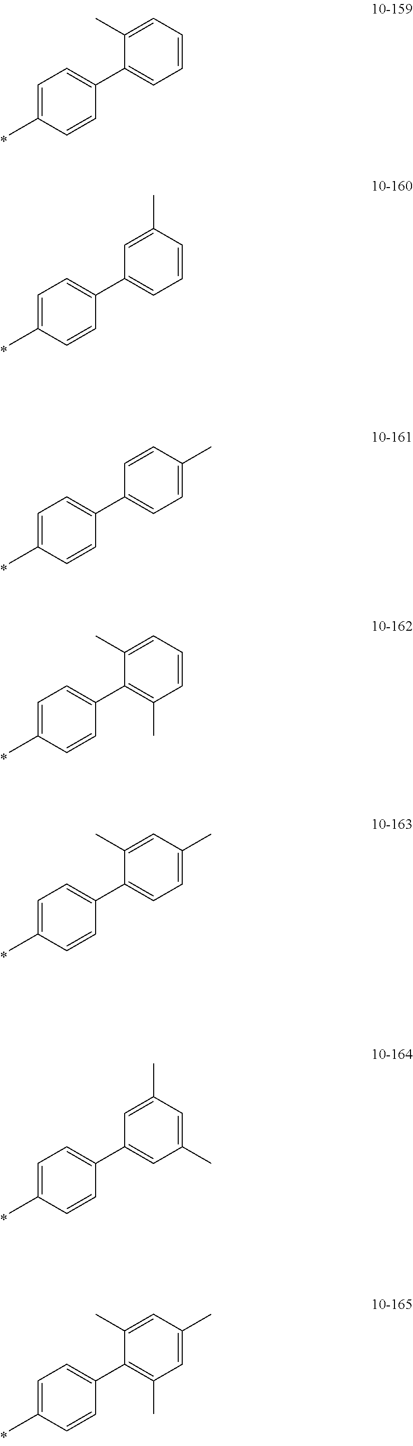

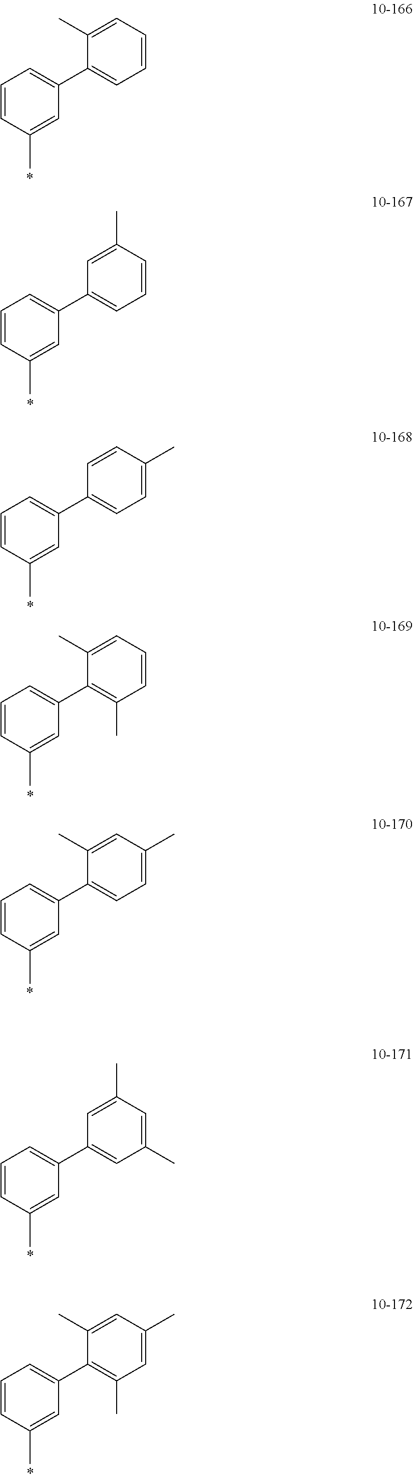

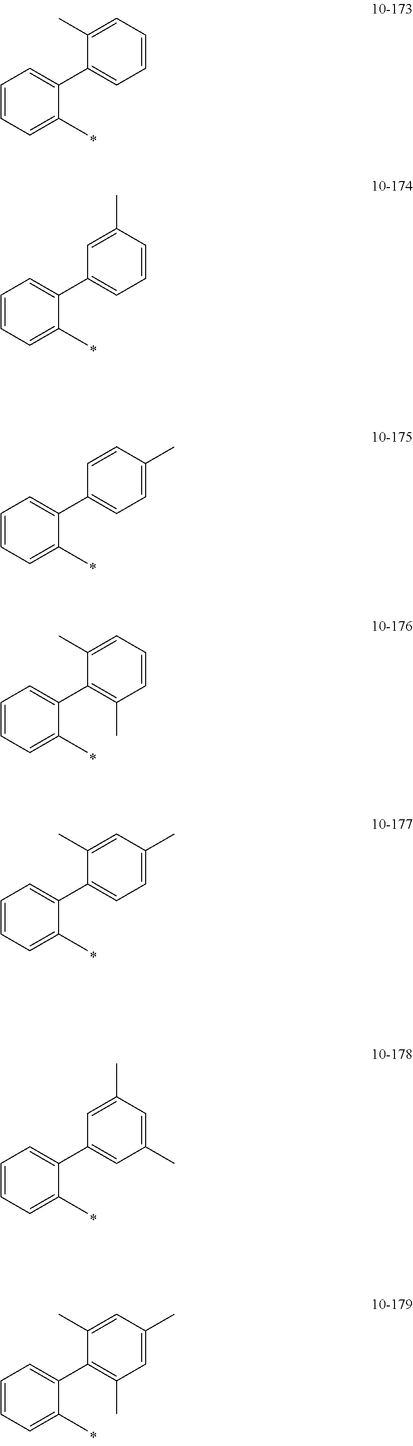

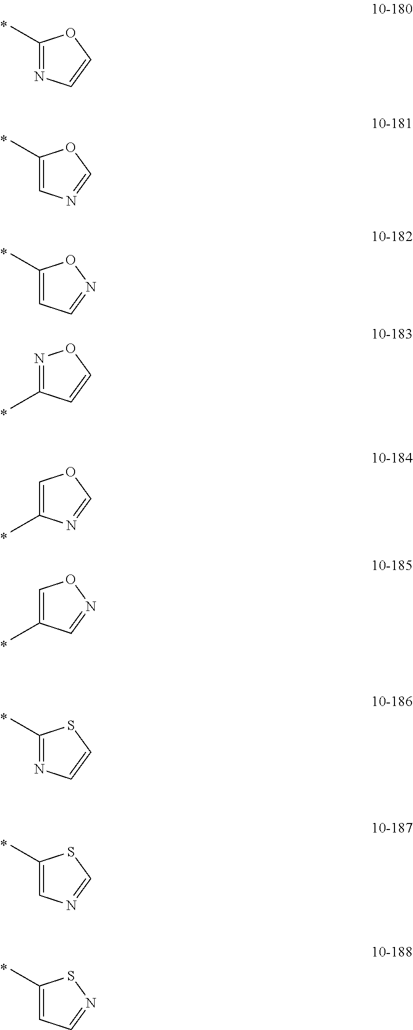

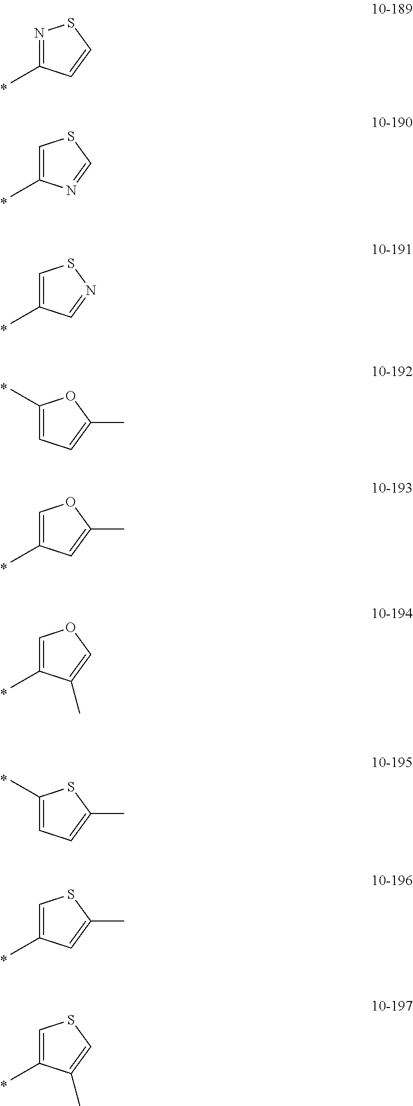

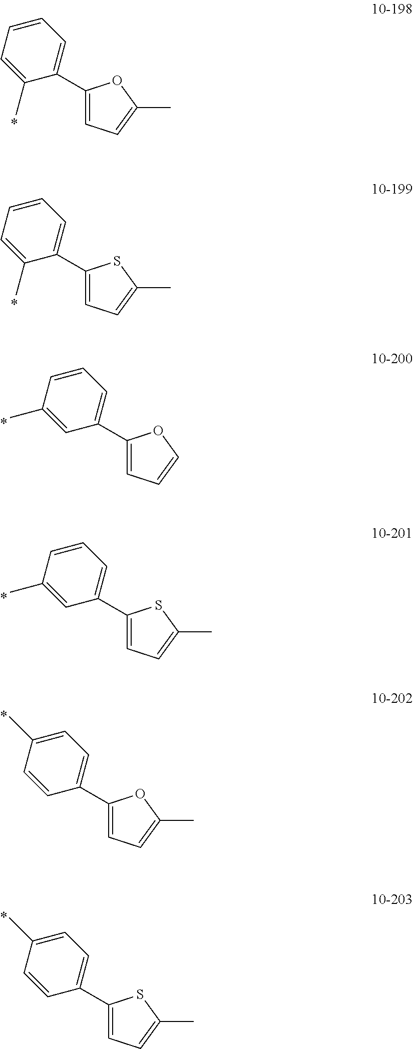

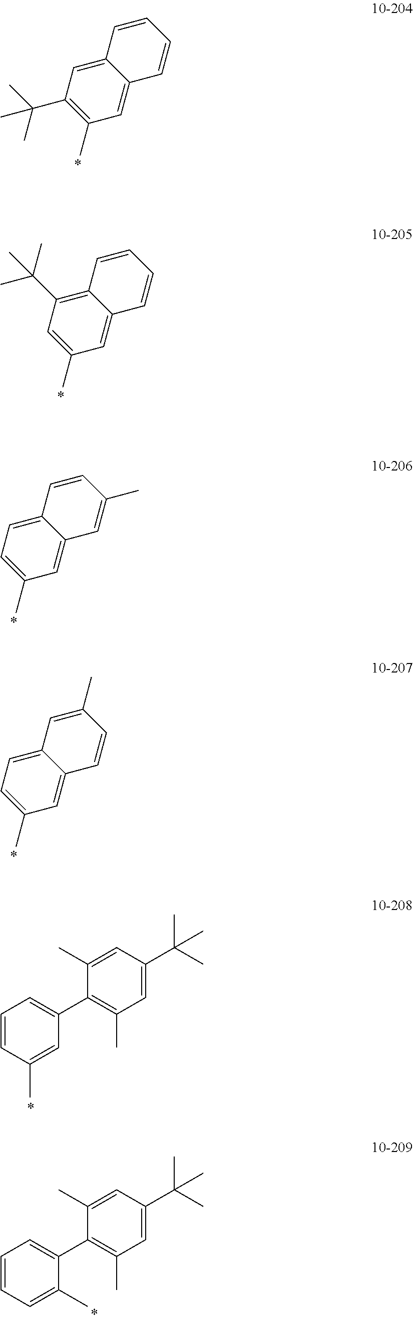

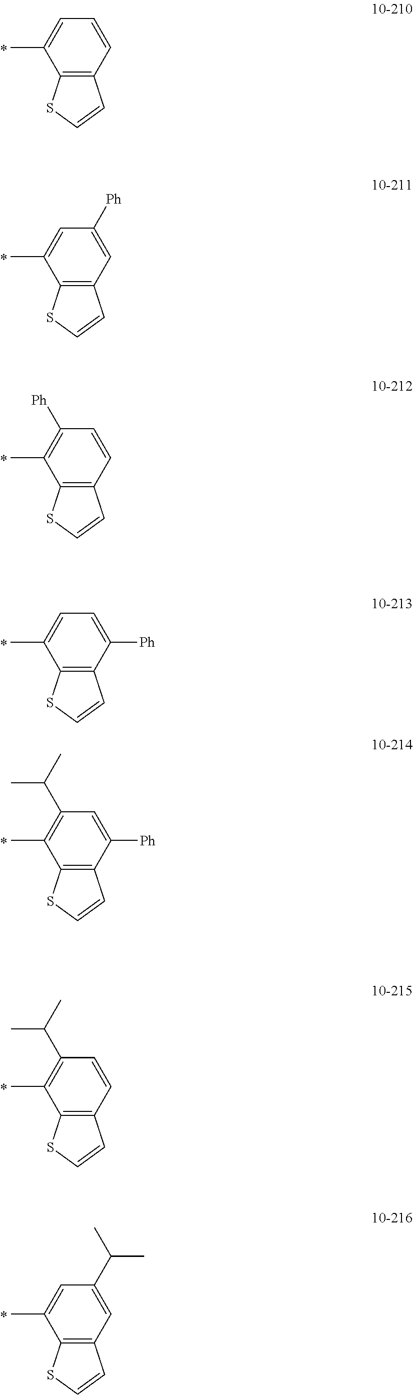

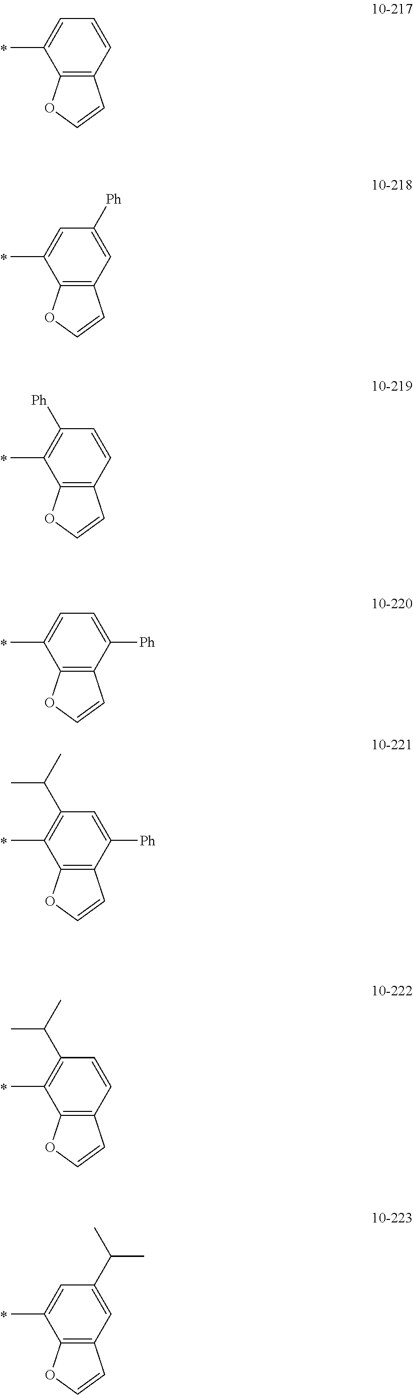

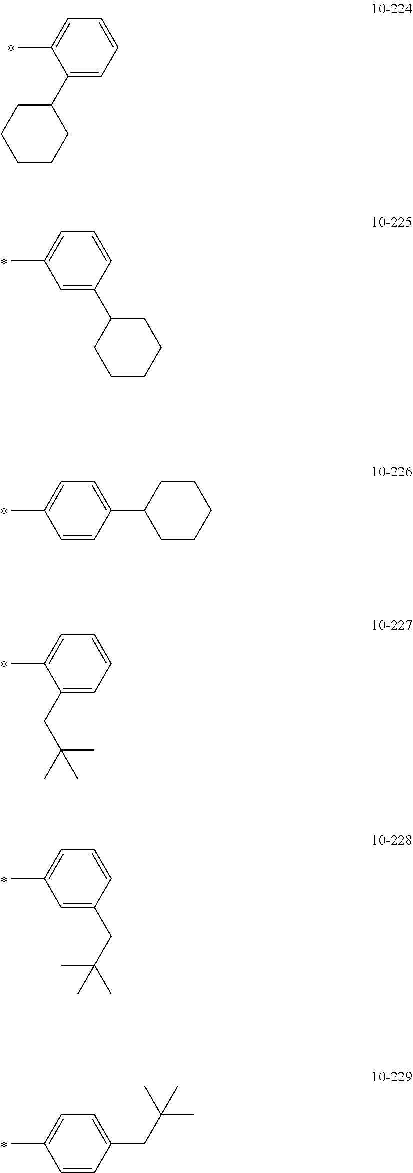

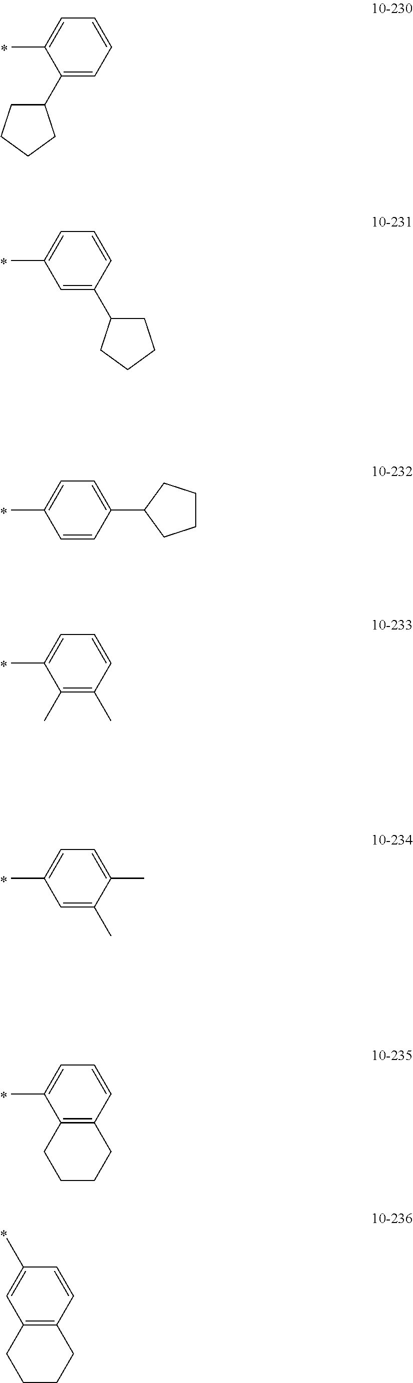

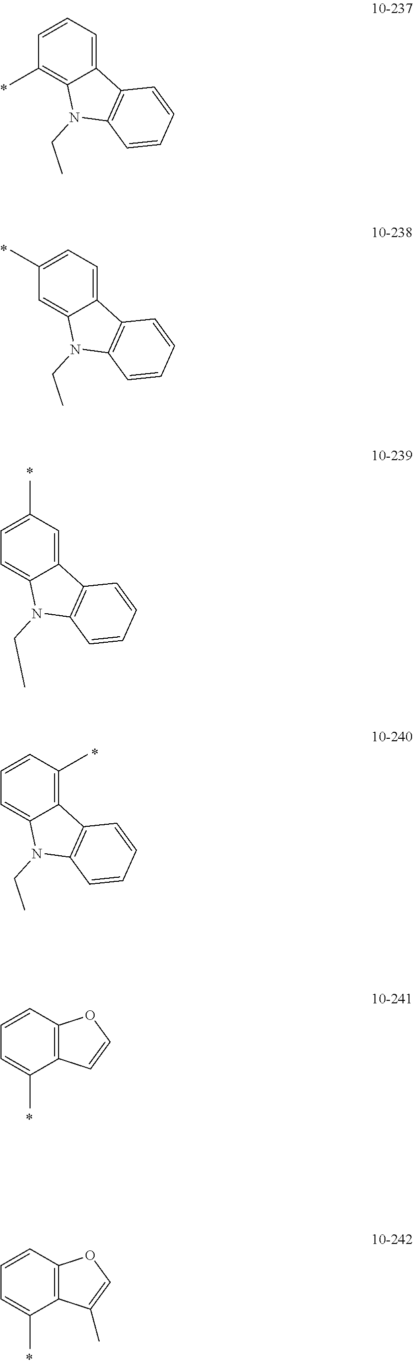

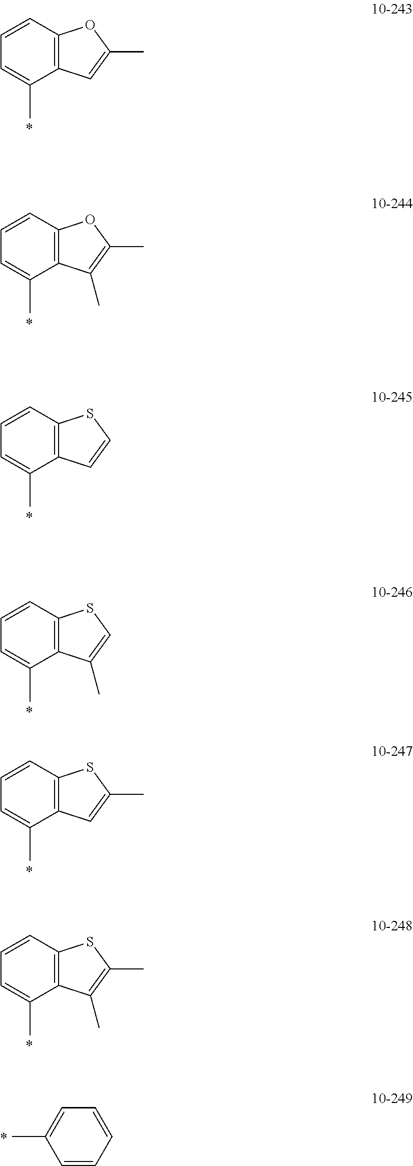

In Formulae 9-1 to 9-66 and 10-1 to 10-249, * indicates a binding site to a neighboring atom, Ph indicates a phenyl group, and TMS indicates a trimethylsilyl group.

The “groups represented by Formulae 9-1 to 9-66 in which a hydrogen is substituted with deuterium” may refer to, for example, groups represented by Formulae 9-501 to 9-552:

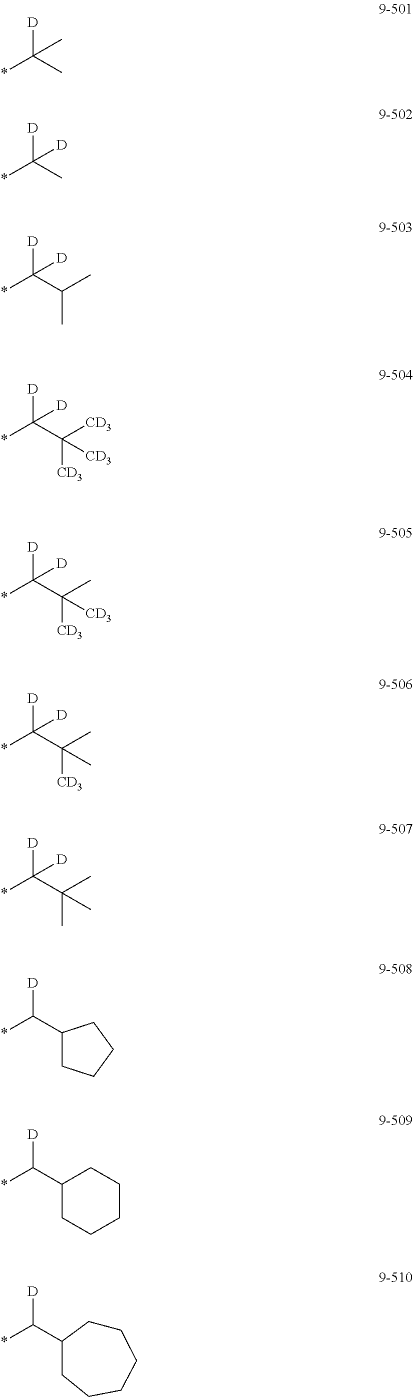

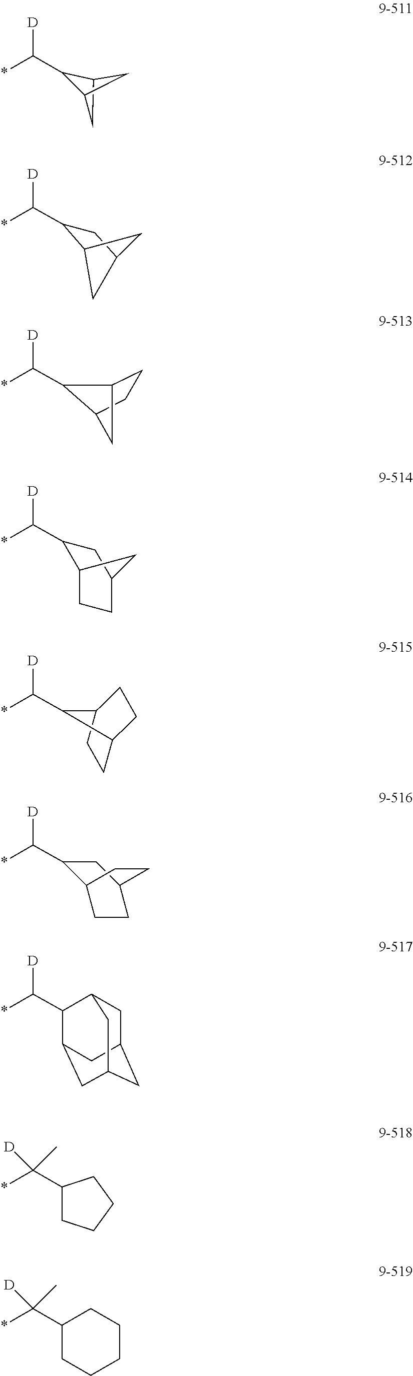

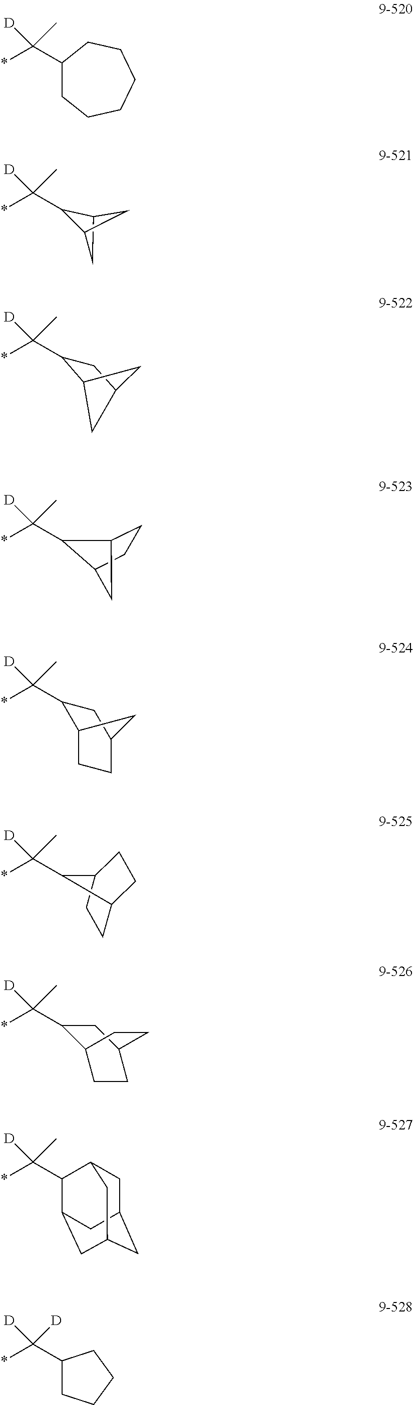

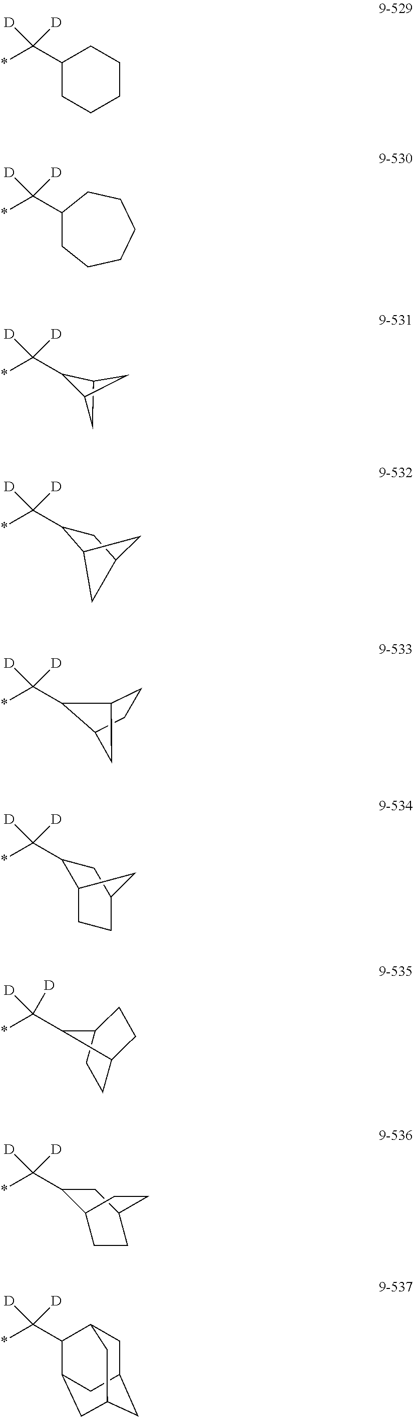

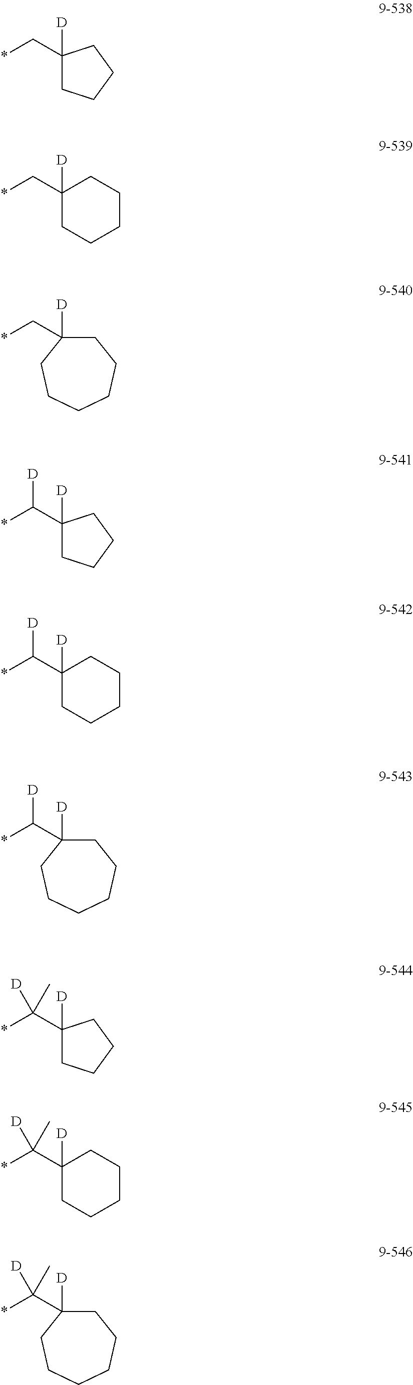

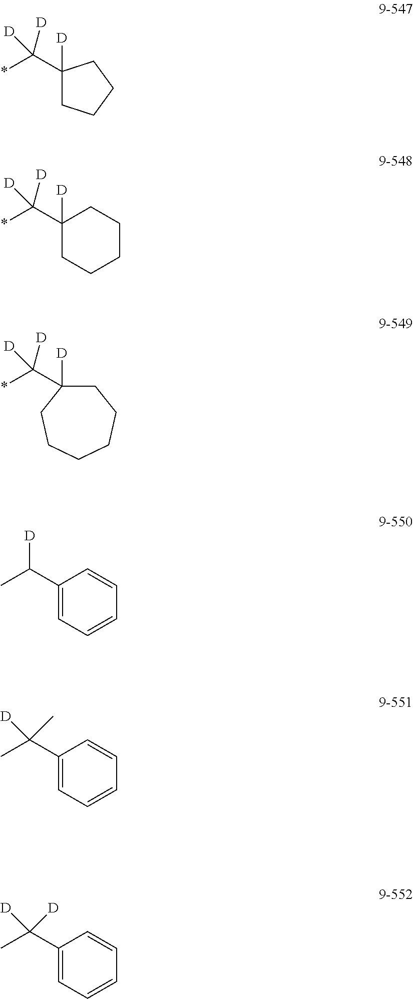

The “groups represented by Formulae 10-1 to 10-249 in which a hydrogen is substituted deuterium” may refer to, for example, groups represented by Formulae 10-501 to 10-510:

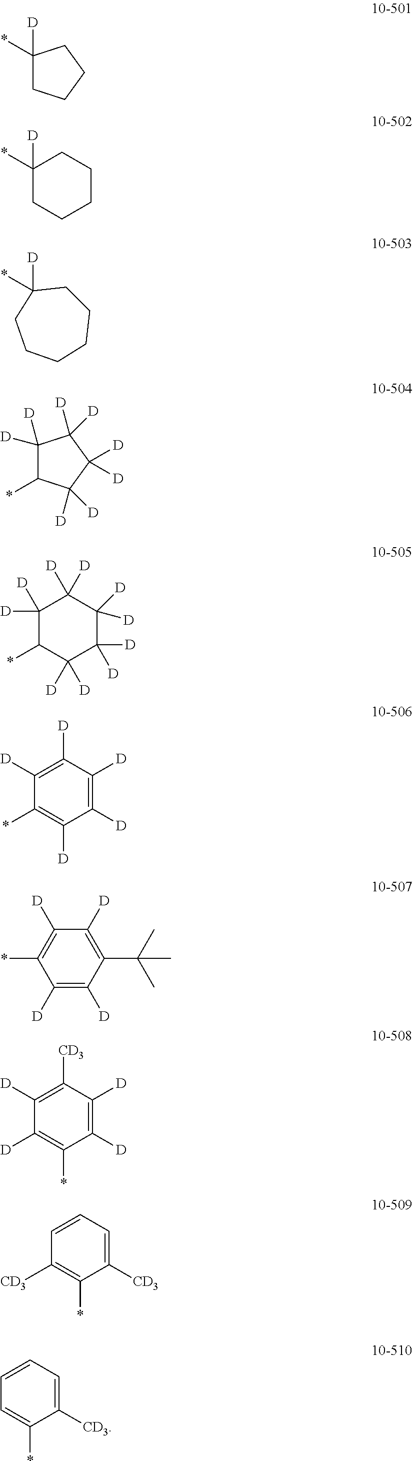

In Formula 1, b1 and b4 respectively indicate the number of R₁ and R₄ and may each independently be 0, 1, 2, 3, or 4, and b3 indicates the number of R₃ and may be 0, 1, 2, or 3. When b1 is two or more, two or more R₁ may be identical to or different from each other, when b2 is two or more, two or more R₂ may be identical to or different from each other, and when b3 is two or more, two or more R₃ may be identical to or different from each other.

In one embodiment, b1, b3, and b4 may each independently be 0, 1, or 2.

In Formula 1, i) two or more R₁ in the number of b1 may optionally be linked to form a C₅-C₃₀ carbocyclic group that is unsubstituted or substituted with an R₁₀ₐ, a C₁-C₃₀ heterocyclic group, or a combination thereof that is unsubstituted or substituted with an R₁₀ₐ (for example, a π electron-depleted nitrogen-free C₁-C₃₀ heterocyclic group unsubstituted or substituted with an R₁₀ₐ), ii) two or more R₂ₐ to R_{2c} may optionally be linked to form a C₅-C₃₀ carbocyclic group that is unsubstituted or substituted with an R₁₀ₐ, a C₁-C₃₀ heterocyclic group, or a combination thereof, that is unsubstituted or substituted with an R₁₀ₐ, iii) two or more R₃ in the number of b3 may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ, iv) two or more R₄ in the number of b4 may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ (for example, a π electron-depleted nitrogen-free C₁-C₃₀ heterocyclic group unsubstituted or substituted with an R₁₀ₐ), v) R₅, R₆, or R₃ may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ, vi) R₅, R₆, or R₄ may optionally be linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ, and R₁₀ₐ may be the same as described in connection with R₁.

In an exemplary embodiment, in Formula 1, i) two or more R₁ in the number of b1 may be linked to form a cyclopentane group, a cyclopentadiene group, a furan group, a thiophene group, a pyrrole group, a silole group, an adamantane group, a norbornane group, a norbornene group, a cyclohexane group, a cyclohexene group, a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group, each unsubstituted or substituted with an R₁₀ₐ, (and/or) ii) two or more R₂ₐ to R_{2c} may be linked to form a cyclopentane group, a cyclopentadiene group, an adamantane group, a norbornane group, a norbornene group, a cyclohexane group, a cyclohexene group, a benzene group, a naphthalene group, a pyridine group, a pyrimidine group, a pyridazine group, a pyrazine group, a triazine group, an oxazole group, an isoxazole group, an oxadiazole group, an isoxadiazole group, an oxatriazole group, a thiazole group, an isothiazole group, a thiadiazole group, an isothiadiazole group, a thiatriazole group, a pyrazole group, an imidazole group, a triazole group, a tetrazole group, an azasilole group, a diazasilole group, or a triazasilole group, each unsubstituted or substituted with an R₁₀ₐ, (and/or) iii) two or more R₃ in the number of b3 may be linked to form a cyclopentane group, a cyclopentadiene group, a furan group, a thiophene group, a pyrrole group, a silole group, an adamantane group, a norbornane group, a norbornene group, a cyclohexane group, a cyclohexene group, a benzene group, a naphthalene group, an indene group, an indole group, a benzofuran group, a benzothiophene group, a benzosilole group, a fluorene group, a carbazole group, a dibenzofuran group, a dibenzothiophene group, a dibenzosilole group, a pyridine group, a pyrimidine group, a pyridazine group, a pyrazine group, a triazine group, an oxazole group, an isoxazole group, an oxadiazole group, an isoxadiazole group, an oxatriazole group, a thiazole group, an isothiazole group, a thiadiazole group, an isothiadiazole group, a thiatriazole group, a pyrazole group, an imidazole group, a triazole group, a tetrazole group, an azasilole group, a diazasilole group, or a triazasilole group, each unsubstituted or substituted with an R₁₀ₐ, (and/or) iv) two or more R₄ in the number of b4 may be linked to form a cyclopentane group, a cyclopentadiene group, a furan group, a thiophene group, a pyrrole group, a silole group, an adamantane group, a norbornane group, a norbornene group, a cyclohexane group, a cyclohexene group, a benzene group, a naphthalene group, an indene group, an indole group, a benzofuran group, a benzothiophene group, a benzosilole group, a fluorene group, a carbazole group, a dibenzofuran group, a dibenzothiophene group, a dibenzosilole group, a pyridine group, a pyrimidine group, a pyridazine group, a pyrazine group, a triazine group, an oxazole group, an isoxazole group, an oxadiazole group, an isoxadiazole group, an oxatriazole group, a thiazole group, an isothiazole group, a thiadiazole group, an isothiadiazole group, a thiatriazole group, a pyrazole group, an imidazole group, a triazole group, a tetrazole group, an azasilole group, a diazasilole group, or a triazasilole group, each unsubstituted or substituted with an R₁₀ₐ, but embodiments of the present disclosure are not limited thereto.

In one embodiment, a group represented by

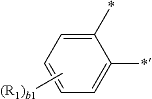

in Formula 1 may be a group represented by one of Formulae CY1-1 to CY1-24:

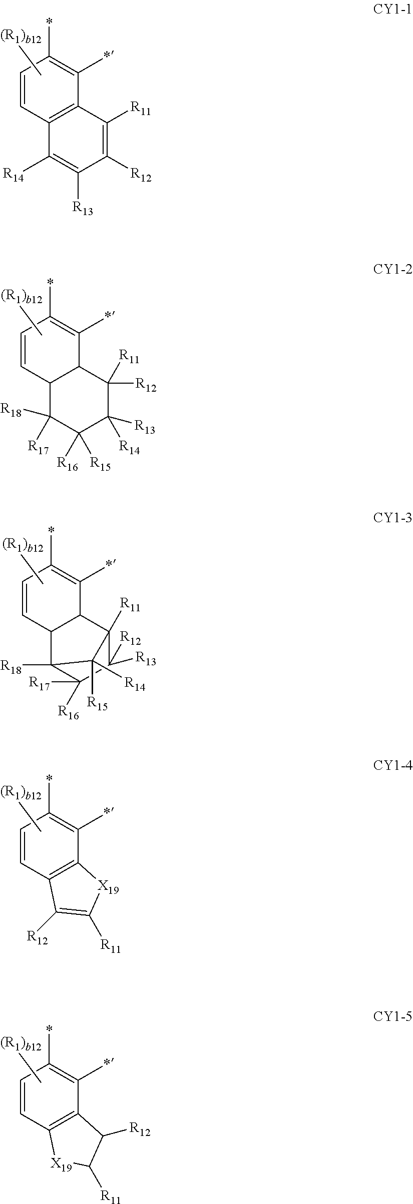

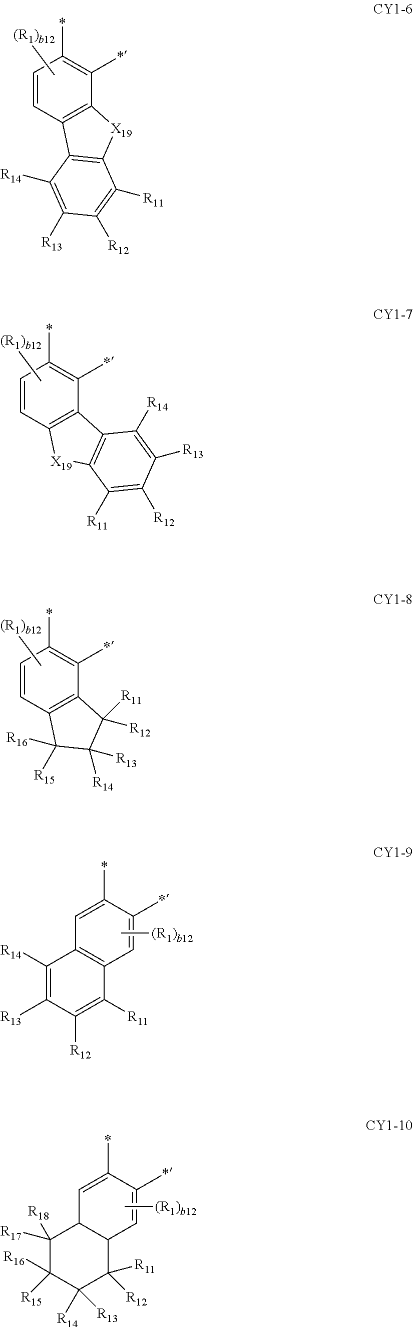

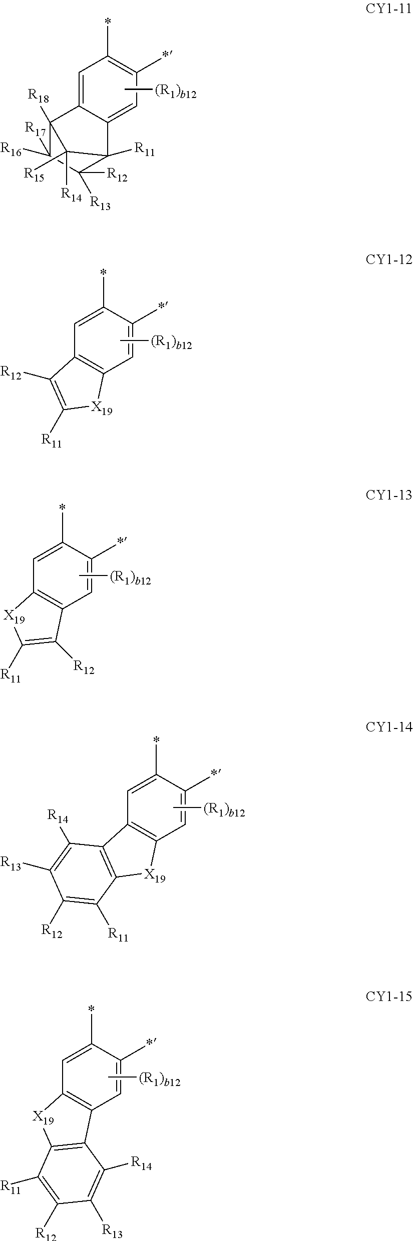

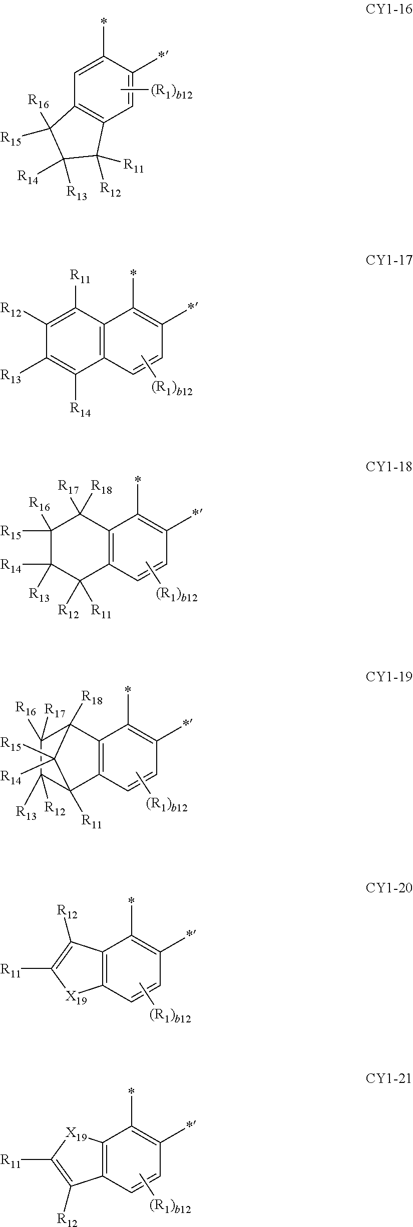

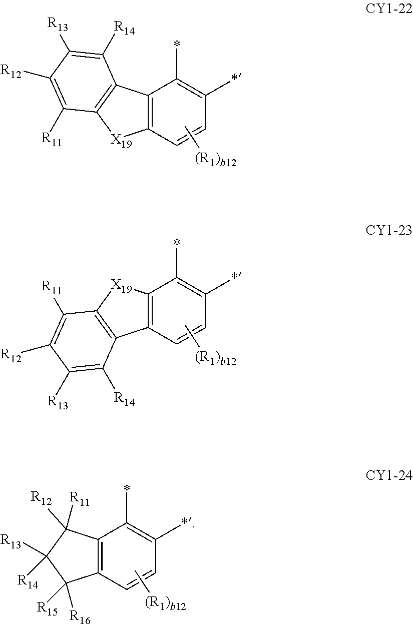

In Formulae CY1-1 to CY1-24,

R₁ is the same as described above,

X₁₉ may be C(R₁₈)(R₁₉), N(R₁₈), O, S, or Si(R₁₈)(R₁₉),

R₁₁ to R₁₉ may each independently be the same as described in connection with R₁,

b12 may be an integer from 0 to 2,

*′ indicates a binding site to X₁ in Formula 1, and

* indicates a binding site to carbon of a neighboring ring in Formula 1.

In one or more embodiments, a group represented by

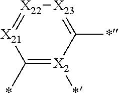

in Formula 1 may be a group represented by one of Formulae CY2-1 to CY2-20:

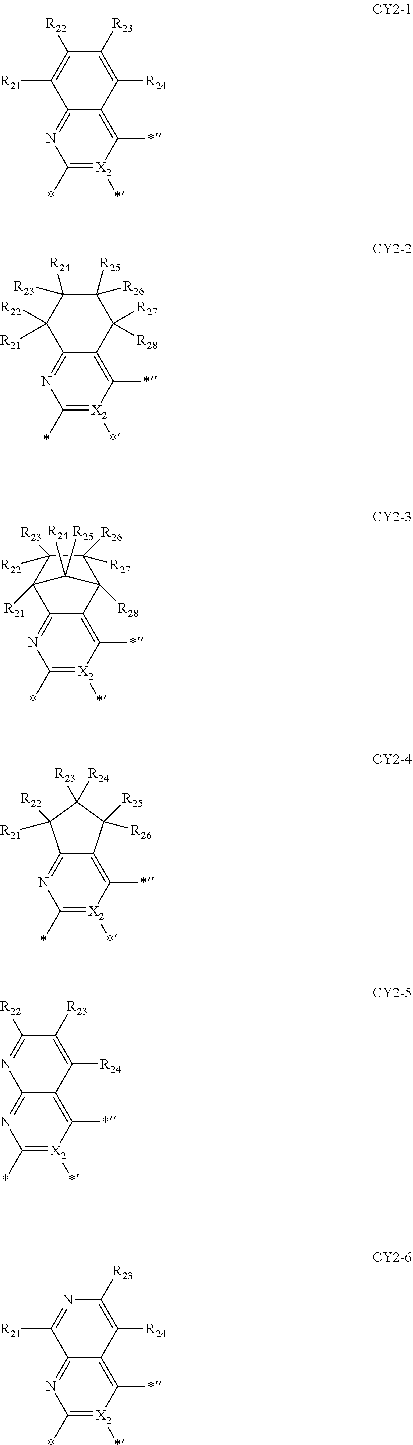

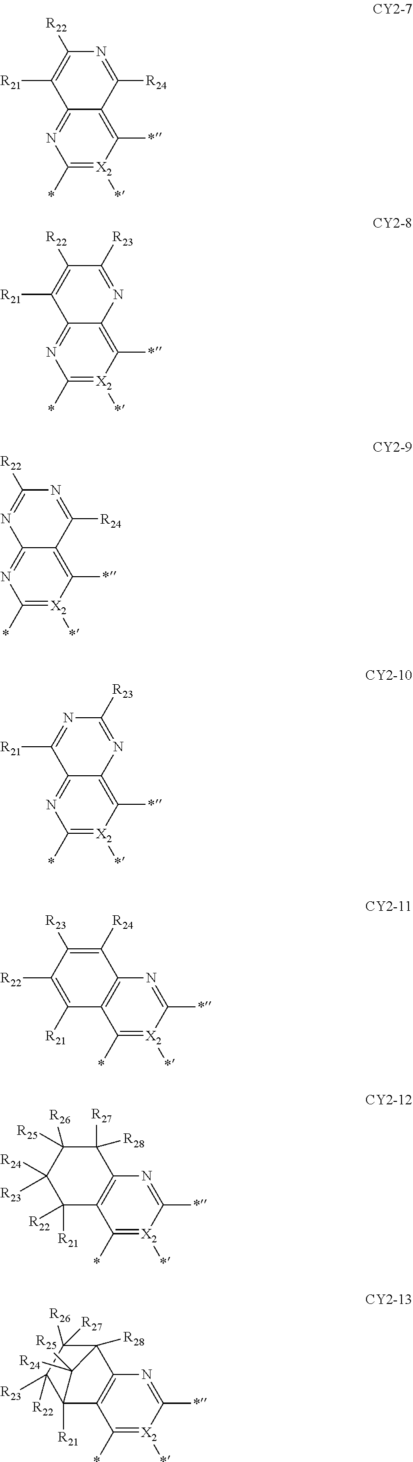

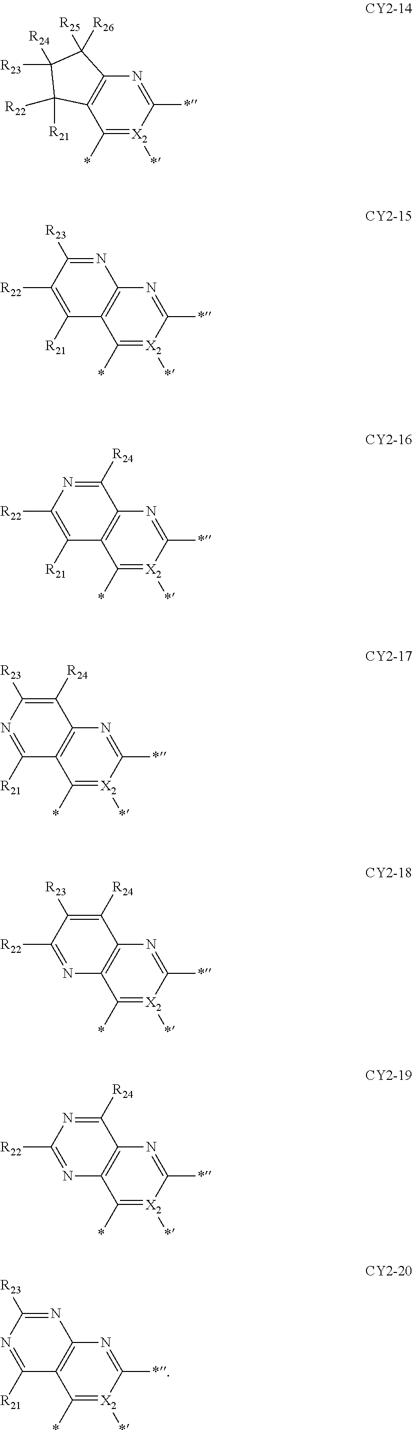

In Formulae CY2-1 to CY2-20,

X₂ is the same as described above,

R₂₁ to R₂₈ may each independently be the same as described in connection with R₂,

* and *″ each indicate a binding site to carbon of a neighboring ring, and

*′ indicates a binding site to M in Formula 1.

In one or more embodiments, a group represented by

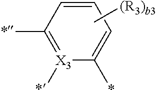

in Formula 1 may be a group represented by one of Formulae CY3-1 to CY3-16:

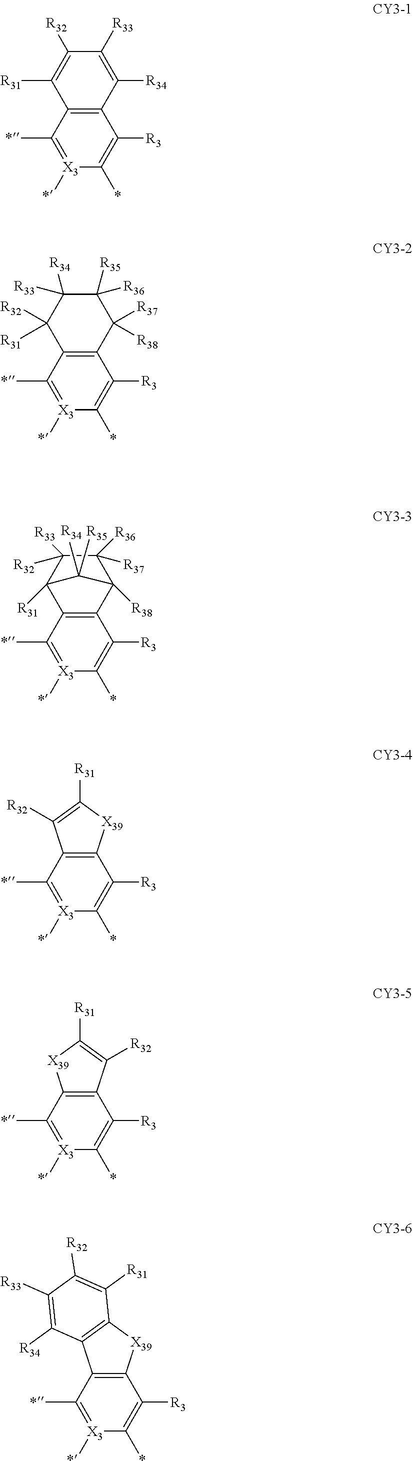

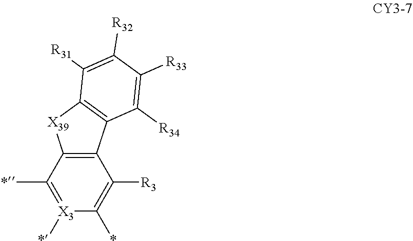

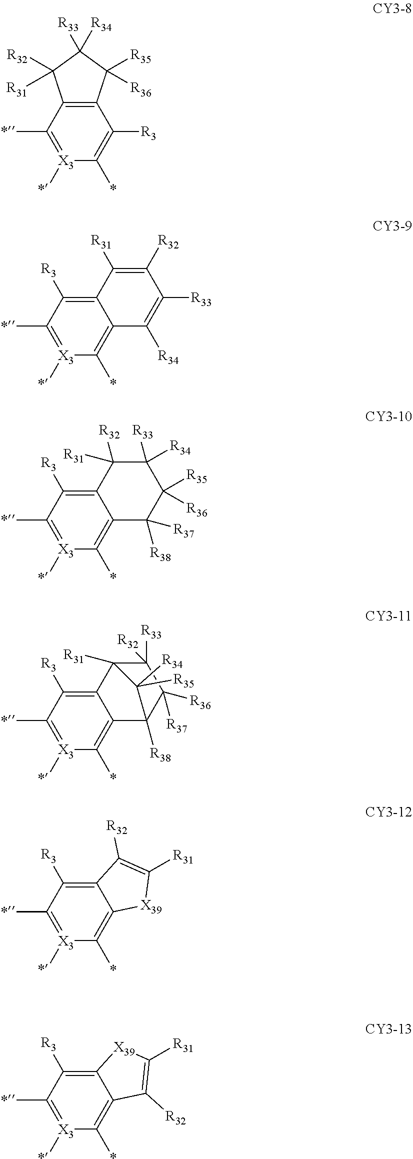

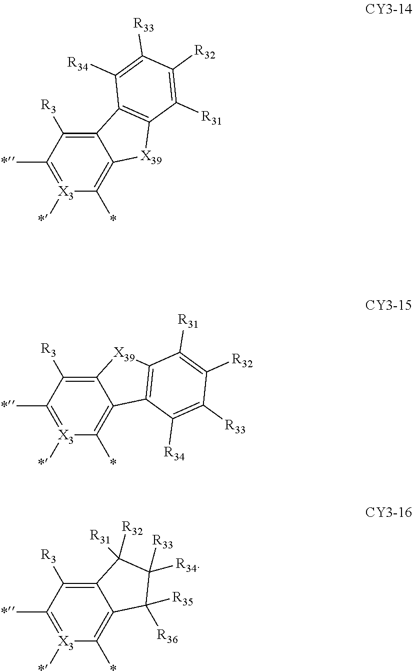

In Formulae CY3-1 to CY3-16,

X₃ and R₃ may each independently be the same as described herein,

X₃₉ may be C(R₃₈)(R₃₉), N(R₃₈), O, S, or Si(R₃₈)(R₃₉),

R₃₁ to R₃₉ may each independently be the same as described in connection with R₃,

* indicates a binding site to T₁ in Formula 1,

*′ indicates a binding site to M in Formula 1, and

*″ indicates a binding site to carbon of a neighboring ring in Formula 1.

In one or more embodiments, a group represented by

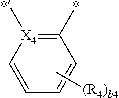

in Formula 1 may be a group represented by one of Formulae CY4-1 to CY4-42:

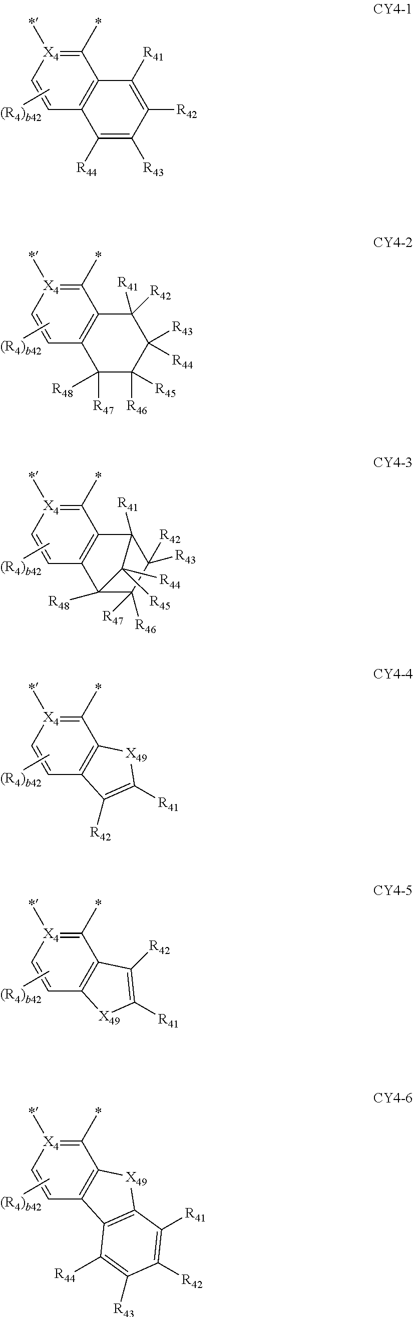

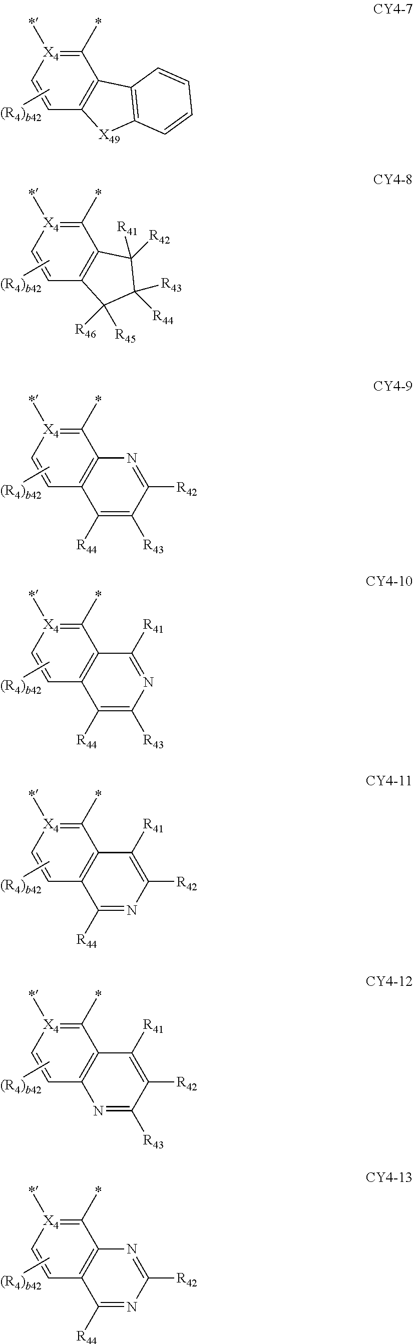

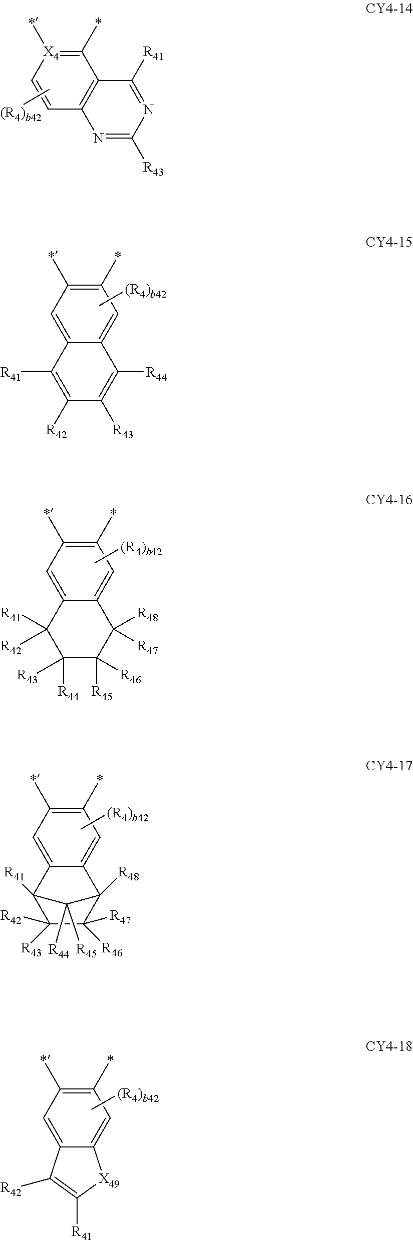

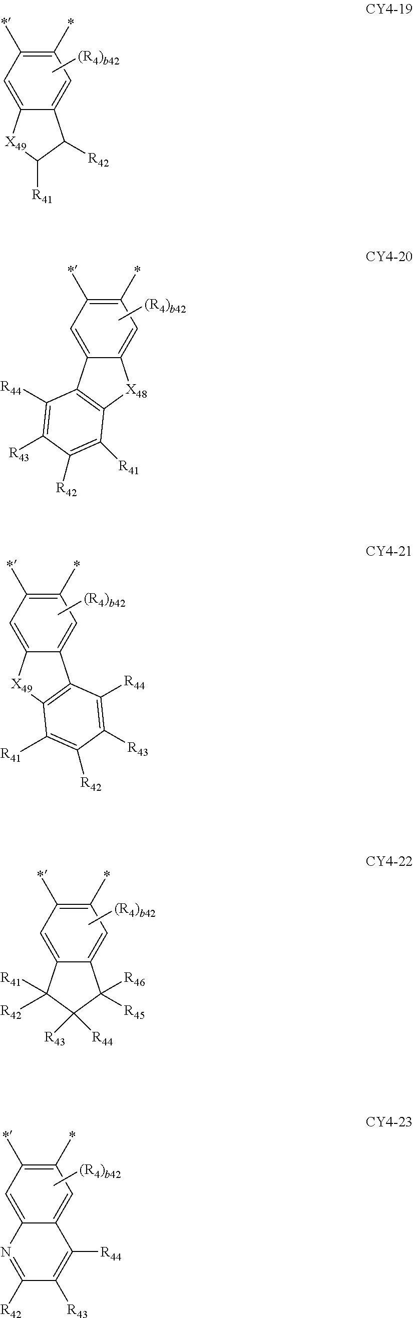

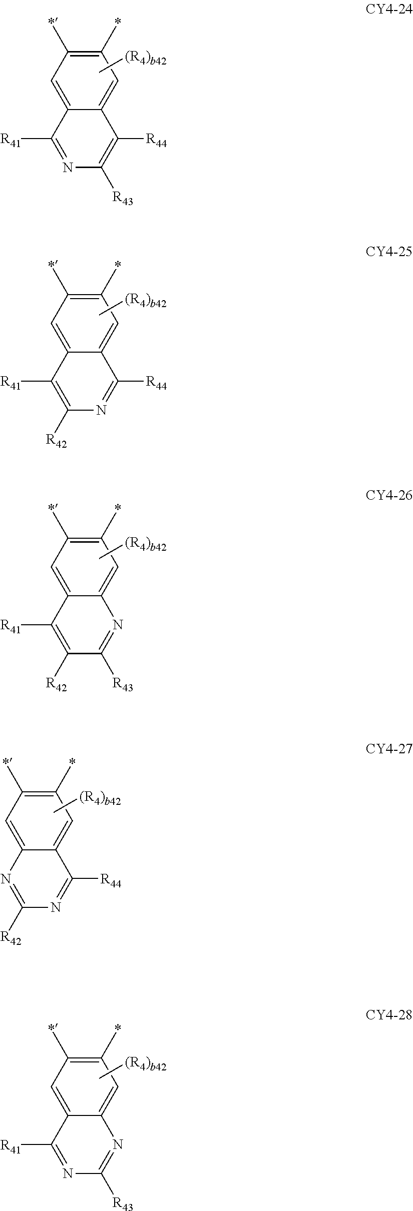

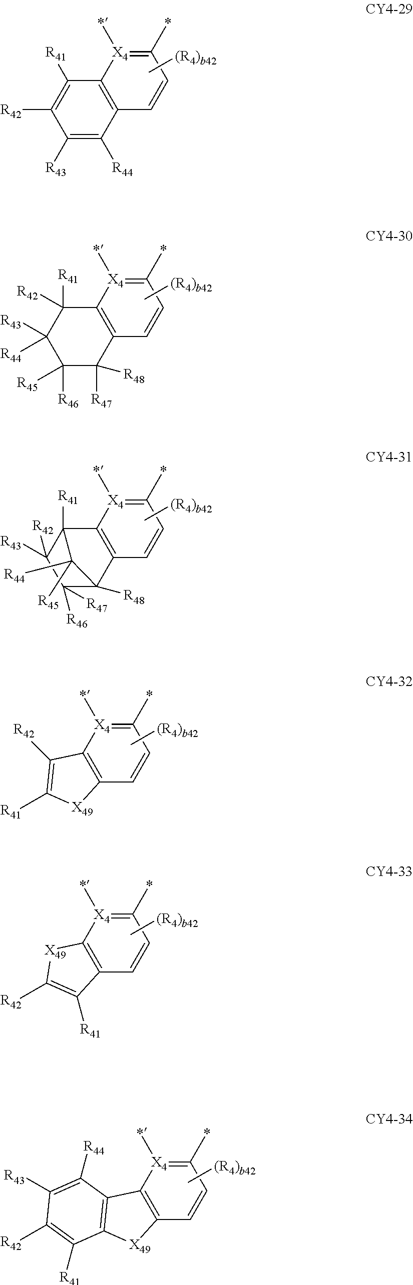

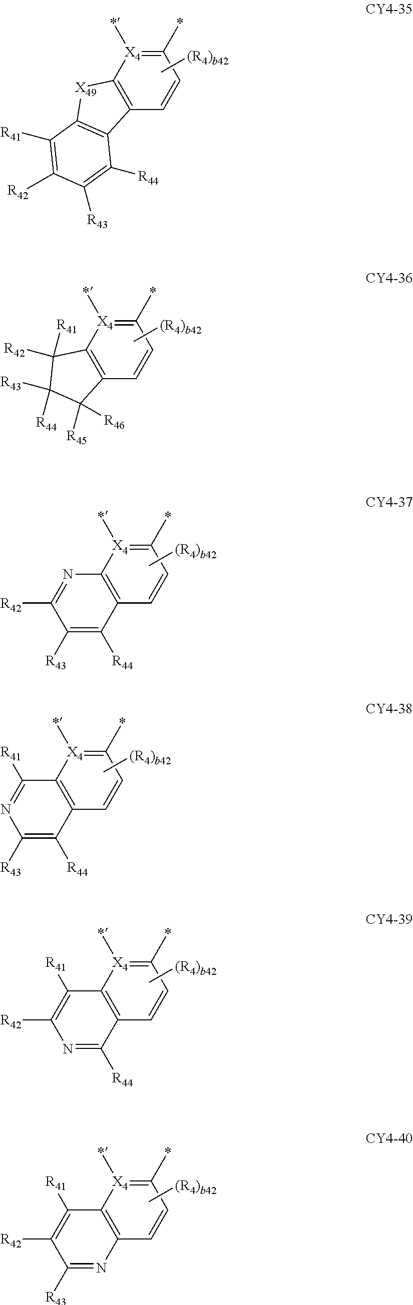

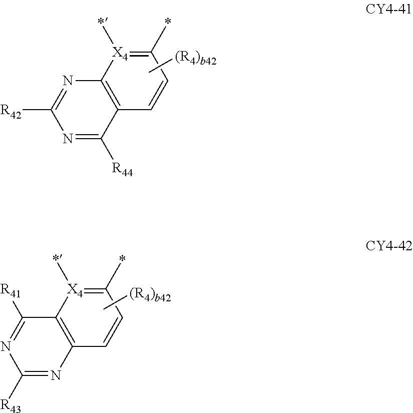

In Formulae CY4-1 to CY4-42,

X₄ and R₄ may each independently be the same as described herein,

X₄₉ may be C(R₄₈)(R₄₉), N(R₄₈), O, S, or Si(R₄₈)(R₄₉),

R₄₁ to R₄₉ may each independently be the same as described in connection with R₄,

a42 may be an integer from 0 to 2,

* indicates a binding site to T₁ in Formula 1, and

*′ indicates a binding site to M in Formula 1.

In one or more embodiments, a group represented by

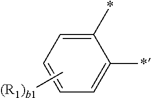

in Formula 1 may be a group represented by one of Formulae CY1(1) to CY1(16):

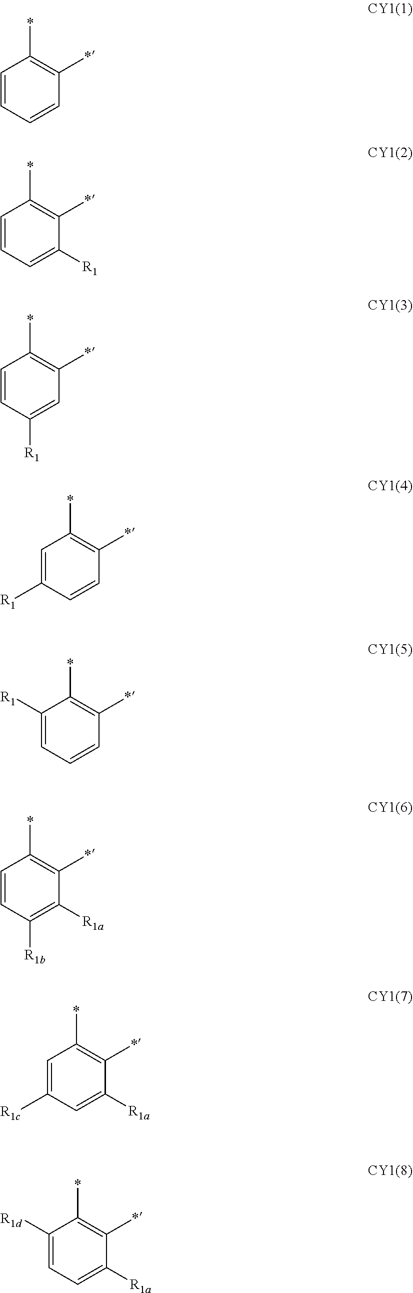

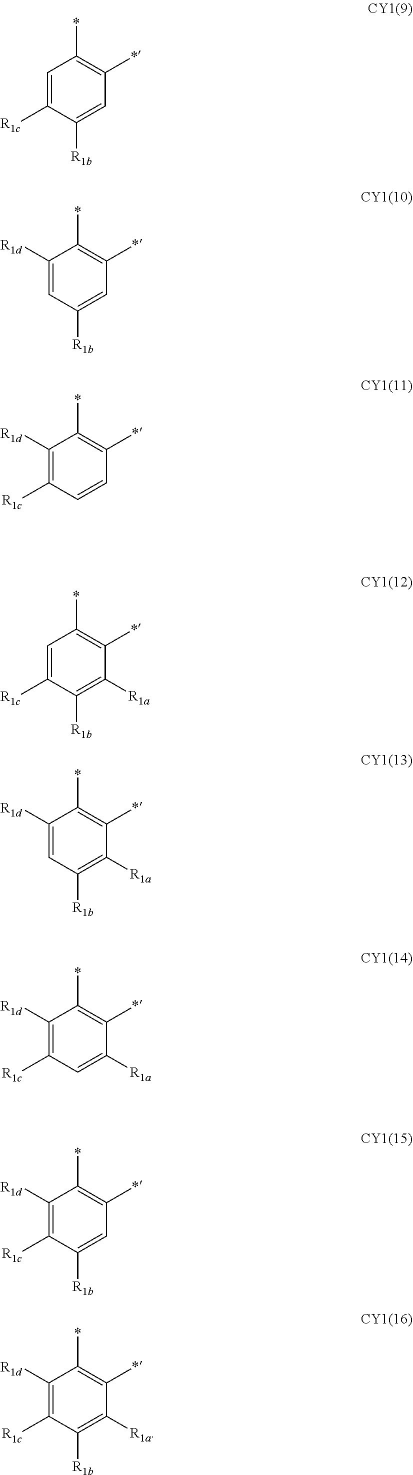

In Formulae CY1(1) to CY1(16), R₁ is the same as described above, R₁ₐ to R_{1d} may each independently be the same as described in connection with R₁, wherein R₁ₐ to R_{1d} are not hydrogen, *′ indicates a binding site to X₁ in Formula 1, and * indicates a binding site to carbon of a neighboring ring in Formula 1.

In one or more embodiments, a group represented by

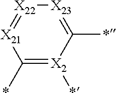

in Formula 1 may be a group represented by one of Formulae CY2(1) to CY2(15):

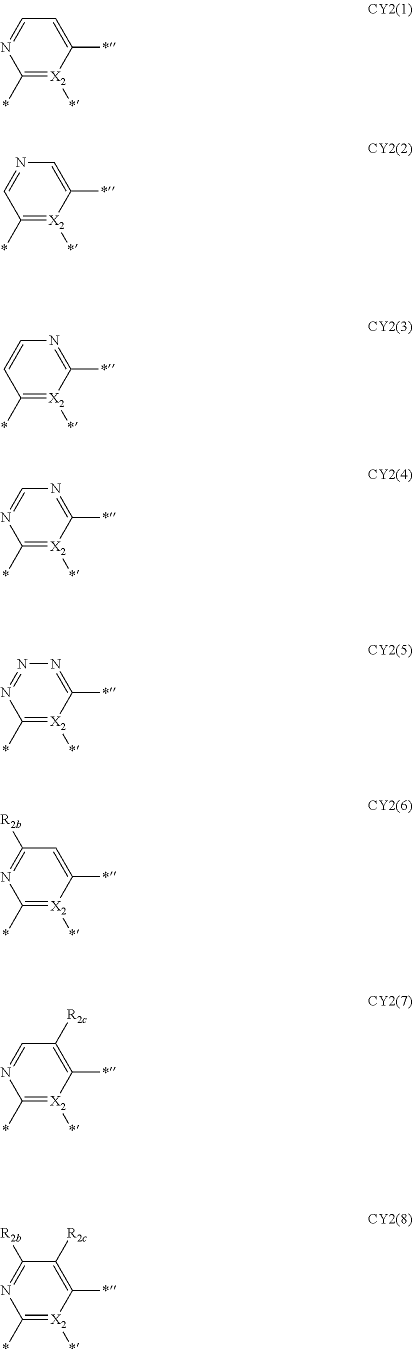

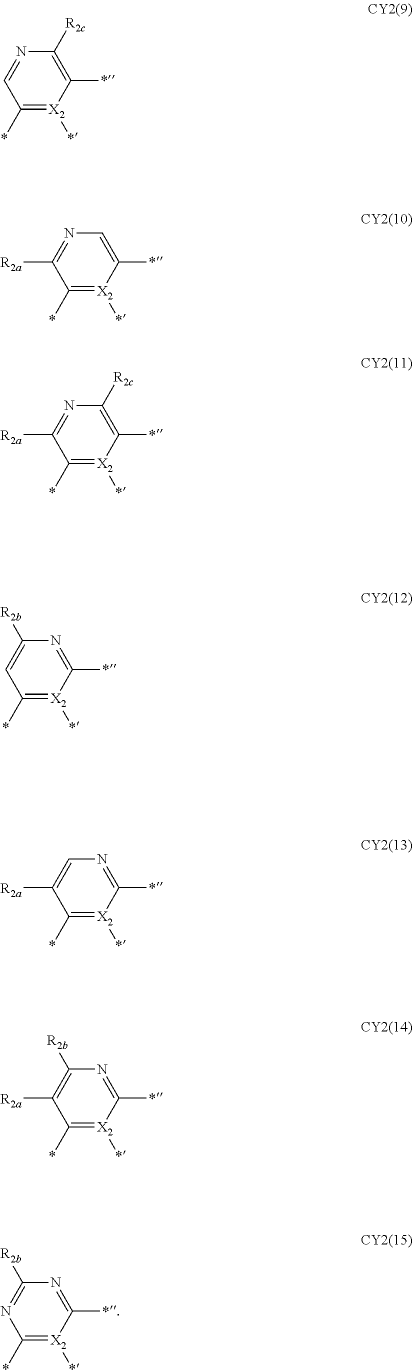

In Formulae CY2(1) to CY2(15), R₂ₐ to R_{2c} and X₂ may each independently be the same as described herein, wherein R₂ₐ to R_{2c} are not hydrogen, * and *″ each indicate a binding site to carbon of a neighboring ring, and *′ indicates a binding site to M in Formula 1.

In one or more embodiments, a group represented by

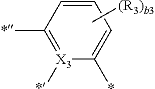

in Formula 1 may be a group represented by one of Formulae CY3(1) to CY3(8):

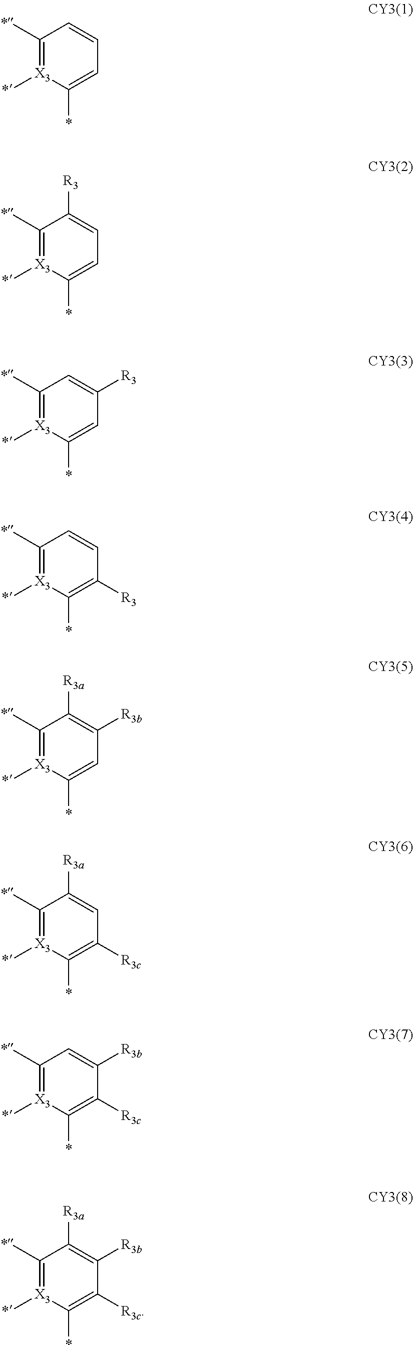

In Formulae CY3(1) to CY3(8), R₃ and X₃ may each independently be the same as described herein, R₃ₐ to R_{3d} may each independently be the same as described in connection with R₃, wherein R₃ and R₃ₐ to R_{3d} are not hydrogen, * indicates a binding site to T₁ in Formula 1, *′ indicates a binding site to M in Formula 1, and *″ indicates a binding site to carbon of a neighboring ring in Formula 1.

In one or more embodiments, a group represented by

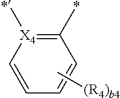

in Formula 1 may be a group represented by one of Formulae CY4(1) to CY4(22):

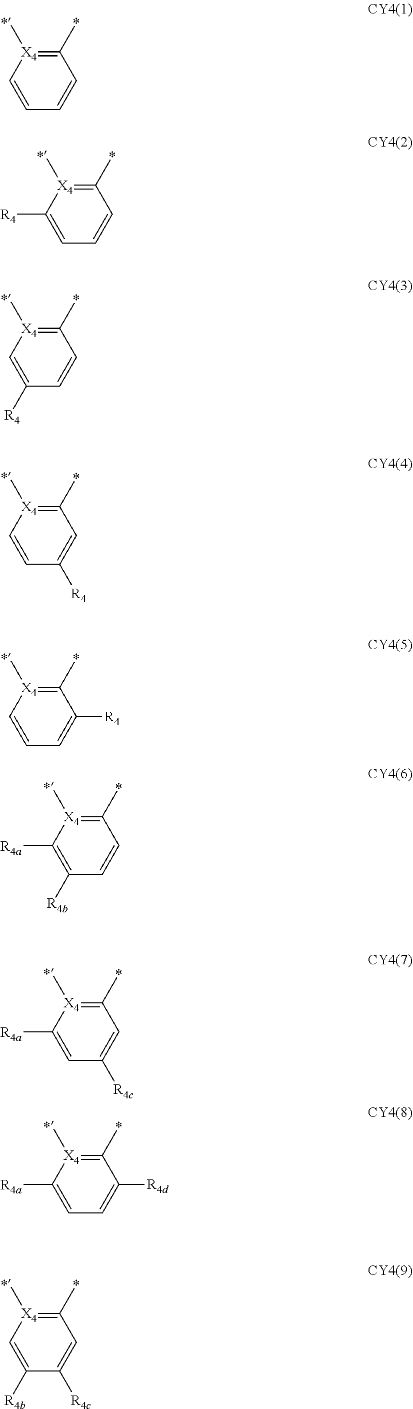

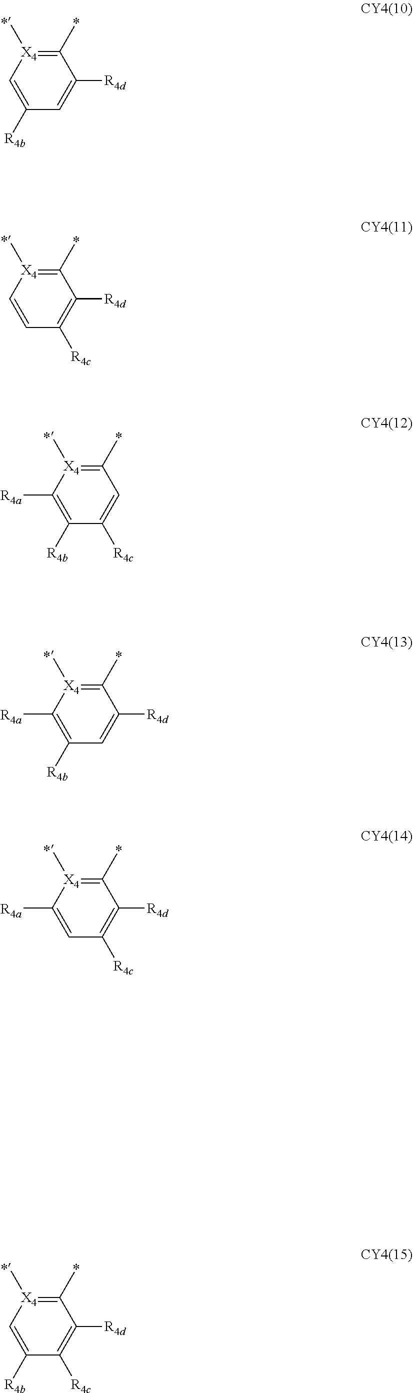

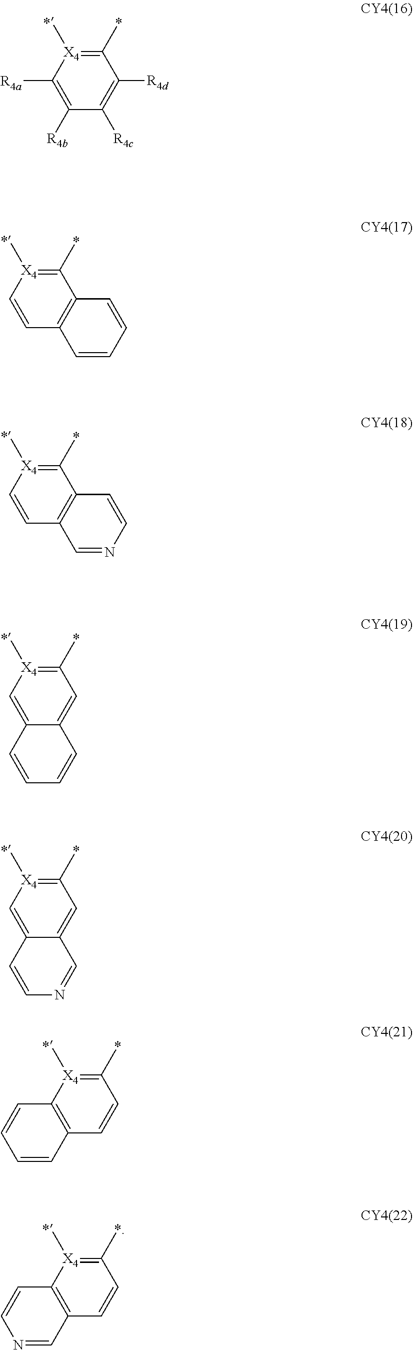

In Formulae CY4(1) to CY4(22), R₄ and X₄ may each independently be the same as described herein, R₄ₐ to R_{4d} may each independently be the same as described in connection with R₄, wherein R₄ and R₄ₐ to R_{4d} are not hydrogen, * indicates a binding site T₁ in Formula 1, and *′ indicates a binding site to M in Formula 1.

In one embodiment, in Formula 1, any of R₂ₐ to R_{2c} may not be linked to form a ring. In an exemplary embodiment, in Formula 1, R₂ₐ to R_{2c} may each independently be hydrogen, deuterium, —F, a cyano group, a nitro group, —SF₅, —CH₃, —CD₃, —CD₂H, —CDH₂, —CF₃, —CF₂H, —CFH₂, groups represented by Formulae 9-1 to 9-66, groups represented by Formulae 9-1 to 9-66 in which a hydrogen is substituted with deuterium, groups represented by Formulae 10-1 to 10-249, groups represented by Formulae 10-1 to 10-249 in which a hydrogen is substituted with deuterium, or —Si(Q₃)(Q₄)(Q₅) (wherein Q₃ to Q₅ are the same as described above).

In one or more embodiments, the organometallic compound may be of Compounds 1 to 200 below, but embodiments of the present disclosure are not limited thereto:

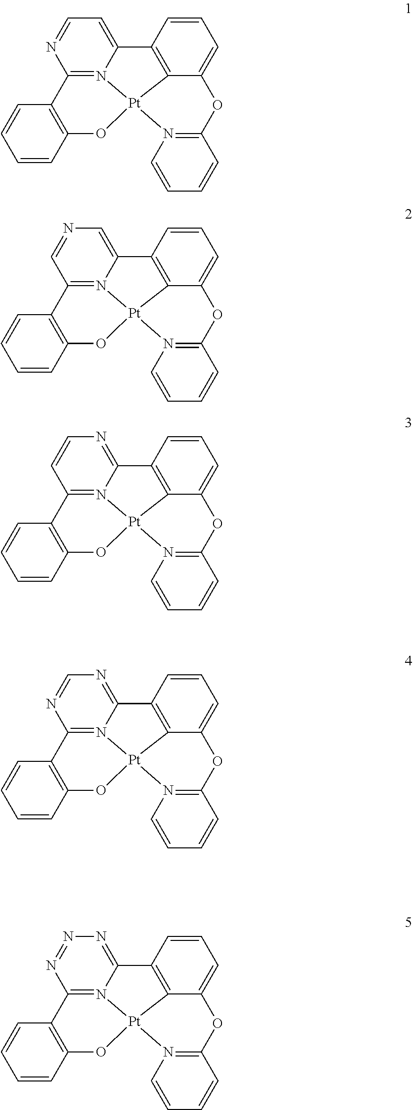

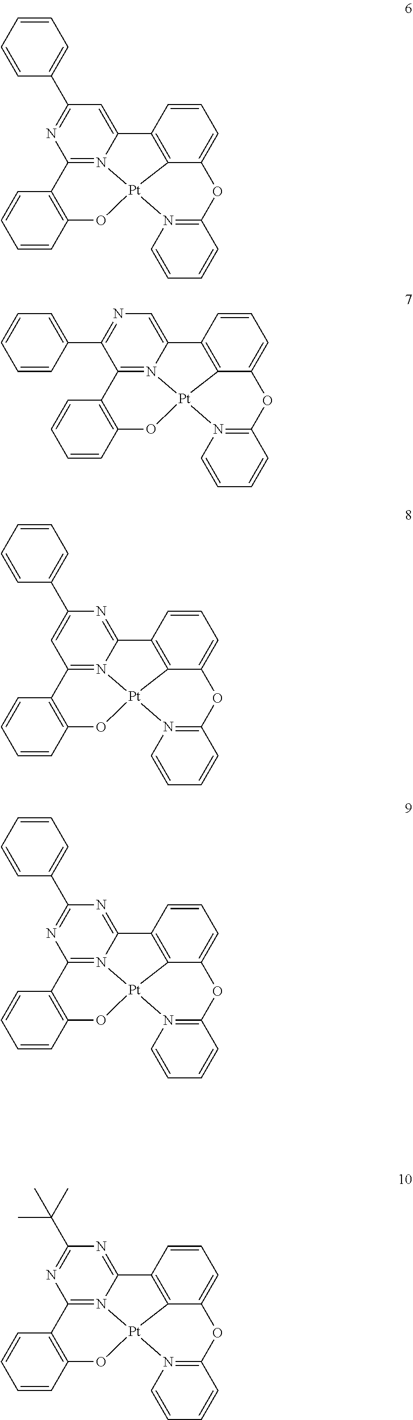

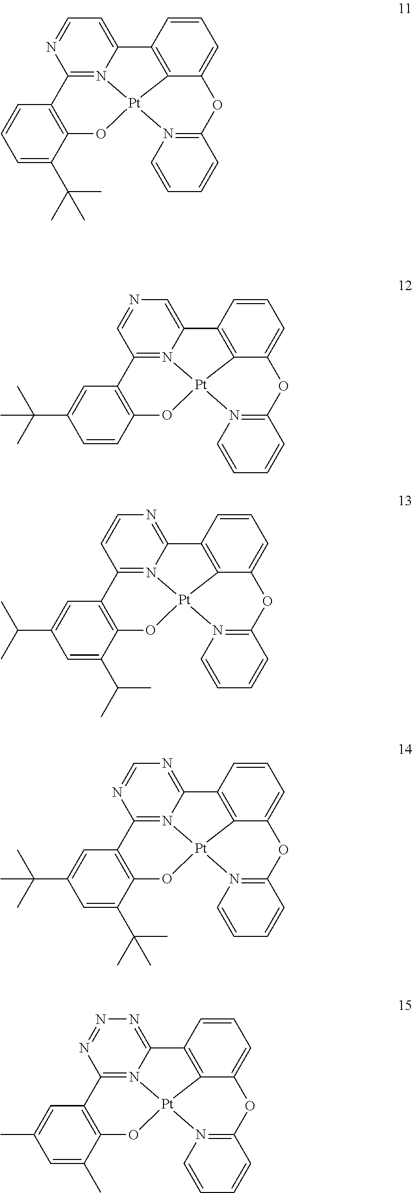

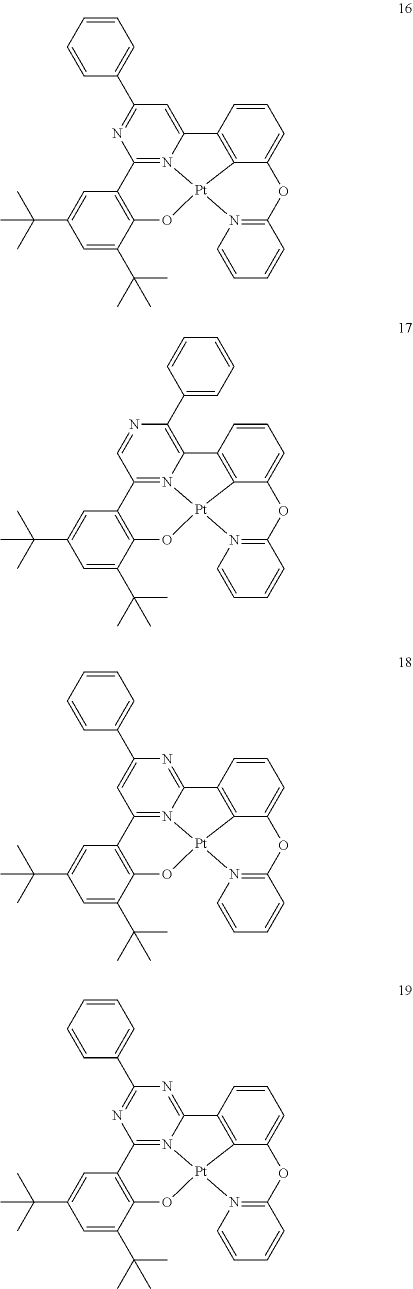

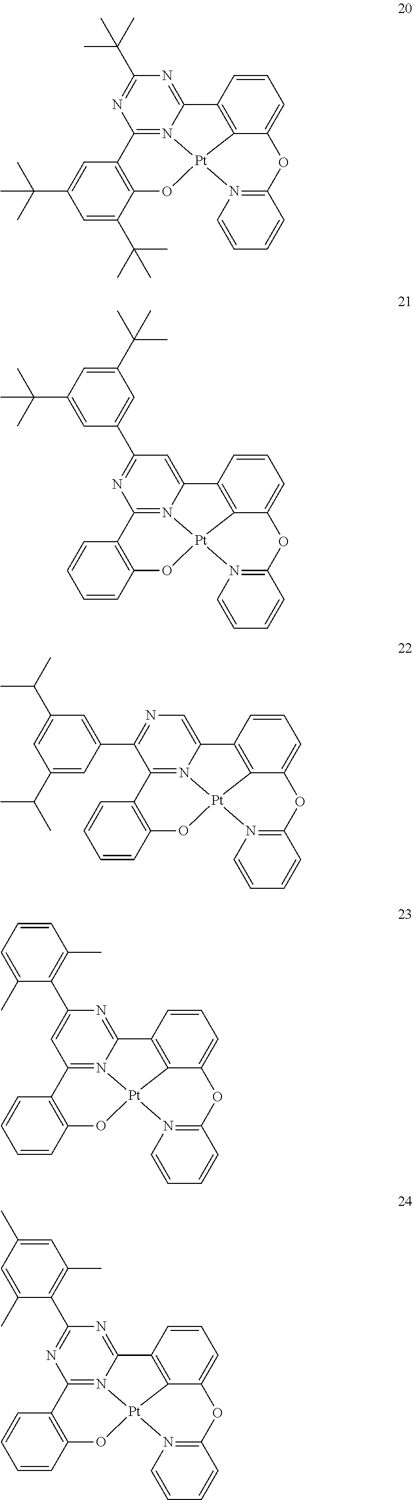

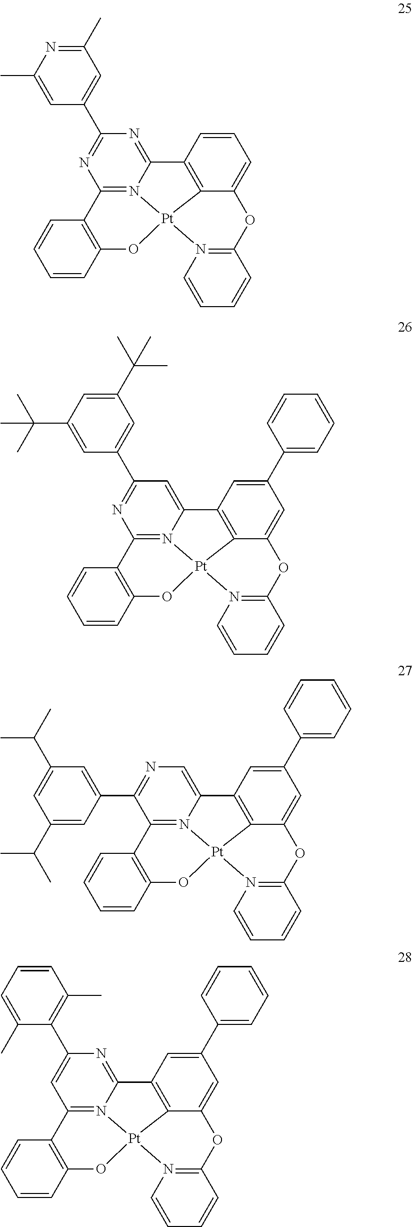

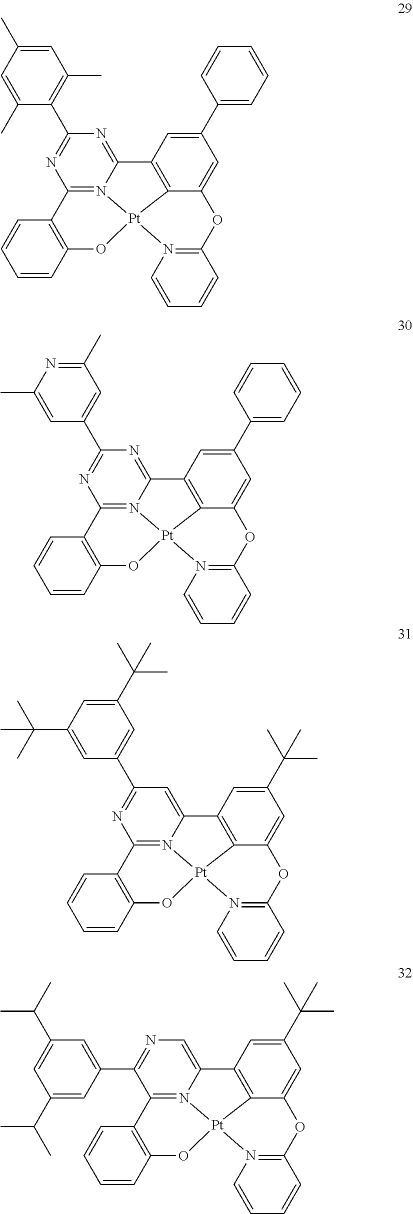

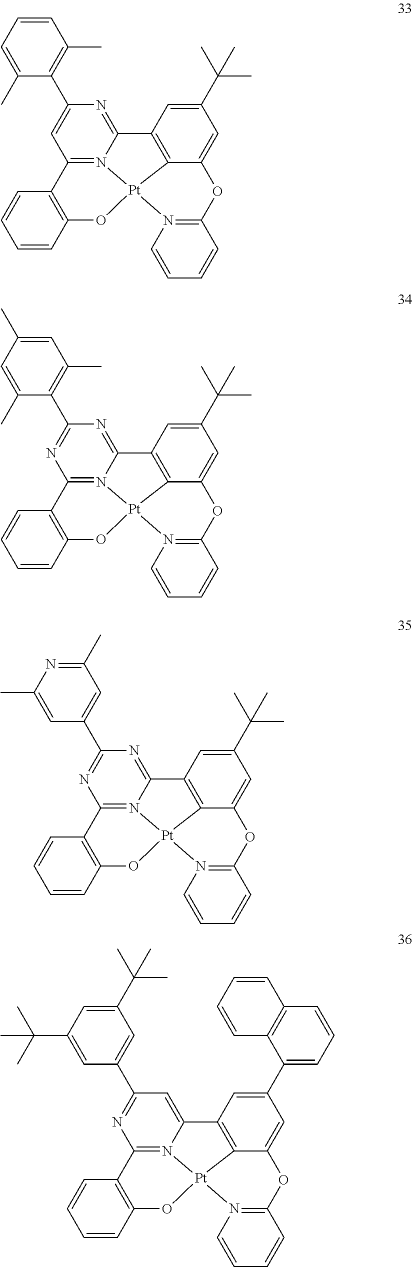

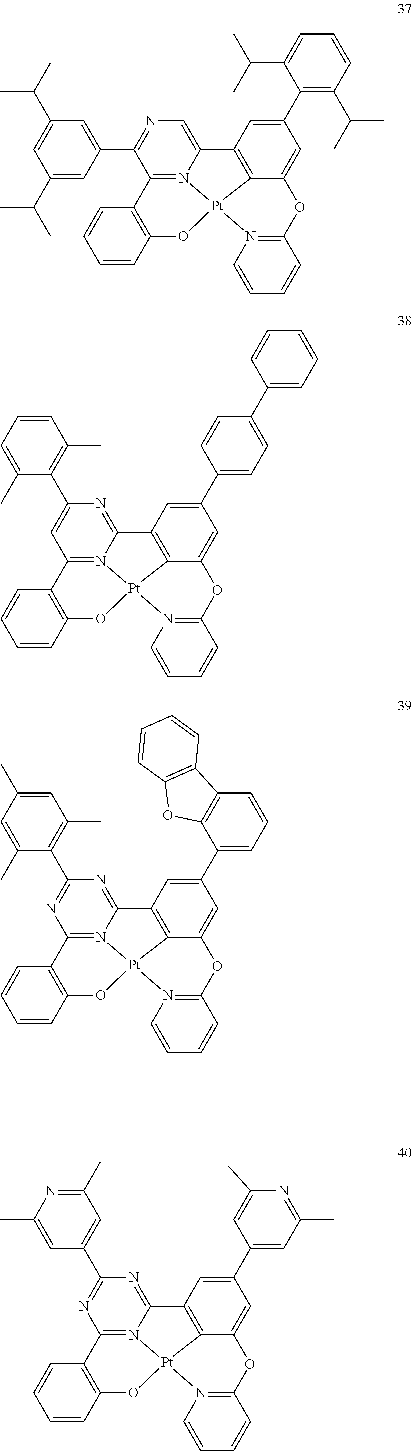

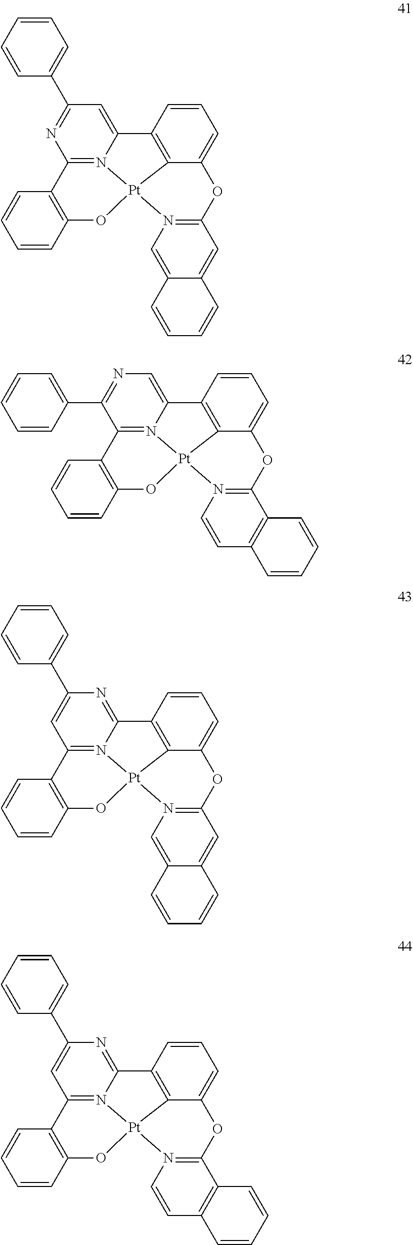

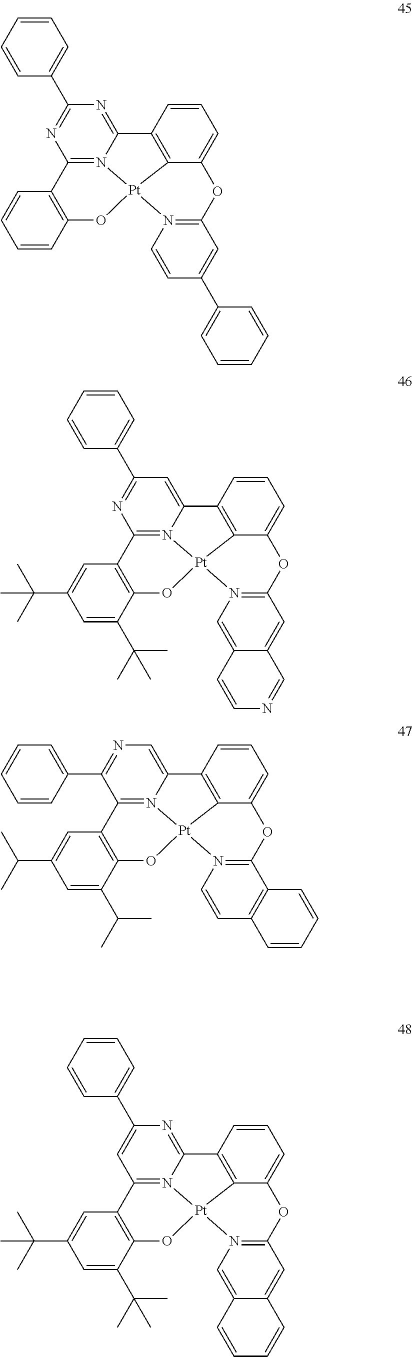

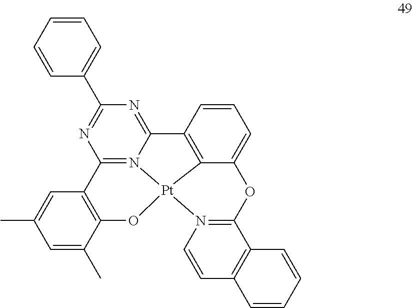

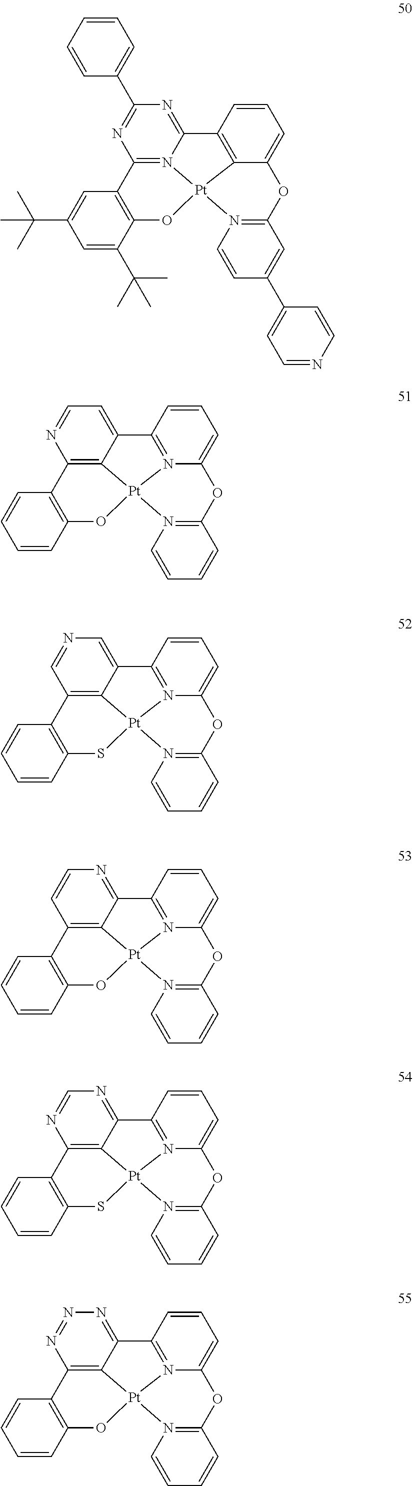

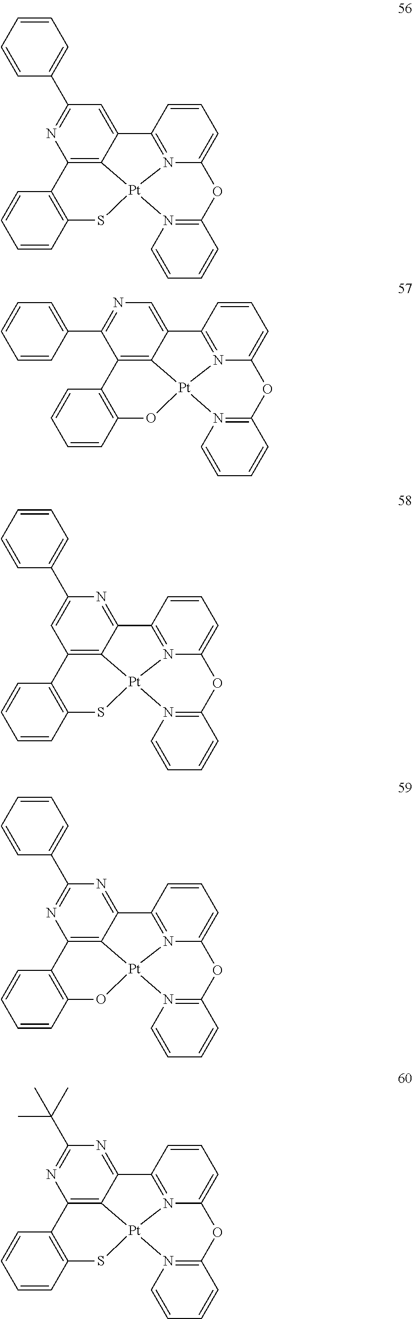

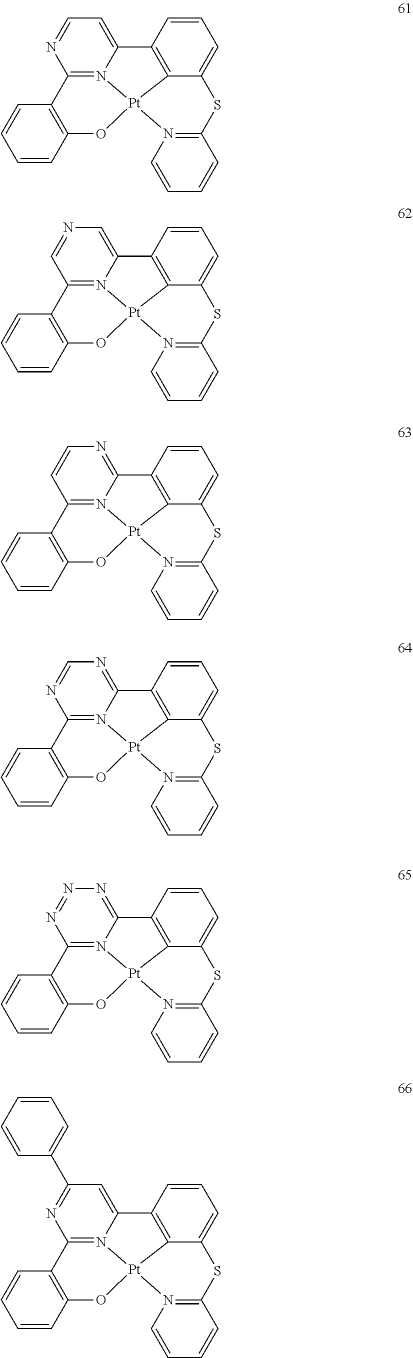

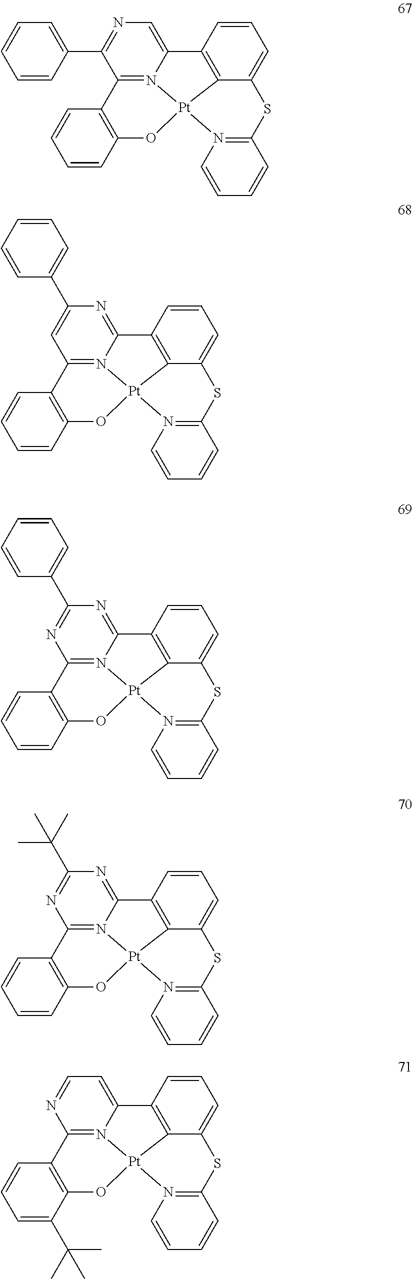

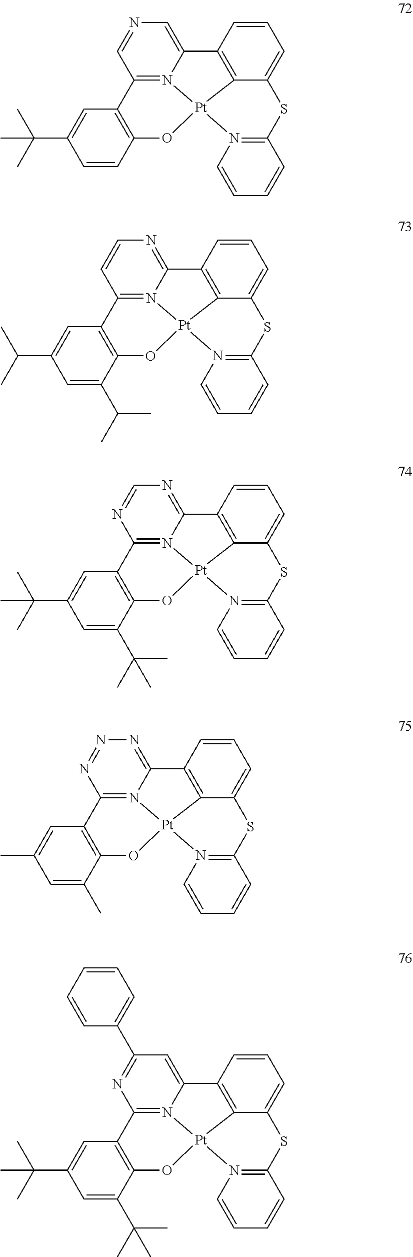

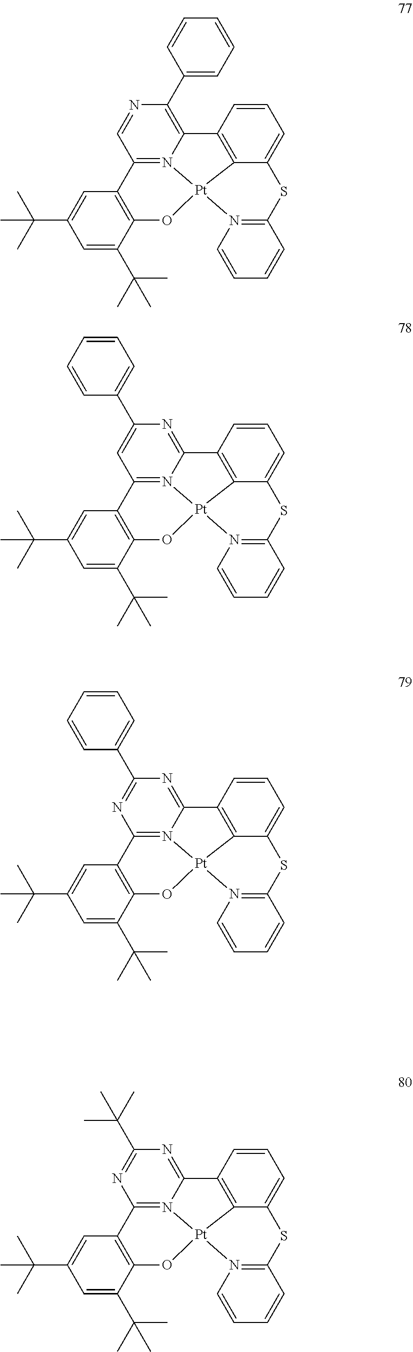

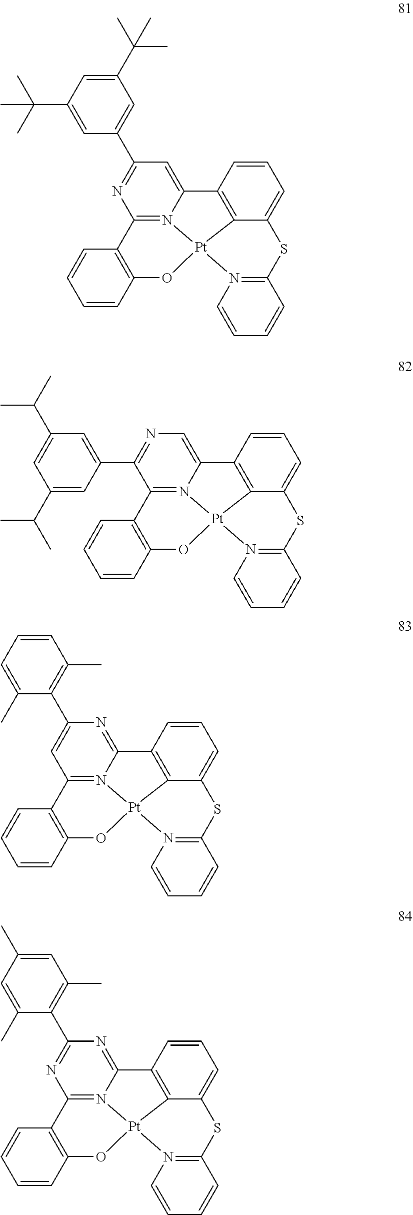

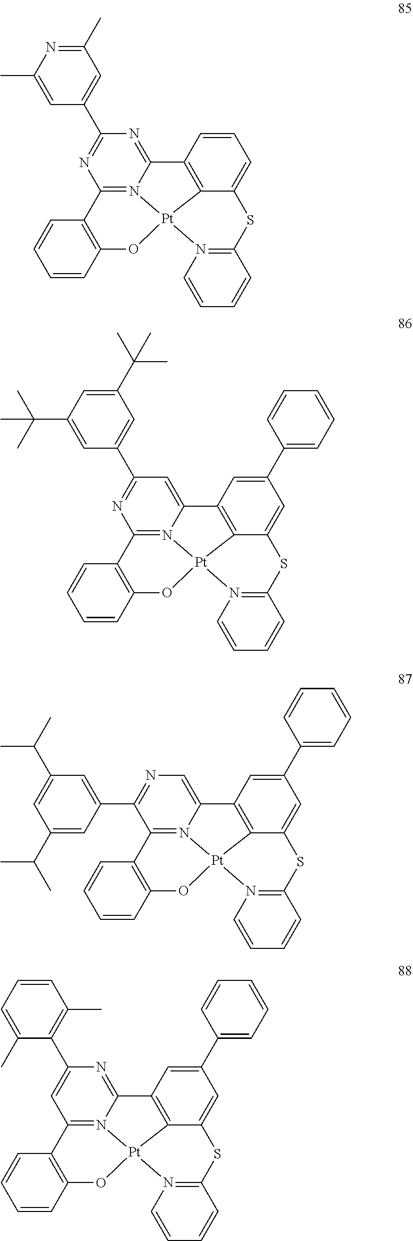

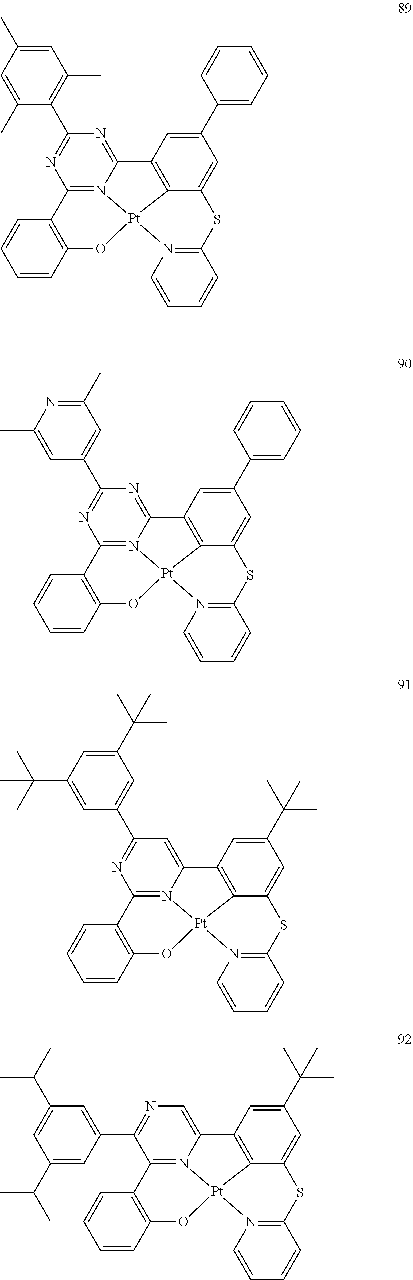

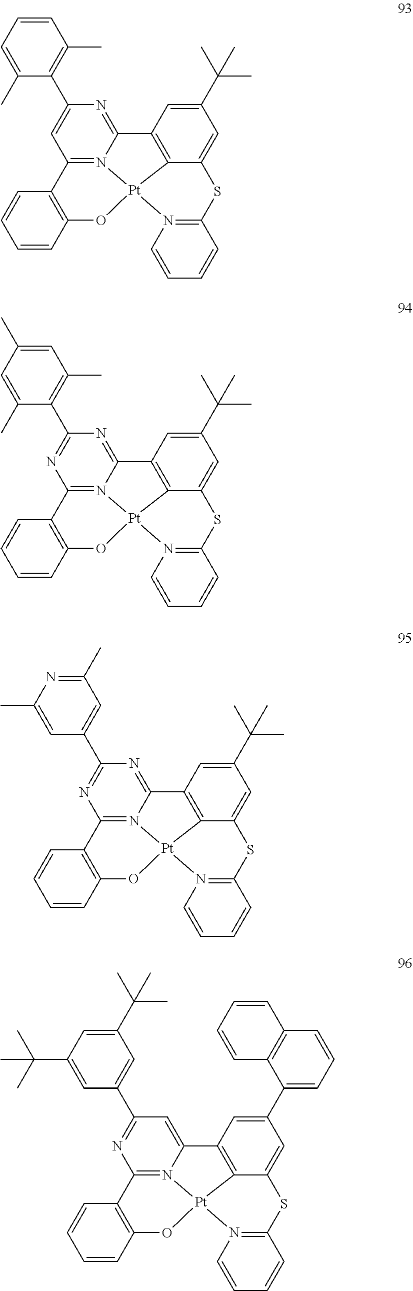

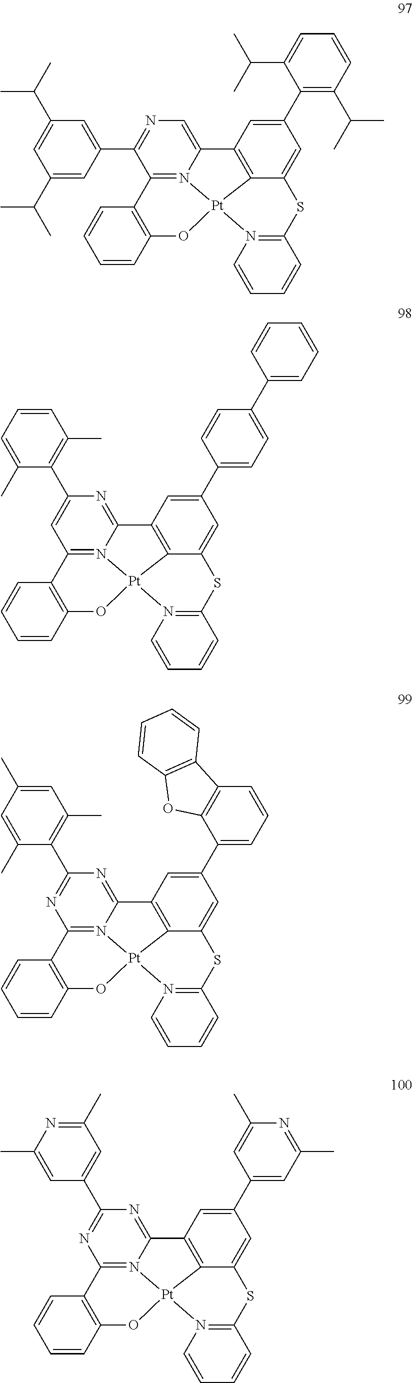

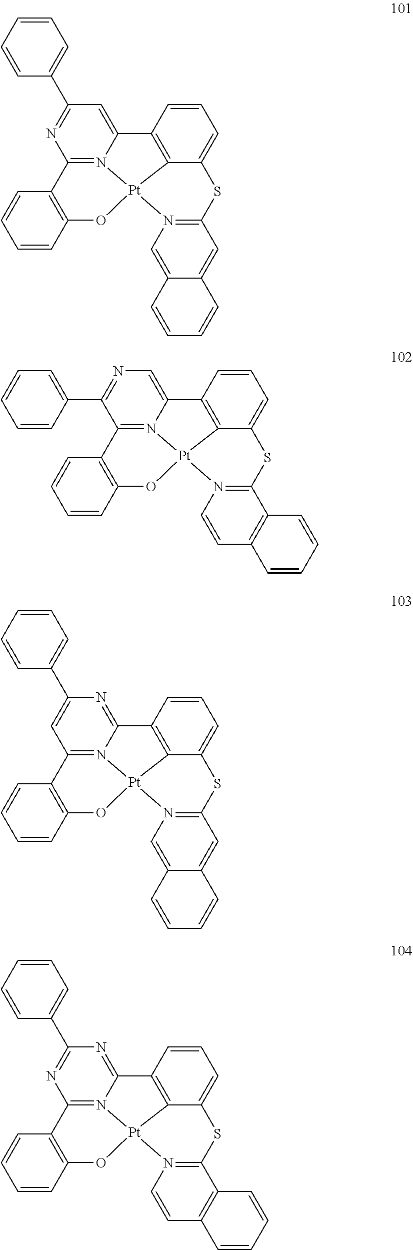

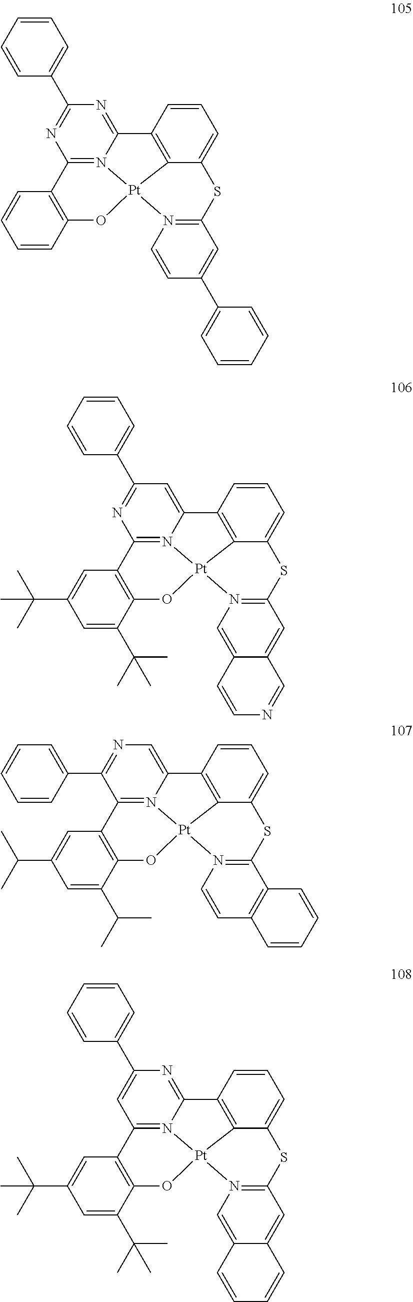

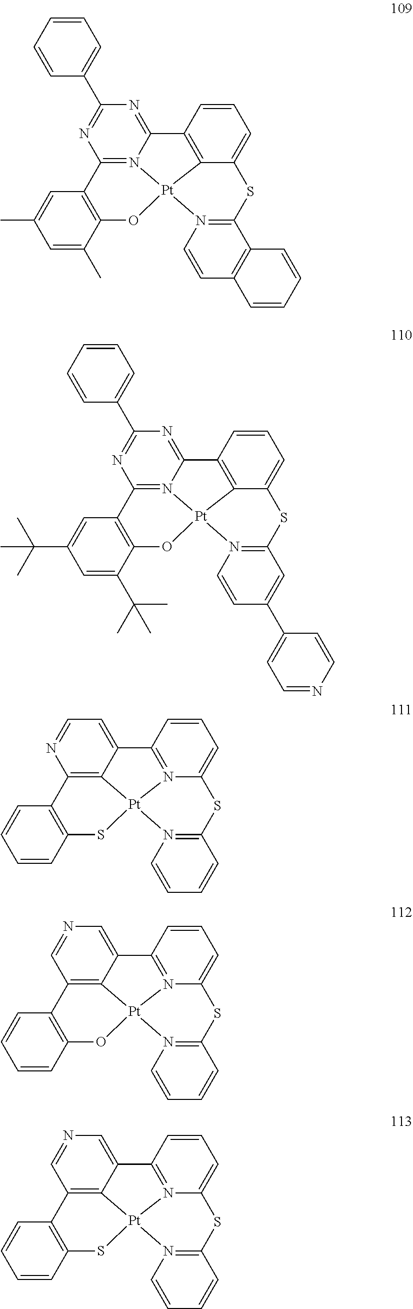

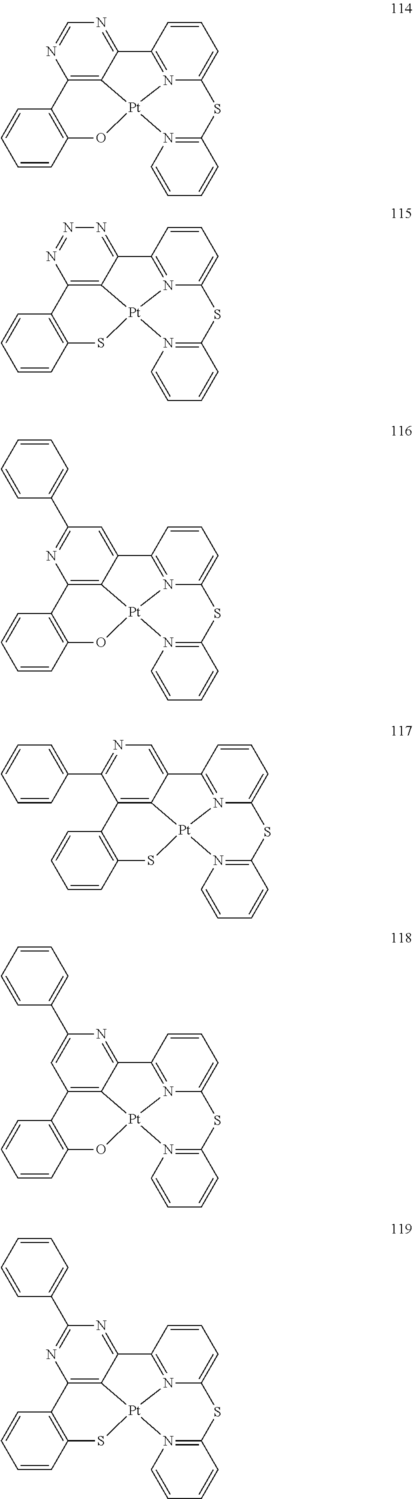

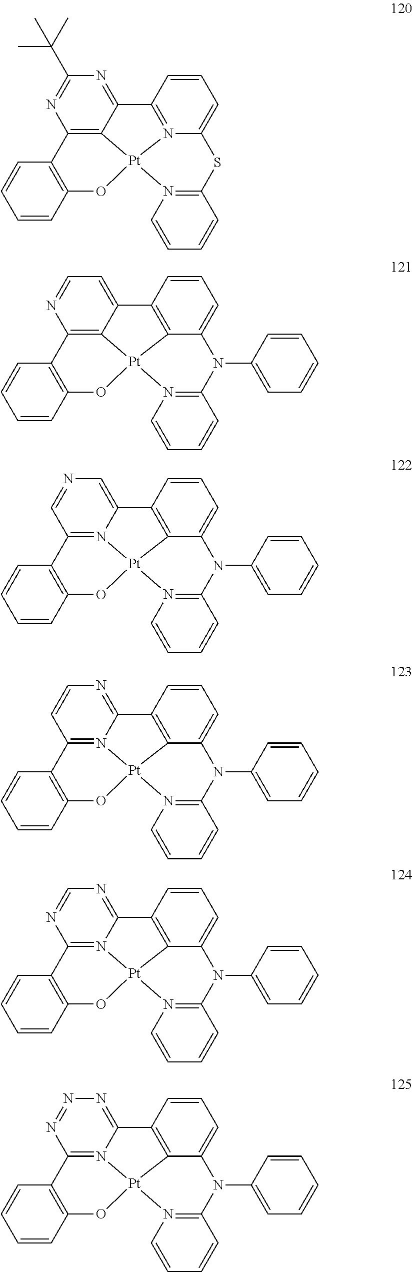

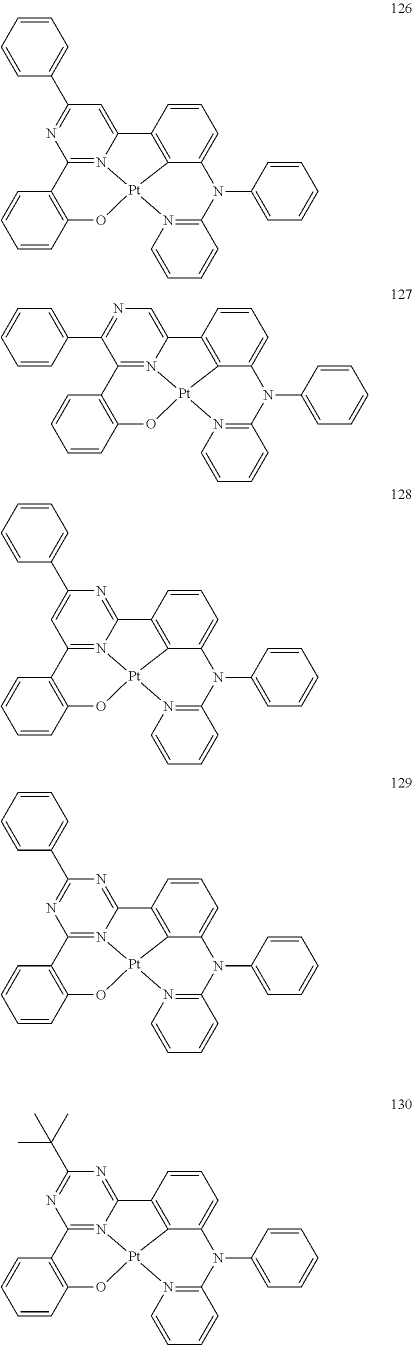

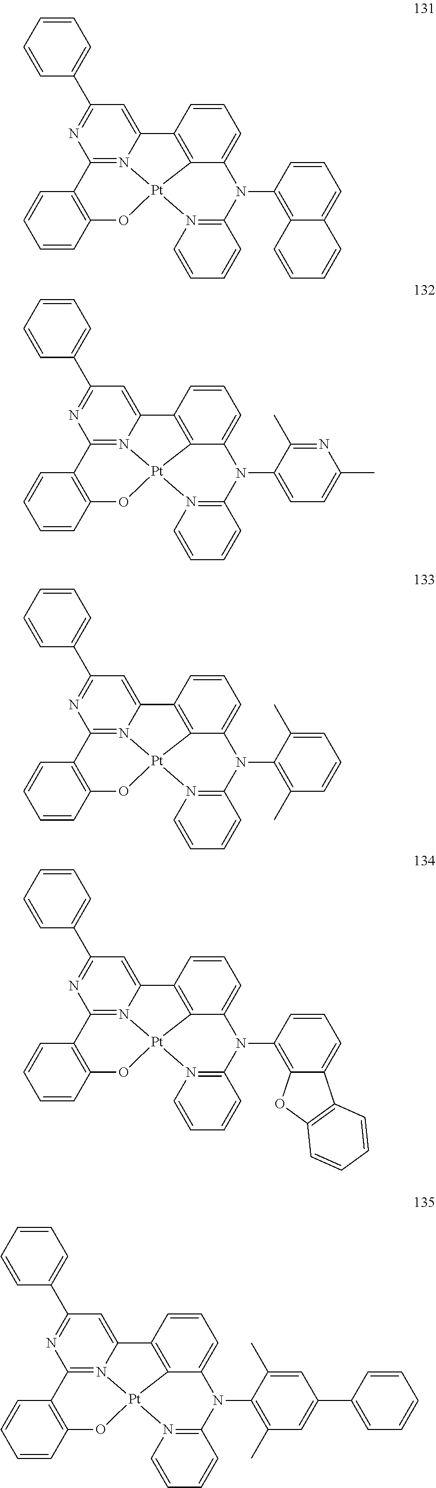

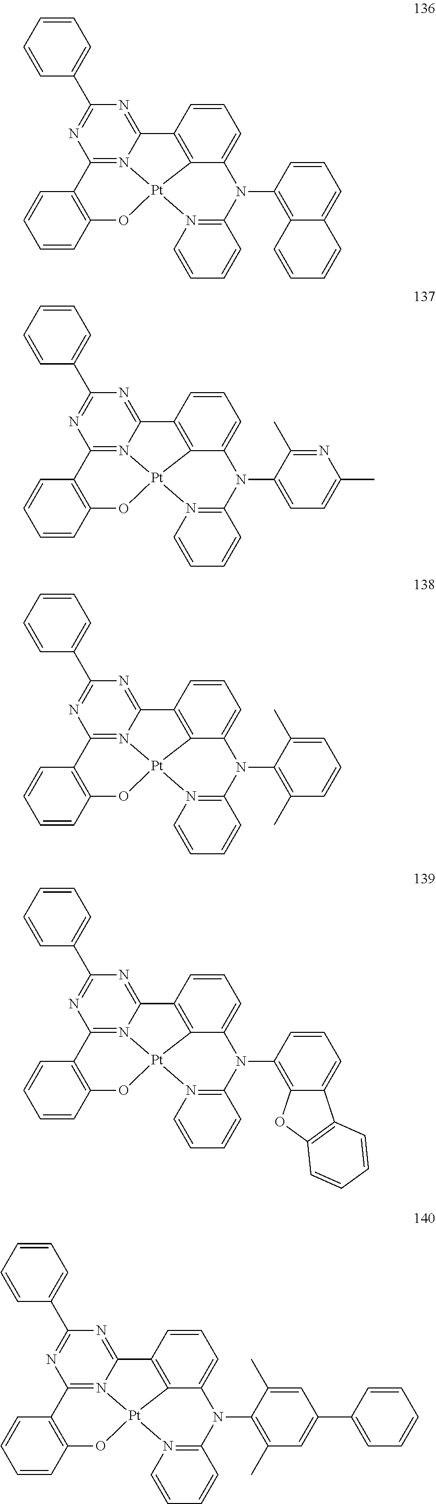

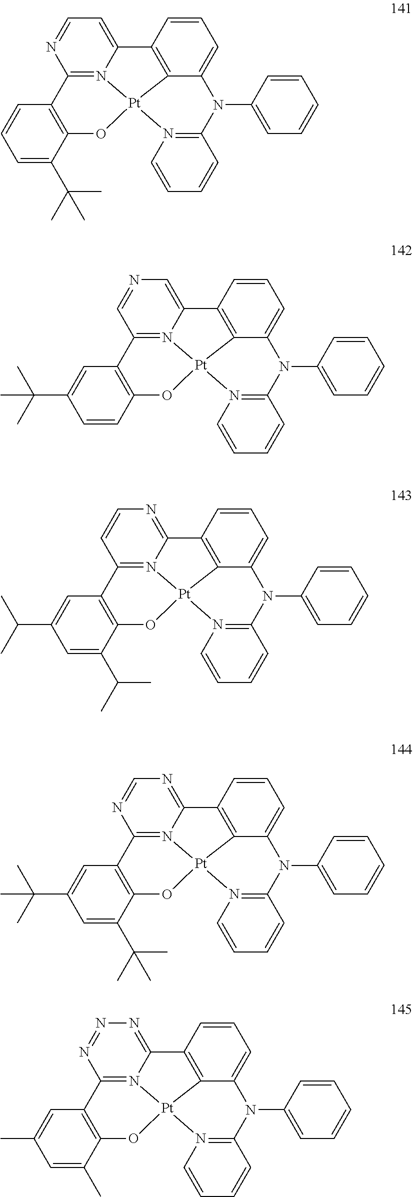

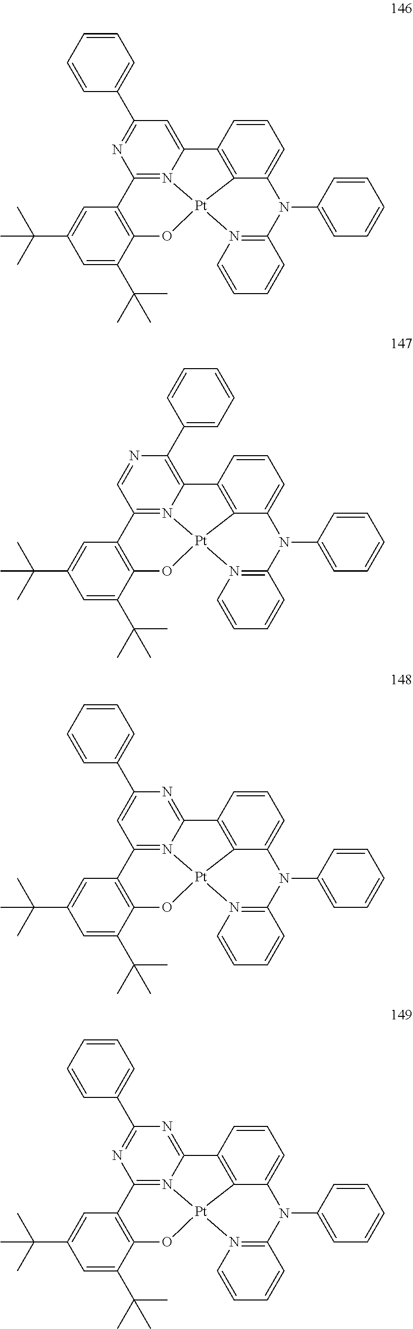

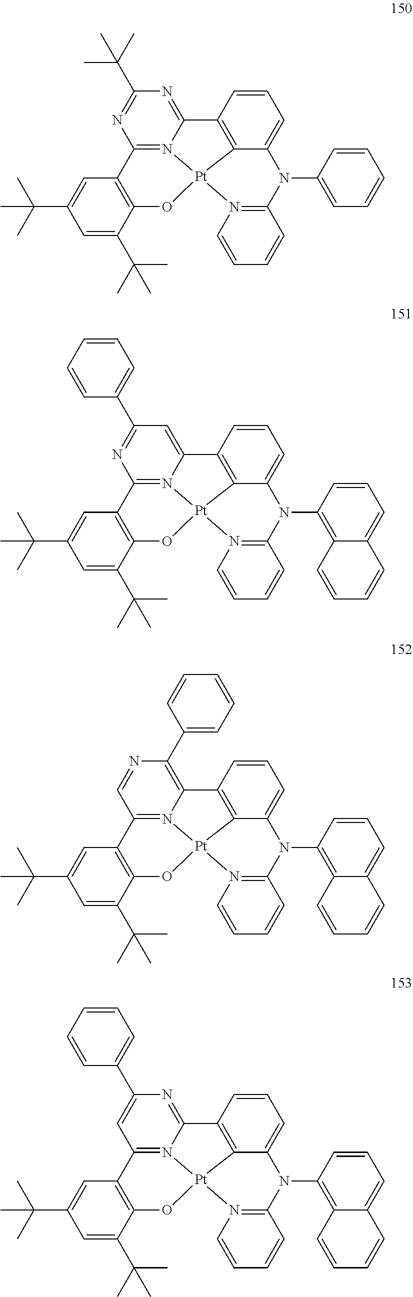

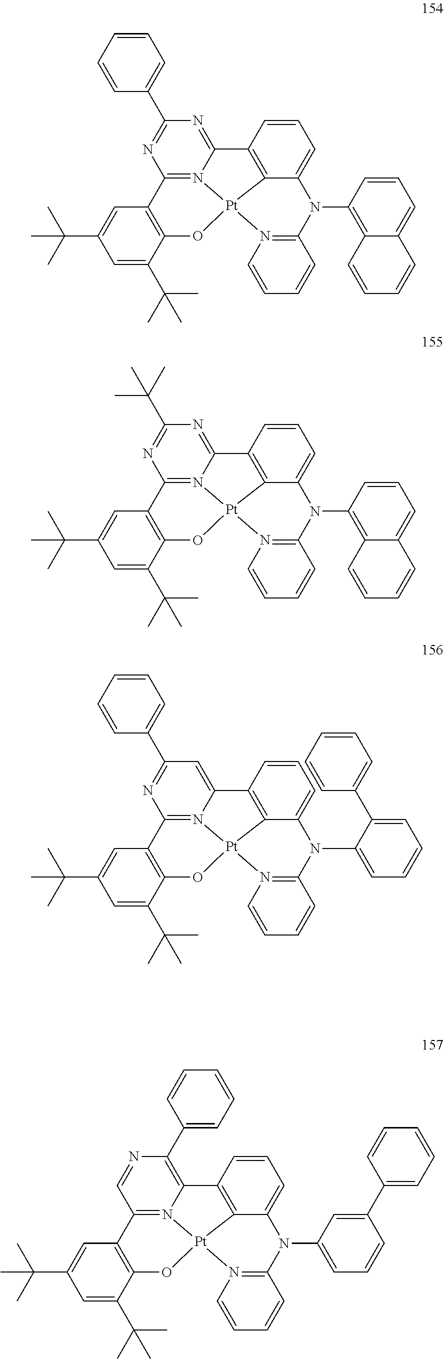

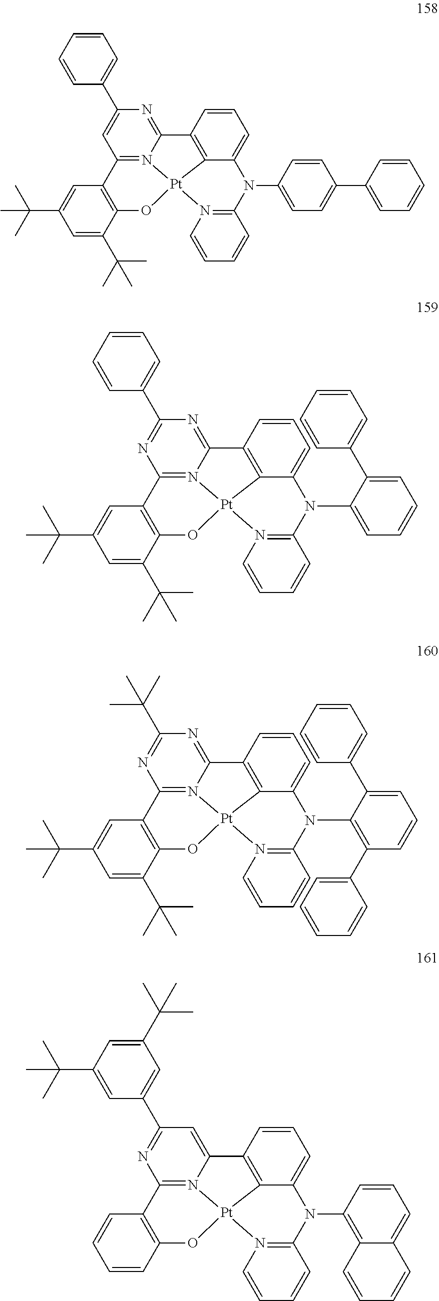

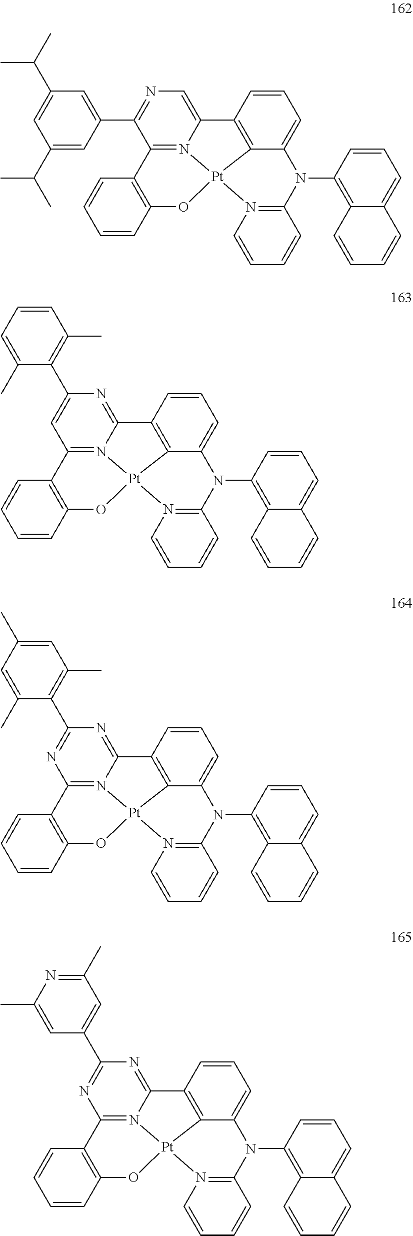

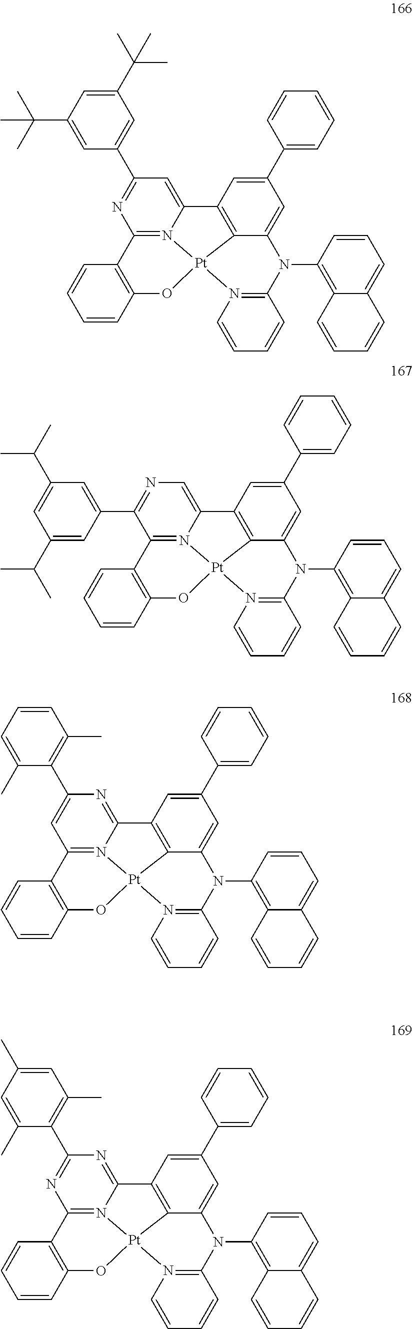

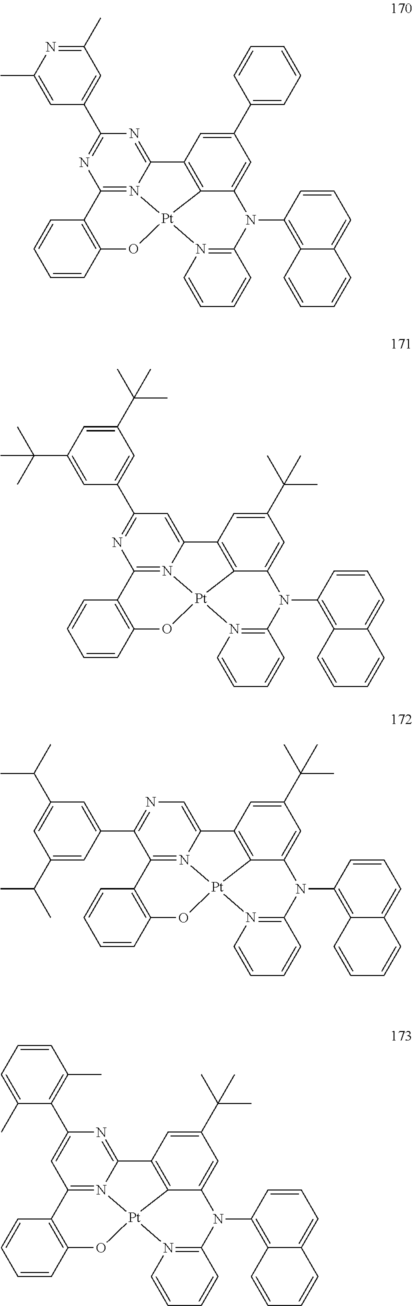

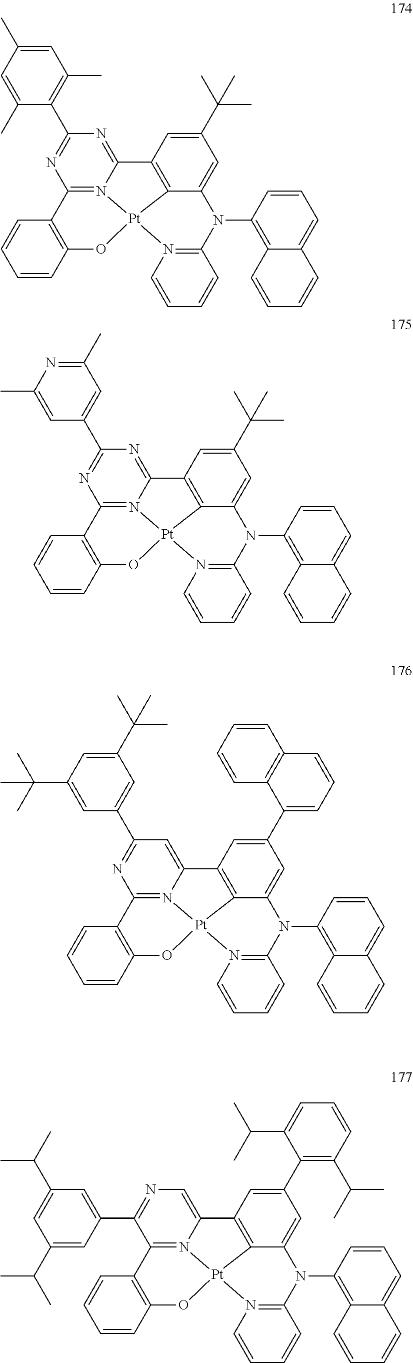

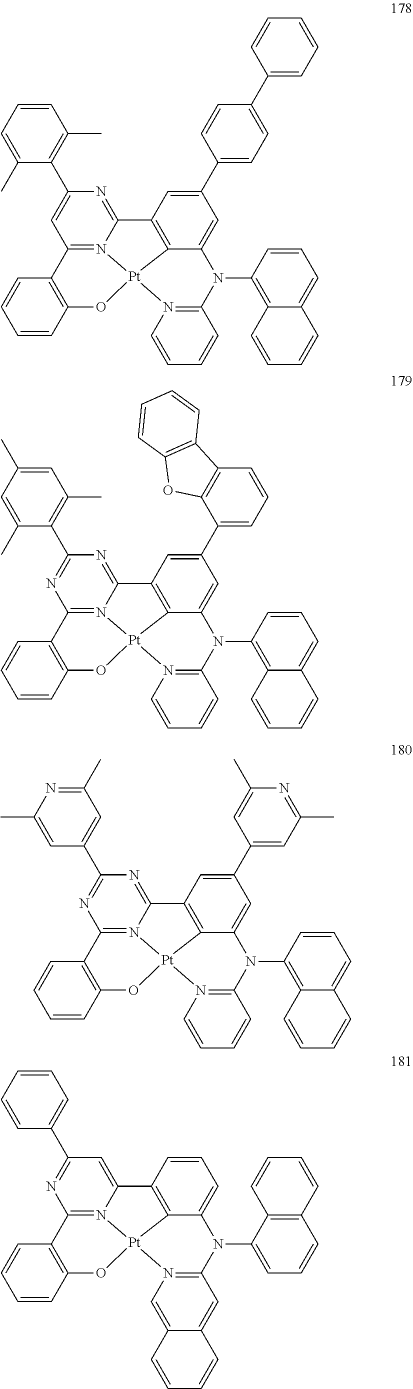

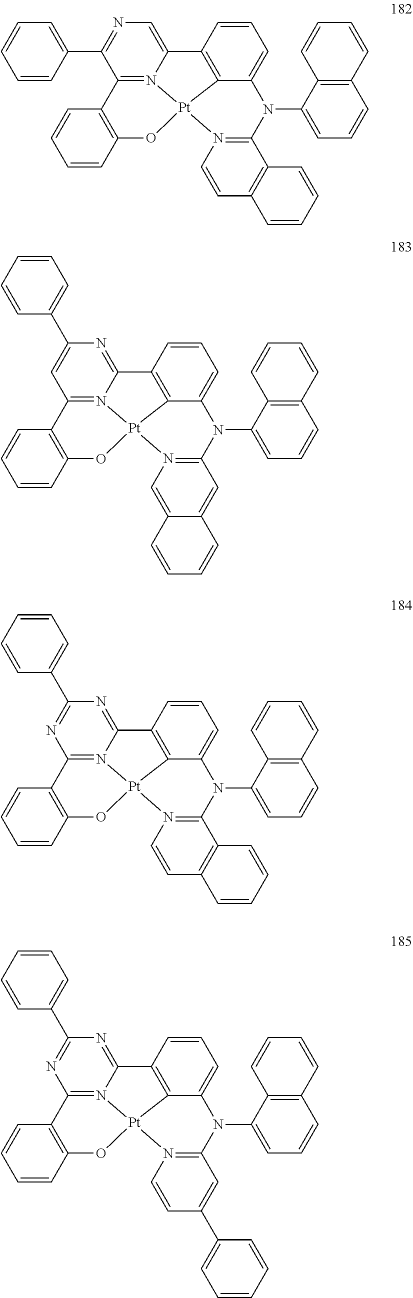

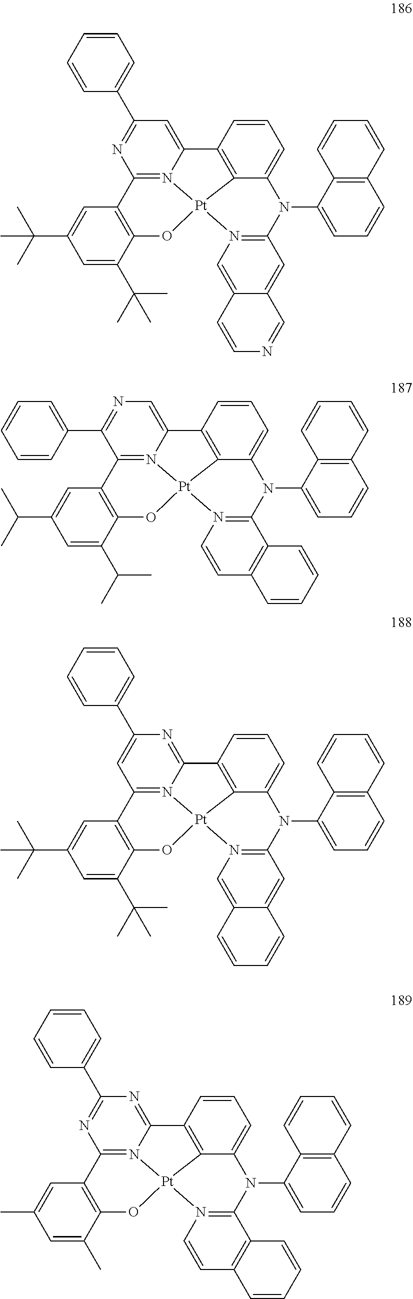

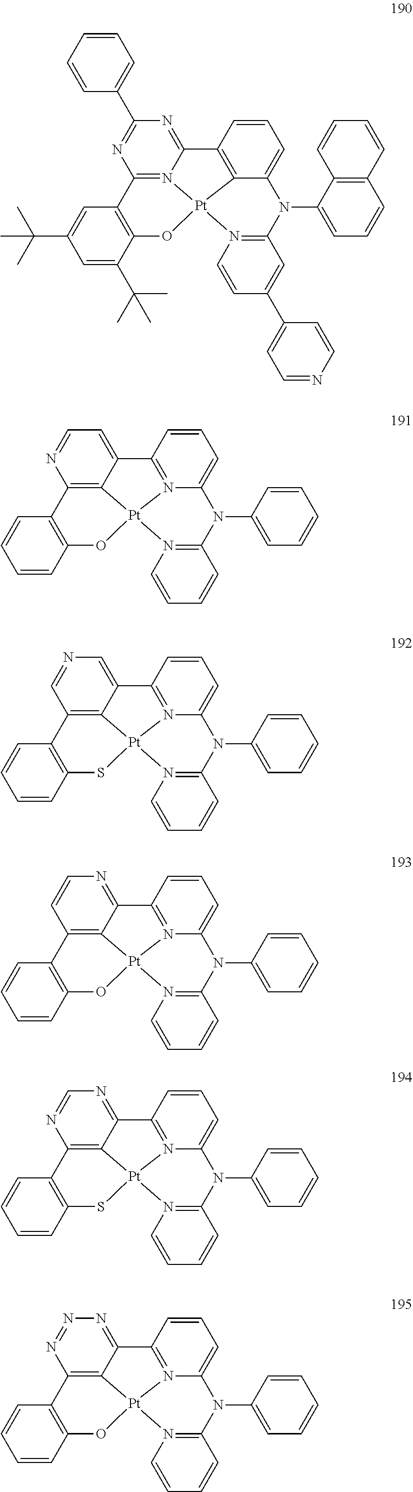

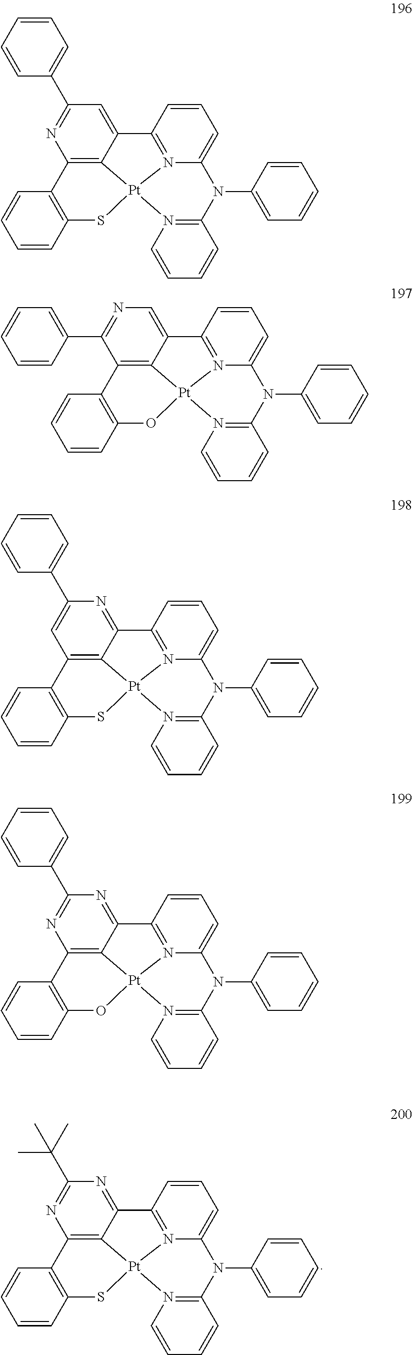

In Formula 1, the first ring does not include N as a ring-forming atom, and the third ring and the fourth ring do not include N as a ring-forming atom, except for X₃ and X₄ (see Formula 1′). Therefore, in Formula 1, the second ring acts as a main acceptor. Therefore, at the time of light emission, intensive energy transfer through the second ring may effectively occur.

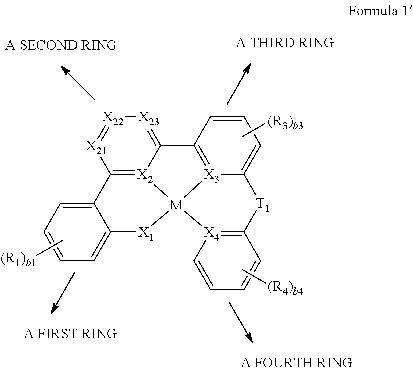

While not wishing to be bound to a specific theory, for example, rings other than a pyridine in a position corresponding to the second ring in Formula 1 in Compounds A, B, and C that do not satisfy the above conditions (that is, a pyridine ring of a position corresponding to the fourth ring of Formula 1 in Compound A, a pyridine ring of a position corresponding to the third ring of Formula 1 in Compound B, and a pyridine ring of a position corresponding to the first ring of Formula 1 in Compound C) may also act as an acceptor to disperse energy transfer at the time of light emission. Therefore, luminescent efficiency of an electronic device, for example, an organic light-emitting device, which includes Compound A, B, or C, may be deteriorated:

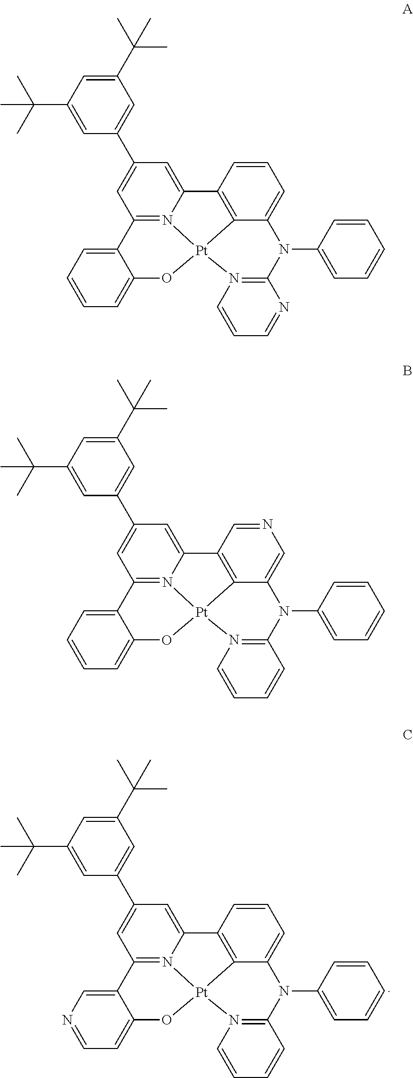

In addition, in Formula 1, X₂₁, X₂₂, X₂₃, or a combination thereof in the second ring is N. Therefore, in Formula 1, planarity between a donor (the first ring, the third ring, and the fourth ring in Formula 1) and an acceptor (the second ring in Formula 1) greatly increases, and non-radiative transition may greatly decrease at the time of light emission of the organometallic compound represented by Formula 1. Therefore, luminescent efficiency of an electronic device, for example, an organic light-emitting device, which includes the organometallic compound represented by Formula 1, may be improved.

In an exemplary embodiment, HOMO, LUMO, singlet (S₁), and triplet (T₁) energy levels of Compounds 16, 19, 151, and 154 were evaluated by a density functional theory (DFT) method of Gaussian program (structurally optimized at a level of B3LYP, 6-31G(d,p)), and results thereof are shown in Table 1.

TABLE 1

| Compound | | | S₁ energy | T₁ energy |
|---|---|---|---|---|
| No. | HOMO (eV) | LUMO (eV) | level (eV) | level (eV) |
| 16 | −4.744 | −2.027 | 2.144 | 1.988 |
| 19 | −4.923 | −2.101 | 2.173 | 2.068 |
| 151 | −4.580 | −1.853 | 2.147 | 1.984 |
| 154 | −4.748 | −1.920 | 2.225 | 2.058 |

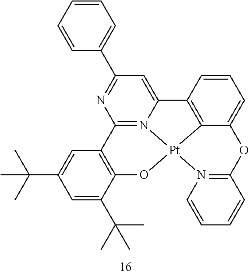

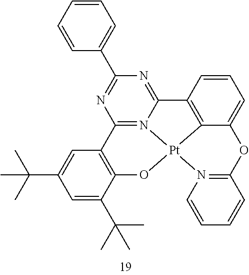

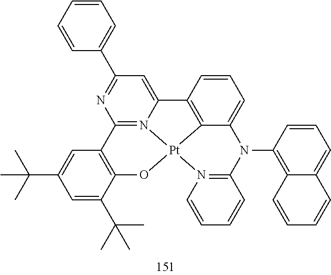

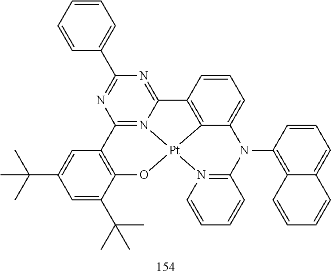

From Table 1, it is confirmed that the organometallic compound represented by Formula 1 has electric characteristics that are suitable for use in an electronic device, for example, for use as a material for an emission layer of an organic light-emitting device.

Synthetic methods of the organometallic compound represented by Formula 1 may be understood by one of ordinary skill in the art by referring to Synthesis Examples provided below.

The organometallic compound represented by Formula 1 is suitable for use in an organic layer of an organic light-emitting device, for example, for use as a material for forming an emission layer of the organic layer. Thus, another aspect of the present disclosure provides an organic light-emitting device that includes: a first electrode; a second electrode; and an organic layer that is disposed between the first electrode and the second electrode and includes an emission layer; and the organic layer includes an organometallic compound represented by Formula 1.

The organic light-emitting device may have, due to the inclusion of an organic layer including the organometallic compound represented by Formula 1, a low driving voltage, high luminescence efficiency, high power efficiency, high quantum emission efficiency, a long lifespan, a low roll-off ratio, and excellent color purity.

In one embodiment, in the organic light-emitting device, the first electrode may be an anode, and the second electrode may be a cathode, and the organic layer may further include a hole transport region between the first electrode and the emission layer and an electron transport region between the emission layer and the second electrode, and the hole transport region includes a hole injection layer, a hole transport layer, an electron blocking layer, or any combination thereof, and the electron transport region may include a hole blocking layer, an electron transport layer, an electron injection layer, or any combination thereof.

In one or more embodiments, the organometallic compound represented by Formula 1 may be included in the emission layer.

In one embodiment, the emission layer including the organometallic compound represented by Formula 1 may further include a host. The host may be any host, and the host is the same as described above. An amount of the host in the emission layer may be larger than an amount of the organometallic compound represented by Formula 1.

The organometallic compound included in the emission layer may act as an emitter. In an exemplary embodiment, the emission layer including the organometallic compound represented by Formula 1 may emit phosphorescence generated when triplet exciton of the organometallic compound transitions to a ground state.

In one or more embodiments, the emission layer may include a host and a dopant. The host may be any host, and the dopant may include the organometallic compound represented by Formula 1. The emission layer may emit phosphorescence generated when triplet exciton of the organometallic compound acting as a dopant transitions to a ground state.

In one or more embodiments, the emission layer including the organometallic compound represented by Formula 1 and the host may further include a fluorescent dopant. The fluorescent dopant may be any dopant capable of emitting fluorescence.

1) A singlet exciton generated in the host of the emission layer is transferred to the organometallic compound and the fluorescent dopant, and 2) i) a triplet exciton generated in the host and transferred to the organometallic compound and ii) a triplet exciton generated when a singlet exciton transferred to the organometallic compound is transited to a triplet excited state via intersystem crossing, are transferred to a singlet excited state of the fluorescent dopant and transited to a ground state to emit fluorescent light. Therefore, the emission layer utilizes not only the singlet exciton generated in the emission layer but also the triplet exciton to enable fluorescence emission. Therefore, as described above, the organic light-emitting device including the emission layer including the host, the organometallic compound represented by Formula 1, and the fluorescent dopant may emit fluorescent light having excellent color purity and full width at half maximum (FWHM) and also have high luminescent efficiency.

In an exemplary embodiment, the fluorescent dopant may be a condensed ring-containing compound, an amino group-containing compound, a styryl group-containing compound, or a boron-containing compound.

In one embodiment, the fluorescent dopant may include a naphthalene-containing compound, a fluorene-containing compound, a spiro-bifluorene-containing compound, a benzofluorene-containing compound, a dibenzofluorene-containing compound, a phenanthrene-containing compound, an anthracene-containing compound, a fluoranthene-containing compound, a triphenylene-containing compound, a pyrene-containing compound, a chrysene-containing compound, a naphthacene-containing compound, a picene-containing compound, a perylene-containing compound, a pentaphene-containing compound, an indenoanthracene-containing compound, a tetracene-containing compound, a bisanthracene-containing compound, a compound including a group represented by Formulae 501-1 to 501-21, or any combination thereof, but embodiments of the present disclosure are not limited thereto:

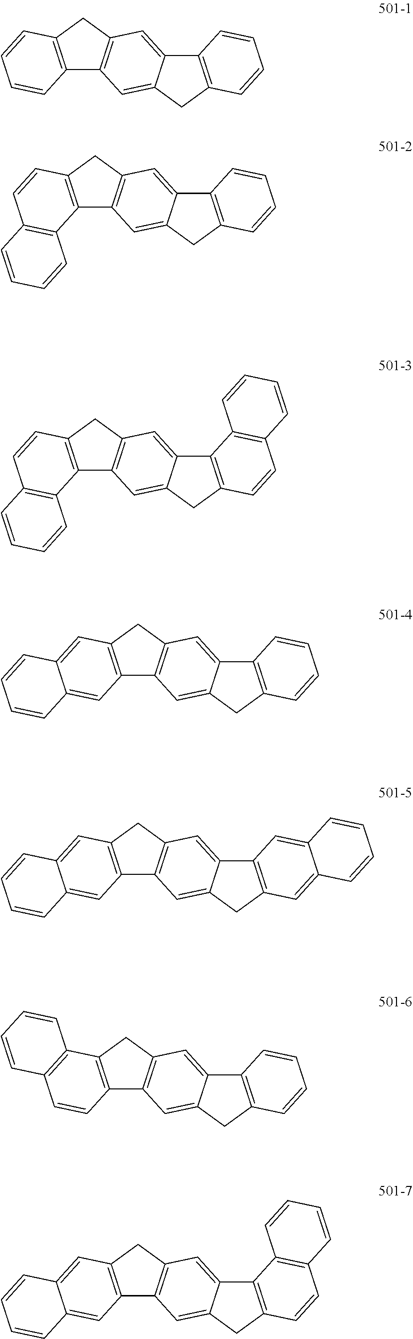

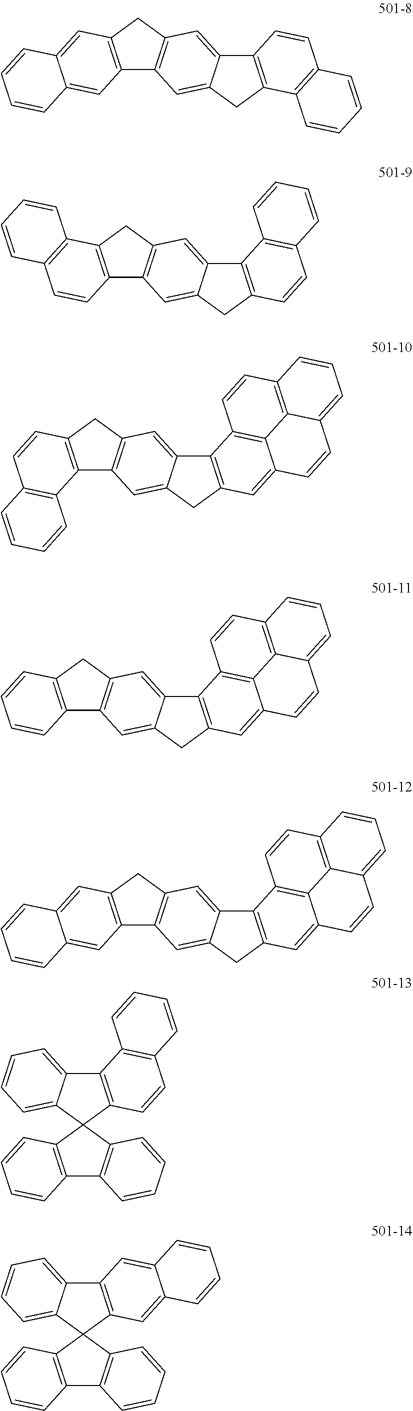

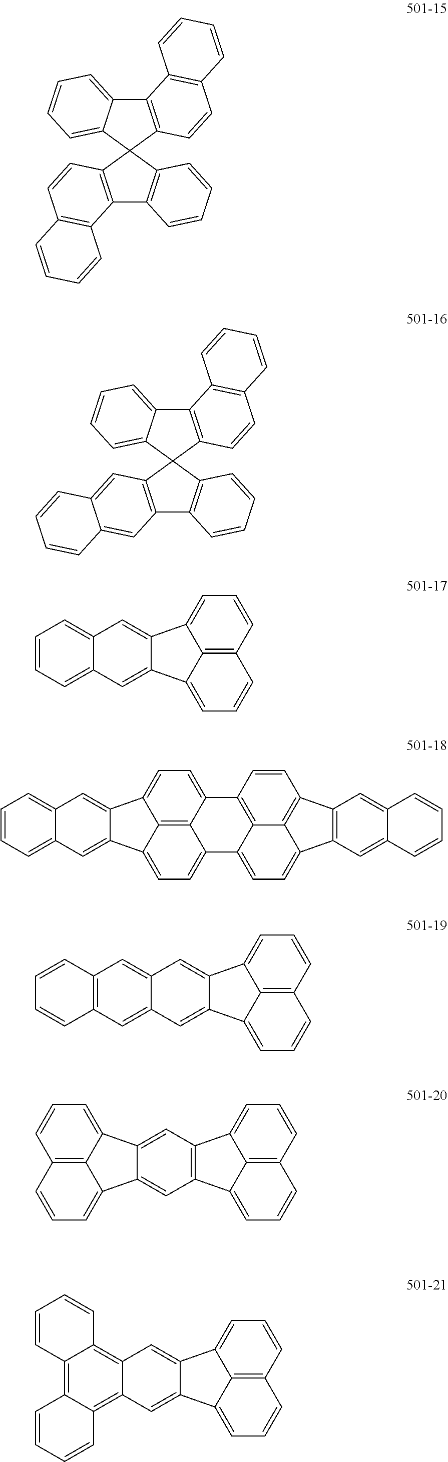

In one or more embodiments, the fluorescent dopant may include a compound represented by Formulae 501A or 1B below, but embodiments of the present disclosure are not limited thereto:

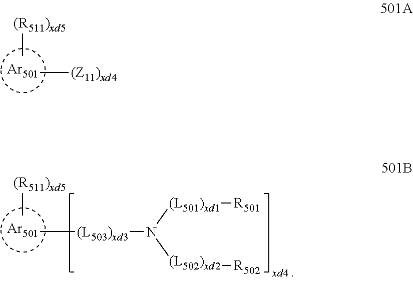

In Formulae 501A and 501B,

Ar₅₀₁ may be a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a naphthacene group, a picene group, a perylene group, a pentaphene group, an indenoanthracene group, a tetracene group, a bisanthracene group, or a group represented by one of Formulae 501-1 to 501-21,

R₅₁₁ may be hydrogen, deuterium, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or —Si(Q₅₀₁)(Q₅₀₂)(Q₅₀₃),

xd5 may be an integer from 0 to 10,

L₅₀₁ to L₅₀₃ may each independently be:

a single bond; or

a C₃-C₁₀ cycloalkylene group, a C₂-C₁₀ heterocycloalkylene group, a C₃-C₁₀ cycloalkenylene group, a C₂-C₁₀ heterocycloalkenylene group, a C₆-C₆₀ arylene group, a C₁-C₆₀ heteroarylene group, a divalent non-aromatic condensed polycyclic group, or a divalent non-aromatic condensed heteropolycyclic group, each unsubstituted or substituted with deuterium, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₅₀₅)(Q₅₀₂)(Q₅₀₃), or a combination thereof,

xd1 to xd3 may each independently be 1, 2, or 3,

R₅₀₁ and R₅₀₂ may each independently be a phenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, a dibenzothiophenyl group, or a dibenzosilolyl group, each unsubstituted or substituted with hydrogen, deuterium, a C₁-C₂₀ alkoxy group, a pyridinyl group, a pyrimidinyl group, a pyridazinyl group, a pyrazinyl group, a triazinyl group, a quinolinyl group, an isoquinolinyl group, a quinoxalinyl group, a quinazolinyl group, a phenanthrolinyl group, or a combination thereof,

xd4 may be 1, 2, 3, 4, 5, or 6, and

Q₅₀₁ to Q₅₀₃ may each independently be hydrogen, a C₁-C₆₀ alkyl group, a C₁-C₆₀ alkoxy group, a C₆-C₆₀ aryl group, a C₁-C₆₀ heteroaryl group, a monovalent non-aromatic condensed polycyclic group, or a monovalent non-aromatic condensed heteropolycyclic group. Here, Q₅₀₁ to Q₅₀₃ may each independently the same as defined in connection with Q₁.

In one or more embodiments, the fluorescent dopant may include one of Compounds FD(1) to FD(16), FD1 to FD13, or any combination thereof:

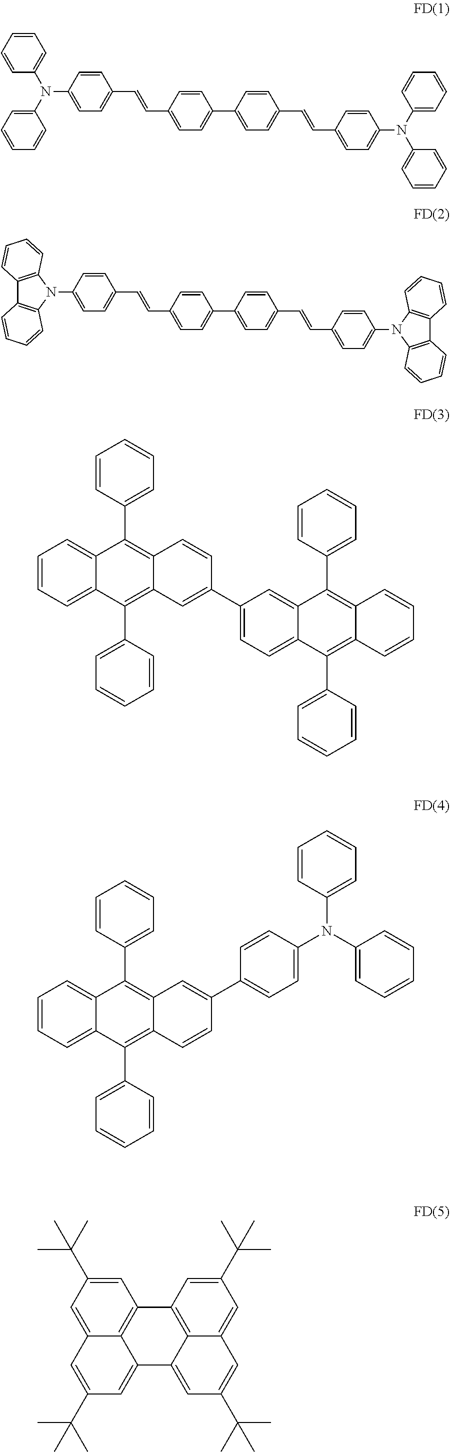

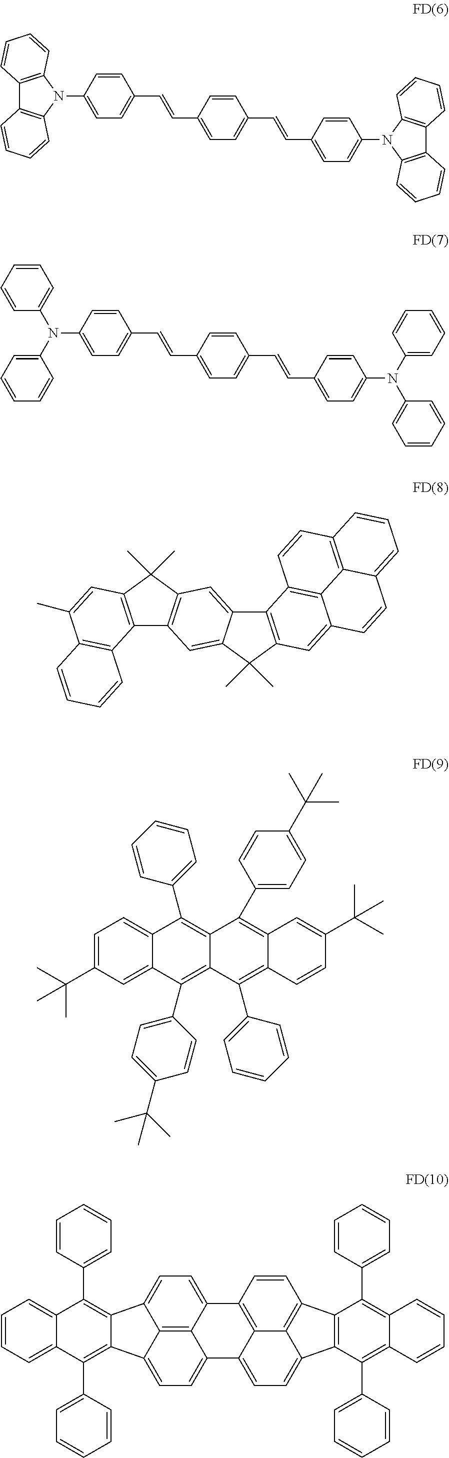

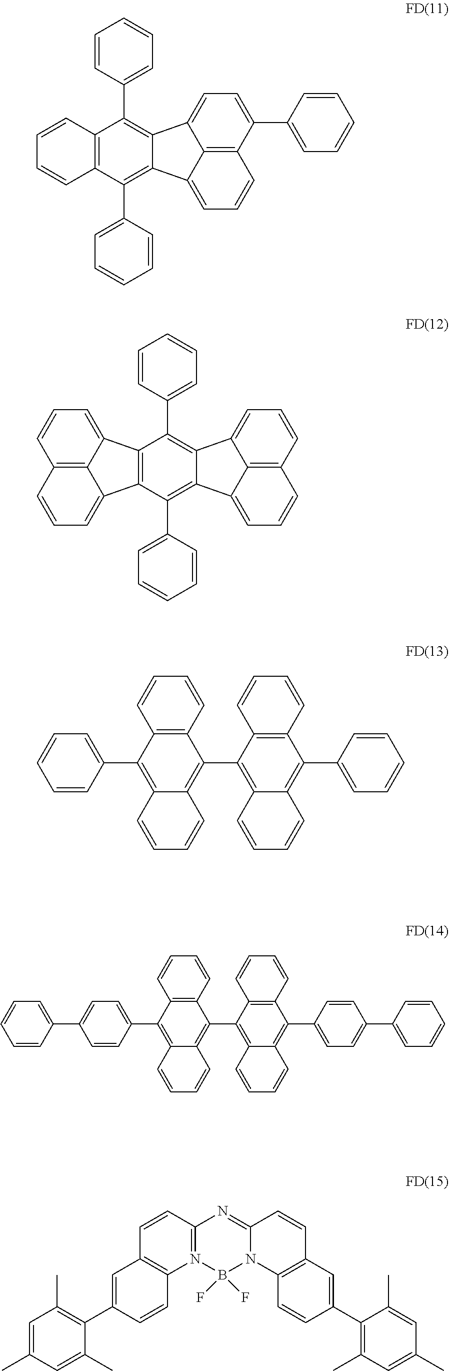

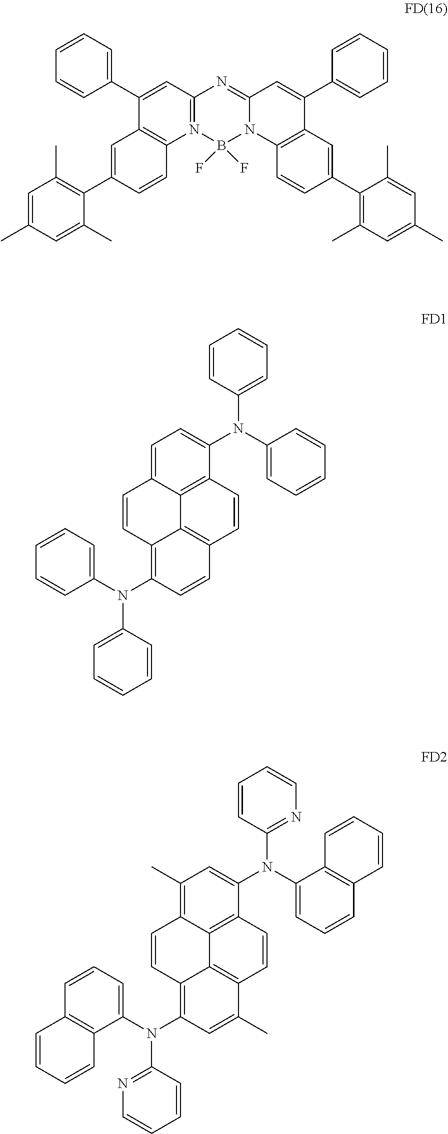

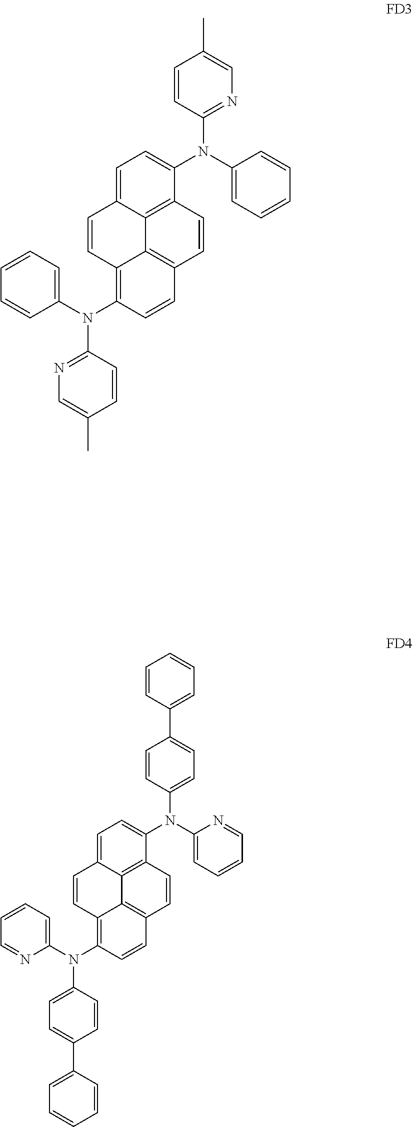 [SMILES: Cc1ccc(N(c2ccccc2)c2ccc3ccc4c(N(c5ccccc5)c5ccc(C)cn5)ccc5ccc2c3c54)nc1 ; c1ccc(-c2ccc(N(c3ccccn3)c3ccc4ccc5c(N(c6ccc(-c7ccccc7)cc6)c6ccccn6)ccc6ccc3c4c65)cc2)cc1]

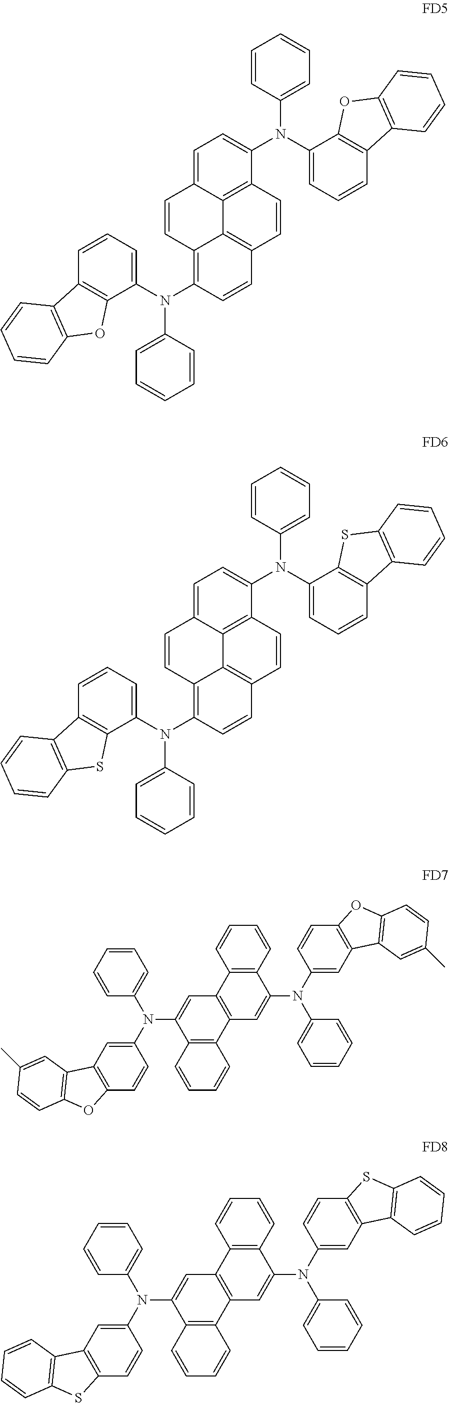

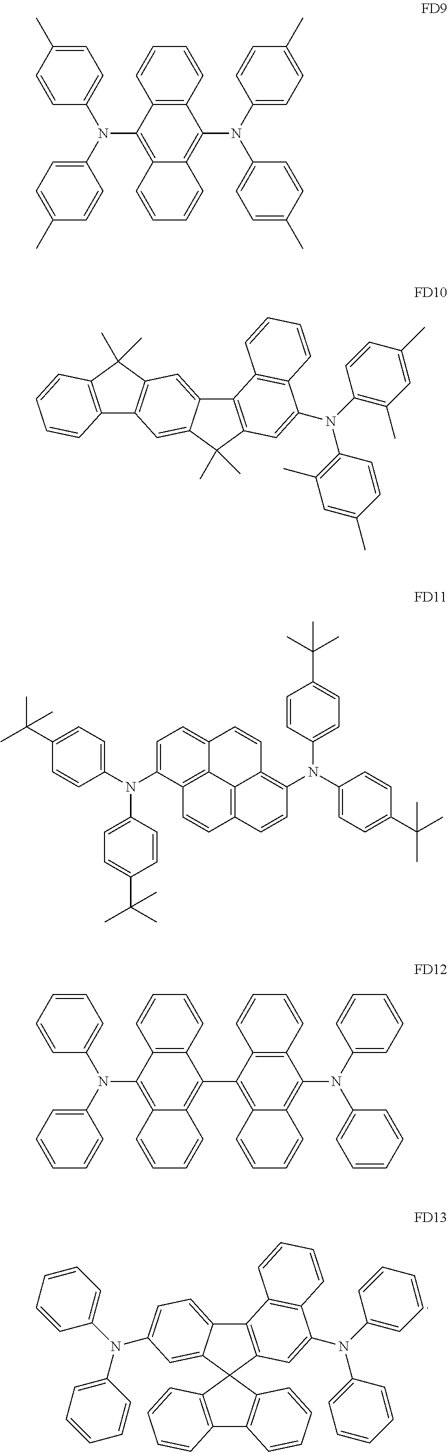

The expression “(an organic layer) includes an organometallic compound” used herein may include a case in which “(an organic layer) includes identical organometallic compounds represented by Formula 1” and a case in which “(an organic layer) includes two or more different organometallic compounds represented by Formula 1.”

In an exemplary embodiment, the organic layer may include, as the organometallic compound, only Compound 1. In this regard, Compound 1 may exist in an emission layer of the organic light-emitting device. In one or more embodiments, the organic layer may include, as the organometallic compound, Compound 1 and Compound 2. In this regard, Compound 1 and Compound 2 may exist in an identical layer (for example, Compound 1 and Compound 2 all may exist in an emission layer).

The term “organic layer” as used herein refers to a single layer and/or a plurality of layers between the first electrode and the second electrode of the organic light-emitting device. The “organic layer” may include, in addition to an organic compound, an organometallic complex including metal.

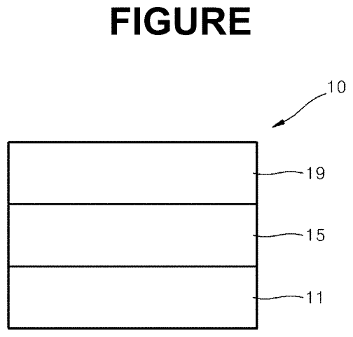

FIG. 1s a schematic view of an organic light-emitting device 10 according to an embodiment. Hereinafter, the structure of an organic light-emitting device according to an embodiment and a method of manufacturing an organic light-emitting device according to an embodiment will be described in connection with the FIGURE. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. The material for forming the first electrode 11 may be a material with a high work function to facilitate hole injection. The first electrode 11 may be a reflective electrode, a semi-transmissive electrode, or a transmissive electrode. The material for forming the first electrode may be, for example, indium tin oxide (ITO), indium zinc oxide (IZO), tin oxide (SnO₂), or zinc oxide (ZnO). In one or more embodiments, magnesium (Mg), aluminum (Al), aluminum-lithium (Al—Li), calcium (Ca), magnesium-indium (Mg—In), or magnesium-silver (Mg—Ag) may be used as the material for forming the first electrode.

The first electrode 11 may have a single-layered structure or a multi-layered structure including two or more layers. In an exemplary embodiment, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include a hole injection layer, a hole transport layer, an electron blocking layer, a buffer layer, or any combination thereof.

The hole transport region may include only either a hole injection layer or a hole transport layer. In one or more embodiments, the hole transport region may have a hole injection layer/hole transport layer structure or a hole injection layer/hole transport layer/electron blocking layer structure, which are sequentially stacked in this stated order from the first electrode 11.

A hole injection layer may be formed on the first electrode 11 by using a suitable method such as vacuum deposition, spin coating, casting, or Langmuir-Blodgett (LB) deposition.

When a hole injection layer is formed by vacuum deposition, the deposition conditions may vary according to a compound that is used to form the hole injection layer, and the structure and thermal characteristics of the hole injection layer. In an exemplary embodiment, the deposition conditions may include a deposition temperature of about 100° C. to about 500° C., a vacuum pressure of about 10⁻⁸ torr to about 10⁻³ torr, and a deposition rate of about 0.01 angstroms per second (Å/sec) to about 100 Å/sec. However, the deposition conditions are not limited thereto.

When the hole injection layer is formed using spin coating, coating conditions may vary according to the material used to form the hole injection layer, and the structure and thermal properties of the hole injection layer. In an exemplary embodiment, a coating speed may be from about 2,000 rpm to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include m-MTDATA, TDATA, 2-TNATA, NPB, P3-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201 below, a compound represented by Formula 202 below, or any combination thereof:

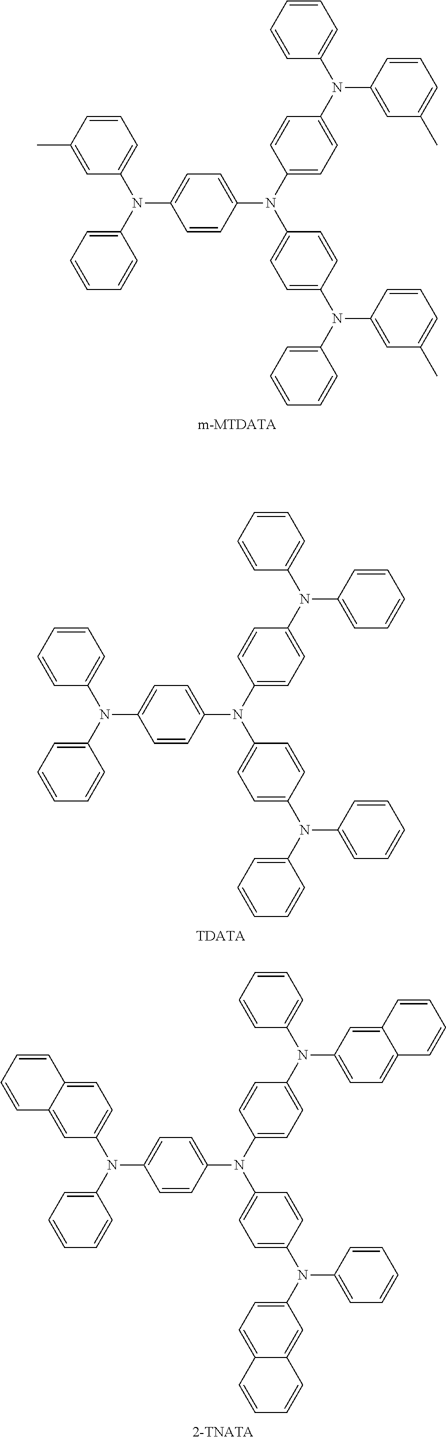

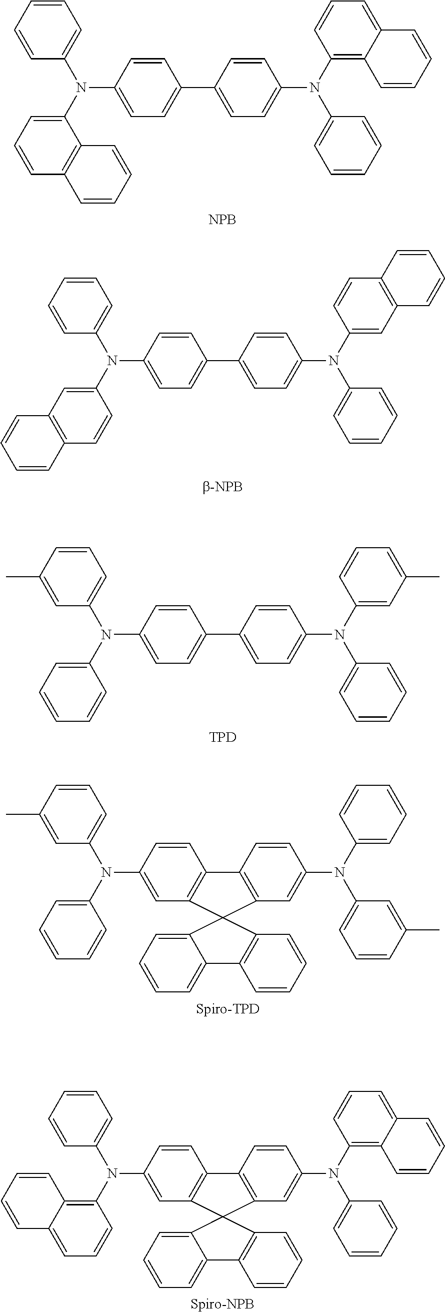

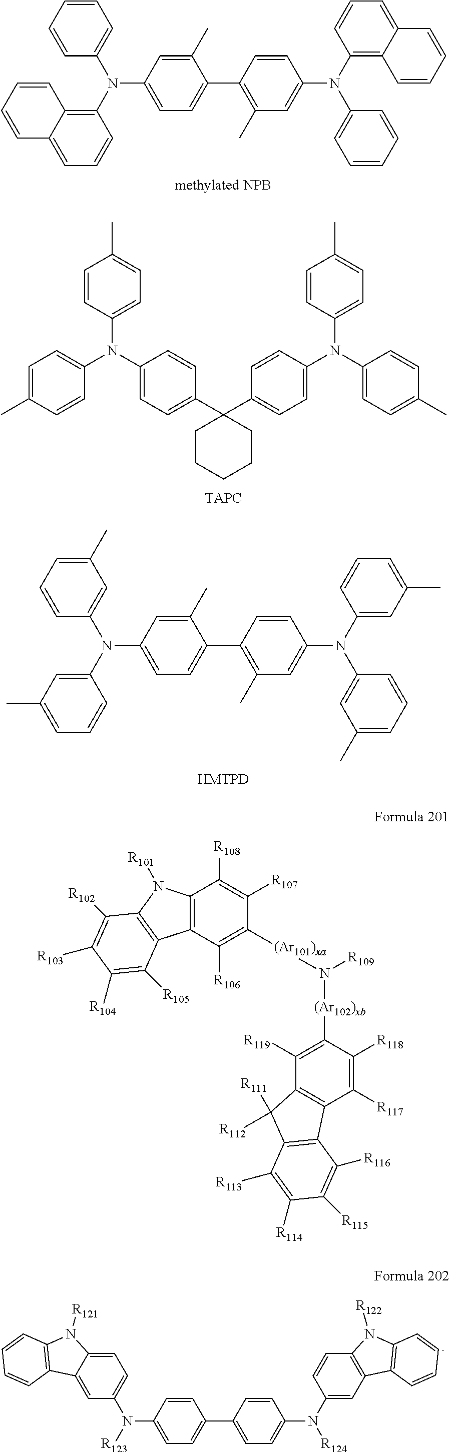

Ar₁₀₁ and Ar₁₀₂ in Formula 201 may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₂-C₁₀ heterocycloalkyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or a combination thereof.

In Formula 201, xa and xb may each independently be an integer from 0 to 5, or may be 0, 1, or 2. In an exemplary embodiment, xa is 1 and xb is 0, but xa and xb are not limited thereto.

R₁₀₁ to R₁₀₈, R₁₁₁ to R₁₁₉, and R₁₂₁ to R₁₂₄ in Formulae 201 and 202 may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, and so on), or a C₁-C₁₀ alkoxy group (for example, a methoxy group, an ethoxy group, a propoxy group, a butoxy group, a pentoxy group, and so on);

a C₁-C₁₀ alkyl group or a C₁-C₁₀ alkoxy group, each substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof; or

a phenyl group, a naphthyl group, an anthracenyl group, a fluorenyl group, or a pyrenyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, or a combination thereof, but embodiments of the present disclosure are not limited thereto.

R₁₀₉ in Formula 201 may be a phenyl group, a naphthyl group, an anthracenyl group, or a pyridinyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyridinyl group, or a combination thereof.

According to an embodiment, the compound represented by Formula 201 may be represented by Formula 201A, but embodiments of the present disclosure are not limited thereto:

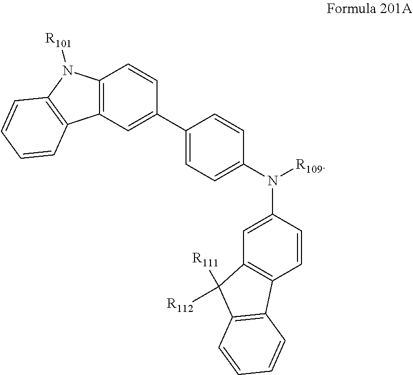

R₁₀₁, R₁₁₁, R₁₁₂, and R₁₀₉ in Formula 201A may be understood by referring to the description provided herein.

In an exemplary embodiment, the compound represented by Formula 201, and the compound represented by Formula 202 may include compounds HT1 to HT20 illustrated below, but are not limited thereto.

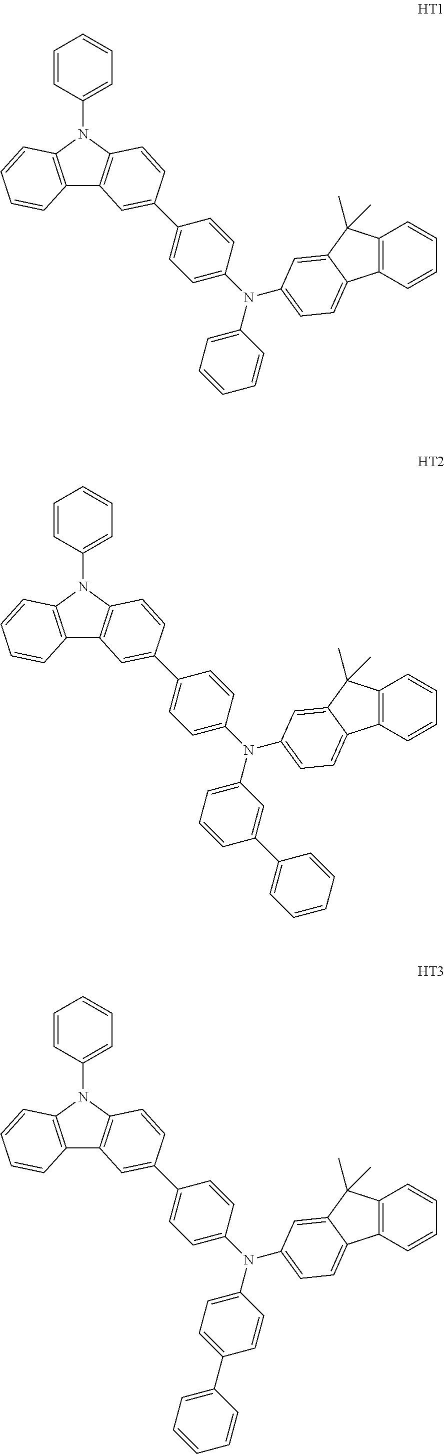 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

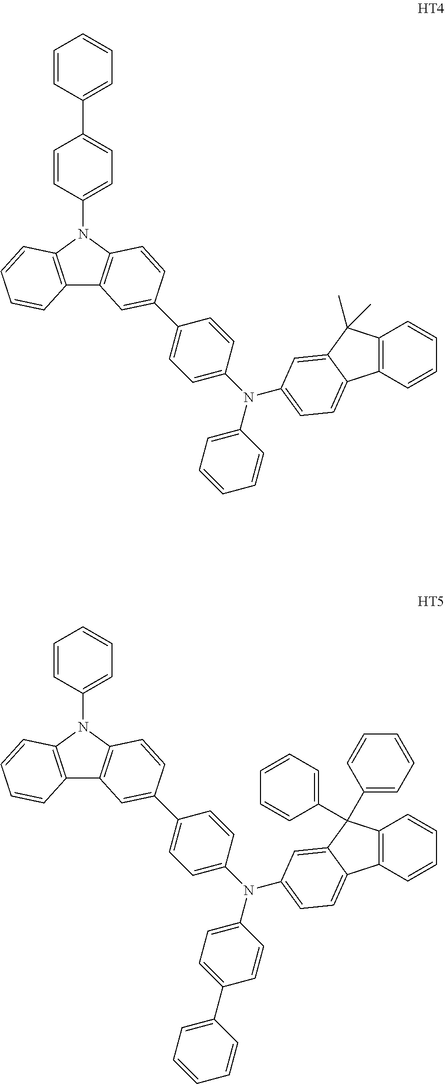 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

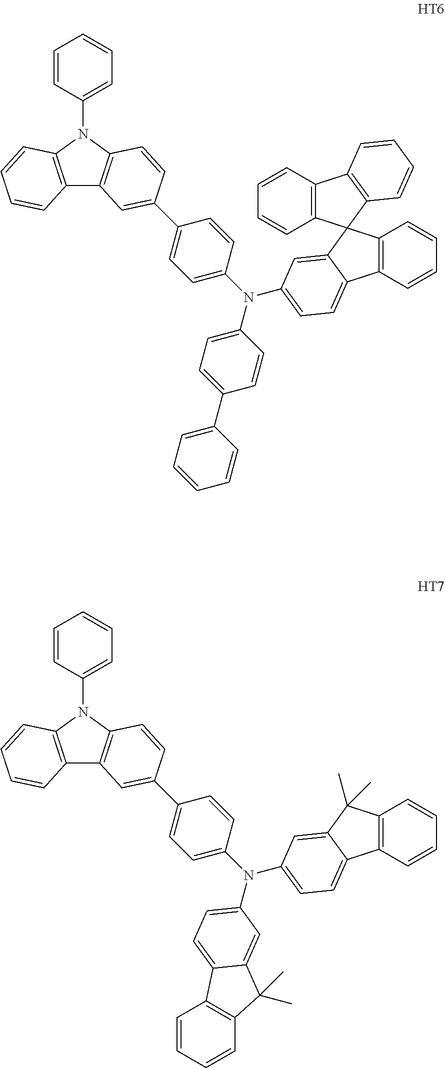 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

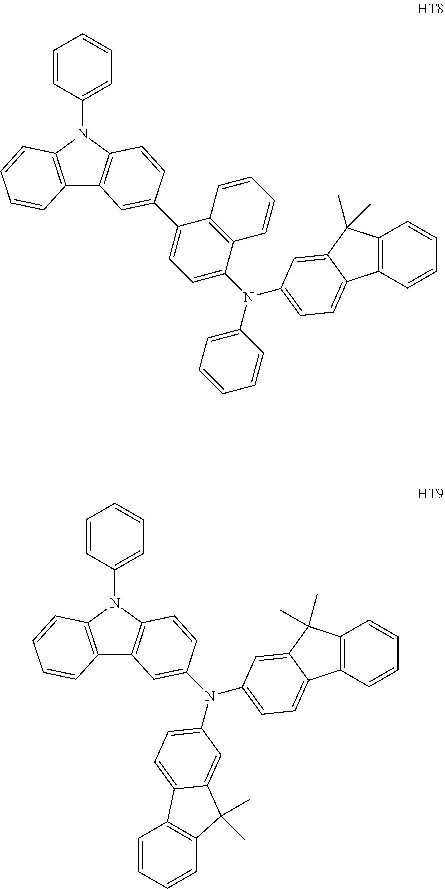 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

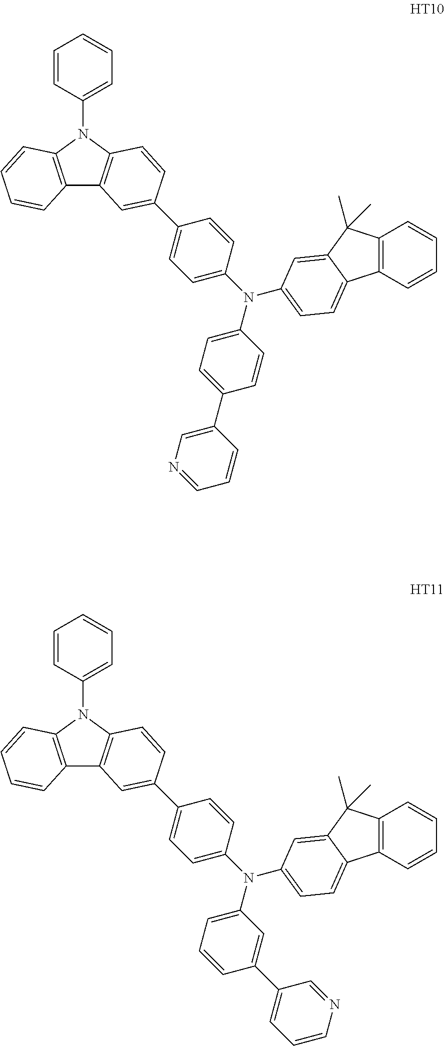 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

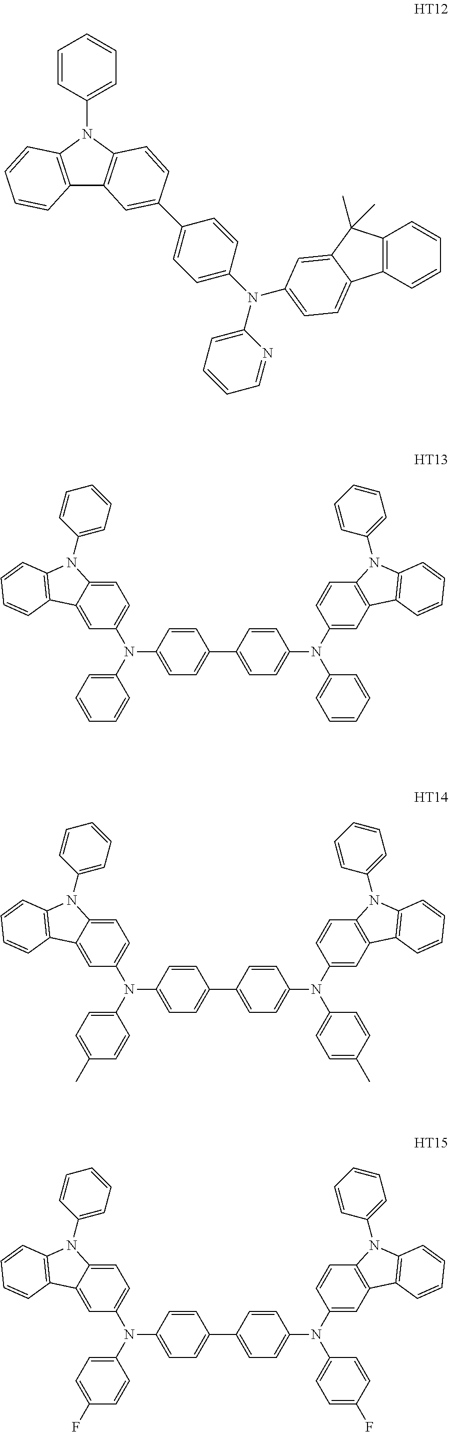 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

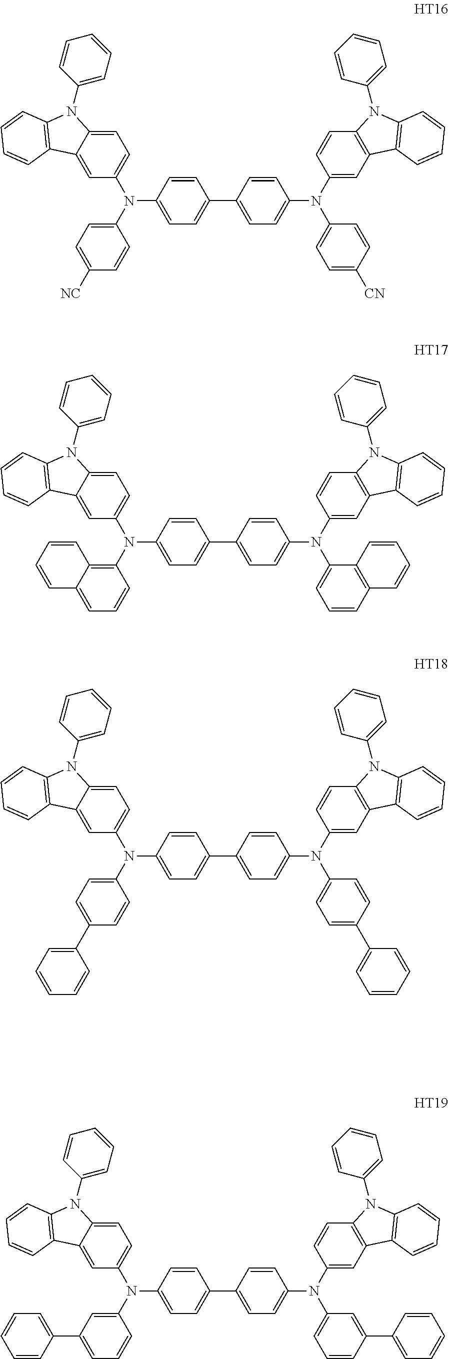 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

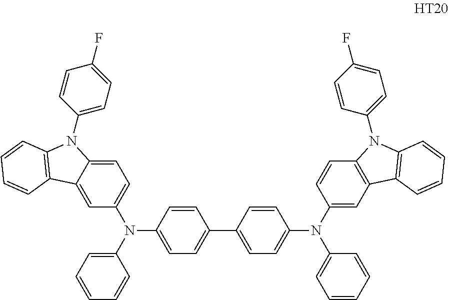 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 1,000 Å. When the hole transport region includes a hole injection layer, a hole transport layer, or a combination thereof, the thickness of the hole injection layer may be in a range of about 100 Å to about 10,000 Å, and for example, about 100 Å to about 1,000 Å, and the thickness of the hole transport layer may be in a range of about 50 Å to about 2,000 Å, and for example, about 100 Å to about 1500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be a quinone derivative, a metal oxide, or a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 below, but are not limited thereto.

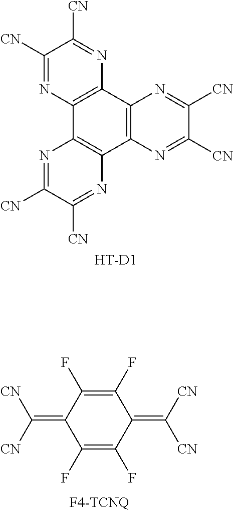

The hole transport region may include a buffer layer.

Also, the buffer layer may compensate for an optical resonance distance according to a wavelength of light emitted from the emission layer, and thus, efficiency of a formed organic light-emitting device may be improved.

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

When the hole transport region includes an electron blocking layer, a material for the electron blocking layer may be a material for the hole transport region described above or a material for a host to be explained later. However, the material for the electron blocking layer is not limited thereto. In an exemplary embodiment, when the hole transport region includes an electron blocking layer, a material for the electron blocking layer may be mCP, which will be explained later.

The emission layer may include a host and a dopant, and the dopant may include the organometallic compound represented by Formula 1.

The host may include TPBi, TBADN, ADN (also referred to as “DNA”), CBP, CDBP, TCP, mCP, Compound H50, Compound H51, or any combination thereof:

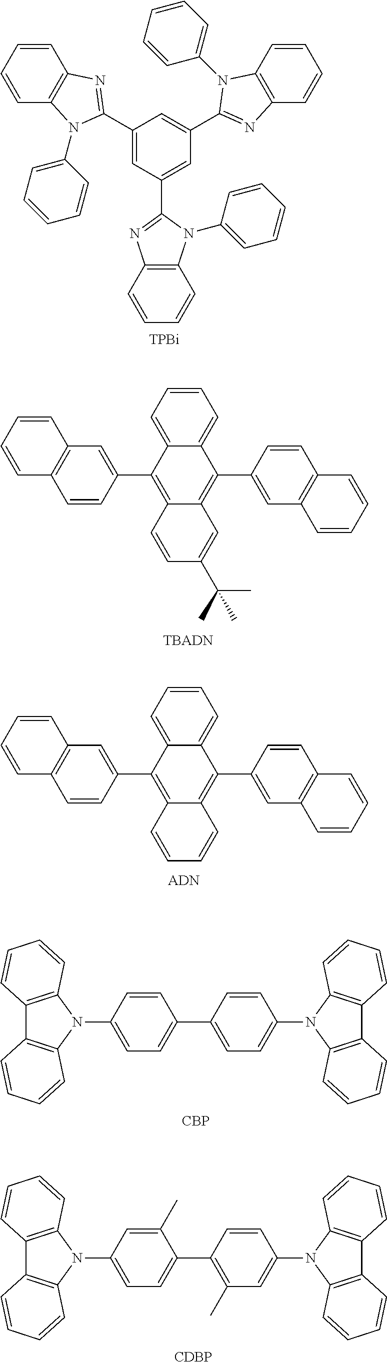

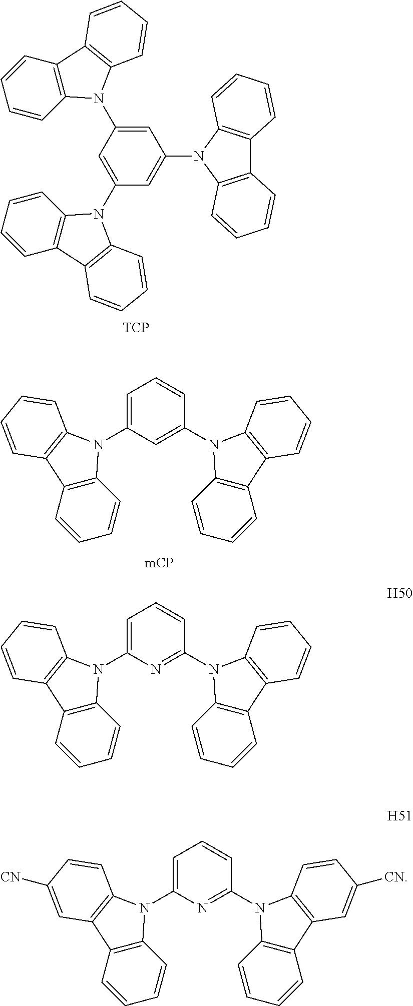

In one or more embodiments, the host may include a compound represented by Formula 301:

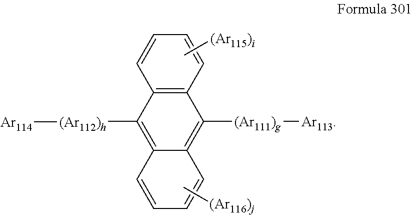

Ar₁₁₁ and Ar₁₁₂ in Formula 301 may each independently be a phenylene group, a naphthylene group, a phenanthrenylene group, or a pyrenylene group, each unsubstituted or substituted with a phenyl group, a naphthyl group, an anthracenyl group, or a combination thereof.

Ar₁₁₃ to Ar₁₁₆ in Formula 301 may each independently be:

a C₁-C₁ alkyl group, a phenyl group, a naphthyl group, a phenanthrenyl group, or a pyrenyl group; or

a phenyl group, a naphthyl group, a phenanthrenyl group, or a pyrenyl group, each substituted with a phenyl group, a naphthyl group, an anthracenyl group, or a combination thereof.

g, h, i, and j in Formula 301 may each independently be an integer from 0 to 4, and may be, for example, 0, 1, or 2.

Ar₁₁₃ to Ar₁₁₆ in Formula 301 may each independently be:

a C₁-C₁₀ alkyl group substituted with a phenyl group, a naphthyl group, an anthracenyl group, or a combination thereof;

a phenyl group, a naphthyl group, an anthracenyl group, a pyrenyl group, a phenanthrenyl group, or a fluorenyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a pyrenyl group, a phenanthrenyl group, a fluorenyl group, or a combination thereof; or

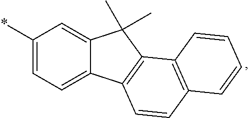 [SMILES: *c1ccc2c(c1)C(C)(C)c1c-2ccc2ccccc12]

but embodiments of the present disclosure are not limited thereto.

In one or more embodiments, the host may include a compound represented by Formula 302 below:

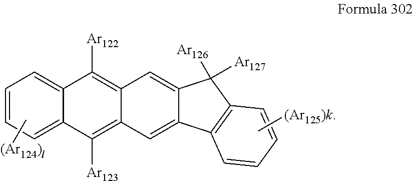

Ar₁₂₂ to Ar₁₂₅ in Formula 302 are the same as described in detail in connection with Ar₁₁₃ in Formula 301.

Ar₁₂₆ and Ar₁₂₇ in Formula 302 may each independently be a C₁-C₁₀ alkyl group (for example, a methyl group, an ethyl group, or a propyl group).

k and I in Formula 302 may each independently be an integer from 0 to 4. In an exemplary embodiment, k and I may be 0, 1, or 2.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

When the emission layer includes a host and a dopant, an amount of the dopant may be in a range of about 0.01 parts by weight to about 15 parts by weight based on 100 parts by weight of the host.

A thickness of the emission layer may be in a range of about 100 Å to about 1,000 Å, for example, about 200 Å to about 600 Å. When the thickness of the emission layer is within this range, excellent light-emission characteristics may be obtained without a substantial increase in driving voltage.

Then, an electron transport region may be disposed on the emission layer.

The electron transport region may include a hole blocking layer, an electron transport layer, an electron injection layer, or any combination thereof.

In an exemplary embodiment, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, BCP, Bphen, BAIq, or any combination thereof, but embodiments of the present disclosure are not limited thereto.

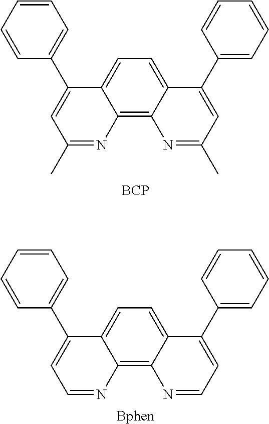

A thickness of the hole blocking layer may be in a range of about 20 Å to about 1,000 Å, for example, about 30 Å to about 300 Å. When the thickness of the hole blocking layer is within these ranges, the hole blocking layer may have improved hole blocking ability without a substantial increase in driving voltage.

The electron transport layer may include BCP, Bphen, Alq₃, BAIq, TAZ, NTAZ, or any combination thereof:

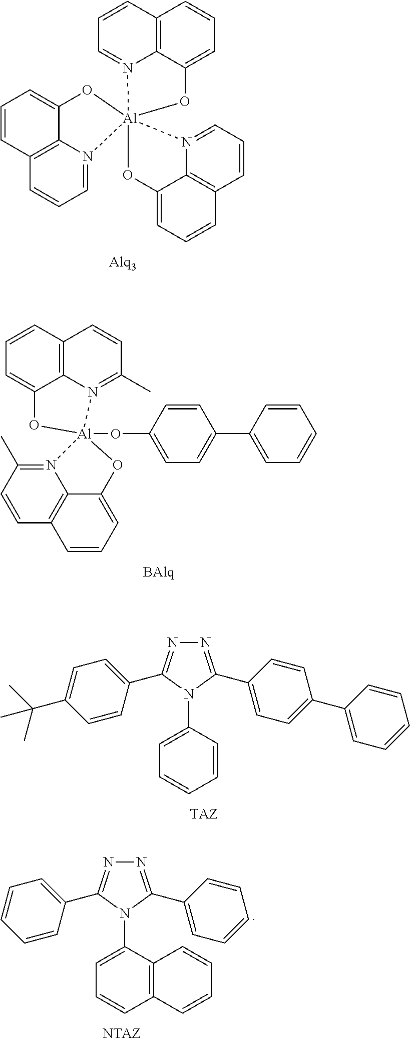

In one or more embodiments, the electron transport layer may include one of ET1 to ET25, or any combination thereof, but are not limited thereto:

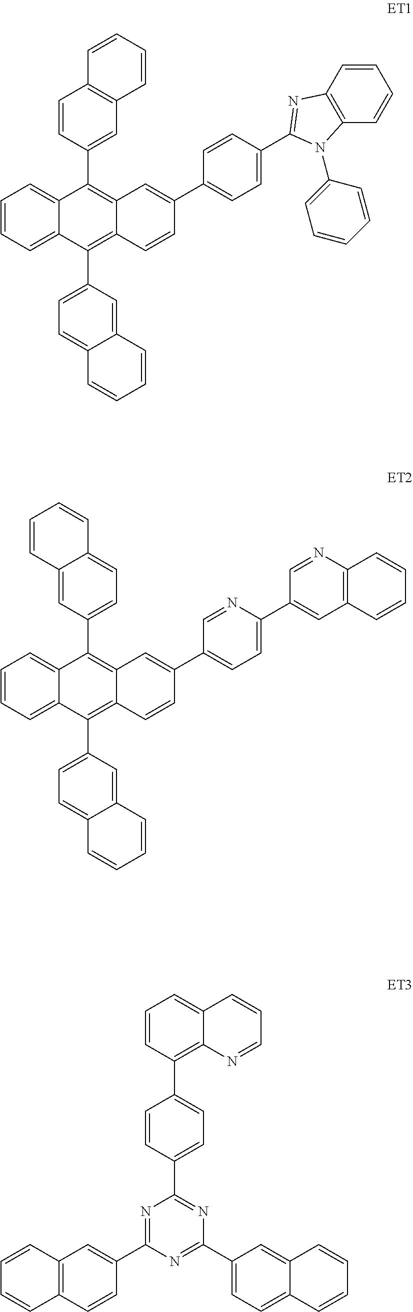 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

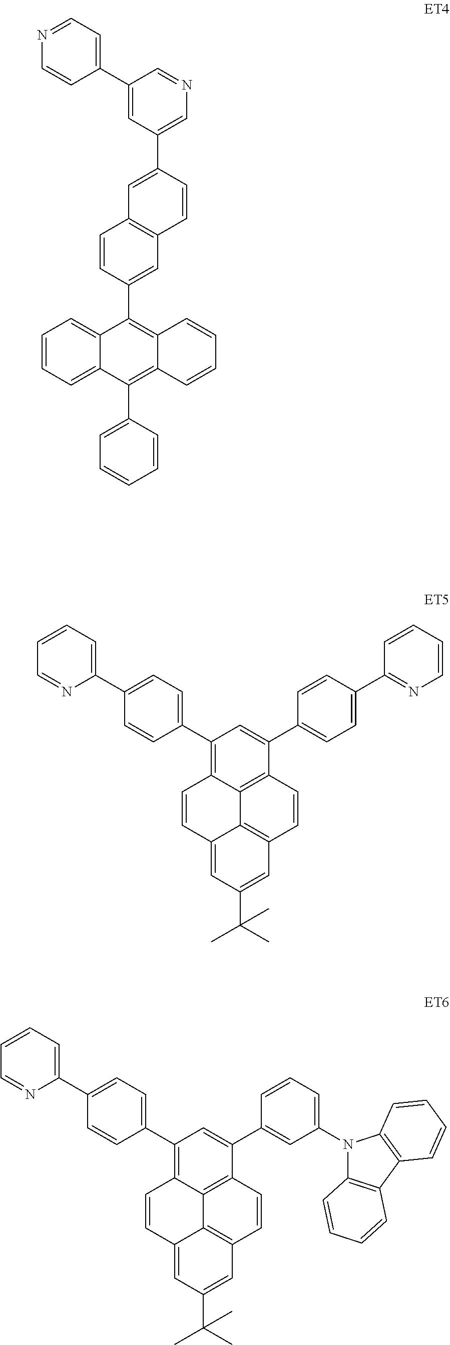 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

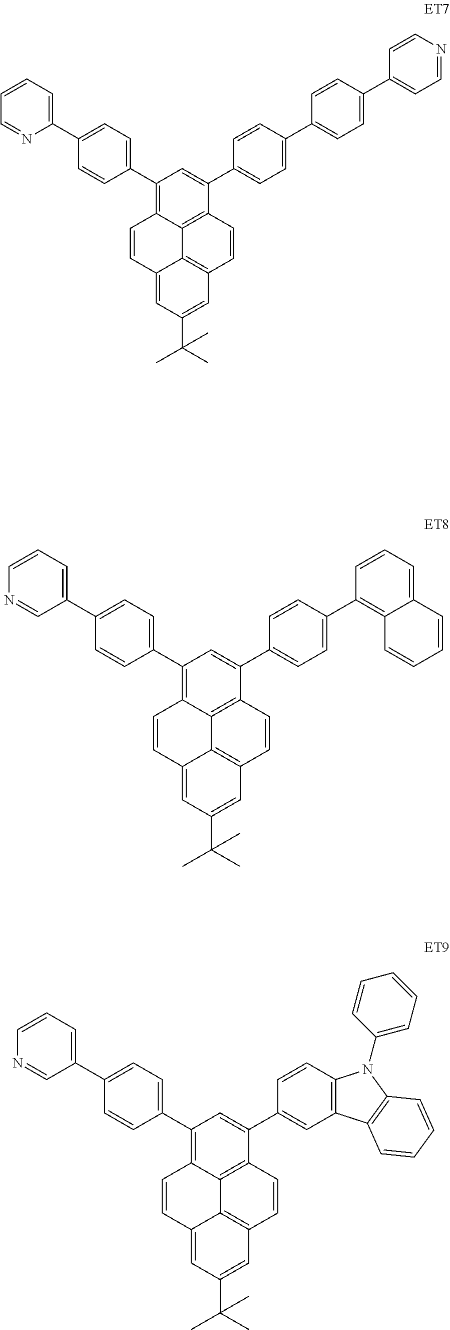 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

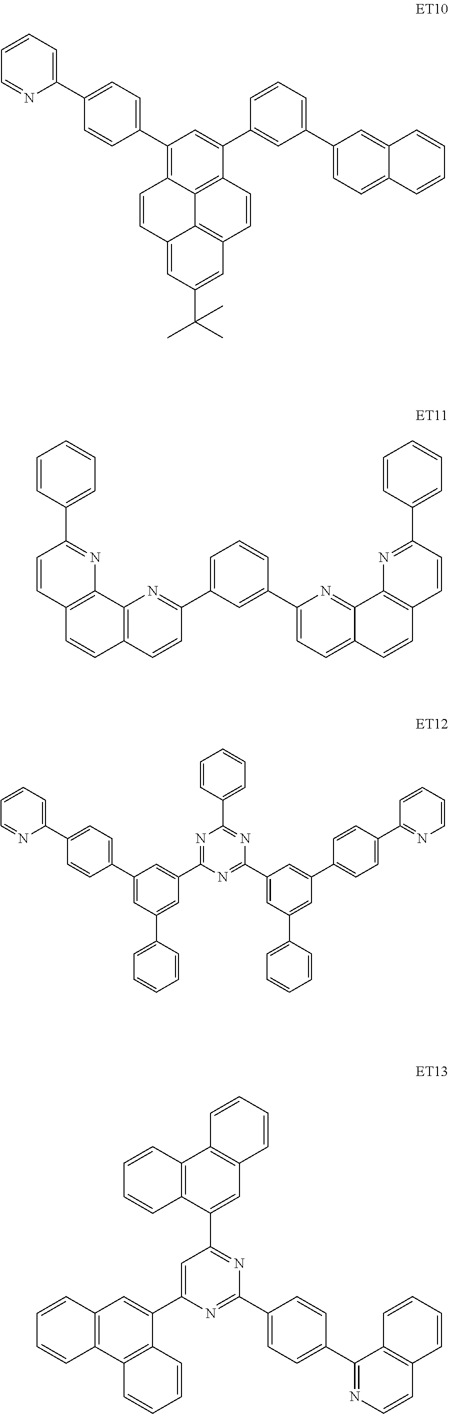 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1]

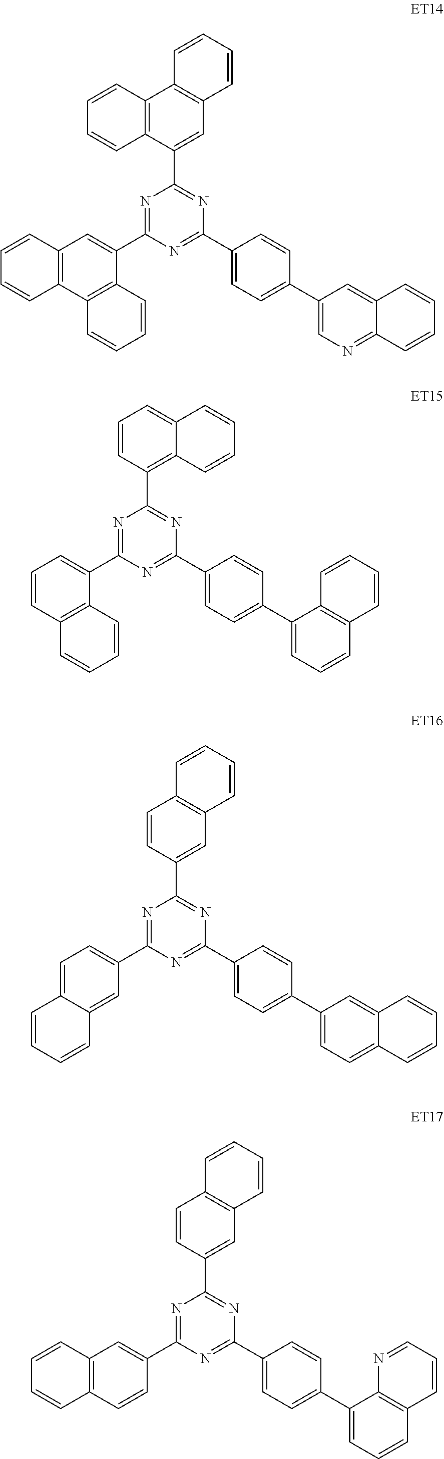 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

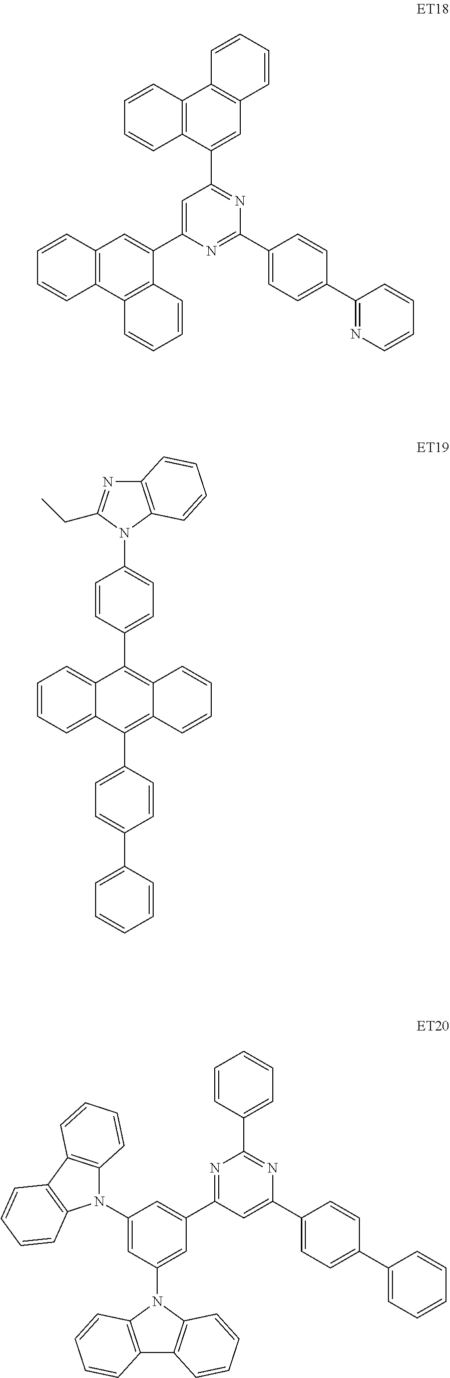 [SMILES: c1ccc(-c2ccc(-c3nc(-c4cc5ccccc5c5ccccc45)cc(-c4cc5ccccc5c5ccccc45)n3)cc2)nc1 ; CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

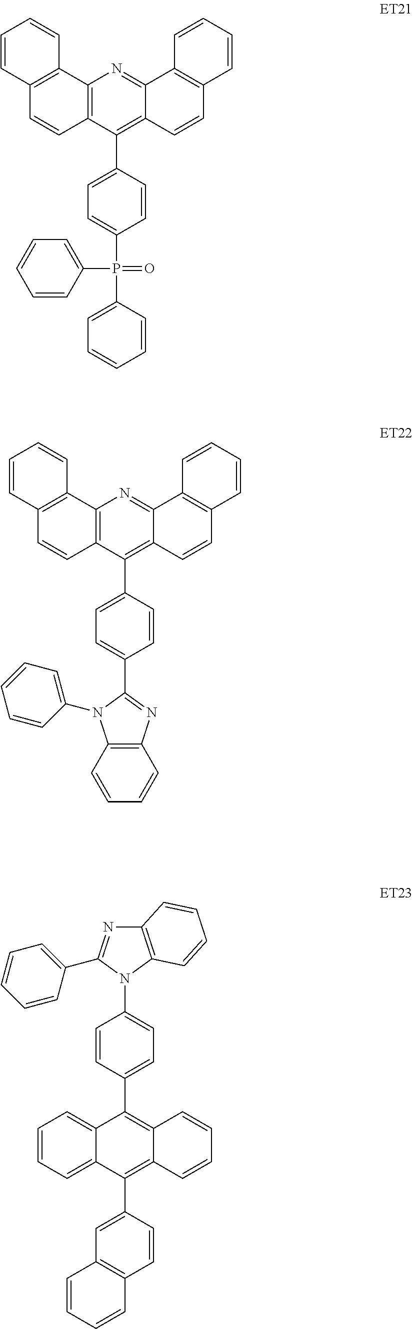 [SMILES: O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1]

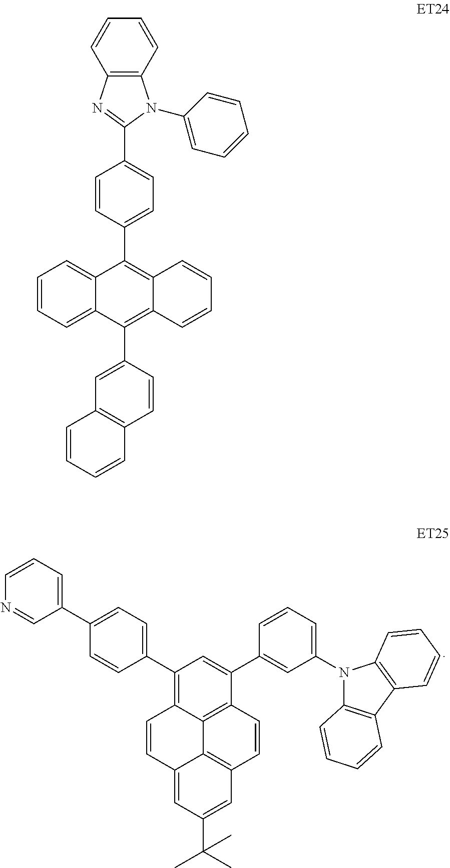 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. When the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (LiQ) or ET-D2.

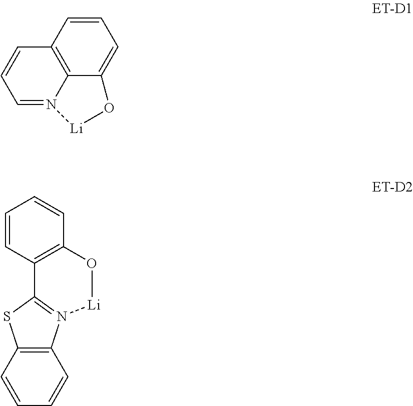

The electron transport region may include an electron injection layer that promotes flow of electrons from the second electrode 19 thereinto.

The electron injection layer may include LiF, NaCl, C₅F, Li₂O, BaO, or a combination thereof.

A thickness of the electron injection layer may be in a range of about 1 Å to about 100 Å, for example, about 3 Å to about 90 Å. When the thickness of the electron injection layer is within the range described above, the electron injection layer may have satisfactory electron injection characteristics without a substantial increase in driving voltage.

The second electrode 19 is disposed on the organic layer 15. The second electrode 19 may be a cathode. A material for forming the second electrode 19 may be a metal, an alloy, an electrically conductive compound, or a combination thereof, which have a relatively low work function. In an exemplary embodiment, lithium (Li), magnesium (Mg), aluminum (Al), aluminum-lithium (Al—Li), calcium (Ca), magnesium-indium (Mg—In), or magnesium-silver (Mg—Ag) may be used as a material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to the FIGURE, but embodiments of the present disclosure are not limited thereto.

Another aspect of the present disclosure provides a diagnostic composition including an organometallic compound represented by Formula 1.

The organometallic compound represented by Formula 1 provides high luminescent efficiency. Accordingly, a diagnostic composition including the organometallic compound may have high diagnostic efficiency.

The diagnostic composition may be used in various applications including a diagnosis kit, a diagnosis reagent, a biosensor, and a biomarker.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an isoamyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by-OA₁₀₁ (wherein A₁₀₁ is the C₁-C₆₀ alkyl group), and non-limiting examples thereof include a methoxy group, an ethoxy group, and an isopropyloxy group.

The term “C₂-C₆₀ alkenyl group” as used herein refers to a hydrocarbon group formed by substituting a double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting a triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic or polycyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₂-C₁₀ heterocycloalkyl group” as used herein refers to a monovalent saturated monocyclic group having N, O, P, Si or S as a ring-forming atom and 2 to 10 carbon atoms, and non-limiting examples thereof include a tetrahydrofuranyl group, and a tetrahydrothiophenyl group. The term “C₂-C₁₀ heterocycloalkylene group” as used herein refers to a divalent group having the same structure as the C₂-C₁₀ heterocycloalkyl group.

The term “C₃-C₁₀ cycloalkenyl group” as used herein refers to a monovalent monocyclic group that has 3 to 10 carbon atoms and a double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₂-C₁₀ heterocycloalkenyl group” as used herein refers to a monovalent monocyclic group that has N, O, P, Si, or S as a ring-forming atom, 2 to 10 carbon atoms, and a double bond in its ring. Examples of the C₂-C₁₀ heterocycloalkenyl group are a 2,3-dihydrofuranyl group, and a 2,3-dihydrothiophenyl group. The term “C₂-C₁₀ heterocycloalkenylene group” as used herein refers to a divalent group having the same structure as the C₂-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other. The term “C₇-C₆₀ alkylaryl group” as used herein refers to a C₆-C₆₀ aryl group substituted with a C₁-C₆₀ alkyl group.

The term “C₁-C₆₀ heteroaryl group” as used herein refers to a monovalent group having a heteroaromatic system that has N, O, P, Si, or S as a ring-forming atom, and 1 to 60 carbon atoms. The term “C₁-C₆₀ heteroarylene group” as used herein refers to a divalent group having a heteroaromatic system that has N, O, P, Si or S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other. The term “C₂-C₆₀ alkylheteroaryl group” as used herein refers to a C₁-C₆₀ heteroaryl group substituted with a C₁-C₆₀ alkyl group.

The term “C₆-C₆₀ aryloxy group” as used herein indicates-OA₁₀₂ (wherein A₁₀₂ is the C₆-C₆₀ aryl group), and a C₆-C₆₀ arylthio group used herein indicates-SA₁₀₃ (wherein A₁₀₃ is the C₆-C₆₀ aryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, N, O, P, Si, or S, other than carbon atoms, as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group.

The term “C₁-C₃₀ heterocyclic group” as used herein refers to a saturated or unsaturated cyclic group having, as a ring-forming atom, N, O, Si, P, or S other than 1 to 30 carbon atoms. The C₁-C₃₀ heterocyclic group may be a monocyclic group or a polycyclic group.

A substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₇-C₆₀ alkyl aryl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted monovalent non-aromatic condensed polycyclic group, and the substituted monovalent non-aromatic condensed heteropolycyclic group may be:

deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group;

a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), —P(═O)(Q₁₈)(Q₁₉), or a combination thereof;

a C₃-C₁₀ cycloalkyl group, a C₂-C₁₀ heterocycloalkyl group, a C₃-C₁₀ cycloalkenyl group, a C₂₋₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), —P(═O)(Q₂₈)(Q₂₉), or a combination thereof;

—N(Q₃₁)(Q₃₂), —Si(Q₃₃)(Q₃₄)(Q₃₅), —B(Q₃₆)(Q₃₇), or —P(═O)(Q₃₈)(Q₃₉); or

any combination thereof;

Q₁ to Q₉, Q₁₁ to Q₁₉, Q₂₁ to Q₂₉, and Q₃₁ to Q₃₉ may each independently be hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₁-C₆₀ alkyl group substituted with deuterium, a C₁-C₆₀ alkyl group, a C₆-C₆₀ aryl group, or a combination thereof, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryl group substituted with deuterium, a C₁-C₆₀ alkyl group, and a C₆-C₆₀ aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, or a combination thereof.

Hereinafter, a compound and an organic light-emitting device according to embodiments are described in detail with reference to Synthesis Example and Examples.

However, the organic light-emitting device is not limited thereto. The wording “B was used instead of A” used in describing Synthesis Examples means that an amount of A used was identical to an amount of B used, in terms of a molar equivalent.

### EXAMPLES

### Synthesis Example 1: Synthesis of Compound 16

### Synthesis of Compound 16-3

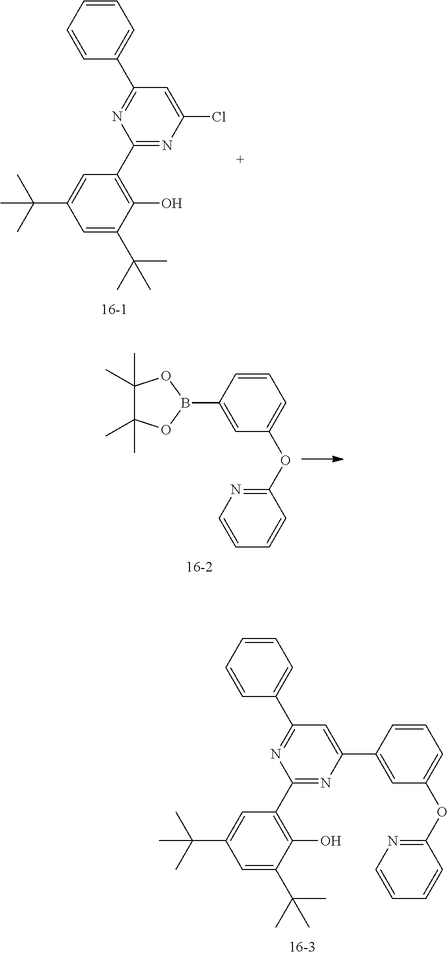 [SMILES: CC(C)(C)c1cc(-c2nc(Cl)cc(-c3ccccc3)n2)c(O)c(C(C)(C)C)c1 ; CC1(C)OB(c2cccc(Oc3ccccn3)c2)OC1(C)C ; CC(C)(C)c1cc(-c2nc(-c3ccccc3)cc(-c3cccc(Oc4ccccn4)c3)n2)c(O)c(C(C)(C)C)c1]

Compound 16-1 (2.2 g, 5.7 mmol), Compound 16-2 (1.9 g, 6.2 mmol), Pd(PPh₃)₄ (0.5 g, 0.4 mmol), K₂CO₃ (2.4 g, 17 mmol), 120 mL of tetrahydrofuran (THF), and 40 mL of distilled water were mixed and stirred for 12 hours under reflux. The reaction mixture was cooled to room temperature, and an organic layer was extracted therefrom by using methylene chloride (MC). The extracted organic layer was dried by using anhydrous magnesium sulfate (MgSO₄) and filtered to obtain a filtrate. A residue obtained by concentrating the filtrate was purified by column chromatography in an MC:hexane condition to obtain Compound 16-3 2.1 g (70%).

### Synthesis of Compound 16

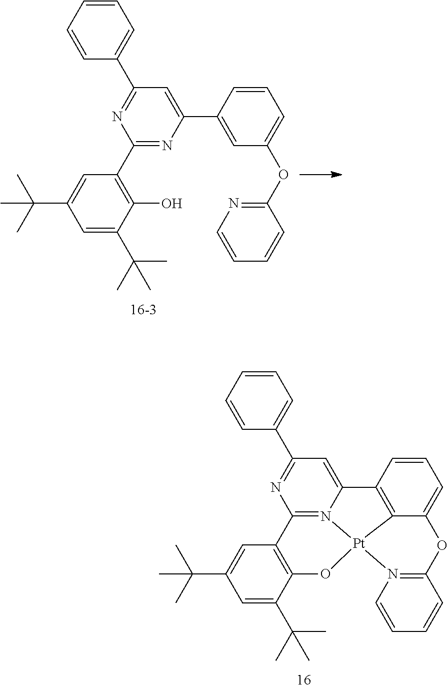

Compound 16-3 (1.5 g, 2.8 mmol), K₂PtCl₄ (1.3 g, 3.0 mmol), and 30 mL of acetic acid were mixed and stirred for 18 hours under reflux. After the reaction was complete, the reaction mixture was cooled down. A solid obtained therefrom was filtered and column chromatography was performed thereon in an MC:hexane condition to obtain 0.6 g (30%) of Compound 16.

HRMS (MALDI) calcd for C₃₅H₃₃N₃O₂Pt: m/z 722.2221, found: 722.2215.

### Synthesis Example 2: Synthesis of Compound 19

### Synthesis of Compound 19-3

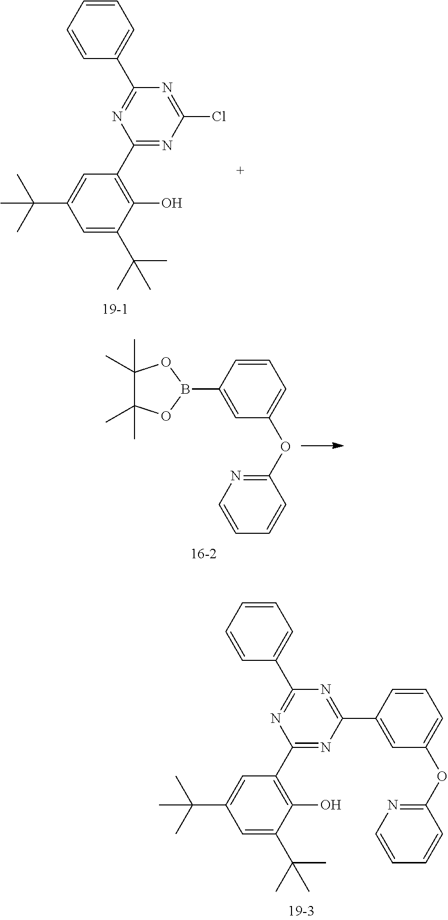 [SMILES: CC(C)(C)c1cc(-c2nc(Cl)nc(-c3ccccc3)n2)c(O)c(C(C)(C)C)c1 ; CC1(C)OB(c2cccc(Oc3ccccn3)c2)OC1(C)C ; CC(C)(C)c1cc(-c2nc(-c3ccccc3)nc(-c3cccc(Oc4ccccn4)c3)n2)c(O)c(C(C)(C)C)c1]

1.9 g (61%) of Compound 19-3 was obtained in the same manner as in the Synthesis of Compound 16-3 in Synthesis Example 1, except that Compounds 19-1 was used instead Compound 16-1.

### Synthesis of Compound 19

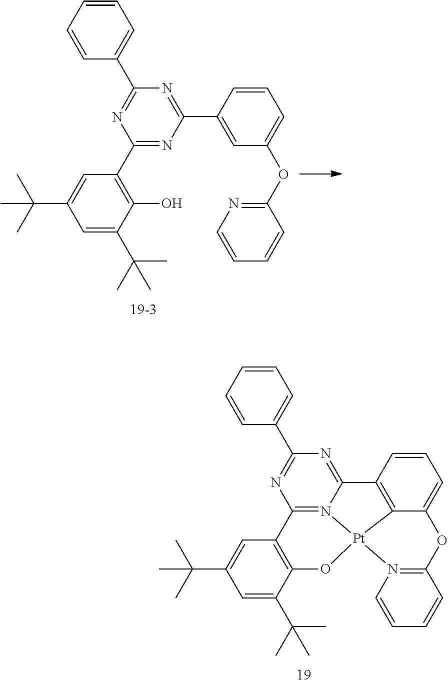

0.45 g (23%) of Compound 19 was obtained in the same manner as in the Synthesis of Compound 16 in Synthesis Example 1, except that Compounds 19-3 was used instead Compound 16-3.

HRMS (MALDI) calcd for C₃₄H₃₂N₄O₂Pt: m/z 723.2173, found: 723.2176.

### Synthesis Example 3: Synthesis of Compound 151

### Synthesis of Compound 151-3

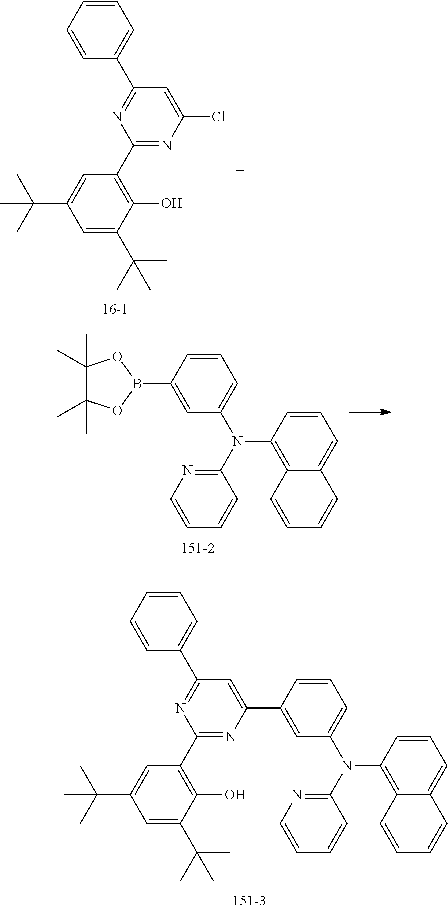 [SMILES: CC(C)(C)c1cc(-c2nc(Cl)cc(-c3ccccc3)n2)c(O)c(C(C)(C)C)c1 ; CC1(C)OB(c2cccc(N(c3ccccn3)c3cccc4ccccc34)c2)OC1(C)C ; CC(C)(C)c1cc(-c2nc(-c3ccccc3)cc(-c3cccc(N(c4ccccn4)c4cccc5ccccc45)c3)n2)c(O)c(C(C)(C)C)c1]

Compound 16-1 (1.8 g, 4.6 mmol), Compound 151-2 (2.1 g, 5.1 mmol), Pd(PPh₃)₄ (0.4 g, 0.3 mmol), K₂CO₃ (1.9 g, 14 mmol), 120 mL of THF, and 40 mL of distilled water were mixed and stirred for 12 hours under reflux. The reaction mixture was cooled to room temperature, and an organic layer was extracted therefrom by using methylene chloride (MC). The extracted organic layer was dried by using anhydrous magnesium sulfate (MgSO₄) and filtered to obtain a filtrate. A residue obtained by decompressing the filtrate was purified by column chromatography in an MC:hexane condition to obtain Compound 151-3 2.3 g (77%).

### Synthesis of Compound 151

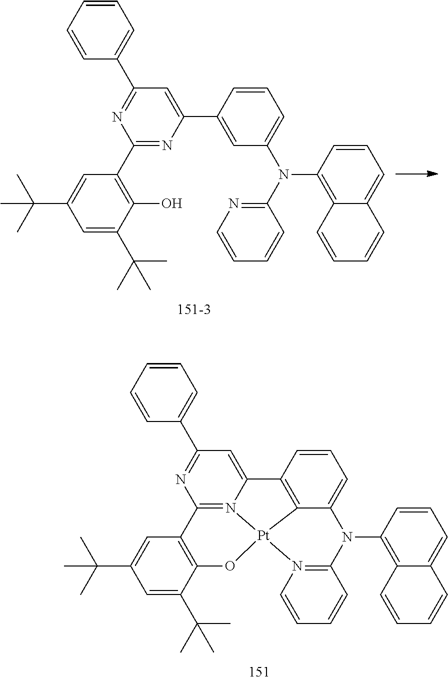

Compound 151-3 (1.6 g, 2.5 mmol), K₂PtCl₄ (1.1 g, 2.7 mmol), and 30 mL of acetic acid were mixed and stirred for 18 hours under reflux. After the reaction was complete, the reaction mixture was cooled down. A solid obtained therefrom was filtered and column chromatography was performed thereon in an MC:hexane condition to obtain 0.7 g (33%) of Compound 151.

HRMS (MALDI) calcd for C₄₅H₄₀N₄OPt: m/z 847.2850, found: 847.2854.

### Synthesis Example 4: Synthesis of Compound 154

### Synthesis of Compound 154-3

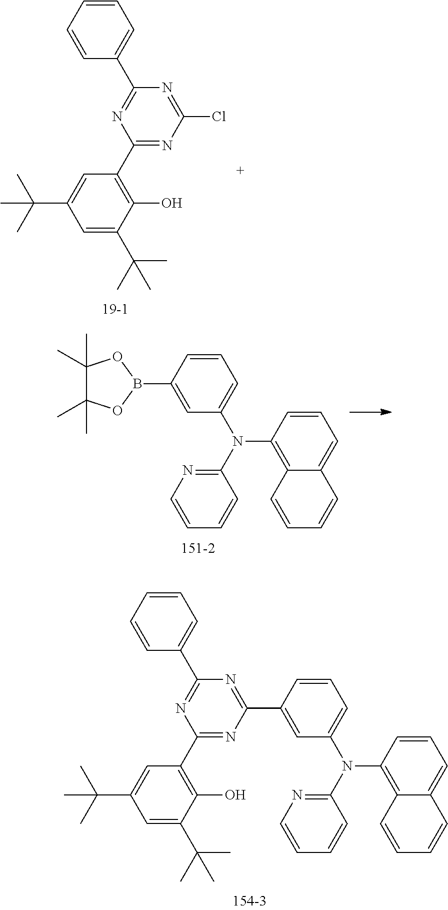 [SMILES: CC(C)(C)c1cc(-c2nc(Cl)nc(-c3ccccc3)n2)c(O)c(C(C)(C)C)c1 ; CC1(C)OB(c2cccc(N(c3ccccn3)c3cccc4ccccc34)c2)OC1(C)C ; CC(C)(C)c1cc(-c2nc(-c3ccccc3)nc(-c3cccc(N(c4ccccn4)c4cccc5ccccc45)c3)n2)c(O)c(C(C)(C)C)c1]

Compound 19-1 (1.8 g, 4.6 mmol), Compound 151-2 (2.1 g, 5.1 mmol), Pd(PPh₃)₄ (0.4 g, 0.3 mmol), K₂CO₃ (1.9 g, 14 mmol), 120 mL of THF, and 40 mL of distilled water were mixed and stirred for 12 hours under reflux. The reaction mixture was cooled to room temperature, and an organic layer was extracted therefrom by using methylene chloride (MC). The extracted organic layer was dried by using anhydrous magnesium sulfate (MgSO₄) and filtered to obtain a filtrate. A residue obtained by concentrating the filtrate was purified by column chromatography in an MC:hexane condition to obtain Compound 154-3 1.6 g (53%).

### Synthesis of Compound 154

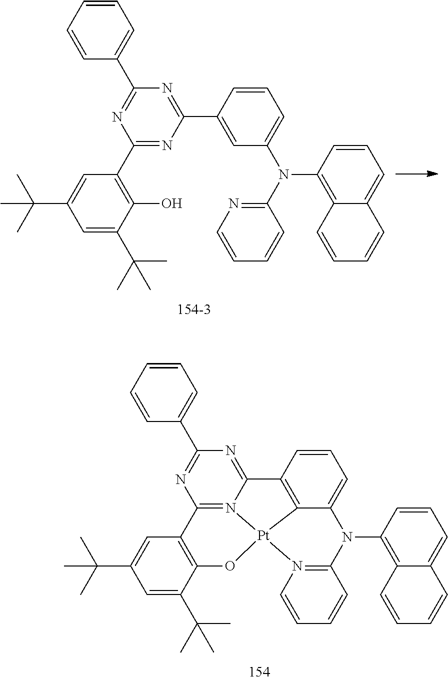

Compound 154-3 (1.4 g, 2.1 mmol), K₂PtCl₄ (1.0 g, 2.3 mmol), and 30 mL of acetic acid were mixed and stirred for 18 hours under reflux. After the reaction was complete, the reaction mixture was cooled down. A solid obtained therefrom was filtered and column chromatography was performed thereon in an MC:hexane condition to obtain 0.5 g (28%) of Compound 154.

HRMS (MALDI) calcd for C₄₄H₃₉N₅OPt: m/z 848.2802, found: 848.2795.

### Example 1

An ITO glass substrate was cut to a size of 50 mm×50 mm×0.5 mm, sonicated with acetone, isopropyl alcohol, and pure water each for 15 minutes, and then cleaned by exposure to ultraviolet rays and ozone for 30 minutes.

Then, m-MTDATA was deposited on an ITO electrode (anode) of the ITO glass substrate at a deposition rate of 1 Å/sec to form a hole injection layer having a thickness of 600 Å, α-NPD (NPB) was deposited on the hole injection layer at a deposition rate of 1 Å/sec to form a hole transport layer having a thickness of 250 Å.

Compound 16 (dopant) and CBP (host) were co-deposited on the hole transport layer at deposition rates of 0.1 Å/sec and 1 Å/sec to form an emission layer having a thickness of 400 Å.

BAIq was deposited on the emission layer at a deposition rate of 1 Å/sec to form a hole blocking layer having a thickness of 50 Å, Alq₃ was deposited on the hole blocking layer to form an electron transport layer having a thickness of 300 Å, LiF was deposited on the electron transport layer to form an electron injection layer having a thickness of 10 Å, and Al was vacuum-deposited on the electron injection layer to form a second electrode (cathode) having a thickness of 1,200 Å, thereby completing the manufacture of an organic light-emitting device having a structure of ITO/m-MTDATA (600 Å)/α-NPD (250 Å)/CBP+Compound 1 (10%) (400 Å)/BAIq (50 Å)/Alq₃ (300 Å)/LiF (10 Å)/Al (1,200 Å).

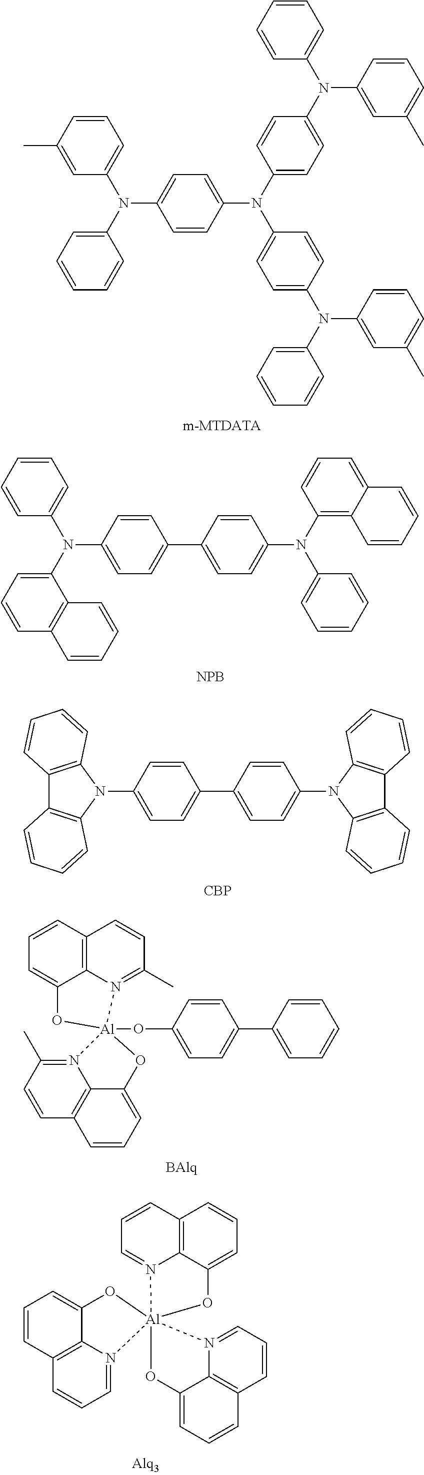

### Examples 2 to 4 and Comparative Examples a to D

Organic light-emitting devices were manufactured in the same manner as in Example 1, except that Compounds shown in Table 2 were each used instead of Compound 1 as a dopant in forming an emission layer.

### Evaluation Example 2: Evaluation of Characteristics of Organic Light-Emitting Devices

Luminescent quantum efficiency, roll-off ratio, and lifespan (T₉₅) of the organic light-emitting devices manufactured according to Examples 1 to 4 and Comparative Examples A to D were evaluated, and results thereof are shown in Table 2. A current-voltage meter (KEITHLEY 2400) and a luminance meter (MINOLTA Cs-1000 Å) were used as the evaluation devices, and the lifespan (T₉₅) (at 6,000 nit) indicates the time that lapsed when luminance was 95% of initial luminance (100%) and was expressed as a relative value (%) with respect to the lifespan of Comparative Example D. The roll-off ratio was calculated by Equation 20 below.

Roll off={1−(Efficiency (at 9,000 nit)/Maximum luminescent efficiency)}×100% Equation 20

TABLE 2

| | | | | Lifespan |
|---|---|---|---|---|
| | Dopant | Luminescent | | (relative |
| | compound | quantum | Roll-off ratio | value, %) |
| No. | No. | efficiency (%) | (%) | (T₉₅) |
| Example 1 | 16 | 26.3 | 9% | 230% |
| Example 2 | 19 | 25.0 | 10% | 150% |
| Example 3 | 151 | 25.7 | 10% | 280% |
| Example 4 | 154 | 24.3 | 11% | 150% |
| Comparative | A | 24.1 | 12% | 42% |
| Example A | | | | |
| Comparative | B | 14.9 | 32% | 25% |
| Example B | | | | |
| Comparative | C | 18.2 | 19% | 35% |
| Example C | | | | |
| Comparative | D | 23.9 | 12% | 100% |
| Example D | | | | |

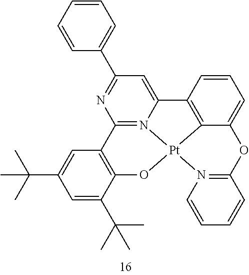

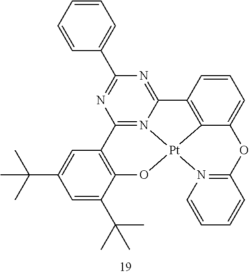

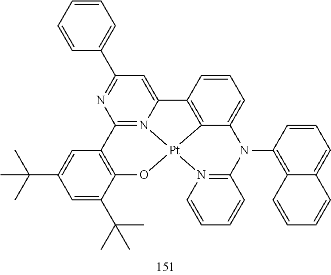

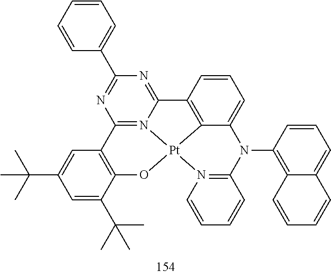

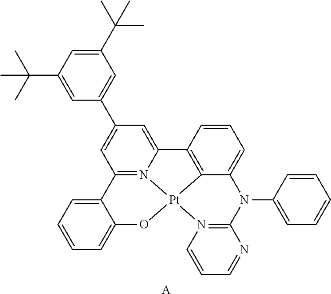

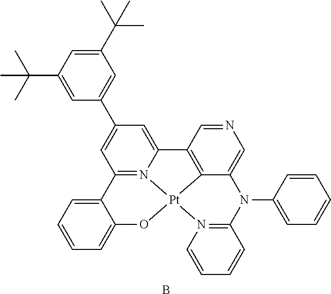

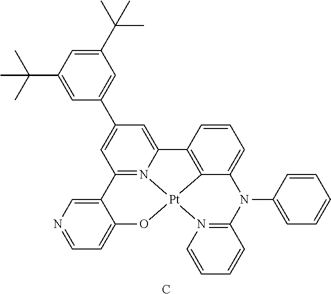

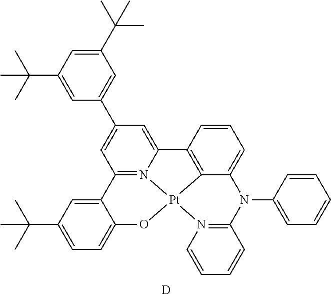

From Table 2, it is confirmed that the organic light-emitting device of Examples 1 to 4 have excellent luminescent quantum efficiency, roll-off ratio, and lifespan characteristics, as compared with those of the organic light-emitting devices of Comparative Examples A to D.

Since the organometallic compound has excellent electric characteristics and/or thermal stability, an organic light-emitting device including the organometallic compound may have excellent driving voltage, efficiency, power, color purity, and lifespan characteristics. In addition, since the organometallic compound has excellent phosphorescence characteristics, a diagnostic composition having high diagnostic efficiency may be provided by using the organometallic compound.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An organometallic compound represented by Formula 1:
Formula 1 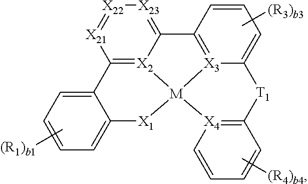
wherein, in Formula 1,
M is beryllium (Be), magnesium (Mg), aluminum (Al), calcium (Ca), titanium (T₁), manganese (Mn), cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au),
X₁ is O or S, and a bond between X₁ and M is a covalent bond,
X₂ to X₄ are each independently C or N,
a bond between X₂ and M, a bond between X₃ and M, or a bond between X₄ and M is a covalent bond, and the others thereof are each a coordinate bond,
X₂₁ is N or C(R₂ₐ), X₂₂ is N or C(R_{2b}), X₂₃ is N or C(R_{2c}), and X₂₁, X₂₂, X₂₃, or a combination thereof is N,
T₁ is *—N(R₅)—*′, *—B(R₅)—*′, *—P(R₅)—*′, *—C(R₅)(R₆)—*′, *—Si(R₅)(R₆)—*′, *—Ge(R₅)(R₆)—*′, *—S—*′, *—Se—*′, *—O—* ′, *—C(═O)—*′, *—S(═O)—*′, *—S(═O)₂—*′, *—C(R₅)═*′, *═C(R₅)—*′, *—C(R₅)═C(R₆)—*′, *—C(═S)—*′, or *—C≡C—*′,
R₅ and R₆ are optionally linked via a single bond, a double bond, or a first linking group to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ,
R₁, R₃ to R₆, and R₂ₐ to R_{2c} are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), or —P(═O)(Q₈)(Q₉),
b1 and b4 are each independently 0, 1, 2, 3, or 4,
b3 is 0, 1, 2, or 3,
two or more R₁ in the number of b1 are optionally linked to form a C₅-C₃₀ carbocyclic group that is unsubstituted or substituted with R₁₀ₐ, a C₁-C₃₀ heterocyclic group, or a combination thereof that is unsubstituted or substituted an R₁₀ₐ,
two or more of R₂ₐ to R_{2c} are optionally linked to form a C₅-C₃₀ carbocyclic group that is unsubstituted or substituted with an R₁₀ₐ, a C₁-C₃₀ heterocyclic group, or a combination thereof that is unsubstituted or substituted with an R₁₀ₐ,
two or more R₃ in the number of b3 are optionally linked to form a C₅-C₃₀ carbocyclic group that is unsubstituted or substituted with an R₁₀ₐ, a C₁-C₃₀ heterocyclic group, or a combination thereof that is unsubstituted or substituted with an R₁₀ₐ,
two or more R₄ in the number of b4 are optionally linked to form a C₅-C₃₀ carbocyclic group that is unsubstituted or substituted with an R₁₀ₐ, a C₁-C₃₀ heterocyclic group, or a combination thereof, that is unsubstituted or substituted with an R₁₀ₐ,
R₅, R₆, or R₃ are optionally linked to form a C₅-C₃₀ carbocyclic group that is unsubstituted or substituted with an R₁₀ₐ, a C₁-C₃₀ heterocyclic group, or a combination thereof, that is unsubstituted or substituted with an R₁₀ₐ,
R₅, R₆, or R₄ are optionally linked to form a C₅-C₃₀ carbocyclic group that is unsubstituted or substituted with R₁₀ₐ, a C₁-C₃₀ heterocyclic group, or a combination thereof, that is unsubstituted or substituted with an R₁₀ₐ,
R₁₀ₐ is the same as described in connection with R₁,
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, or the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group, or a combination thereof;
a C₁-C₆₀ alkyl group, a C₂-C₆₀ alkenyl group, a C₂-C₆₀ alkynyl group, a C₁-C₆₀ alkoxy group, or a combination thereof each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), —P(═O)(Q₁₈)(Q₁₉), or a combination thereof;
a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or a combination thereof, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), —P(═O)(Q₂₈)(Q₂₉), or a combination thereof;
—N(Q₃₁)(Q₃₂), —Si(Q₃₃)(Q₃₄)(Q₃₅), —B(Q₃₆)(Q₃₇), —P(═O)(Q₃₈)(Q₃₉), or a combination thereof; or
any combination thereof;
Q₁ to Q₉, Q₁₁ to Q₁₉, Q₂₁ to Q₂₉, and Q₃₁ to Q₃₉ are each independently hydrogen, deuterium, —F, —Cl, —Br, —I, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryl group substituted with a C₁-C₆₀ alkyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or a combination thereof.

2. The organometallic compound of claim 1, wherein
M is Pd, Pt, or Au.

3. The organometallic compound of claim 1, wherein
i) X₂ and X₄ are each independently N, X₃ is C, a bond between X₂ and M and a bond X₄ and M are each a coordinate bond, and a bond between X₃ and M is a covalent bond, or
ii) X₂ is C, X₃ and X₄ are each independently N, a bond between X₂ and M is a covalent bond, and a bond between X₃ and M and a bond between X₄ and M are each a coordinate bond.

4. The organometallic compound of claim 1, wherein
X₂₁ is N, X₂₂ is C(R_{2b}), and X₂₃ is C(R_{2c}); or
X₂₁ is N, X₂₂ is C(R_{2b}), and X₂₃ is N.

5. The organometallic compound of claim 1, wherein
T₁ is *—N(R₅)—*′, *—C(R₅)(R₆)—*′, *—Si(R₅)(R₆)—*′, *—S—*′, or *—O—*′.

6. The organometallic compound of claim 1, wherein
R₁, R₃ to R₆, and R₂ₐ to R_{2c} are each independently:
hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;
a C₁-C₂₀ alkyl group or a C₁-C₂₀ alkoxy group, each substituted with —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cycloctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[1.1.1]octyl group, a phenyl group, a biphenyl group, a terphenyl group, a naphthyl group, a pyridinyl group, a pyrimidinyl group, or a combination thereof;
a cyclopentyl group, a cyclohexyl group, a cycloheptyl group, a cycloctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[1.1.1]octyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each unsubstituted or substituted with —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cycloctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[1.1.1]octyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, or —Si(Q₃₃)(Q₃₄)(Q₃₅); or
—N(Q₁)(Q₂), —Si(Q₃)(Q₄)(Q₅), —B(Q₆)(Q₇), or —P(═O)(Q₅)(Q₉), and
Q₁ to Q₉ and Q₃₃ to Q₃₅ are each independently:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, and a naphthyl group, each unsubstituted or substituted with a C₁-C₁₀ alkyl group, a phenyl group, or a combination thereof.

7. The organometallic compound of claim 1, wherein
a group represented by 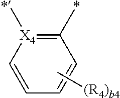
in Formula 1 is a group represented by one of Formulae CY4-1 to CY4-42: 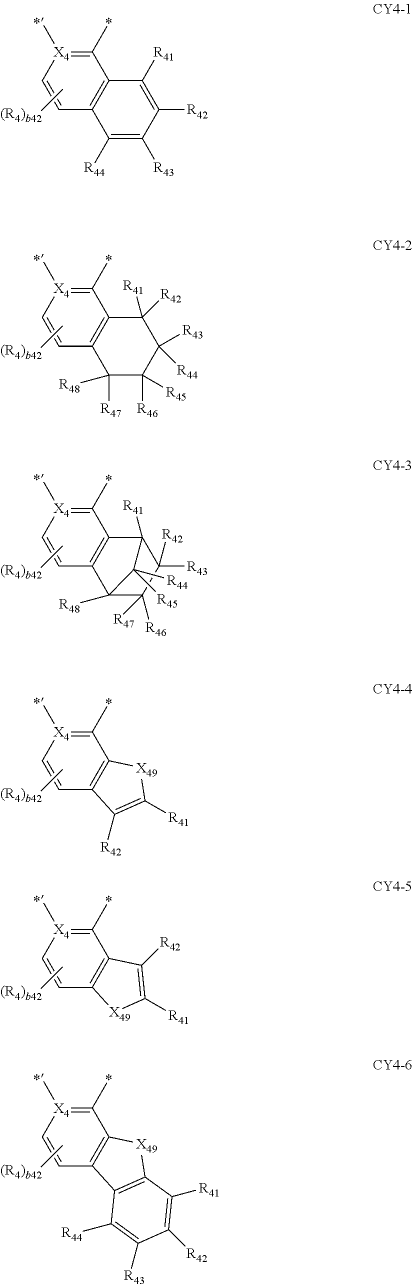 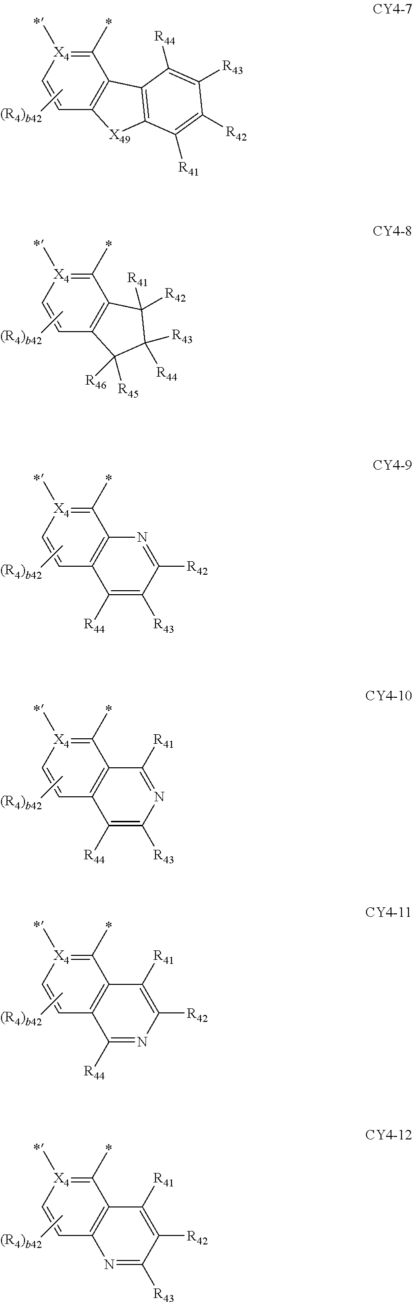 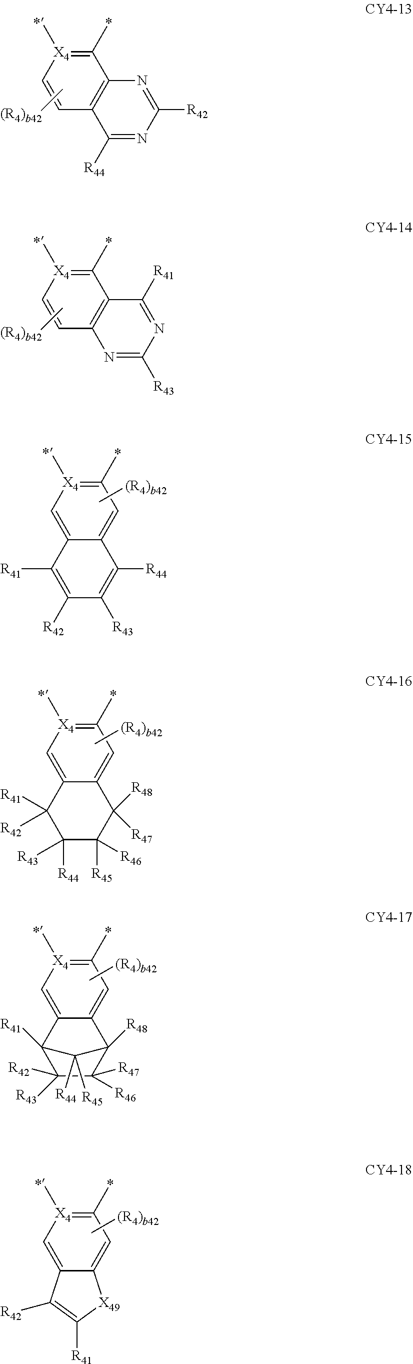 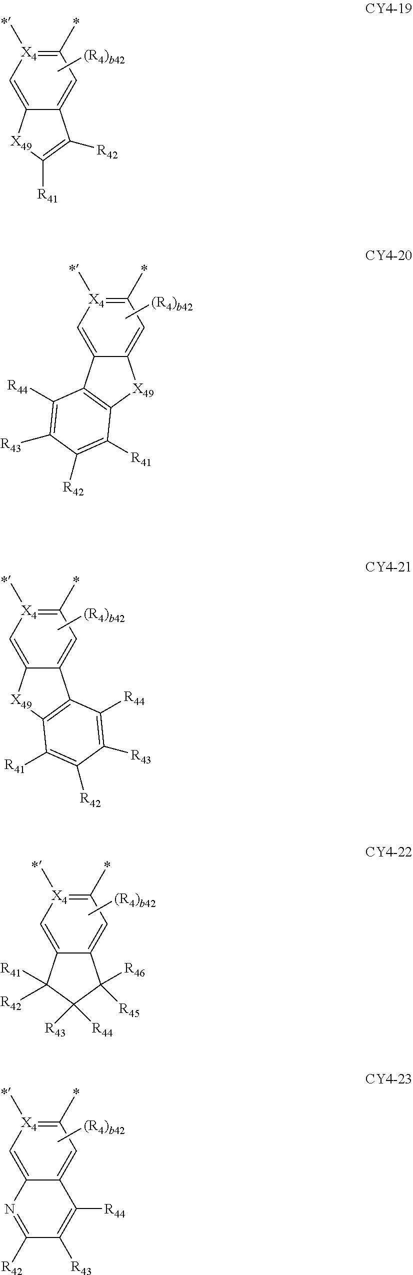 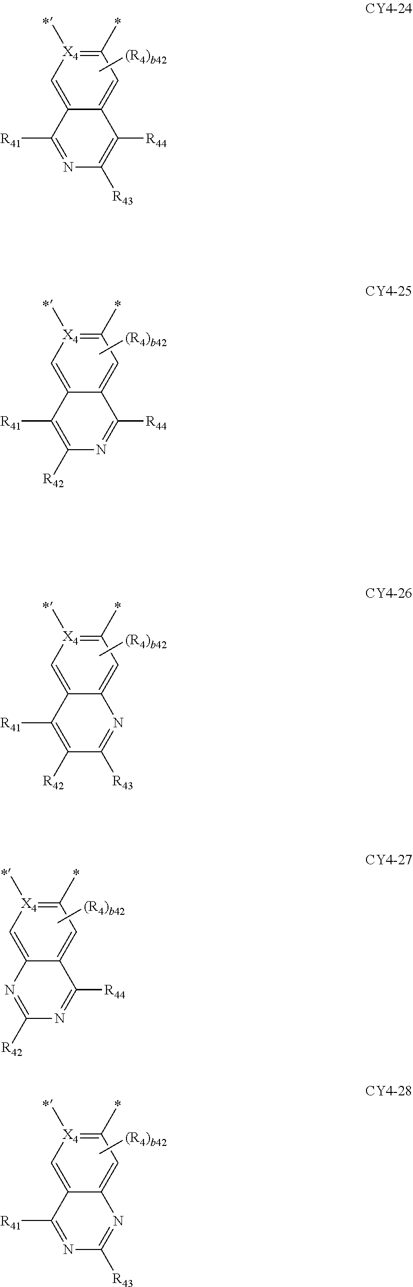 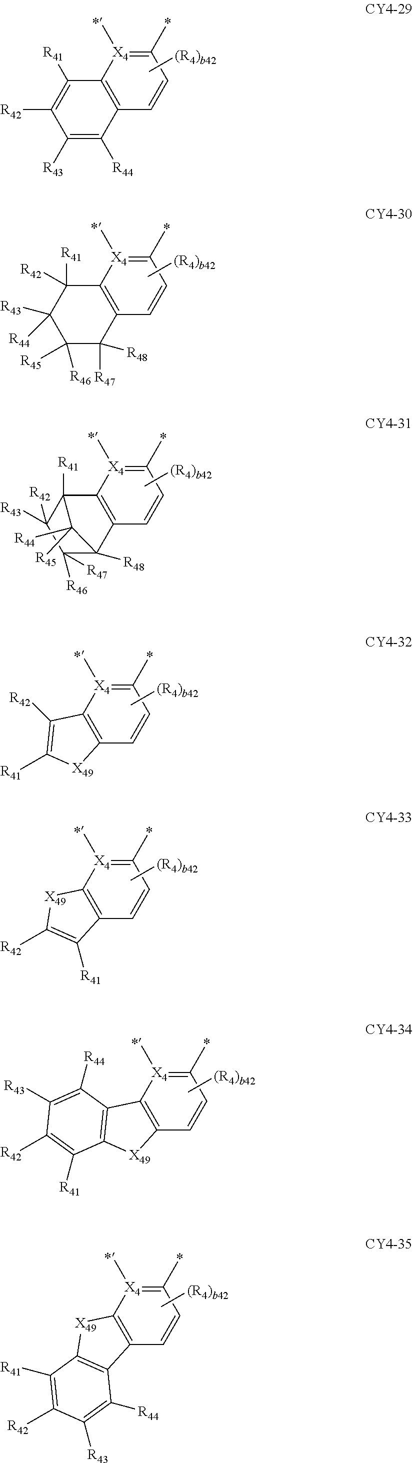 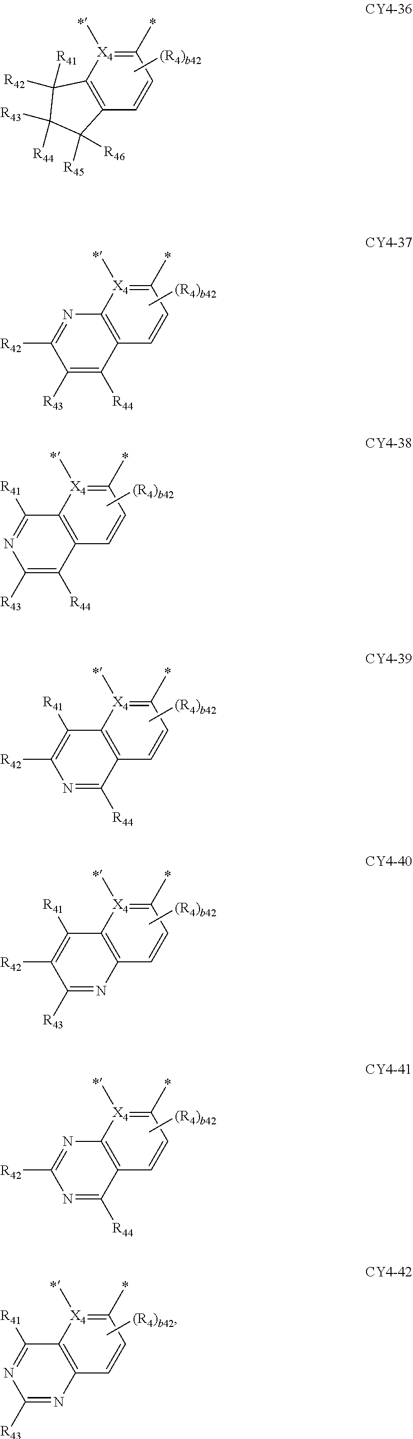
wherein, in Formulae CY4-1 to CY4-42,
X₄ and R₄ are each independently the same as described in claim 1,
X₄₉ is C(R₄₈)(R₄₉), N(R₄₈), O, S, or Si(R₄₈)(R₄₉),
R₄₁ to R₄₉ are each independently the same as described in connection with R₄ in claim 1,
a42 is an integer from 0 to 2,
* indicates a binding site to T₁ in Formula 1, and
*′ indicates a binding to M in Formula 1.

8. The organometallic compound of claim 1, wherein
a group represented by 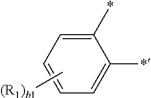
in Formula 1 is a group represented by one of Formulae CY1(1) to CY1(16): 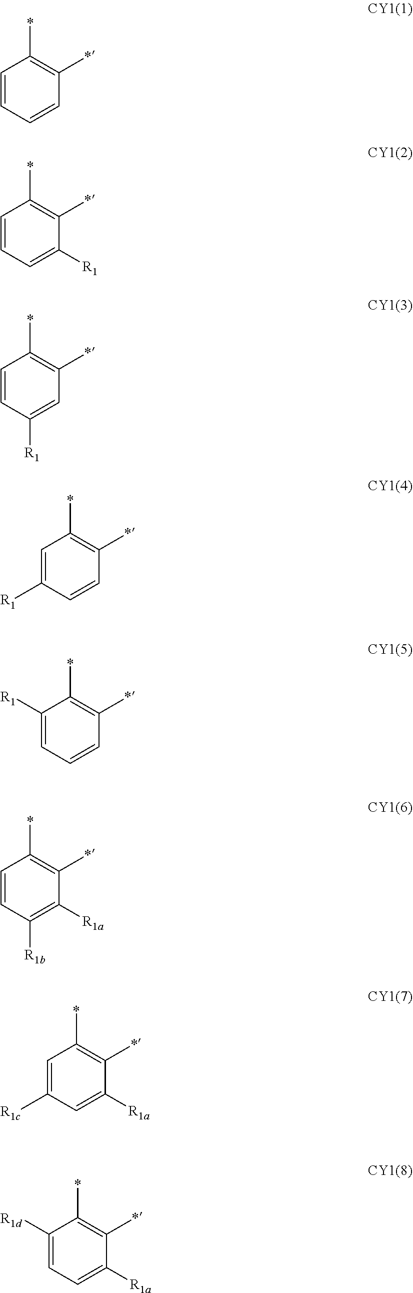 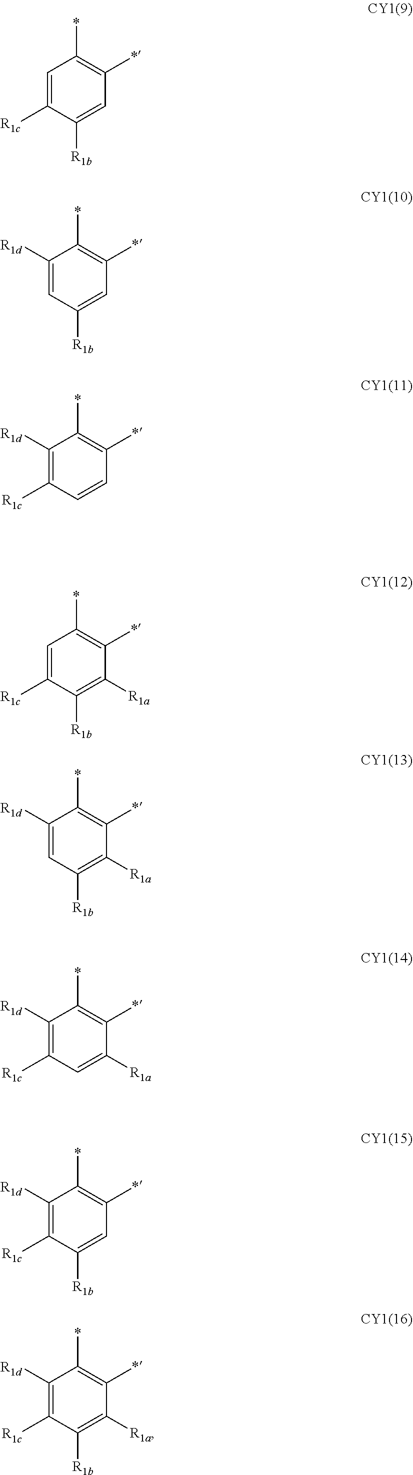
wherein, in Formulae CY1(1) to CY1(16), R₁ is the same as described in claim 1, R₁ₐ to R_{1d} are each independently the same as described in connection with R₁ in claim 1, wherein R₁ and R₁ₐ to R_{1d} are not hydrogen, *′ indicates a binding site to X₁ in Formula 1, and * indicates a binding site to carbon of a neighboring ring in Formula 1.

9. The organometallic compound of claim 1, wherein
a group represented by 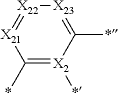
in Formula 1 is a group represented by one of Formulae CY2(1) to CY2(15): 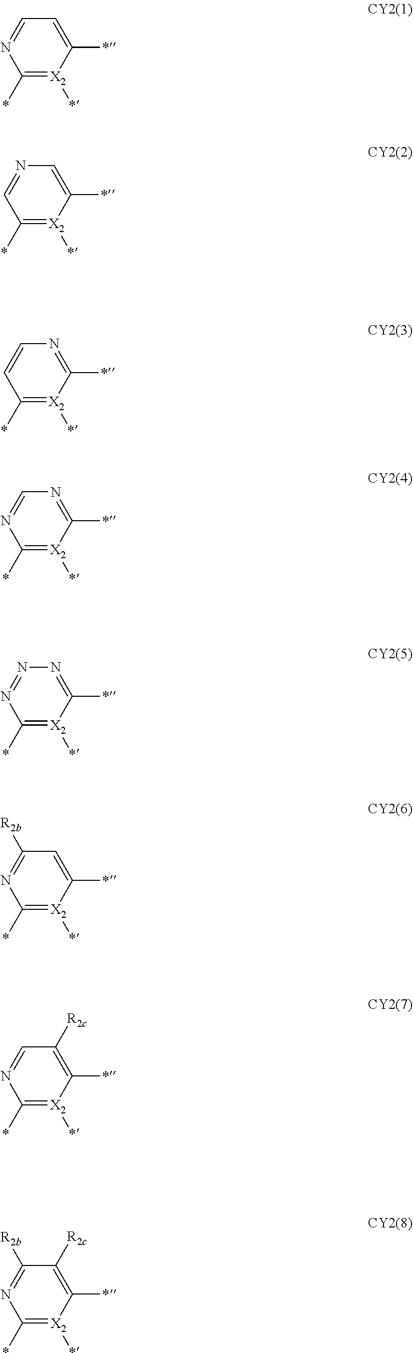 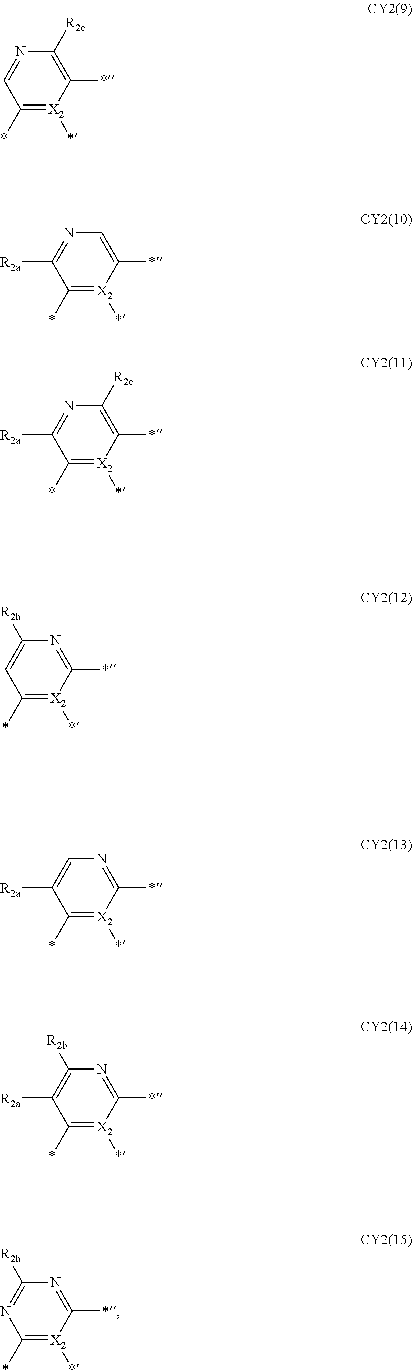
wherein, in Formulae CY2(1) to CY2(15), R₂ₐ to R_{2c} and X₂ are each independently the same as described in claim 1, wherein R₂ₐ to R_{2c} are not hydrogen, * and *″ each indicate a binding site to carbon of a neighboring ring, and *′ indicates a binding site to M in Formula 1.

10. The organometallic compound of claim 1, wherein
a group represented by 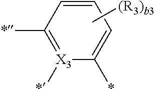
in Formula 1 is a group represented by one of Formulae CY3(1) to CY3(8): 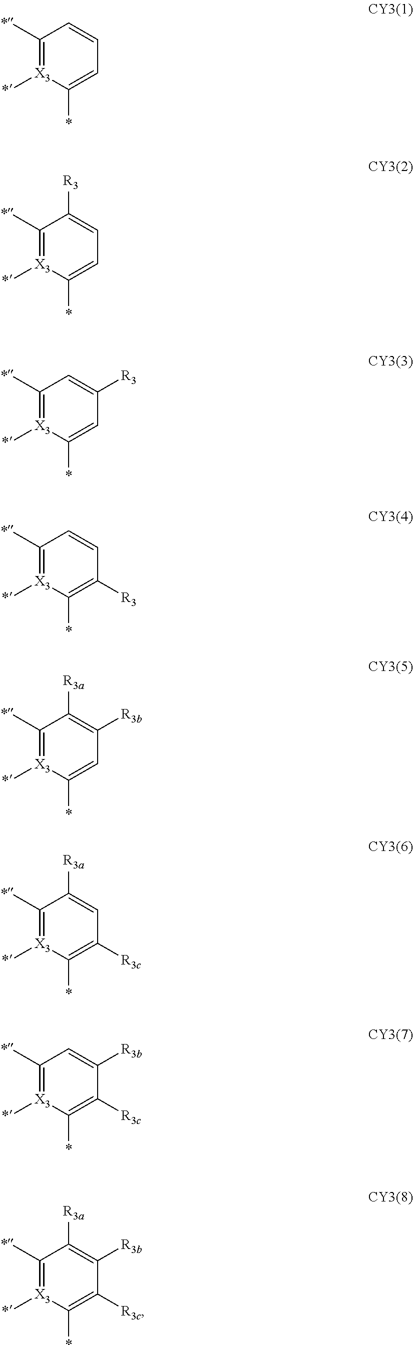
wherein, in Formulae CY3(1) to CY3(8), R₃ and X₃ are each independently the same as described in claim 1, R₃ₐ to R_{3d} are each independently the same as described in connection with R₃ in claim 1, wherein R₃ and R₃ₐ to R_{3d} are not hydrogen, * indicates a binding site to T₁ in Formula 1, *′ indicates a binding site to M in Formula 1, and *″ indicates a binding site to carbon of a neighboring ring in Formula 1.

11. The organometallic compound of claim 1, wherein
a group represented by 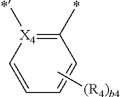
in Formula 1 is a group represented by one of Formulae CY4(1) to CY4(22): 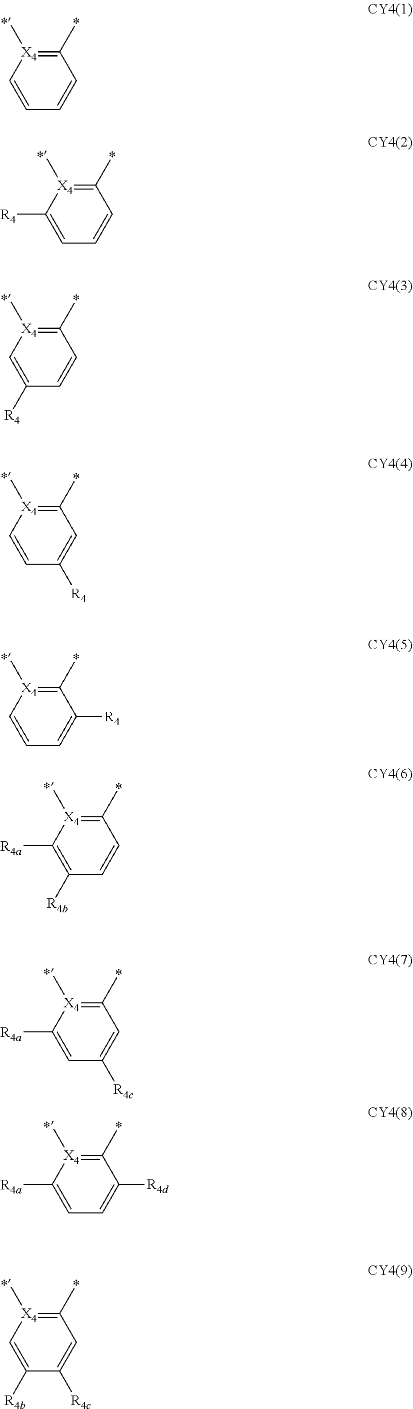 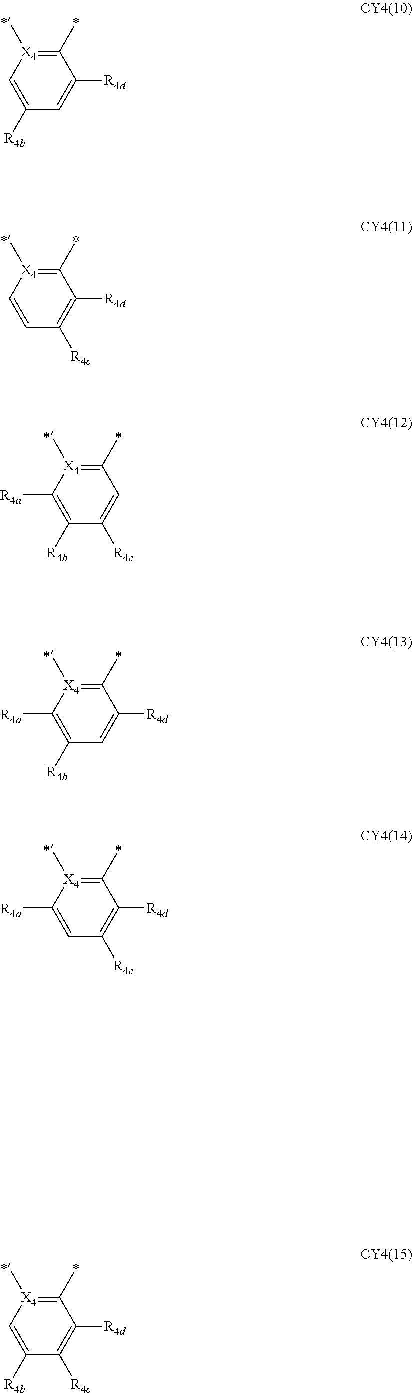 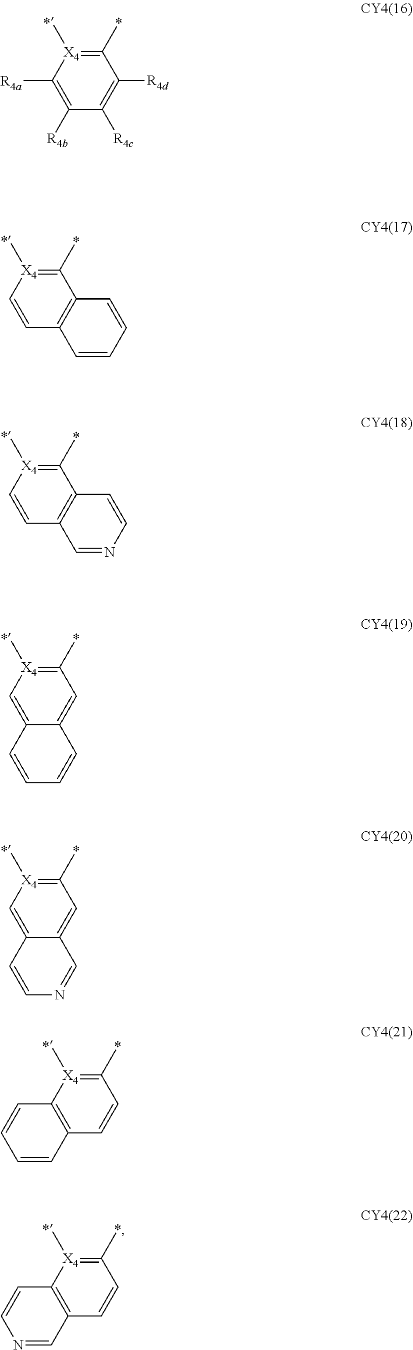
wherein, in Formulae CY4(1) to CY4(22), R₄ and X₄ are each independently the same as described in claim 1, R₄ₐ to R_{4d} are each independently the same as described in connection with R₄ in claim 1, wherein R₄ and R₄ₐ to R_{4d} are not hydrogen, * indicates a binding site to T₁ in Formula 1, and *′ indicates a binding site to M in Formula 1.

12. The organometallic compound of claim 1, wherein
the organometallic compound is of Compounds 1 to 200:

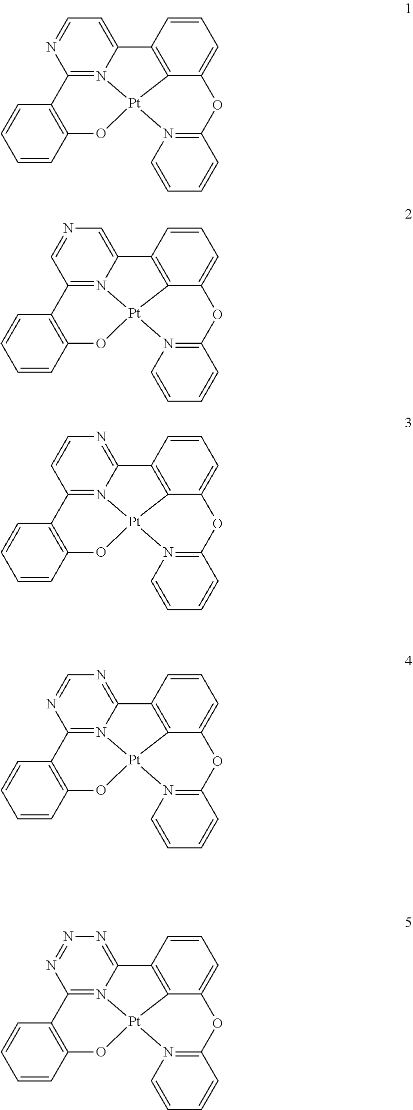

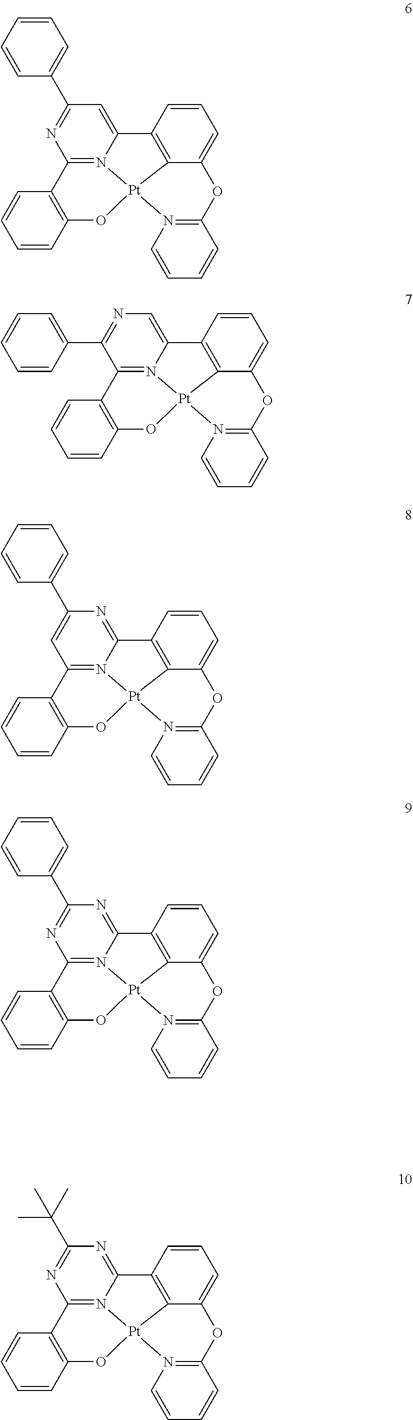

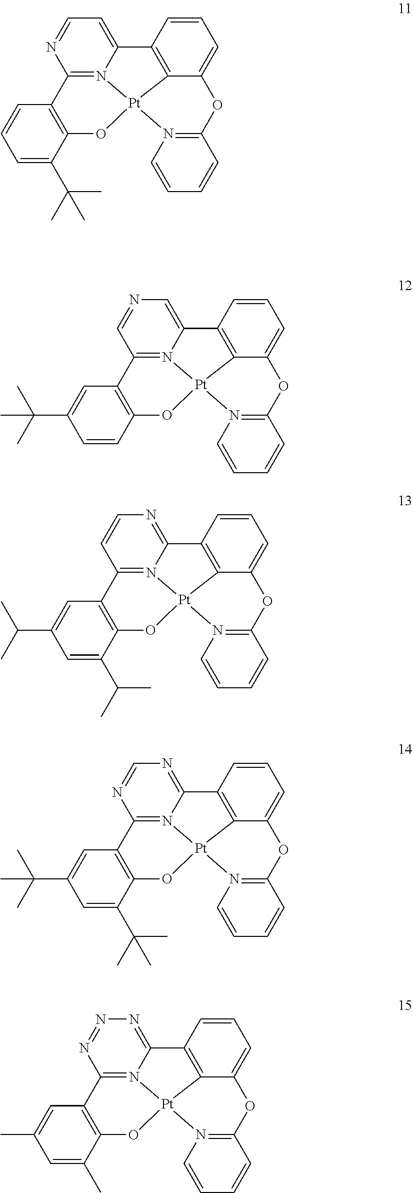

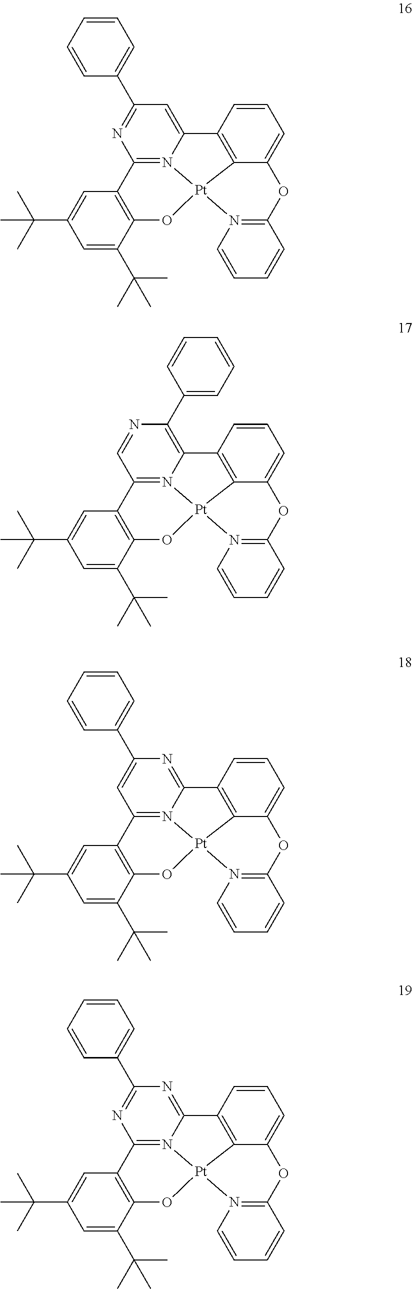

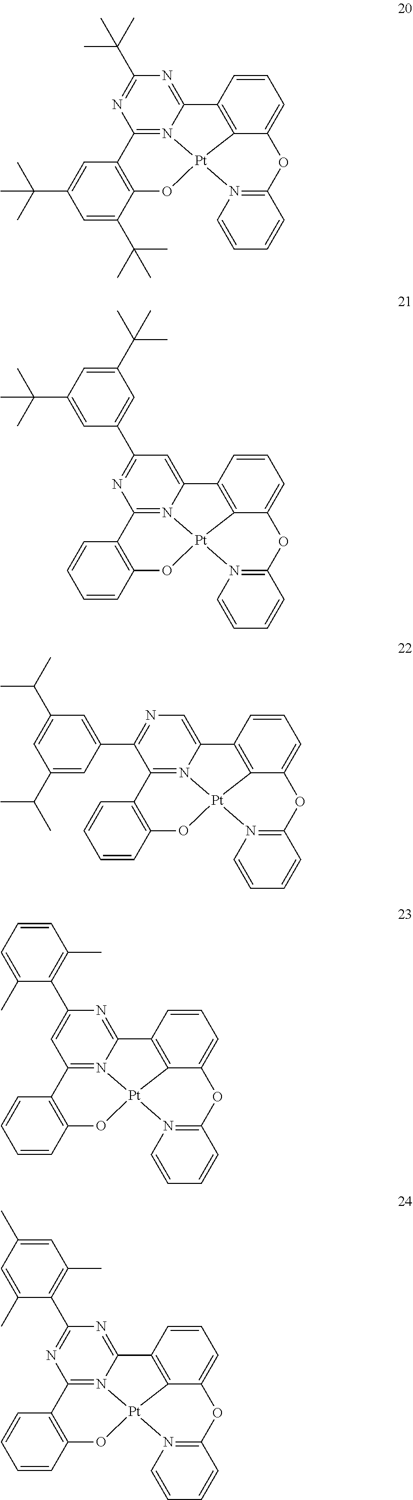

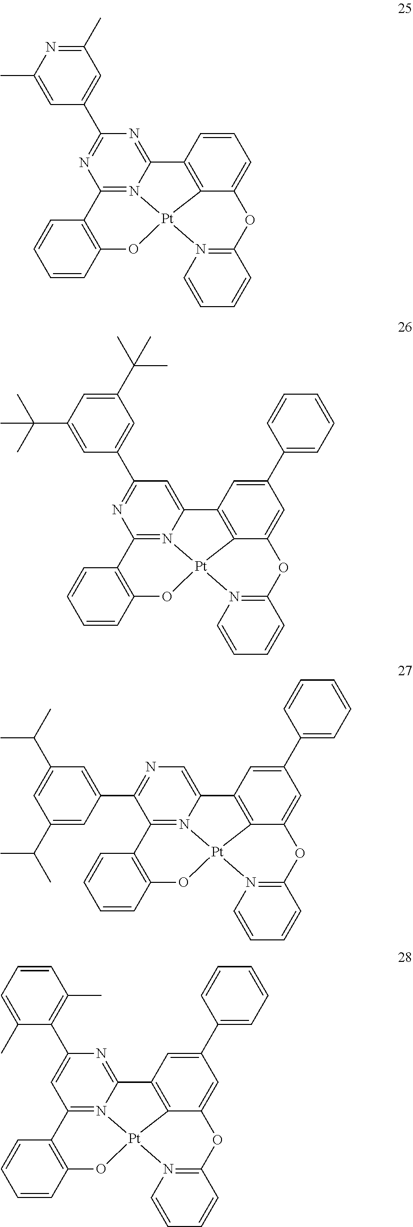

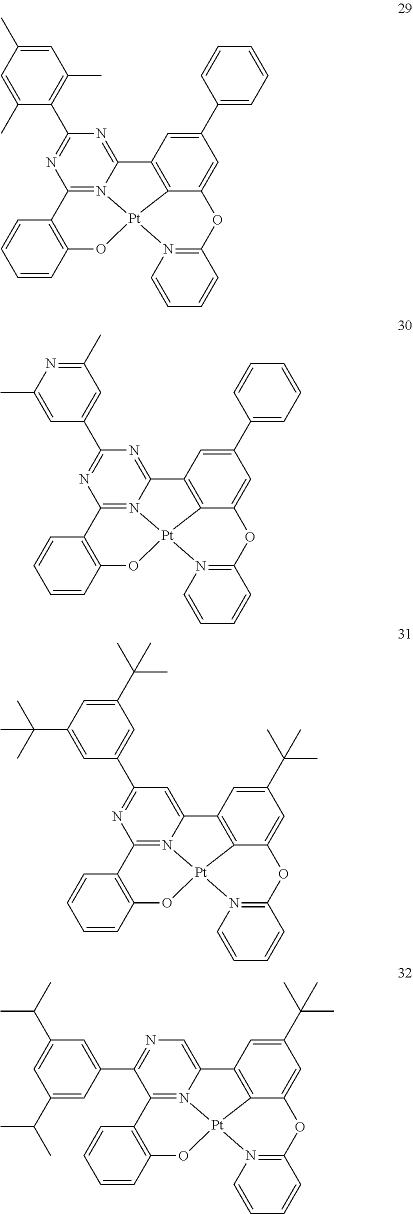

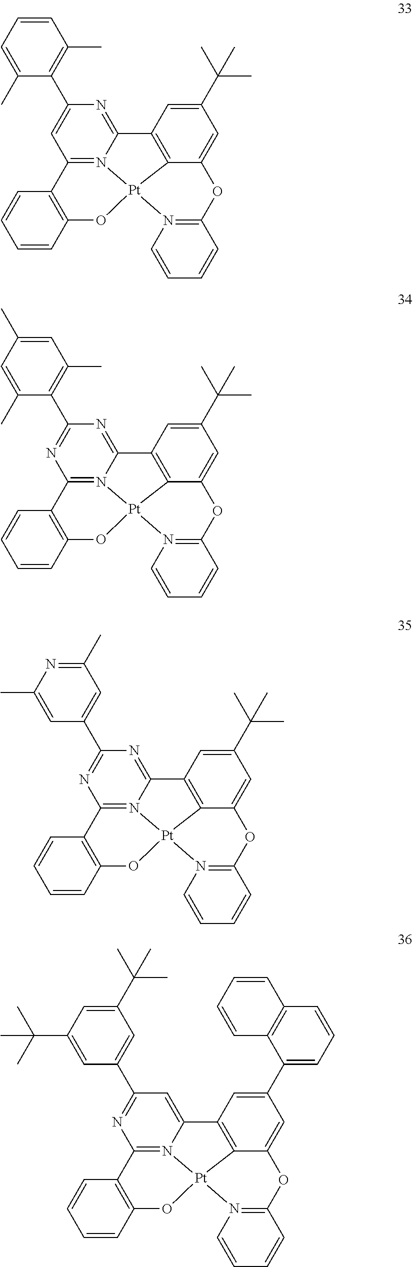

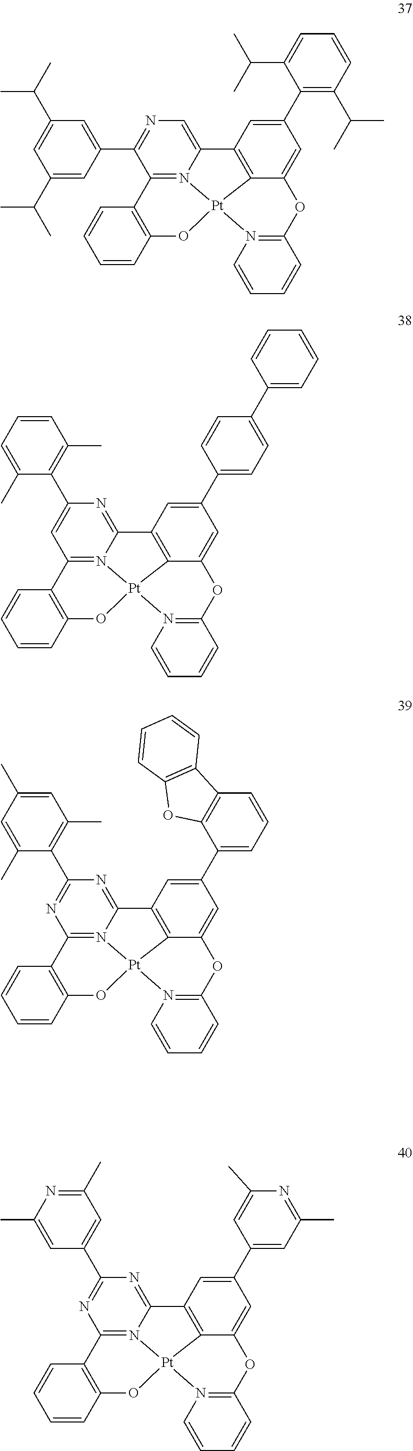

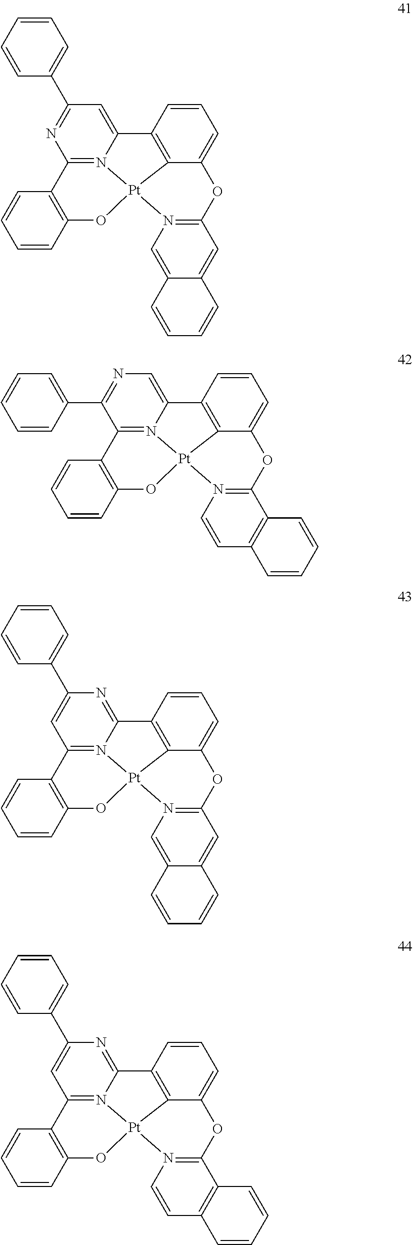

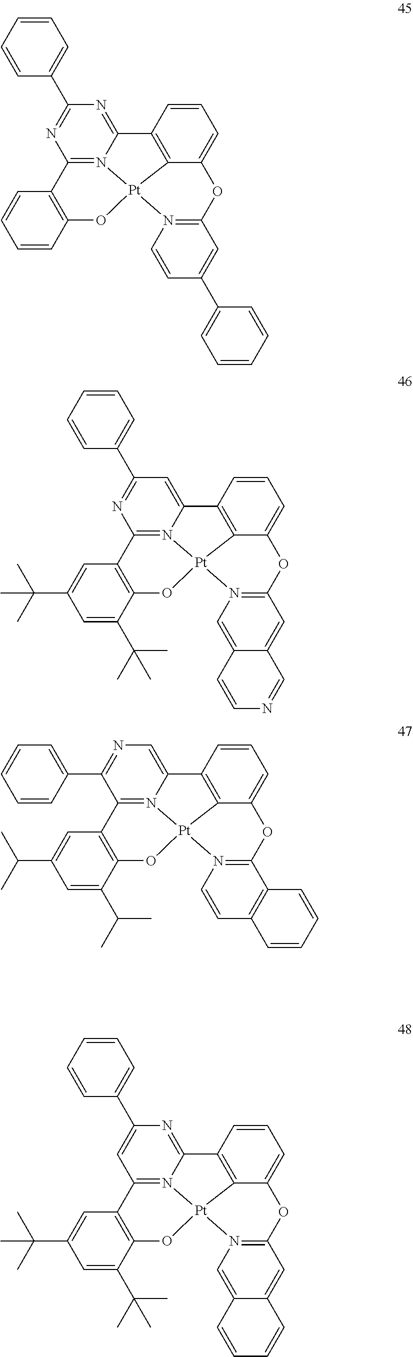

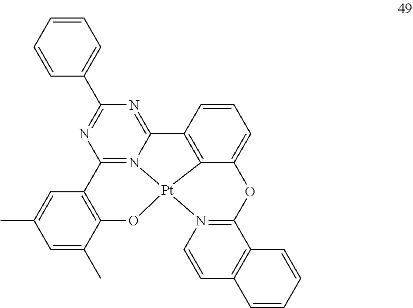

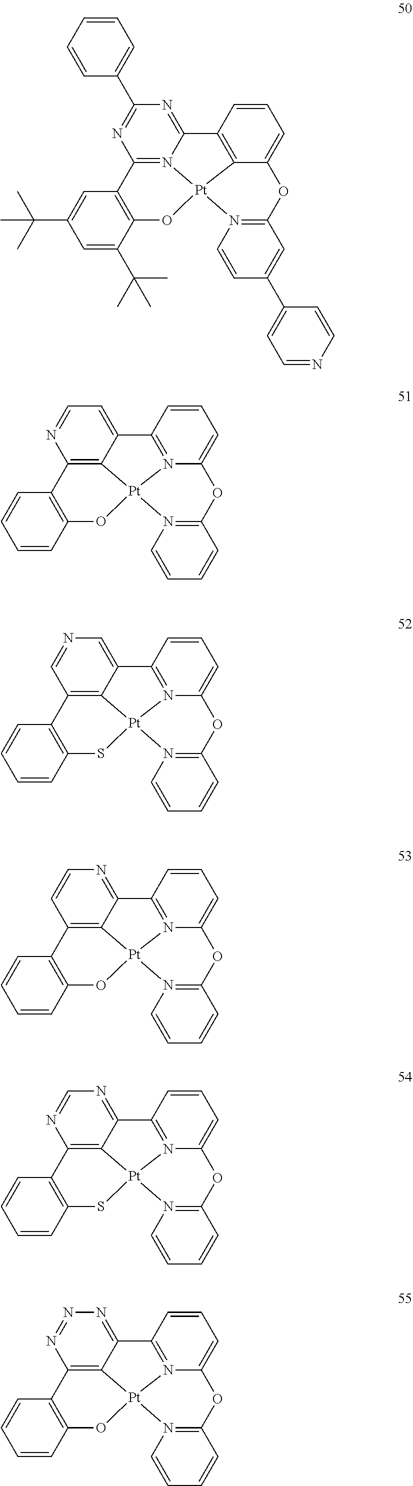

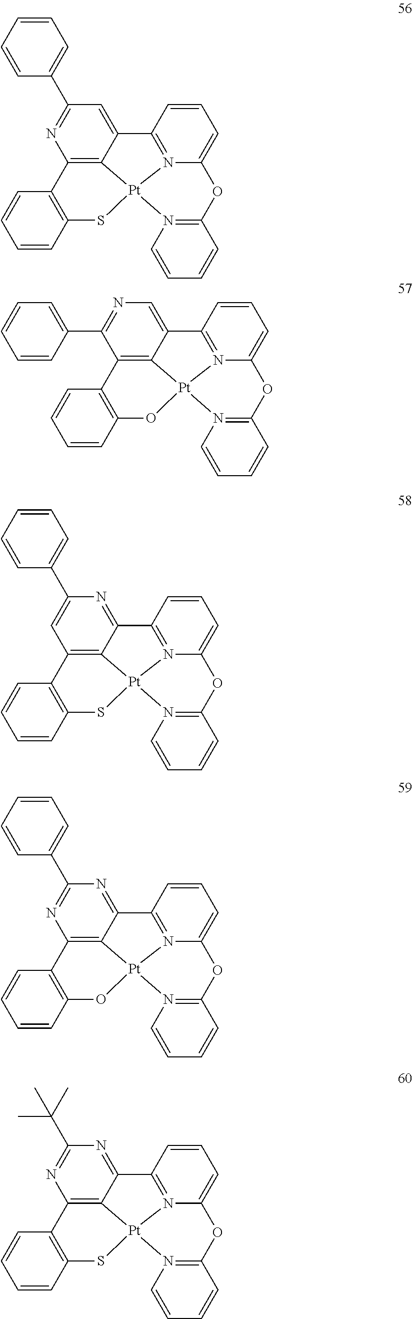

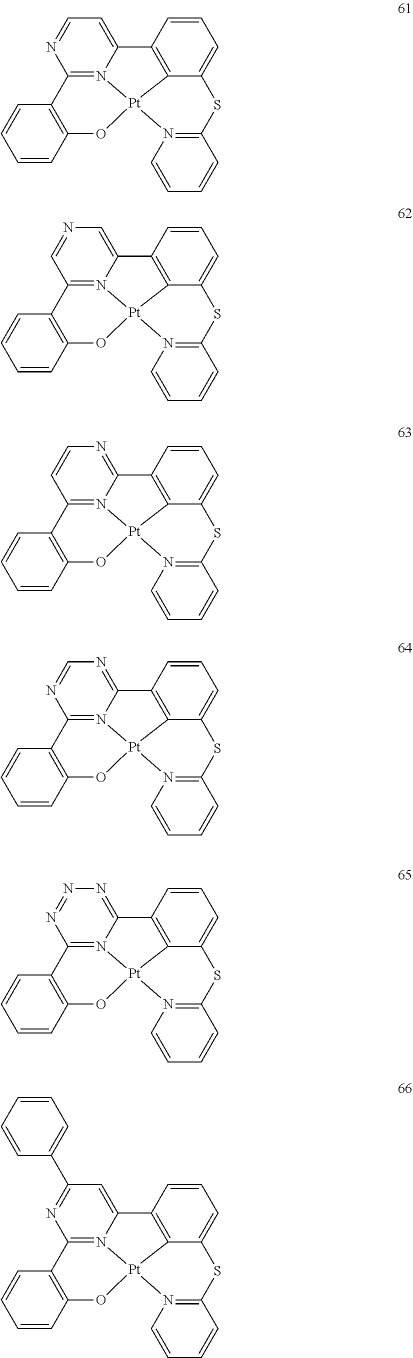

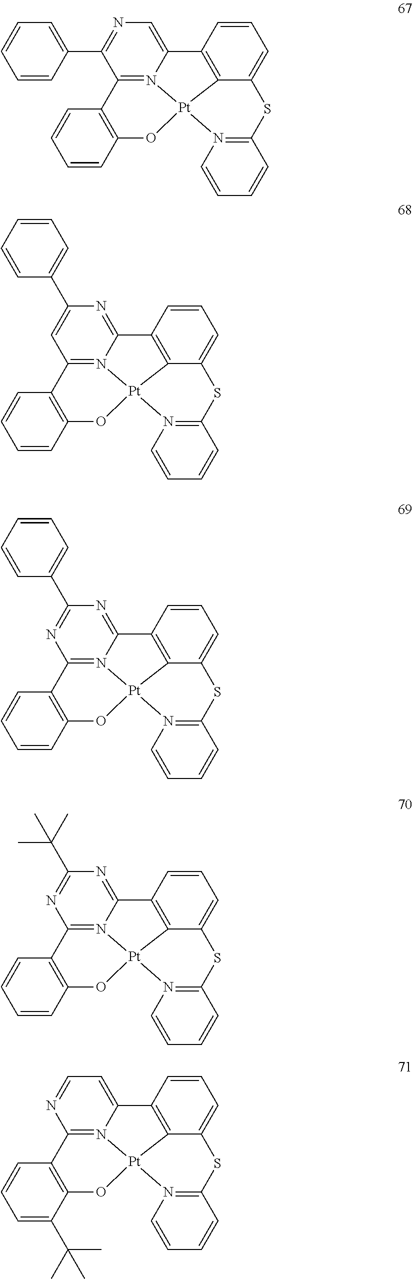

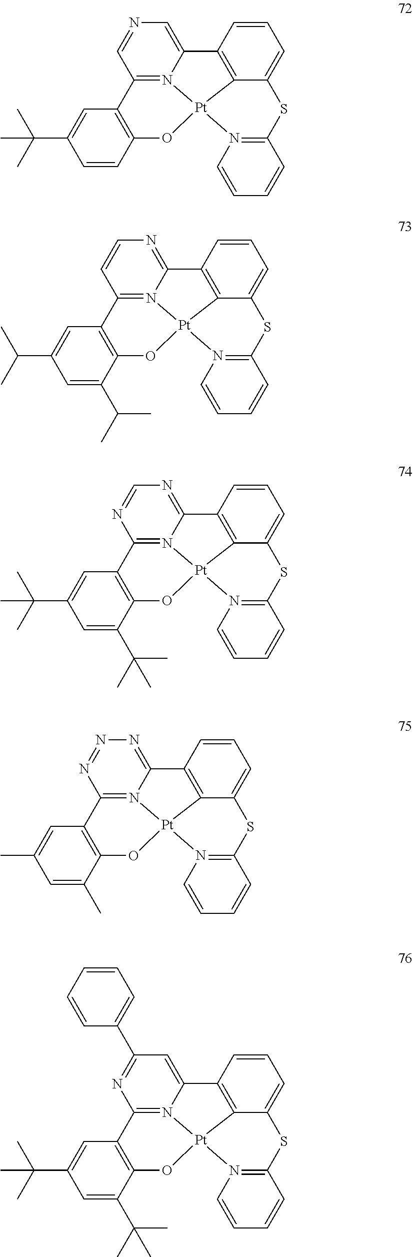

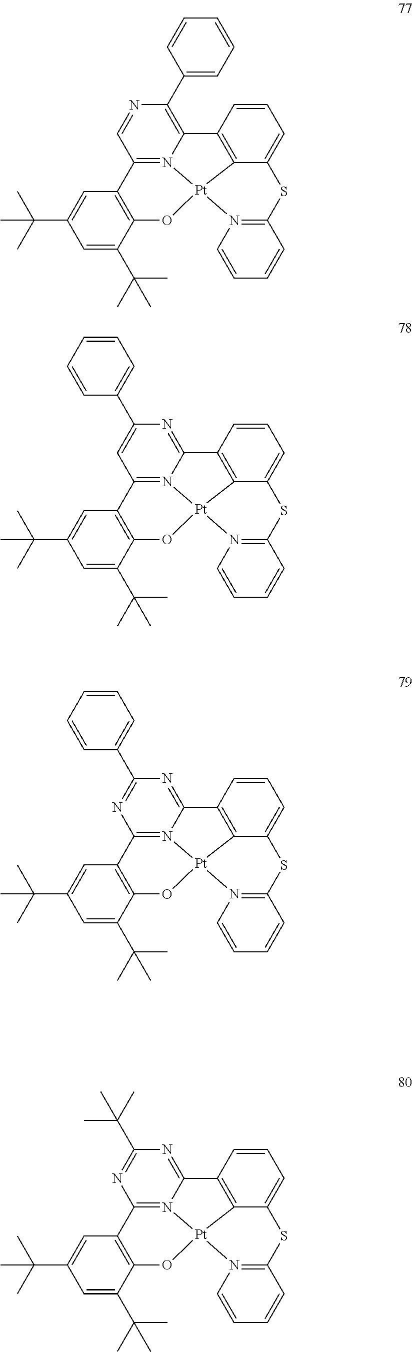

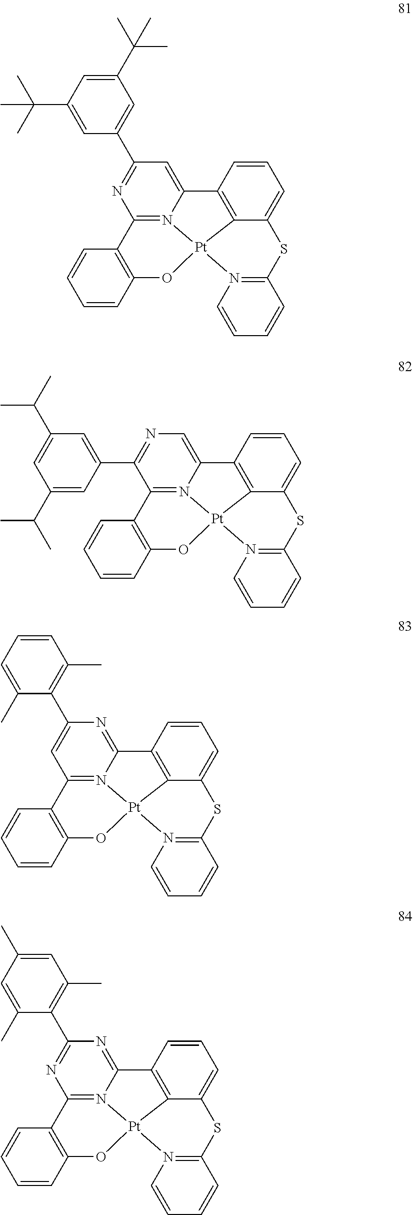

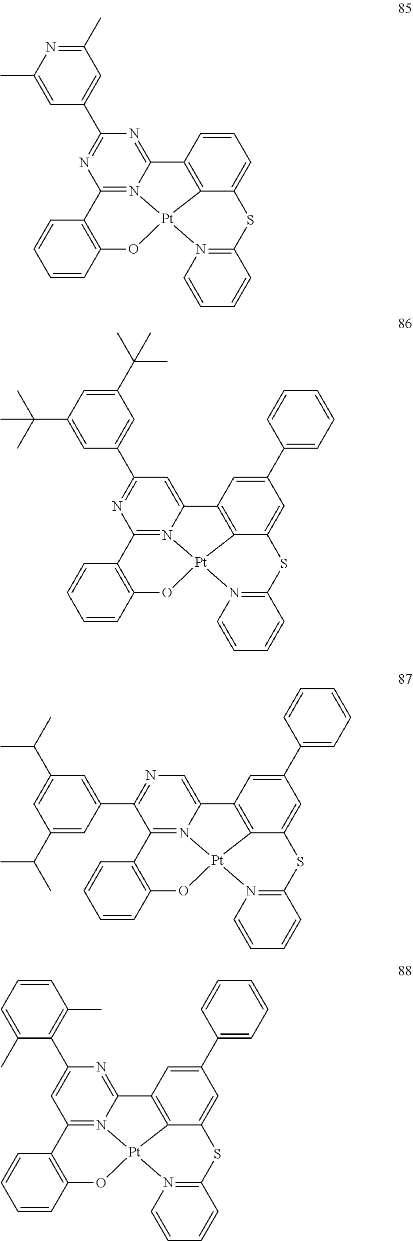

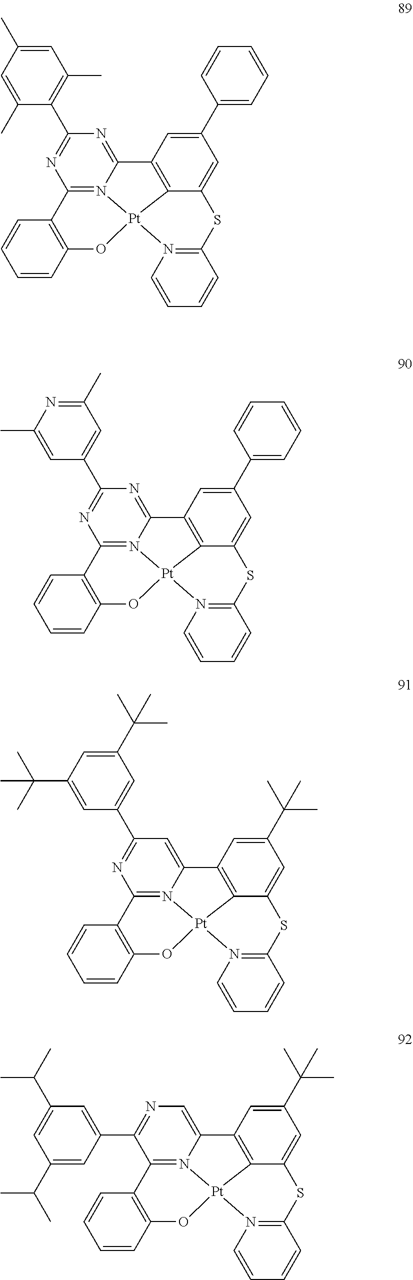

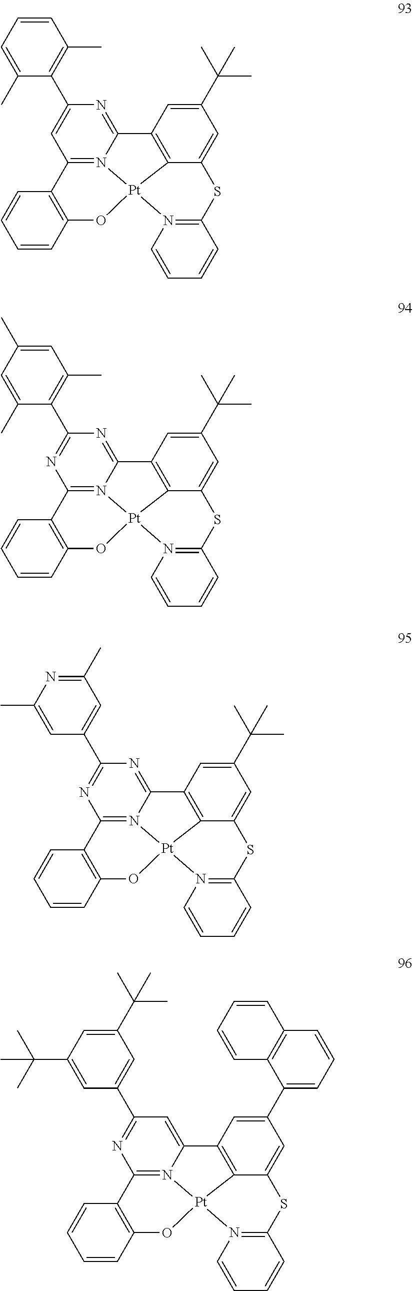

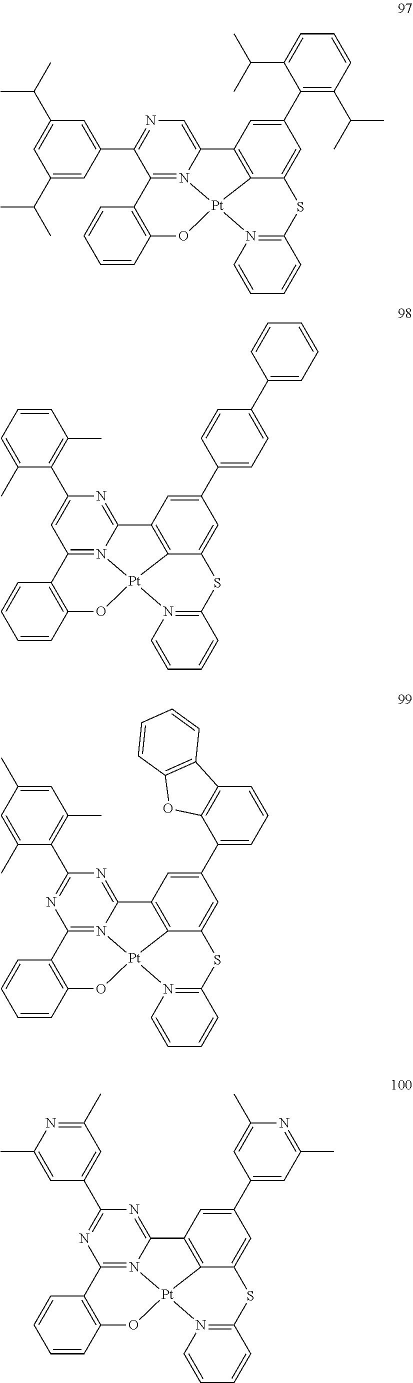

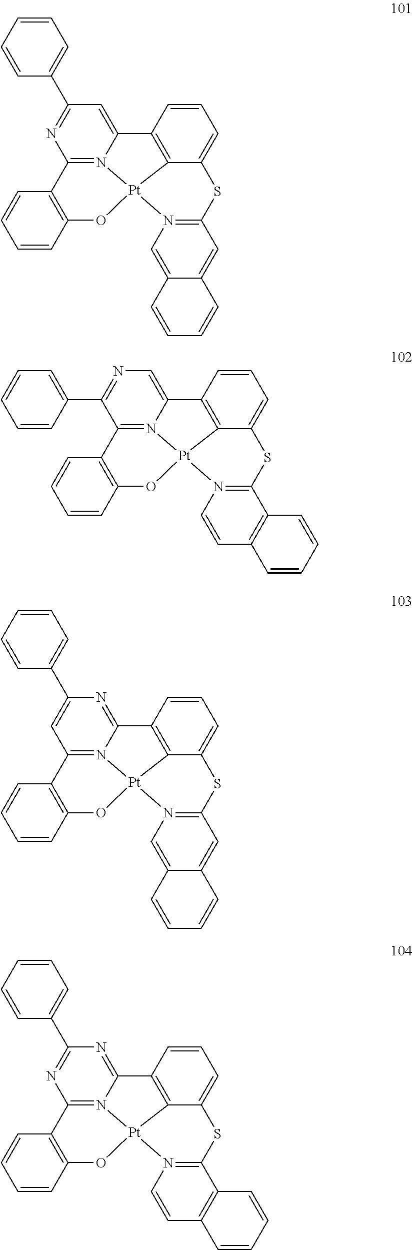

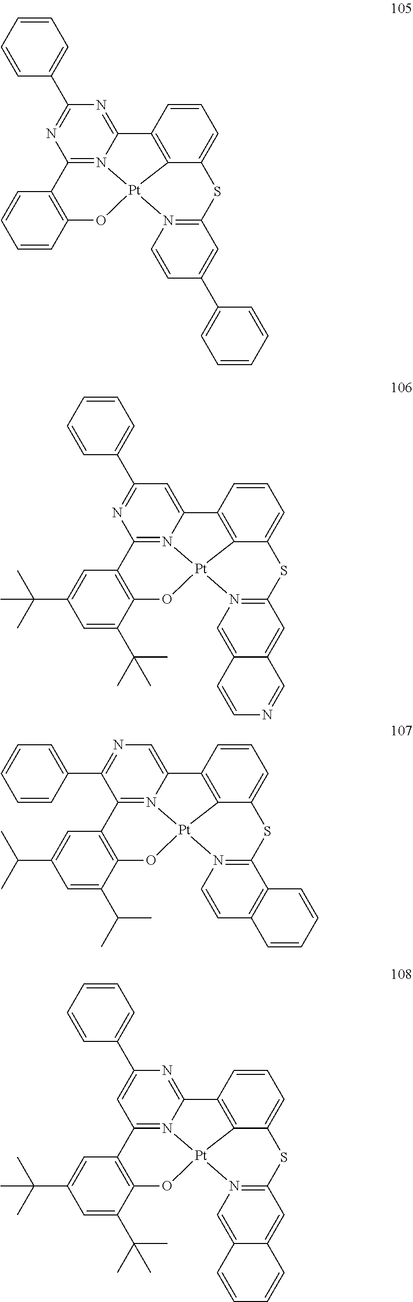

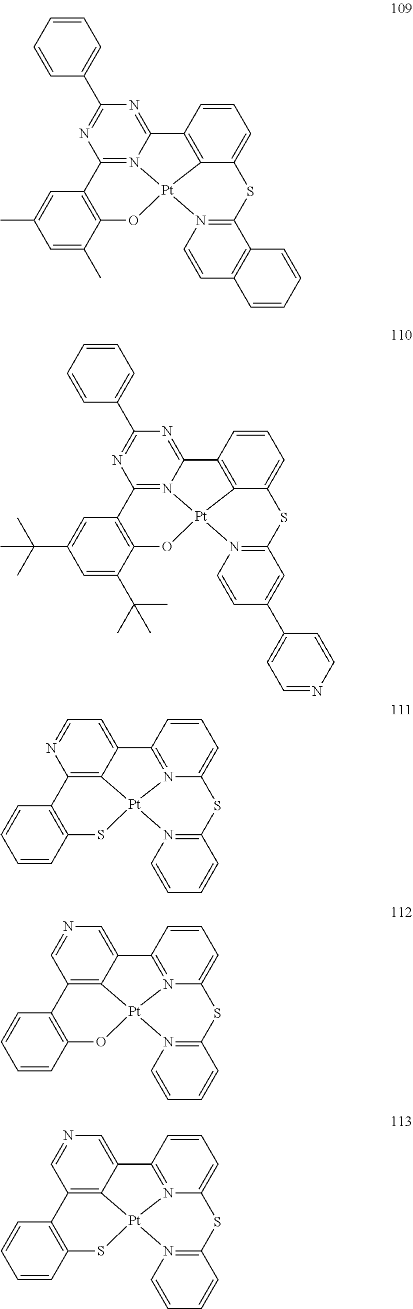

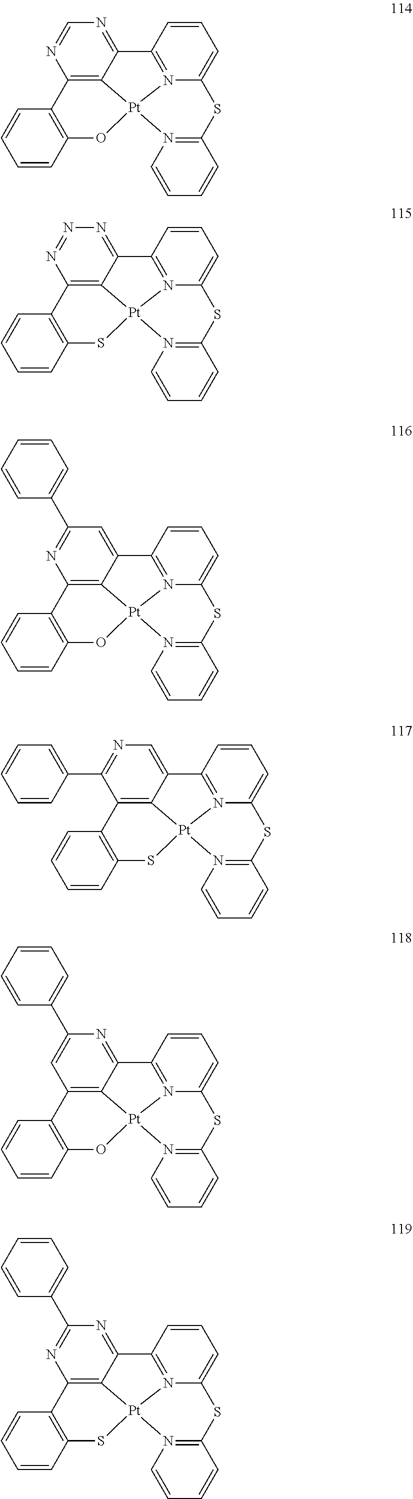

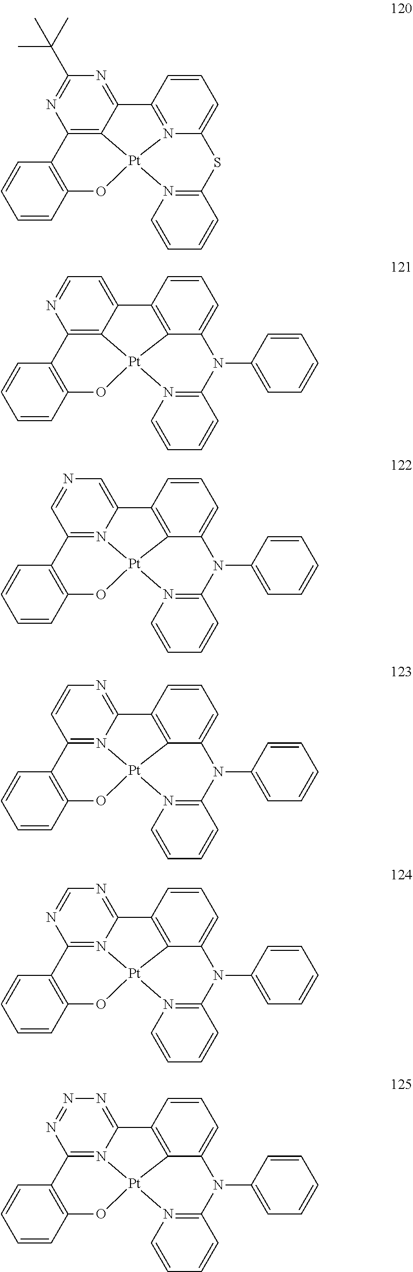

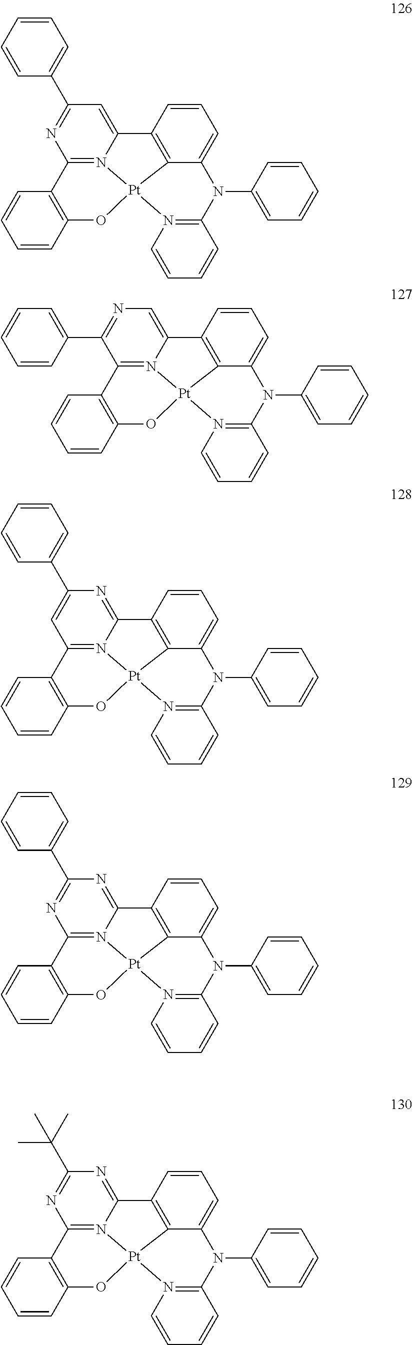

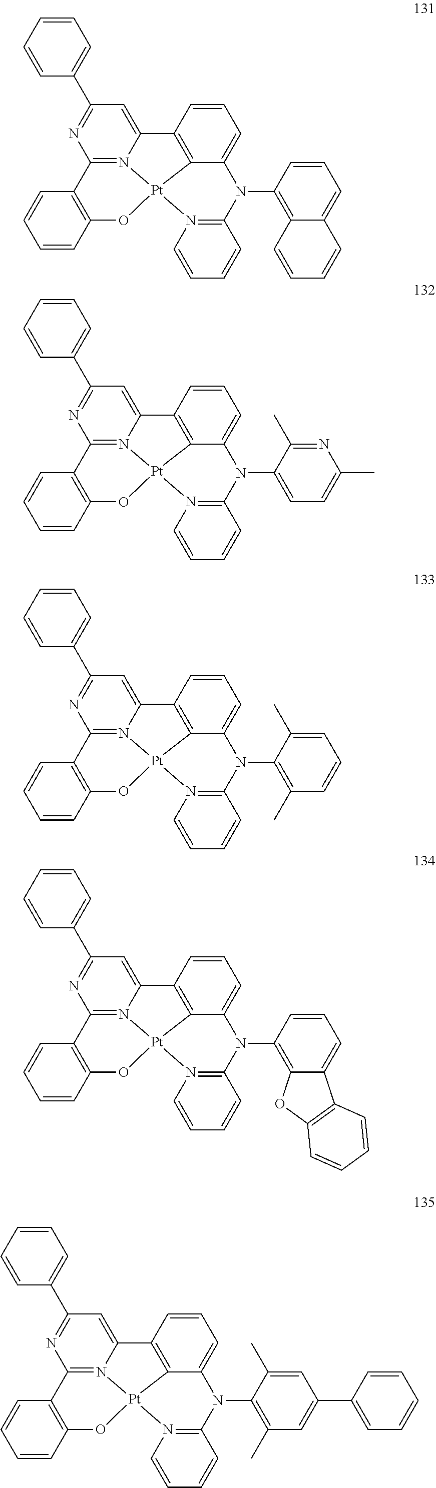

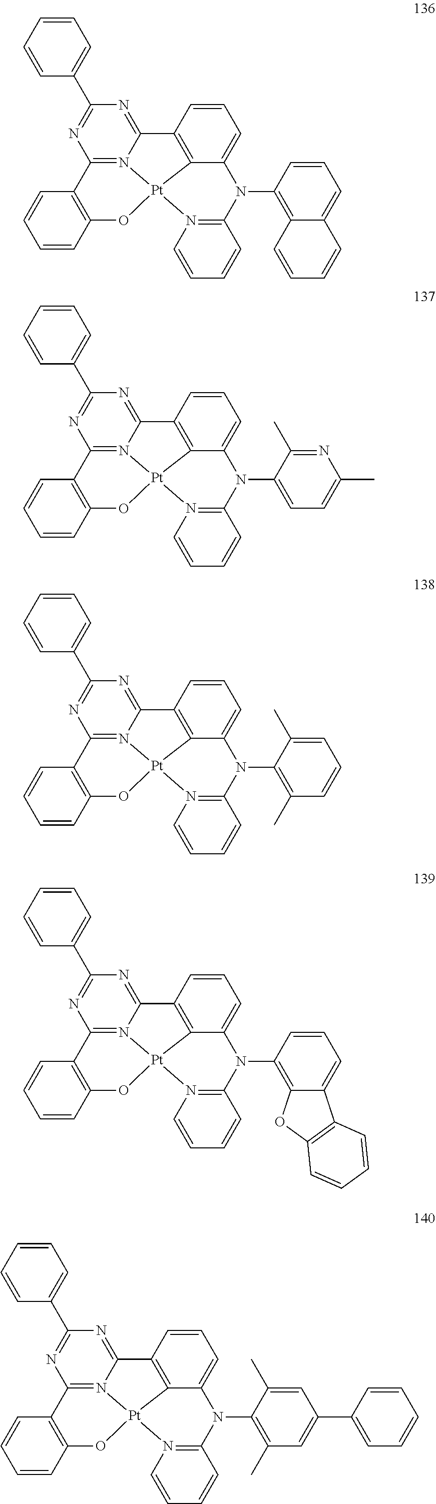

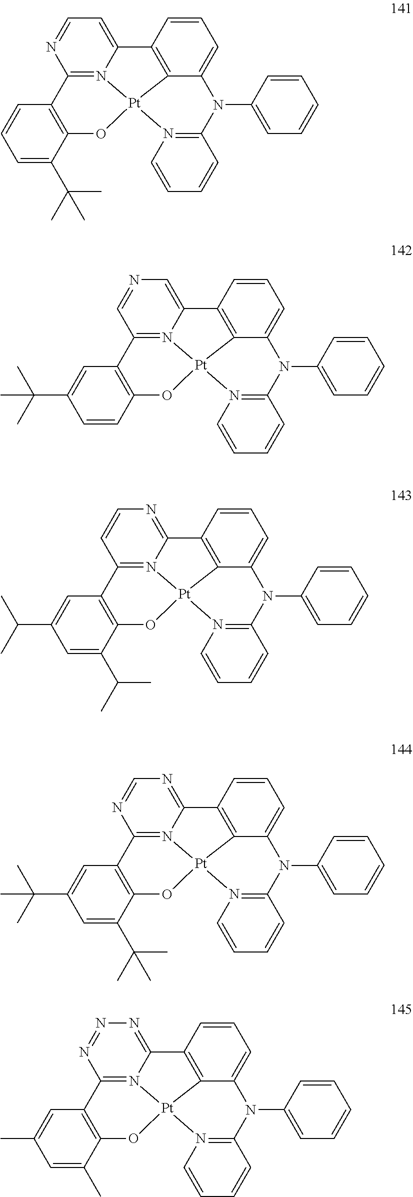

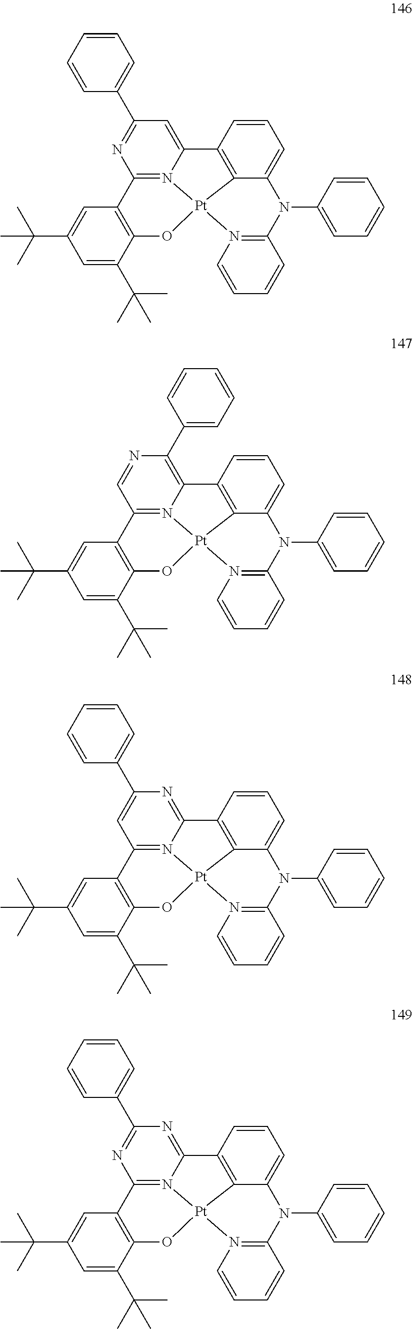

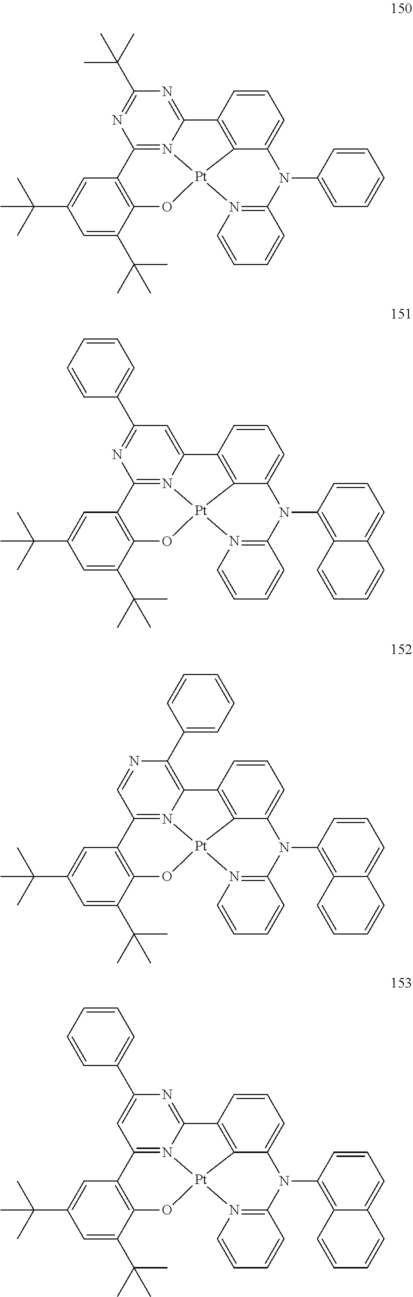

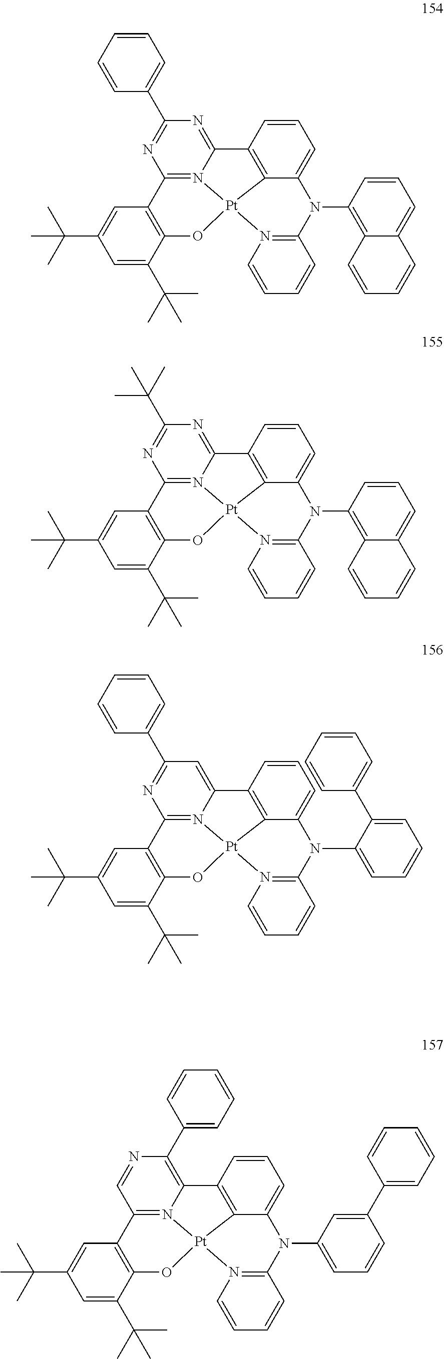

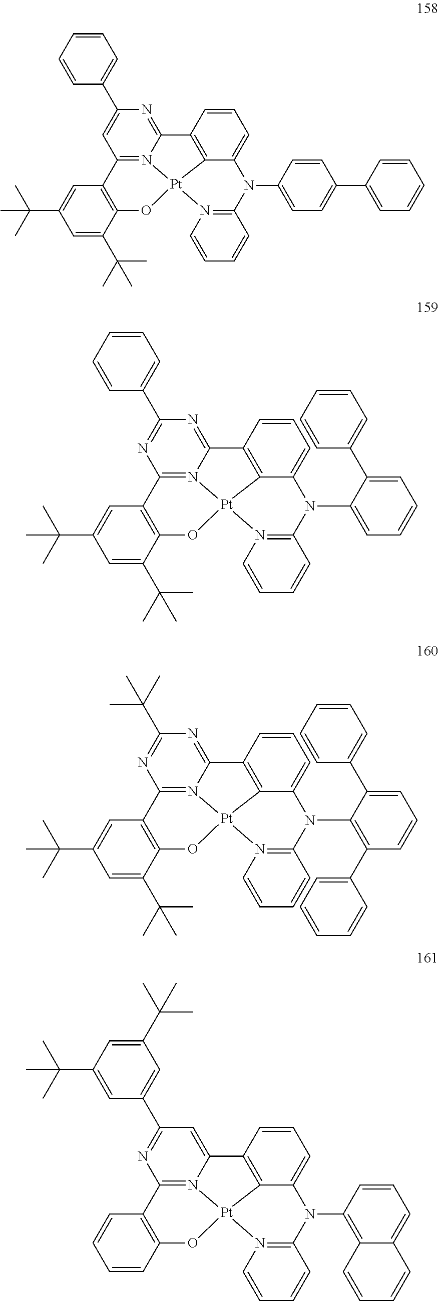

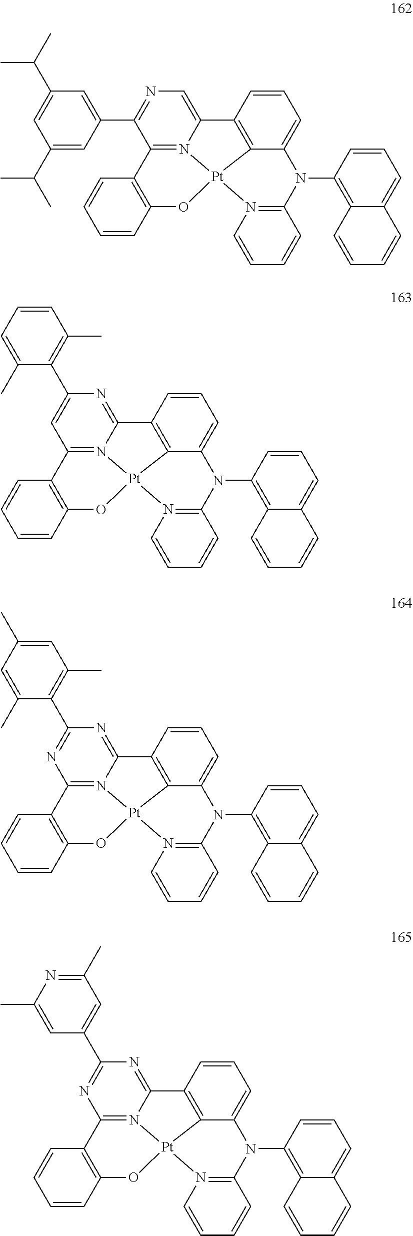

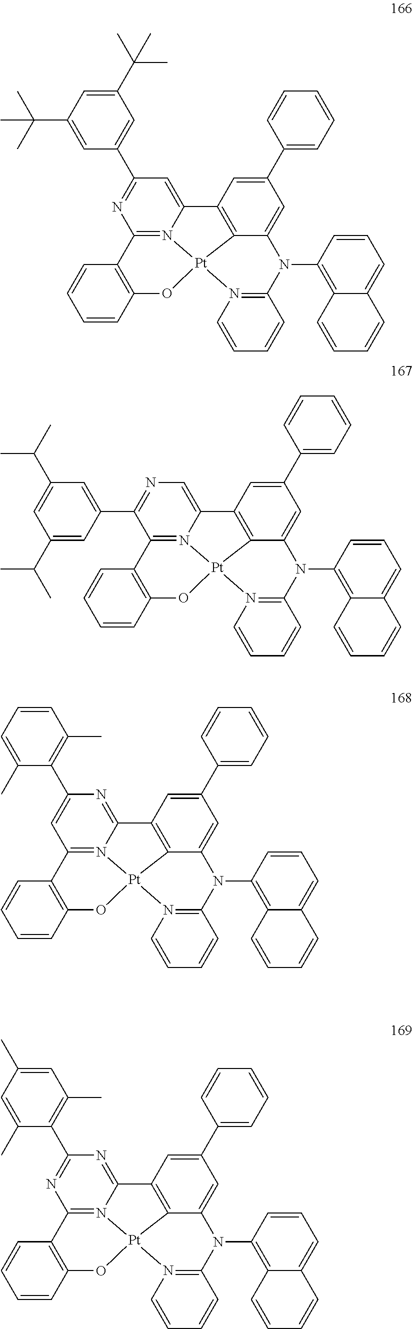

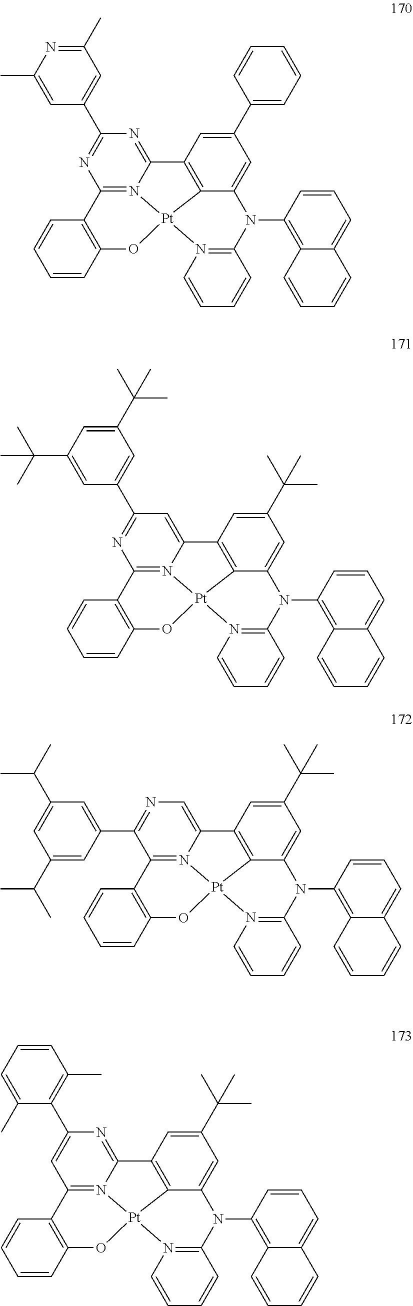

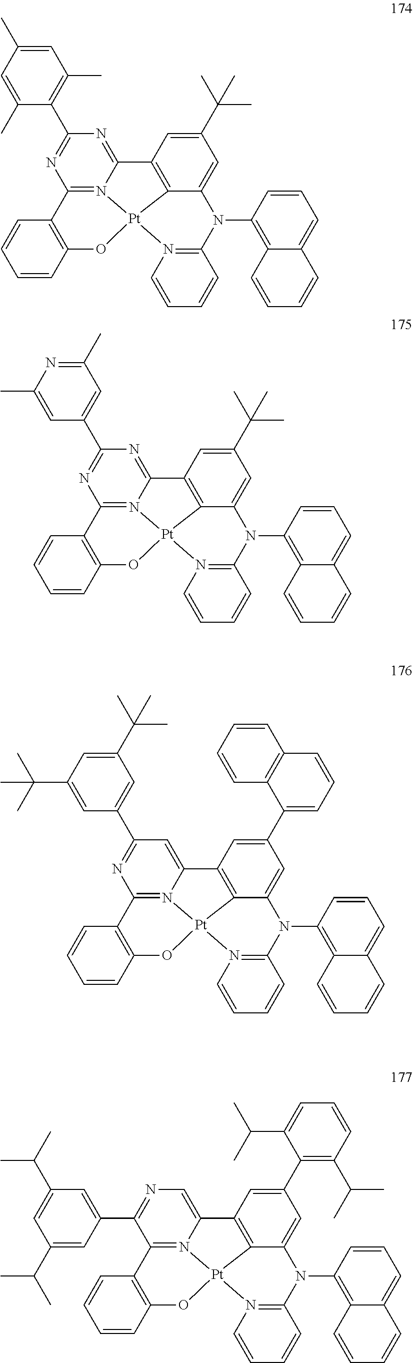

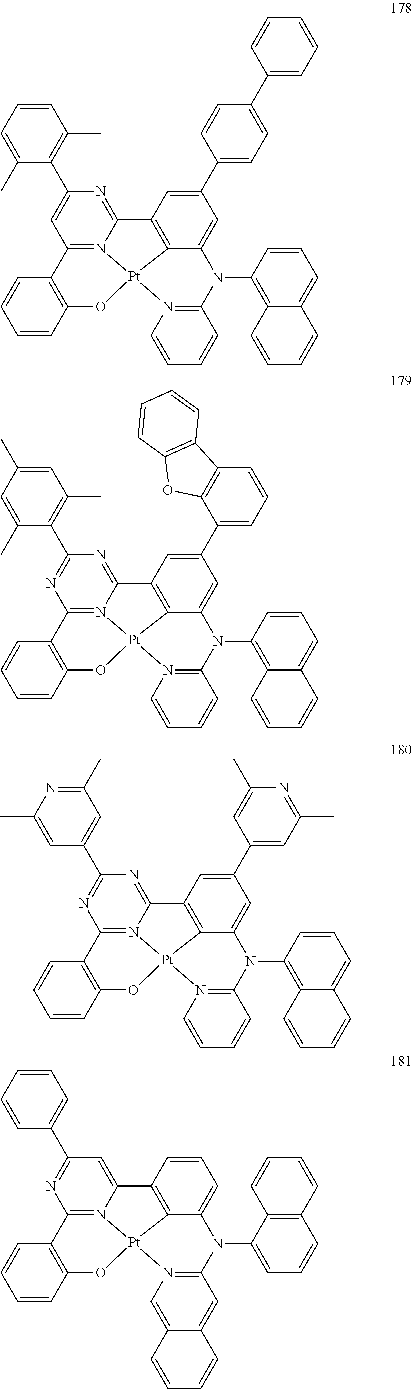

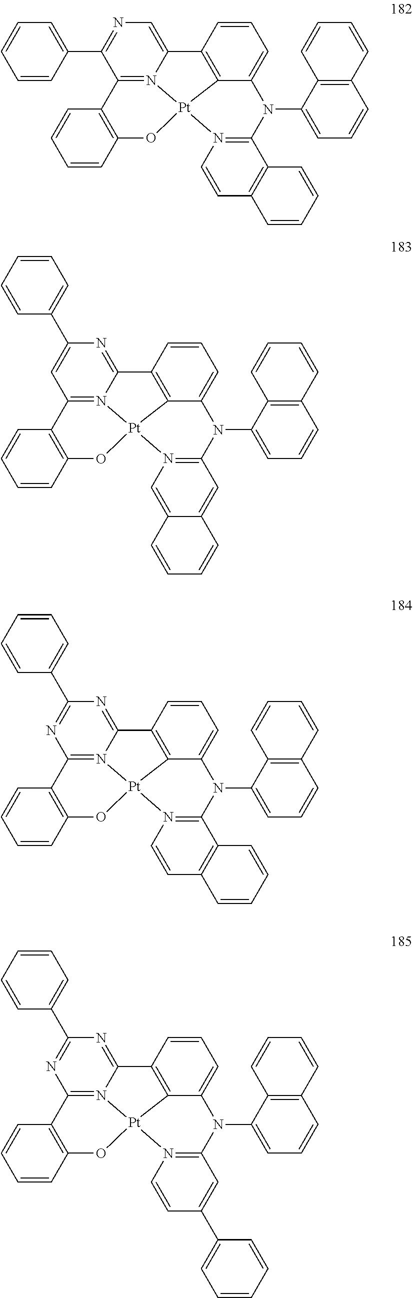

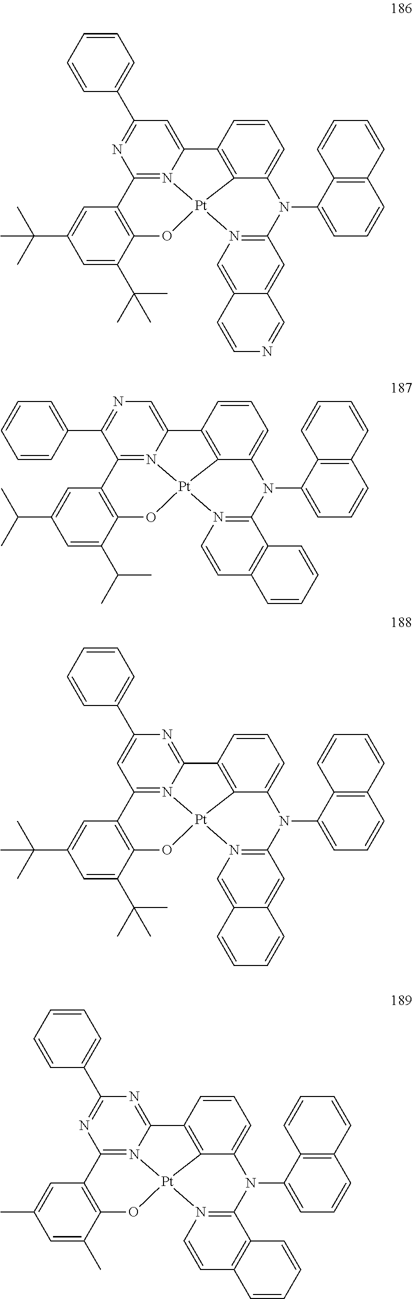

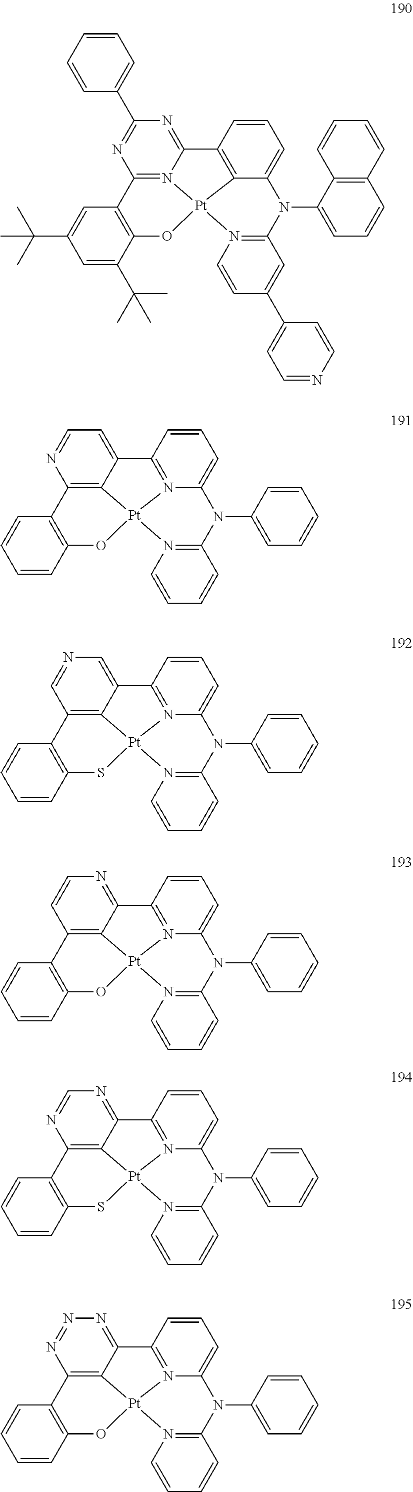

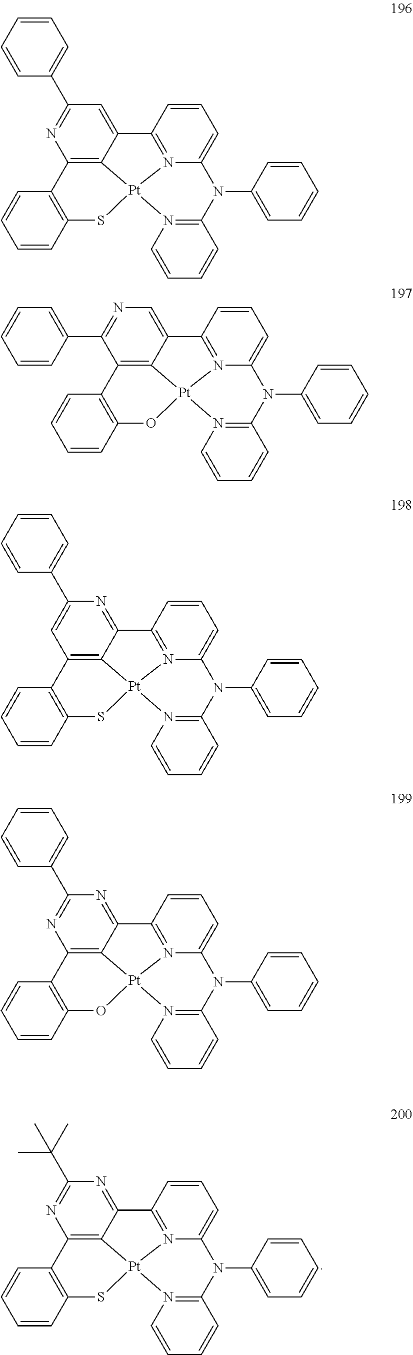

13. An organic light-emitting device comprising:
a first electrode;
a second electrode; and
an organic layer between the first electrode and the second electrode and comprising an emission layer,
wherein the organic layer comprises the organometallic compound of claim 1.

14. The organic light-emitting device of claim 13, wherein
the first electrode is an anode,
the second electrode is a cathode,
the organic layer further comprises a hole transport region between the first electrode and the emission layer and an electron transport region between the emission layer and the second electrode,
the hole transport region comprises a hole injection layer, a hole transport layer, an electron blocking layer, or any combination thereof, and
the electron transport region comprises a hole blocking layer, an electron transport layer, an electron injection layer, or any combination thereof.

15. The organic light-emitting device of claim 13, wherein
the emission layer comprises the organometallic compound.

16. The organic light-emitting device of claim 15, wherein
the emission layer further comprises a host.

17. The organic light-emitting device of claim 16, wherein
the organic light-emitting device emits light generated when a triplet exciton of the organometallic compound transitions to a ground state.

18. The organic light-emitting device of claim 16, wherein
the emission layer further comprises a fluorescent dopant.

19. The organic light-emitting device of claim 18, wherein
a singlet exciton generated in the host is transferred to the organometallic compound and the fluorescent dopant, and
i) a triplet exciton generated in the host and transferred to the organometallic compound and ii) a triplet exciton generated when a singlet exciton transferred to the organometallic compound is transited to a triplet excited state via intersystem crossing, are transferred to a singlet excited state of the fluorescent dopant and transited to a ground state to emit fluorescent light.

20. A diagnostic composition comprising the organometallic compound of claim 1.
